(19) United States
(12) Patent Application Publication
(10) Pub. No.: US 2025/0089554 A1
(43) Pub. Date: Mar. 13, 2025

(54) LIGHT-EMITTING ELEMENT, POLYCYCLIC COMPOUND FOR THE LIGHT-EMITTING ELEMENT, AND DISPLAY DEVICE INCLUDING THE LIGHT-EMITTING ELEMENT

(71) Applicant: Samsung Display Co., Ltd., Yongin-si (KR)

(72) Inventors: YOUNGJIN PARK, Yongin-si (KR); HEECHOON AHN, Yongin-si (KR); HYUNAH UM, Yongin-si (KR); YESEUL LEE, Yongin-si (KR); SEOWON CHO, Yongin-si (KR); MORAN HA, Yongin-si (KR)

(21) Appl. No.: 18/814,245

(22) Filed: Aug. 23, 2024

(30) Foreign Application Priority Data
Aug. 28, 2023 (KR) 10-2023-0112577

(51) Int. Cl. H10K 85/40; C09K 11/02; C09K 11/06; H10K 50/12; H10K 85/30; H10K 85/60

(52) U.S. Cl. CPC H10K 85/40; C09K 11/02; C09K 11/06; H10K 50/12; H10K 85/346; H10K 85/654; H10K 85/6572; H10K 85/6574; H10K 85/658

(57) ABSTRACT

A light-emitting element is provided, the light-emitting element including a first electrode, a second electrode disposed on the first electrode, and a functional layer disposed between the first electrode and the second electrode, the functional layer contains a first compound represented by Formula 1. The light-emitting element may exhibit characteristics of excellent or suitable color reproducibility and long lifespan.

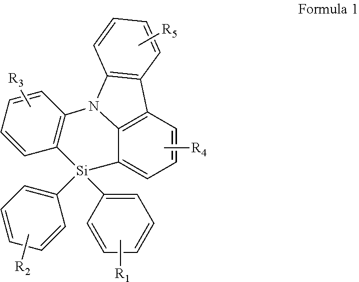

### CROSS-REFERENCE TO RELATED APPLICATIONS

This application claims priority to and the benefit of Korean Patent Application No. 10-2023-0112577, filed on Aug. 28, 2023, in the Korean Intellectual Property Office, the entire content of which is incorporated herein by reference.

### BACKGROUND

### 1. Field

The present disclosure herein relates to a light-emitting element, a polycyclic compound utilized in the same, and a display device including the light-emitting element.

### 2. Description of the Related Art

Recently, organic electroluminescence display devices and/or the like have been actively developed as image display devices. Organic electroluminescence display devices and/or the like are display devices including so-called “self-luminous” type or kind light-emitting elements in which holes and electrons, respectively, injected from a first electrode and a second electrode combine in an emission layer of the display device. Subsequently, a light-emitting material of the emission layer (e.g., light emitting layer), emits light to implement display (e.g., of an image).

The application of light-emitting elements to display devices requires, or there is a desire or demand for, improvements in luminous efficiency, lifespan, and/or the like. Therefore, the need exists for the research and development of materials, e.g., for light-emitting elements, capable of stably attaining such characteristics or desires, and such development is continuously being pursued.

### 1 SUMMARY

One or more aspects of embodiments of the present disclosure are directed toward a light-emitting element having improved luminous efficiency and lifespan.

One or more aspects of embodiments of the present disclosure are directed toward a polycyclic compound that has improved material lifespan.

One or more aspects of embodiments of the present disclosure are directed toward a display device including a light-emitting element, which has improved luminous efficiency and lifespan, to thereby have excellent or suitable display quality.

Additional aspects will be set forth in part in the description which follows and, in part, will be apparent from the description, or may be learned by practice of the presented embodiments of the disclosure.

One or more embodiments of the present disclosure provides a polycyclic compound represented by Formula 1.

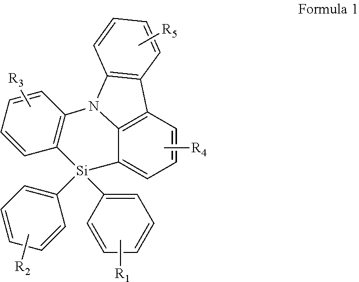

In Formula 1, one or two (e.g., at least one selected from) among R₁ to R₅ may be represented by Formula 2, and the rest (e.g., any remaining selected from among R₁ to R₅) may be a hydrogen atom or a deuterium atom.

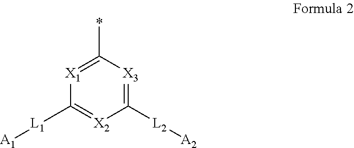

In Formula 2, X₁ to X₃ may each independently be N, CH, or CD, two or more among X₁ to X₃ are N, L1, and L2 may each independently be a direct linkage, a substituted or unsubstituted arylene group having 6 to 30 ring-forming carbon atoms, or a substituted or unsubstituted heteroarylene group having 3 to 30 ring-forming carbon atoms, A₁ and A₂ may each independently be, a substituted or unsubstituted aryl group having 6 to 30 ring-forming carbon atoms, a substituted or unsubstituted heterocyclic group having 3 to 30 ring-forming carbon atoms, or a substituted or unsubstituted silyl group, and

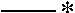 [SMILES: *C]

may be a part connected to Formula 1.

In one or more embodiments, Formula 2 may be represented by Formula 2-1 or Formula 2-2.

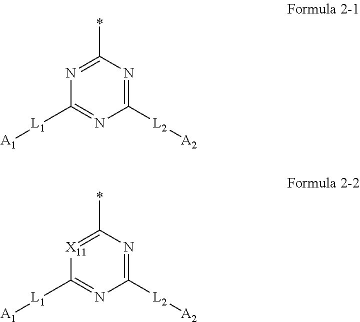

In Formula 2-2, X₁₁ may be CH or CD, and in Formulas 2-1 and Formula 2-2, L₁, L₂, A₁, and A₂ may each independently be as defined in Formula 2.

A₁ and A₂ in Formula 2 may each independently be a substituted or unsubstituted phenyl group, a substituted or unsubstituted carbazole group, a substituted or unsubstituted triphenylsilyl group, or may be represented by Formula SG. For example, when A₁ or A₂ is represented by Formula SG, any (e.g., at least) one ring selected from among C₁ to C₅ rings in Formula SG may be connected to L₁ or L₂.

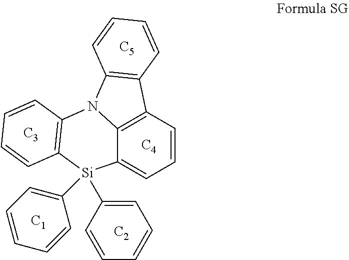

In one or more embodiments, any (e.g., at least) one selected from among A₁ and A₂ may be represented by Formula SG, and the rest (e.g., any remaining selected from among A₁ and A₂) may be a substituted or unsubstituted phenyl group, a substituted or unsubstituted carbazole group, or a substituted or unsubstituted triphenylsilyl group.

In one or more embodiments, L₁ and L₂ in Formula 2 may each independently be a direct linkage, or a substituted or unsubstituted phenylene group.

In one or more embodiments, at least one selected from among hydrogen atoms of a compound represented by Formula 1 may be substituted with a deuterium atom.

In one or more embodiments, the compound represented by Formula 1 may be a phosphorescent host.

In one or more embodiments of the present disclosure, a light-emitting element includes a first electrode, a second electrode arranged on the first electrode, and a functional layer arranged between the first electrode and the second electrode and including (e.g., containing) a first compound represented by Formula 1.

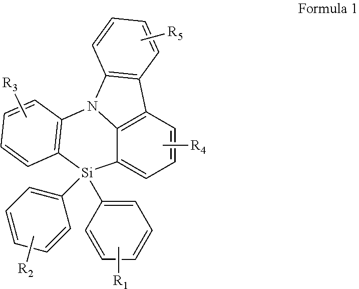

In Formula 1, one or two (e.g., at least one selected from) among R₁ to R₅ may be represented by Formula 2, and the rest (e.g., any remaining selected from among R₁ to R₅) may be a hydrogen atom or a deuterium atom.

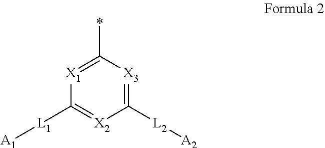

In Formula 2, X₁ to X₃ may each independently be N, CH, or CD, two or more among X₁ to X₃ are N, L₁ and L₂ may each independently be a direct linkage, a substituted or unsubstituted arylene group having 6 to 30 ring-forming carbon atoms, a substituted or unsubstituted heteroarylene group having 3 to 30 ring-forming carbon atoms, A₁ and A₂ may each independently be a substituted or unsubstituted aryl group having 6 to 30 ring-forming carbon atoms, a substituted or unsubstituted heterocyclic group having 3 to 30 ring-forming carbon atoms, or a substituted or unsubstituted silyl group and

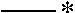 [SMILES: *C]

may be a portion connected to Formula 1.

In one or more embodiments, the functional layer may include an emission layer, a hole transport region arranged between the first electrode and the emission layer, an electron transport region arranged between the emission layer and the second electrode, and at least one selected from among the emission layer and the electron transport region may include (e.g., contain) the first compound.

In one or more embodiments, the emission layer may include the first compound and a phosphorescent dopant.

In one or more embodiments, the emission layer may include the first compound, a second compound represented by Formula D-1, and a third compound represented by Formula HT-1.

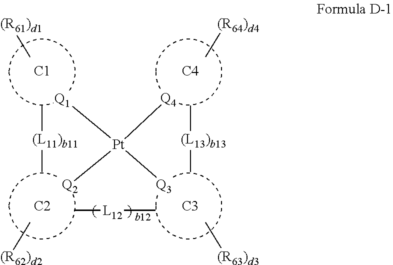

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted hetero ring having 2 to 30 ring-forming carbon atoms, and L₁₁ to L₁₃ may each independently be a direct linkage,

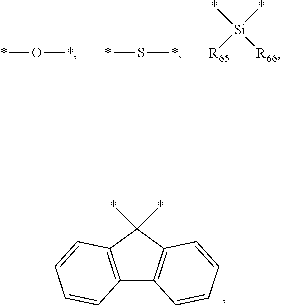

a substituted or unsubstituted divalent alkyl having 1 to 20 carbon atoms, a substituted or unsubstituted arylene group having 6 to 30 ring-forming carbon atoms, or a substituted or unsubstituted heteroarylene group having 2 to 30 ring-forming carbon atoms. b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4:

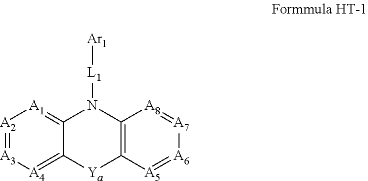

In Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, and Ar₁ may be a substituted or unsubstituted aryl group having 6 to 30 ring-forming carbon atoms, or a substituted or unsubstituted heteroaryl group having 2 to 30 ring-forming carbon atoms. R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or may be connected to an adjacent group to form a ring.

In one or more embodiments, the emission layer may further include a fourth compound represented by Formula F-1.

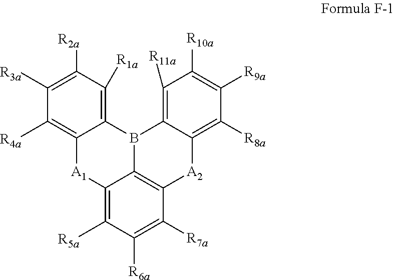

where, in Formula F-1, A₁ and A₂ may each independently be O, S, Se, or NRₘ, Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁ₐ to R₁₁ₐ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, the emission layer may be to emit blue light.

In one or more embodiments, Formula 2 may be represented by Formula 2-1 or Formula 2-2.

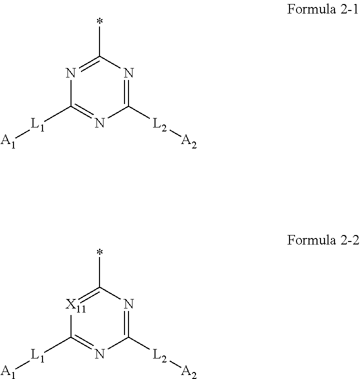

In Formula 2-2, X₁₁ may be CH or CD, and in Formula 2-1 and Formula 2-2, L₁, L₂, A₁, and A₂ may each independently be as defined in Formula 2.

In one or more embodiments of the present disclosure, a display device includes a base layer, a circuit layer arranged on the base layer, and a display device layer arranged on the circuit layer and including a light-emitting element. The light-emitting element includes a first electrode, a second electrode facing the first electrode, and an emission layer arranged between the first electrode and the second electrode, and including (e.g., containing) the polycyclic compound according to a described embodiment.

In one or more embodiments, the light-emitting element may be to emit blue light.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device according to one or more embodiments of the present disclosure;

FIG. 2 is a cross-sectional view illustrating a portion taken along the line I-I′ in FIG. 1;

FIG. 3 is a cross-sectional view schematically illustrating a light-emitting element according to one or more embodiments of the present disclosure;

FIG. 4 is a cross-sectional view schematically illustrating a light-emitting element according to one or more embodiments of the present disclosure;

FIG. 5 is a cross-sectional view schematically illustrating a light-emitting element according to one or more embodiments of the present disclosure;

FIG. 6 is a cross-sectional view schematically illustrating a light-emitting element according to one or more embodiments of the present disclosure;

FIG. 7 is a cross-sectional view schematically illustrating a light-emitting element according to one or more embodiments of the present disclosure;

FIG. 8 is a cross-sectional view illustrating a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure;

FIG. 11 is a cross-sectional view illustrating a display device according to one or more embodiments of the present disclosure; and

FIG. 12 is a view illustrating an inside of a vehicle in which a display device according to one or more embodiments is arranged;

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements, and duplicative descriptions thereof may not be provided. In the accompanying drawings, the dimensions of each structure are exaggeratingly illustrated for clarity of the present disclosure.

It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise.

In the present application, it will be understood that the terms “include,” “includes,” “including,” “comprise,” “comprises”, “comprising,” “has,” “having,” and/or “have” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. It will be understood that when a part is referred to as being “on” another part, it can be arranged above the other part, or arranged under the other part as well.

For example, the terms, such as “lower”, “above”, “upper” and/or the like, are utilized herein for ease of description to describe one element's relation to another element(s) as illustrated in the drawings. The terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition, but the “component” of less than a suitable amount may still be included due to other impurities and/or external factor.

### Definitions

In the specification, the term “substituted or unsubstituted” may refer to substituted with at least one substituent of (e.g., selected from among) the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group, or unsubstituted. In one or more embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In one or more embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

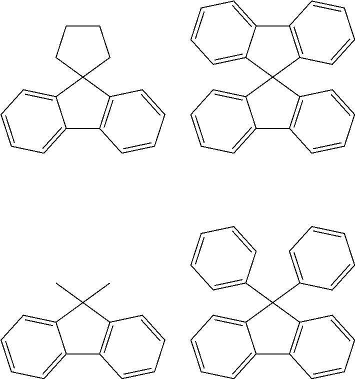

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the preceding description of the aryl group may be applied to an arylene group except that the arylene group is a divalent group. The preceding description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

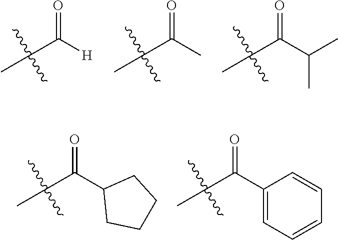

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In one or more embodiments, in the specification, and

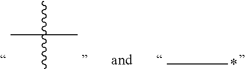

refer to a position to be connected.

Hereinafter, embodiments of the present disclosure will be described with reference to the accompanying drawings.

### Display Device

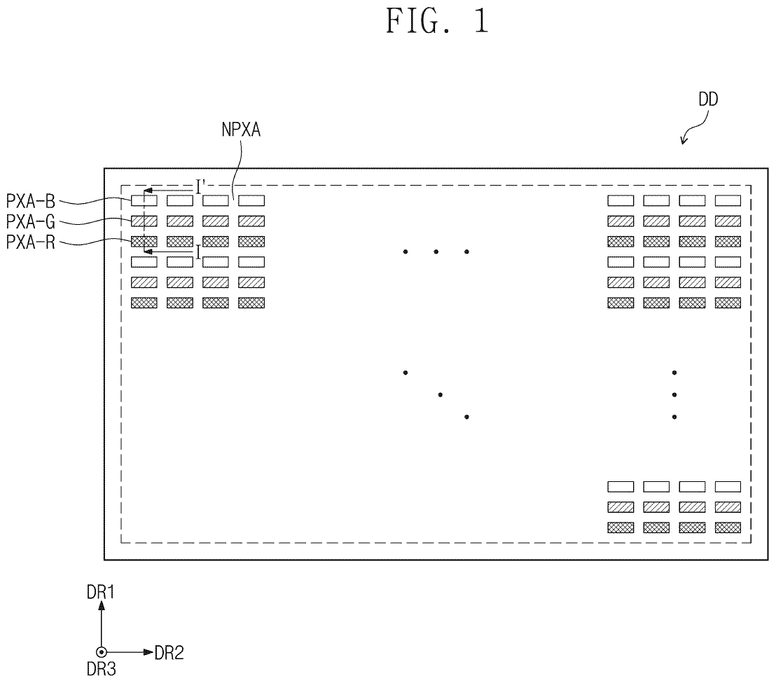

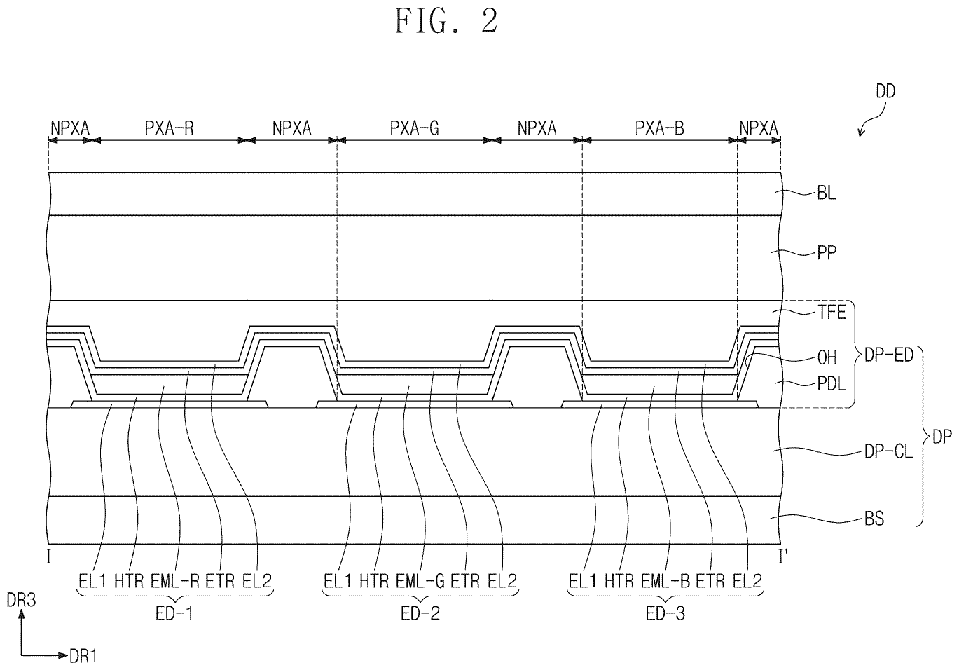

FIG. 1 is a plan view illustrating one or more embodiments of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP arranged on the display panel DP. The display panel DP includes light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer or a color filter layer. In one or more embodiments, unlike the configuration illustrated in the drawing, the optical layer PP may not be provided from the display device DD of one or more embodiments.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In one or more embodiments, unlike the configuration illustrated, in one or more embodiments, the base substrate BL may not be provided.

The display device DD according to one or more embodiments may further include a filling layer. The filling layer may be arranged between a display device layer DP-ED and the base substrate BL. The filling layer may be an organic material layer. The filling layer may include at least one of an acrylic-based resin, a silicone-based resin, or an epoxy-based resin (e.g., at least one selected from among an acrylic-based resin, a silicone-based resin, and an epoxy-based resin).

The display panel DP may include a base layer BS, a circuit layer DP-CL provided on the base layer BS, and the display device layer DP-ED. The display device layer DP-ED may include a pixel defining layer PDL, the light emitting elements ED-1, ED-2, and ED-3 arranged between portions of the pixel defining layer PDL, and an encapsulation layer TFE arranged on the light emitting elements ED-1, ED-2, and ED-3.

The base layer BS may be a member which provides a base surface on which the display device layer DP-ED is arranged. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is arranged on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

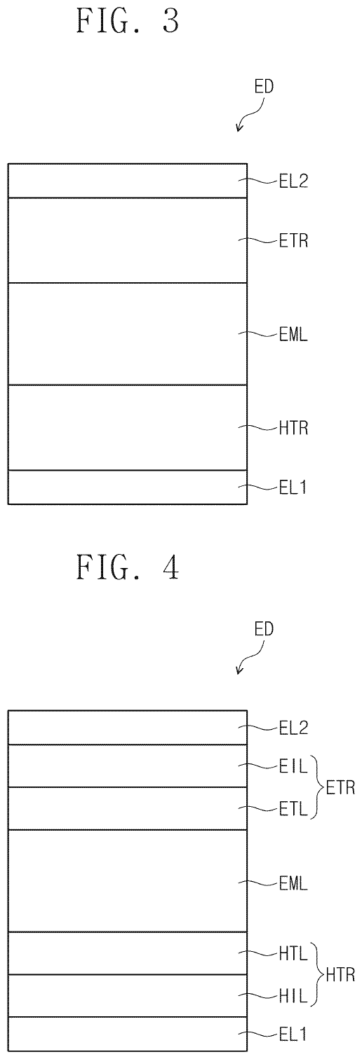

Each of the light emitting elements ED-1, ED-2, and ED-3 may have a structure of each light emitting element ED of embodiments according to FIGS. 3 to 7, as described in more detail elsewhere herein. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are arranged in openings OH defined in the pixel defining layer PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining layer PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be arranged on the second electrode EL2 and may be arranged filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting elements ED-1, ED-2, and ED-3 are emitted. The light emitting regions PXA-R, PXA-G, and PXA-B may be spaced and/or apart from each other on a plane (e.g., in a plan view).

Each of the light emitting regions PXA-R, PXA-G, and PXA-B may be a region divided (i.e., defined) by the pixel defining layer PDL. The non-light emitting areas NPXA may be areas between the adjacent light emitting areas PXA-R, PXA-G, and PXA-B, which correspond to the pixel defining layer PDL. In one or more embodiments, in the specification, the light emitting regions PXA-R, PXA-G, and PXA-B may respectively correspond to pixels. The pixel defining layer PDL may divide the light emitting elements ED-1, ED-2, and ED-3. The emission layers EML-R, EML-G, and EML-B of the light emitting elements ED-1, ED-2, and ED-3 may be arranged in openings OH defined in the pixel defining layer PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In one or more embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, the arrangement form of the light emitting regions PXA-R, PXA-G, and PXA-B may be a pentile (PENTILE™) arrangement form or a diamond (Diamond Pixel™) arrangement form, (PENTILE™ and Diamond Pixel™ are registered trademarks owned by Samsung Display Co., Ltd.).

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIGS. 3 to 7 are cross-sectional views schematically illustrating light emitting elements according to one or more embodiments. Each of the light emitting elements ED according to one or more embodiments may include a first electrode EL1, a hole transport region HTR, an emission layer EML, an electron transport region ETR, and a second electrode EL2 that are sequentially stacked.

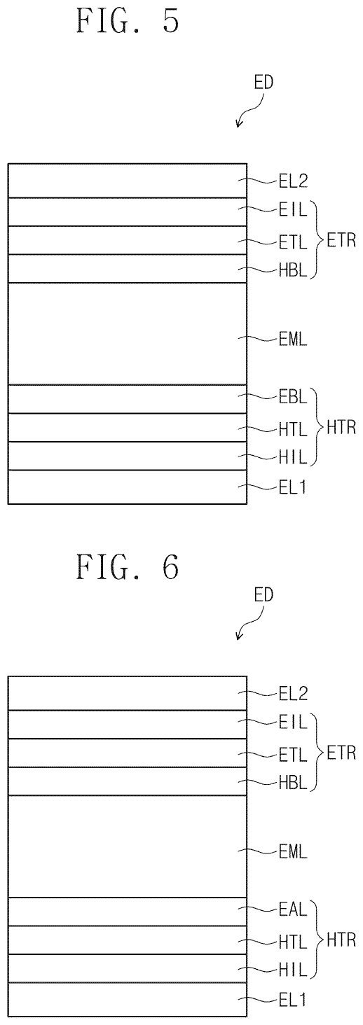

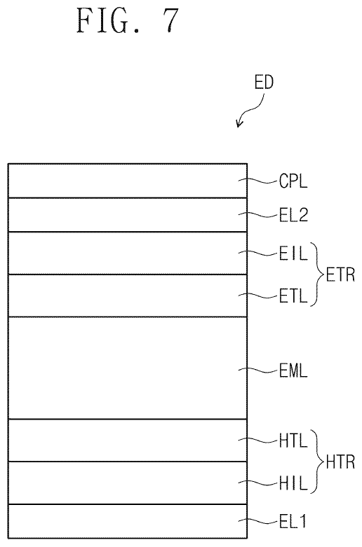

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In one or more embodiments, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. As compared with FIG. 3, FIG. 6 illustrates a cross-sectional view of a light emitting element ED of one or more embodiments, in which a hole transport region HTR includes a hole injection layer HIL, a hole transport layer HTL, and an emission-auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light emitting element ED of one or more embodiments including a capping layer CPL arranged on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these (thereof), a mixture of two or more selected from among these (thereof), and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a (e.g., any suitable) compound or mixture thereof (e.g., a mixture of Ag and Mg). In one or more embodiments, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In one or more embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, an emission-auxiliary layer EAL, or an electron blocking layer EBL. The thickness of the hole transport region HTR may be, for example, from about 50 Å to about 15,000 Å. The emission-auxiliary layer EAL may be referred to as a buffer layer.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or

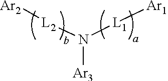

unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In one or more embodiments, the compound represented by Formula H-1 may be a diamine compound in which at least one among Ar₁ to Ar₃ includes the amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar or Ar₂.

The compound represented by Formula H-1 may be represented by any one (e.g., one) selected from among the compounds in Compound Group H. However, the compounds listed in Compound Group H are examples, and the compounds represented by Formula H-1 are not limited to those represented by Compound Group H.

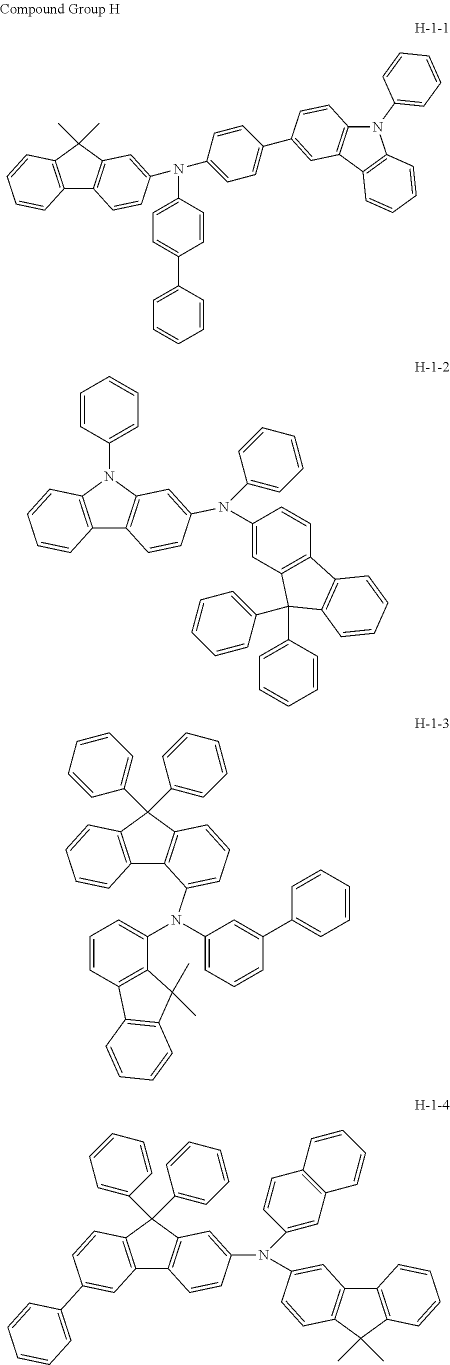 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

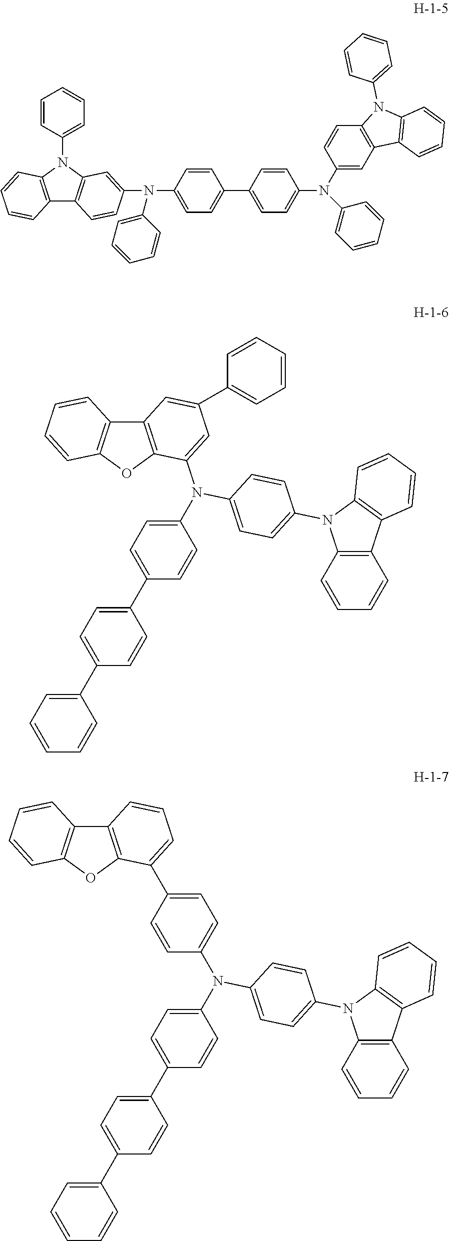 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

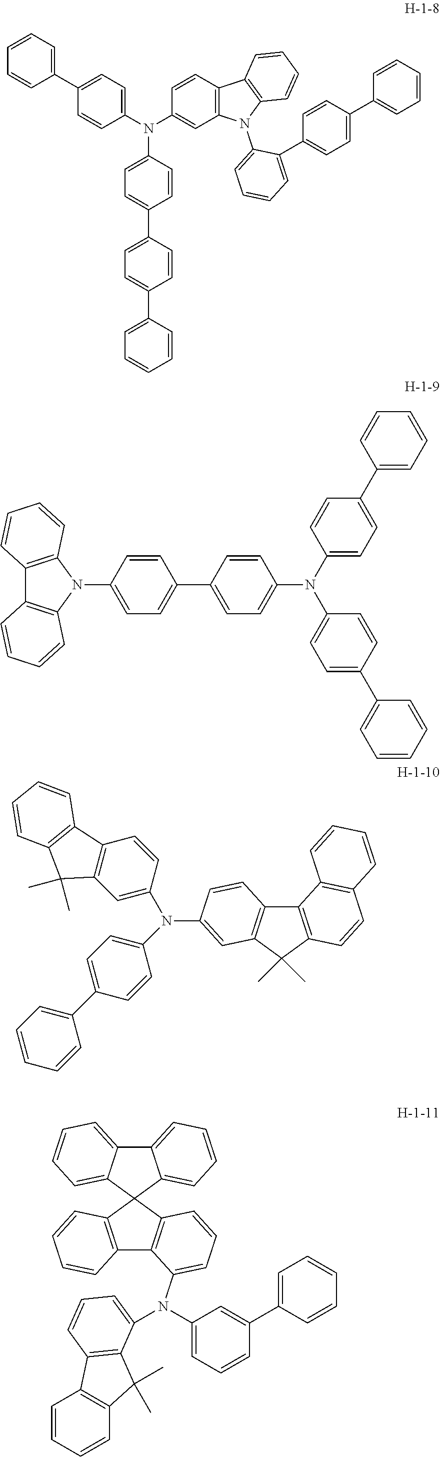 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

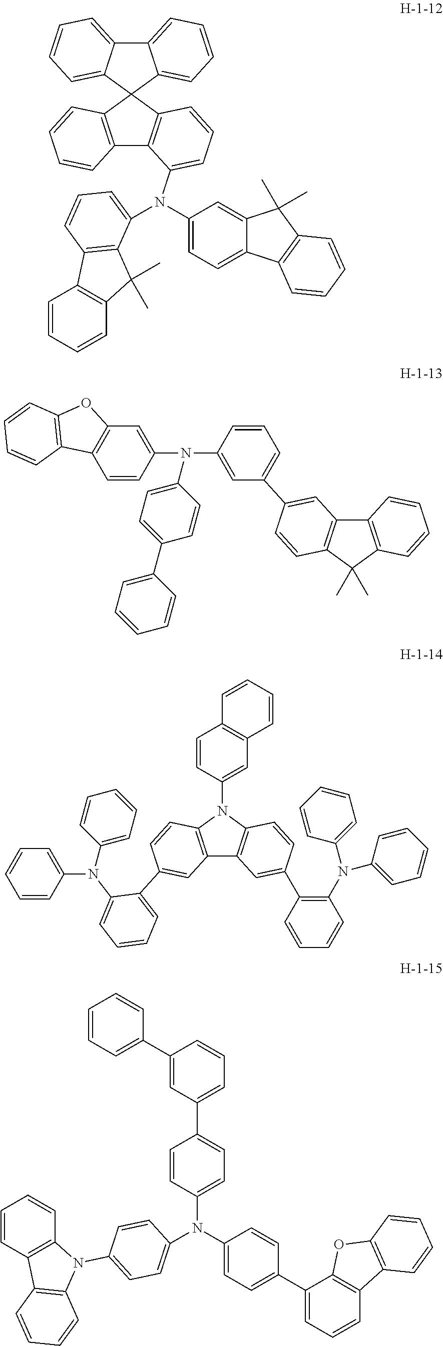 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

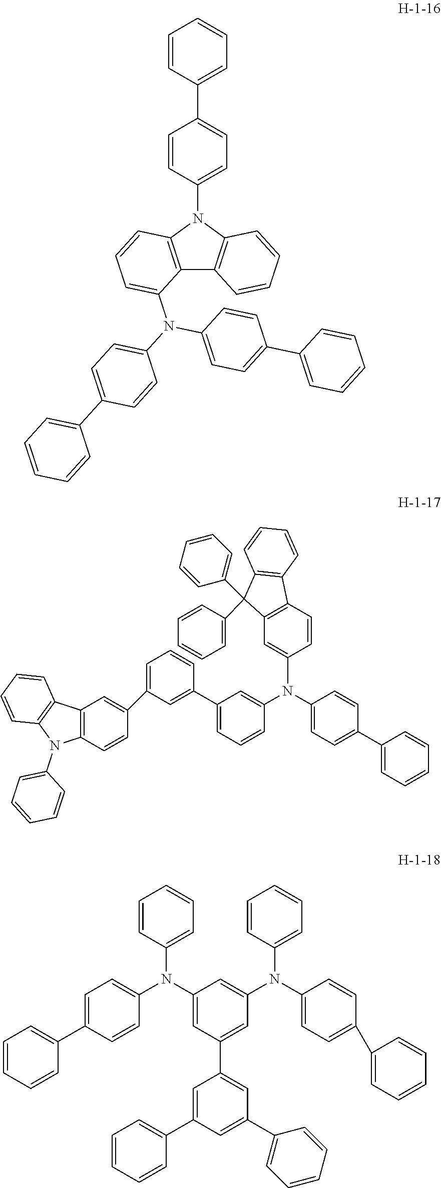 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

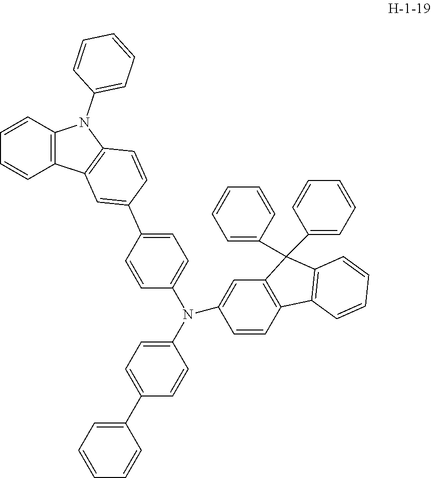 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include at least one selected from among a phthalocyanine compound such as copper phthalocyanine; N¹,N^{1′}-([1,1′-biphenyl]-4,4′-diyl)bis(N¹-phenyl-N4,N4-di-m-tolylbenzene-1,4-diamine) (DNTPD), 4,4′,4″-[tris(3-methyl phenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, an emission-auxiliary layer EAL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, if (e.g., when) the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the described ranges, satisfactory hole transport properties may be achieved without a substantial increase in driving voltage.

The hole transport region HTR may further include a charge generating material to increase conductivity in addition to the herein-described materials. The charge generating material may be dispersed uniformly (substantially uniformly) or non-uniformly (substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as Cul or Rbl, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,1 0,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the auxiliary emission layer EAL or the electron blocking layer EBL, in addition to the hole injection layer HIL and the hole transport layer HTL. The auxiliary emission layer EAL may compensate a resonance distance according to the wavelength of light emitted from the emission layer EML and regulate a hole charge balance to increase light emitting efficiency. In one or more embodiments, the auxiliary emission layer EAL may serve to prevent or reduce electrons from being injected into the hole transport region HTR. Materials which may be included in the hole transport region HTR may be included in the auxiliary emission layer EAL. The electron blocking layer EBL is a layer that serves to prevent or reduce electrons from being injected from the electron transport region ETR to the hole transport region HTR.

### Polycyclic Compound

A light-emitting element ED according to one or more embodiments may contain a first compound, which may be the polycyclic compound of the present disclosure. According to one or more embodiments, the first compound (i.e., the polycyclic compound) may be included in at least one selected from among functional layers HTR, EML and ETR between the first electrode EL1 and the second electrode EL2. In one or more embodiments, the first compound may be contained in at least one selected from among the emission layer EML and the electron transport region ETR.

In one or more embodiments, the first compound included (e.g., contained) in the emission layer EML may be utilized as a host material. In the light-emitting element ED according to one or more embodiments, the emission layer EML may include the first compound and a second compound which is a phosphorescent dopant. In one or more embodiments, the second compound may be an organic metal compound.

The light-emitting element ED according to one or more embodiments may further include a third compound in the emission layer EML as a host material, in addition to the first compound. In one or more embodiments, the third compound may include a tricyclic fused ring containing a nitrogen atom as a ring-forming atom.

In one or more embodiments, the light-emitting element ED according to one or more embodiments may further include a fourth compound which is a delayed fluorescent dopant, in addition to the first compound, the second compound, and the third compound. For example, the fourth compound may be a thermally activated delayed fluorescent (TADF) dopant. The second to fourth compounds are described in more detail elsewhere herein.

The light-emitting element ED according to one or more embodiments may include a first compound, which is the polycyclic compound according to one or more embodiments, in the electron transport region ETR. For example, in one or more embodiments, the first compound may be included in the electron transport layer ETL, the hole-blocking layer HBL, and/or the like.

The first compound, which is the polycyclic compound according to one or more embodiments, may be an electron-transporting compound. The polycyclic compound according to one or more embodiments may include a fused ring containing Si and N as a ring-forming atom and a heteroaryl ring with two or more carbon atoms of benzene rings substituted with N. The fused ring may include a structure of FG1, and the heteroaryl ring may include a structure of FG2.

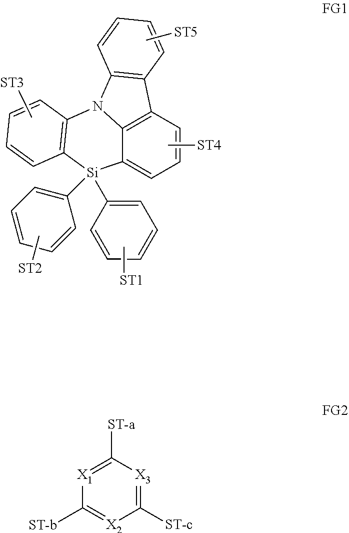

The FG2 group may be bonded at any (e.g., at least) one position selected from among ST1 to ST5 of the FG1 group. The FG1 group may be bonded at any (e.g., at least) one position selected from among ST-a to ST-c of the FG2 group. In the groups represented by FG2, two or more selected from among X₁ to X₃ may be N, and the rest (e.g., any remaining selected from among X₁ to X₃) may be CH, or CD in which H is substituted with a deuterium atom.

The polycyclic compound according to one or more embodiments may have a structure in which at least one FG1 group and at least one FG2 group are bonded. For example, the polycyclic compound according to one or more embodiments may include one FG1 group and one FG2 group, include one FG1 group and two FG2 groups, or include one FG2 group and two FG1 groups.

The polycyclic compound according to one or more embodiments may include at least one FG1 group to thus have a three-dimensionally bulky structure. The polycyclic compound according to one or more embodiments may have less interaction with other compounds utilized together in substantially the same layer due to the bulky three-dimensional structure.

For example, the polycyclic compound according to one or more embodiments may include a fused ring in which a silyl group containing Si is bonded to a carbazole group to form a ring. The polycyclic compound according to one or more embodiments may have high three-dimensional hindrance characteristics to an adjacent compound molecule due to the fused ring compared to a case where the compound includes a substituent such as a triphenylsilyl group, which forms no ring. As a result, the polycyclic compound containing a silyl group to form a fused ring, according to one or more embodiments, may have less interaction with the adjacent compound molecule than the compound in which a triphenyl silyl group forms no ring.

When the polycyclic compound according to one or more embodiments is included in the emission layer EML and is utilized as a host material, the polycyclic compound according to one or more embodiments may have less interaction with a dopant material included in the emission layer EML due to the three-dimensional aspect of the bulky structure. As a result, the polycyclic compound according to one or more embodiments has no influence on emission characteristics of the dopant, and the light-emitting element ED according to one or more embodiments including the polycyclic compound according to one or more embodiments in the emission layer EML may exhibit excellent or suitable color reproductivity. In one or more embodiments, the polycyclic compound according to one or more embodiments includes a silyl group, thereby having bipolar characteristics, and thus may exhibit excellent or suitable material stability. Due to the excellent or suitable material stability of the polycyclic compound according to one or more embodiments, the light-emitting element ED according to one or more embodiments including the same may also have an improved element lifespan.

The polycyclic compound according to one or more embodiments may be represented by Formula 1.

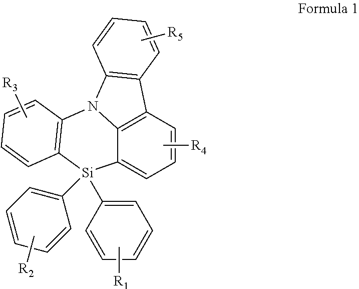

In Formula 1, at least one (e.g., one or two) selected from among R₁ to R₅ may be represented by Formula 2, and the rest (e.g., any remaining selected from among R₁ to R₅) may be a hydrogen atom or a deuterium atom. One or two selected from among R₁ to R₅ may be a substituent represented by Formula 2, and the rest (e.g., any remaining selected from among R₁ to R₅) may be a hydrogen atom or a deuterium atom.

In one or more embodiments, in the structure represented by Formula 1, at least one of the hydrogen atoms in the rest of the hydrocarbons other than the substituent represented by Formula 2 may be substituted with a deuterium atom. In one or more embodiments, at least one of the hydrogen atoms in the substituent represented by Formula 2 may be substituted with a deuterium atom.

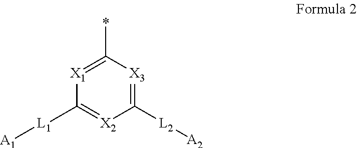

In Formula 2, X₁ to X₃ may each independently be N, CH, or CD, and two or more among X₁ to X₃ may be N. In one or more embodiments, a portion represented by Formula 2 may be a triazine moiety, in which all X₁ to X₃ are N, or a pyrimidine moiety, in which two selected from among X₁ to X₃ are N.

In Formula 2, L₁ and L₂ may each independently be a direct linkage, a substituted or unsubstituted arylene group having 6 to 30 ring-forming carbon atoms, or a substituted or unsubstituted heteroarylene group having 3 to 30 ring-forming carbon atoms. For example, L₁ and L₂ may be each a direct linkage, a substituted or unsubstituted phenylene group, and/or the like, but one or more embodiments of the present disclosure is not limited thereto. In one or more embodiments, if (e.g., when) Li or L₂ is a substituted or unsubstituted arylene group or a substituted or unsubstituted heteroarylene group, at least one among hydrogen atoms of L₁ or L₂ may be substituted with a deuterium atom.

In Formula 2, A₁ and A₂ may each independently be a substituted or unsubstituted aryl group having 6 to 30 ring-forming carbon atoms, a substituted or unsubstituted heterocyclic group having 3 to 30 ring-forming carbon atoms, or a substituted or unsubstituted silyl group. In one or more embodiments, the heterocyclic group may be an aliphatic heterocyclic group or an aromatic heterocyclic group.

For example, in one or more embodiments, A₁ and A₂ may each independently be a substituted or unsubstituted phenyl group, a substituted or unsubstituted carbazole group, or a substituted or unsubstituted triphenylsilyl group, or may be represented by Formula SG.

In one or more embodiments, any one (e.g., one or more) selected from among A₁ and A₂ may be represented by Formula SG, and the rest (e.g., any remaining selected from among A₁ and A₂) may not be represented by Formula SG and may be a substituted or unsubstituted aryl group having 6 to 30 ring-forming carbon atoms, a substituted or unsubstituted heterocyclic group having 3 to 30 ring-forming carbon atoms, or a substituted or unsubstituted silyl group. For example, any one (e.g., one or more) selected from among A₁ and A₂ may be represented by Formula SG, and the rest (e.g., any remaining selected from among A₁ and A₂) may be a substituted or unsubstituted phenyl group, a substituted or unsubstituted carbazole group, or a substituted or unsubstituted triphenylsilyl group.

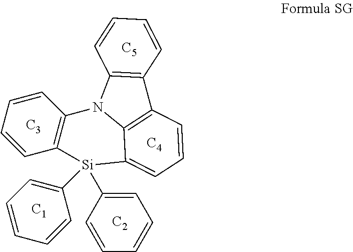

When A₁ or A₂ is represented by Formula SG, any one ring selected from among C₁ to C₅ may be bonded to L₁ or L₂.

In one or more embodiments, Formula 2 may be represented by Formula 2-1 or Formula 2-2.

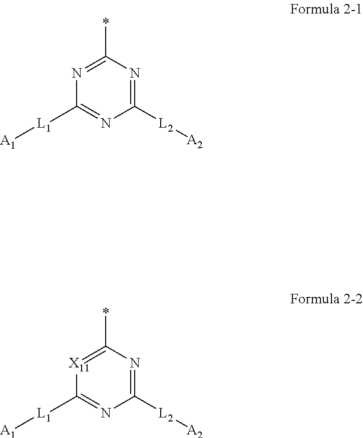

In Formula 2-2, X₁₁ may be CH or CD. In Formula 2-1 and Formula 2-2, the same descriptions as in Formula 2 may be applied to L₁, L₂, A₁, and A₂. In Formula 2-1 and Formula 2-2, any one (e.g., one or more) selected from among A₁ and A₂ may be represented by Formula SG previously described, and the rest (e.g., any remaining selected from among A₁ and A₂) may not be represented by Formula SG and may be a substituted or unsubstituted aryl group having 6 to 30 ring-forming carbon atoms, a substituted or unsubstituted heterocyclic group having 3 to 30 ring-forming carbon atoms, or a substituted or unsubstituted silyl group. For example, any one (e.g., one or more) selected from among A₁ and A₂ may be represented by Formula SG, and the rest (e.g., any remaining selected from among A₁ and A₂) may be a substituted or unsubstituted phenyl group, a substituted or unsubstituted carbazole group, or a substituted or unsubstituted triphenylsilyl group.

In one or more embodiments, in Formula 2 represented by Formula 2-2 according to one or more embodiments, A₁ in Formula 2-2 may be represented by Formula SG, and A₂ may be represented by (e.g., not Formula SG) an aryl group, a heterocyclic group, or a silyl group.

In the polycyclic compound according to one or more embodiments, including the structures of Formulas 1 and Formula 2, at least one of the hydrogen atoms may be substituted with a deuterium atom. In this case, at least one of the hydrogen atoms of the substituent linked to the structures of Formula 1 and Formula 2 may also be substituted with a deuterium atom.

The polycyclic compound according to one or more embodiments may be represented by any one selected from among compounds in Compound Group 1. The light-emitting element ED according to one or more embodiments may include at least one selected from among the compounds in Compound Group 1. In Compound Group 1, D is a deuterium atom.

The light-emitting element ED according to one or more embodiments may include at least one selected from among the compounds in Compound Group 1 in the emission layer EML. However, one or more embodiments of the present disclosure is not limited thereto, and the light-emitting element ED according to one or more embodiments may include at least one selected from among the compounds in Compound Group 1, in the electron transport region ETR.

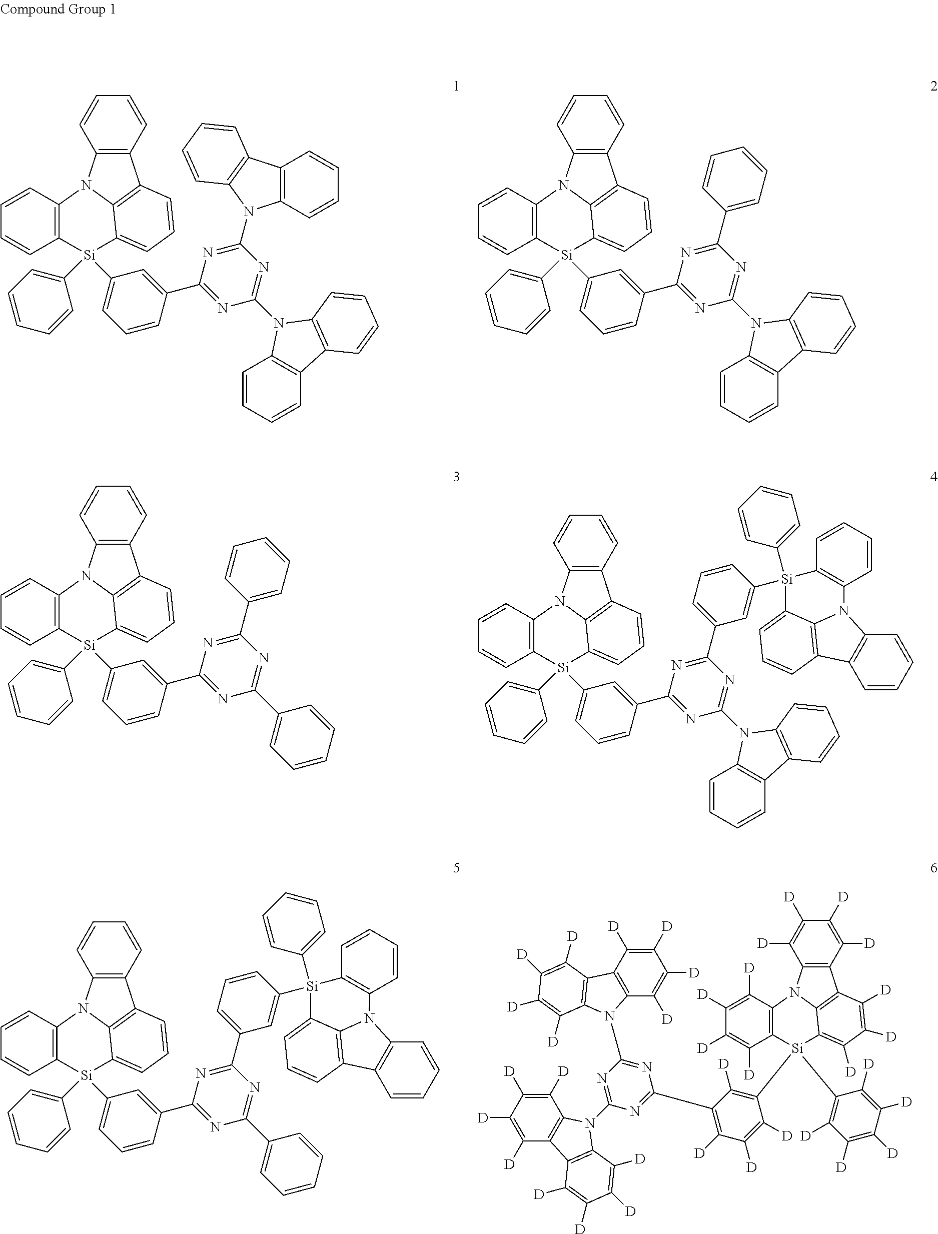

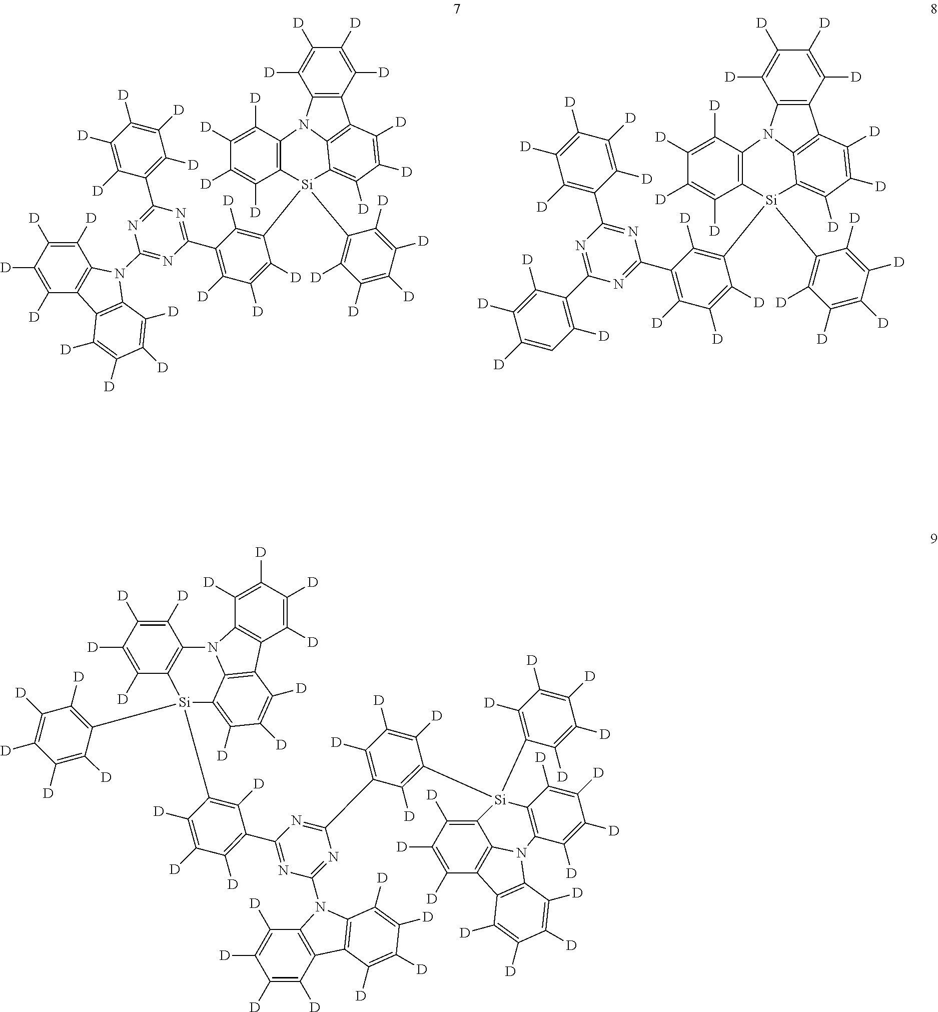

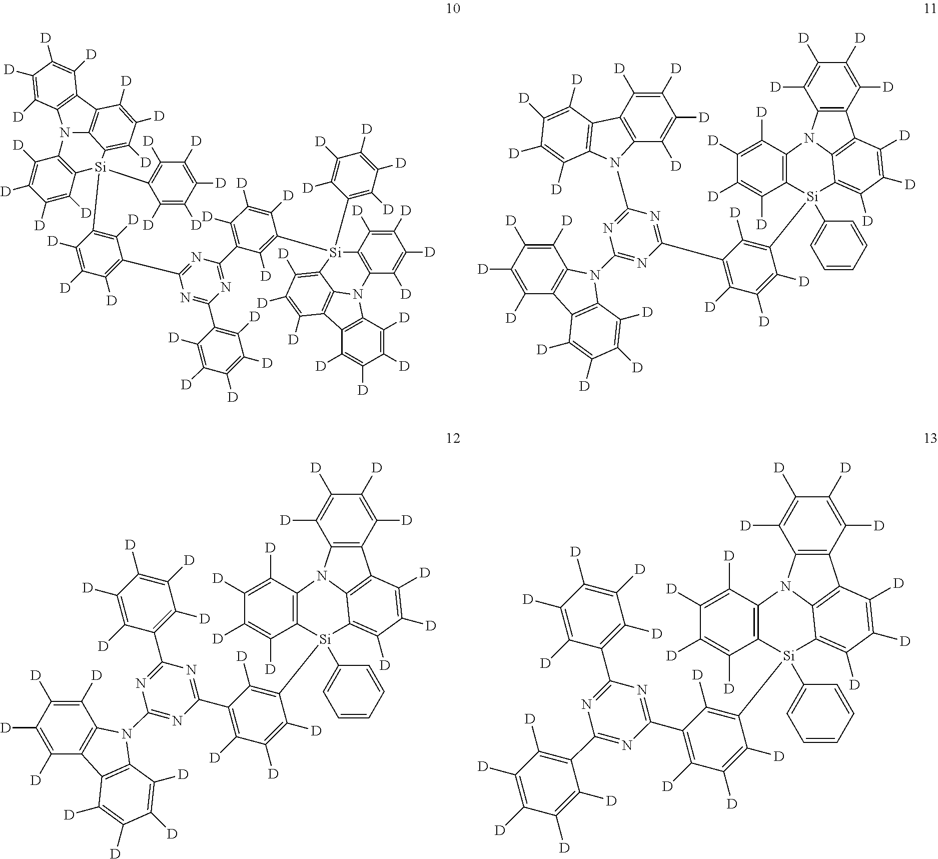

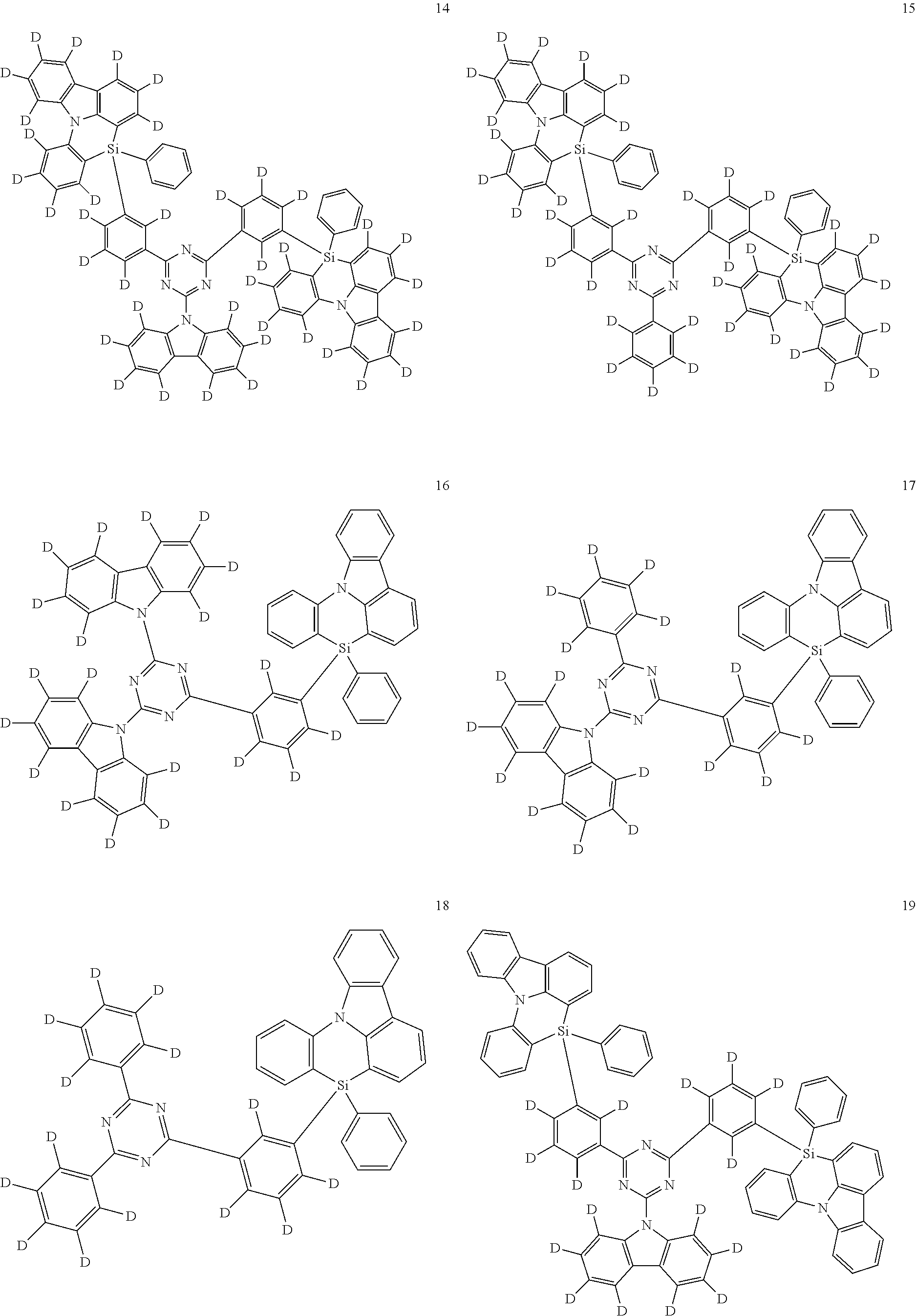

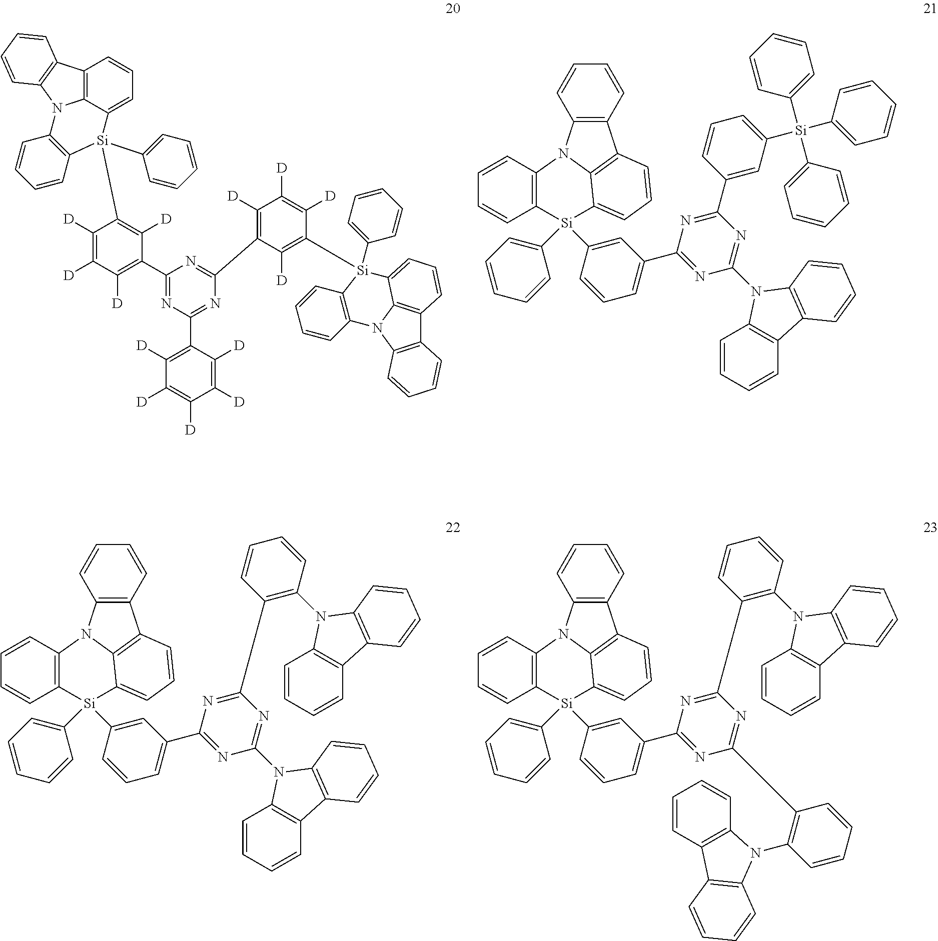

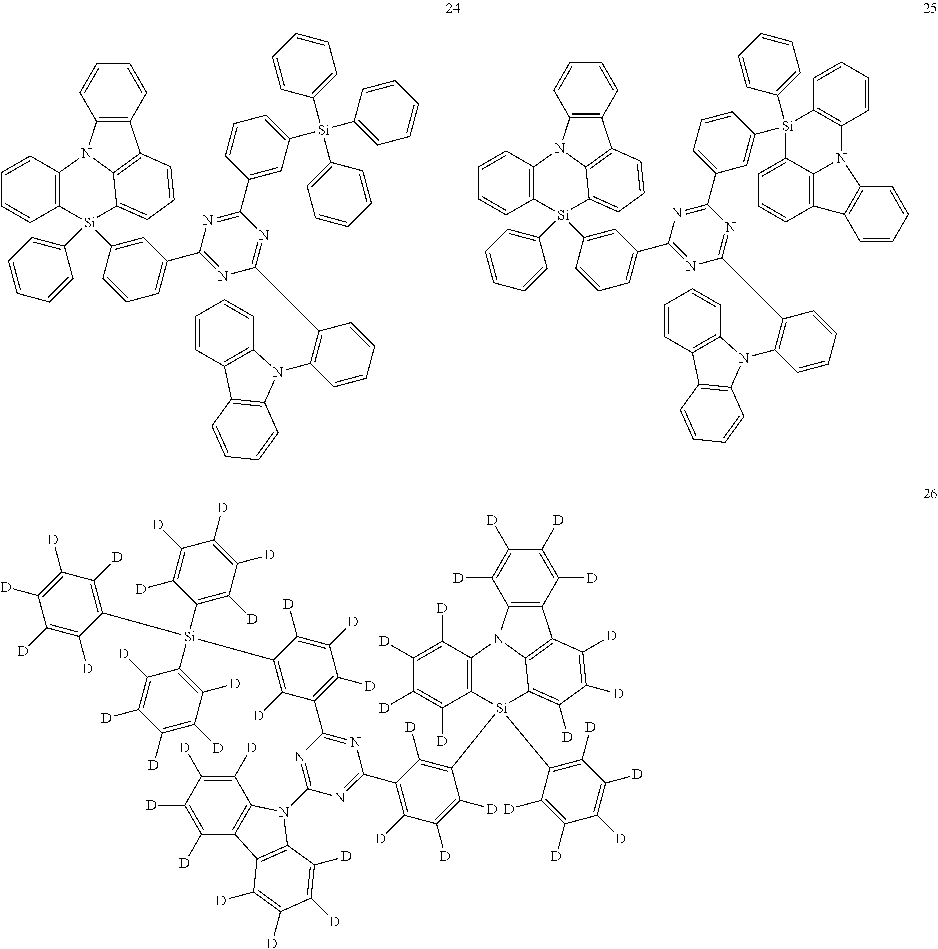

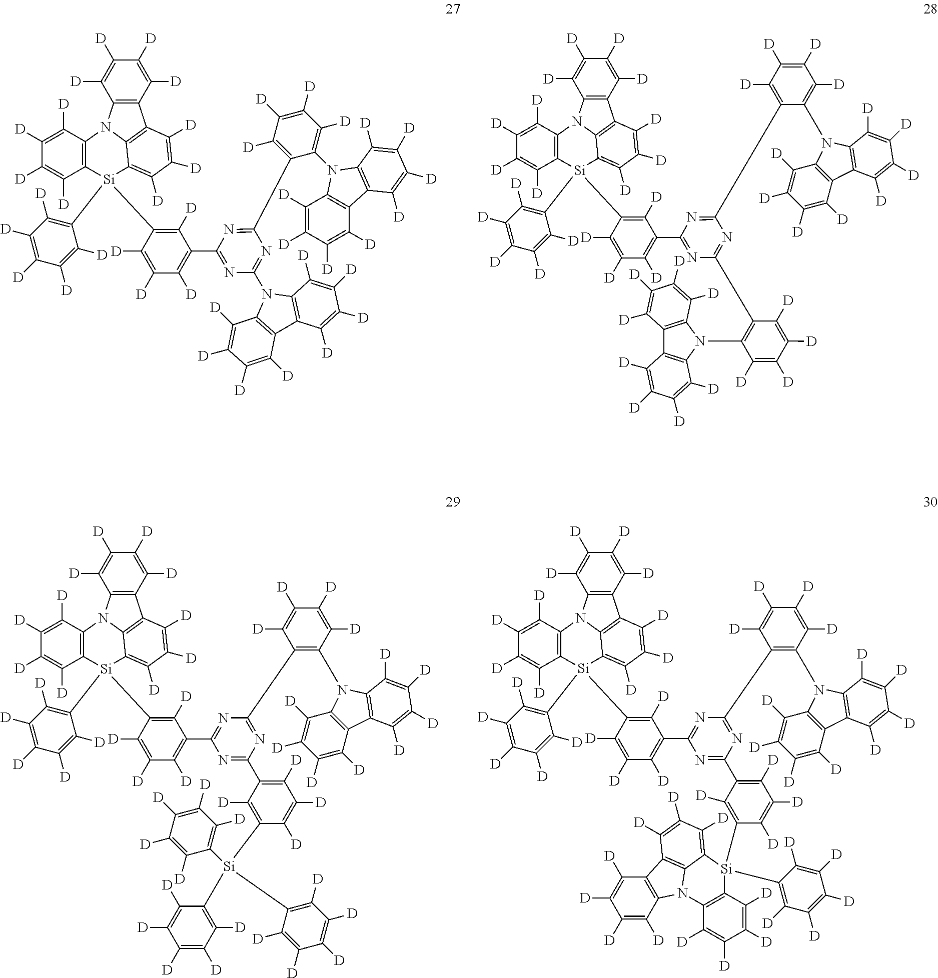

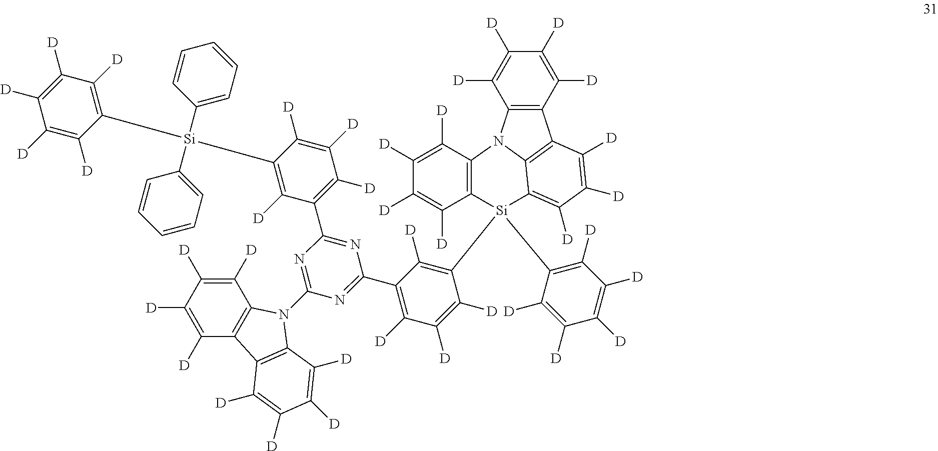 [SMILES: [2H]c1c([2H])c([2H])c([Si](c2ccccc2)(c2ccccc2)c2c([2H])c([2H])c([2H])c(-c3nc(-c4c([2H])c([2H])c([2H])c([Si]5(c6c([2H])c([2H])c([2H])c([2H])c6[2H])c6c([2H])c([2H])c([2H])c([2H])c6-n6c7c([2H])c([2H])c([2H])c([2H])c7c7c([2H])c([2H])c([2H])c5c76)c4[2H])nc(-n4c5c([2H])c([2H])c([2H])c([2H])c5c5c([2H])c([2H])c([2H])c([2H])c54)n3)c2[2H])c([2H])c1[2H]]

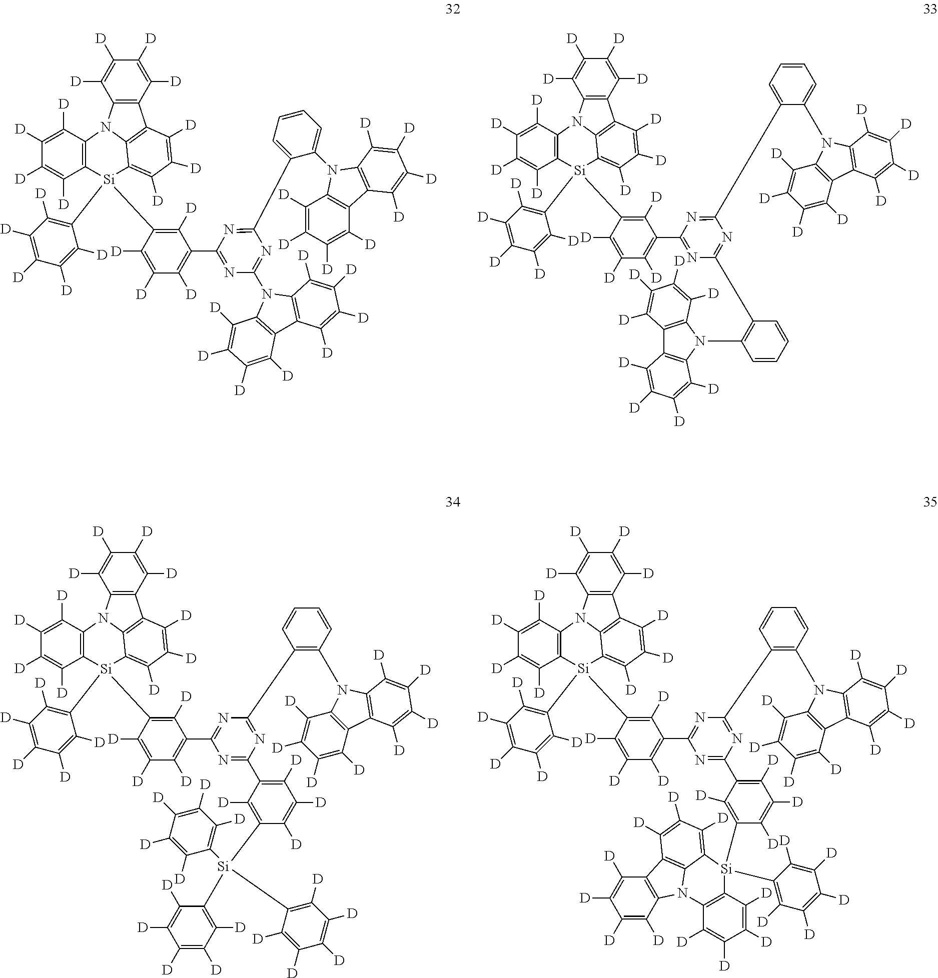

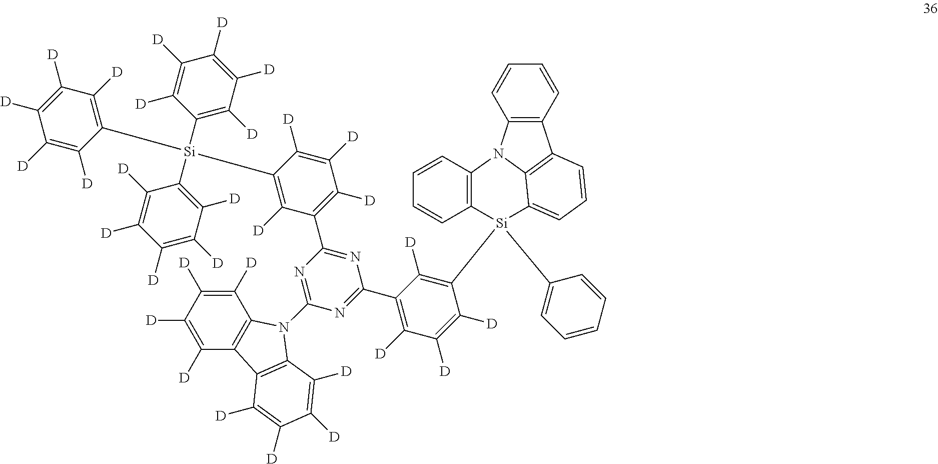 [SMILES: [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(-c3nc(-c4c([2H])c([2H])c([2H])c([Si]5(c6ccccc6)c6ccccc6-n6c7ccccc7c7cccc5c76)c4[2H])nc(-n4c5c([2H])c([2H])c([2H])c([2H])c5c5c([2H])c([2H])c([2H])c([2H])c54)n3)c2[2H])c([2H])c1[2H]]

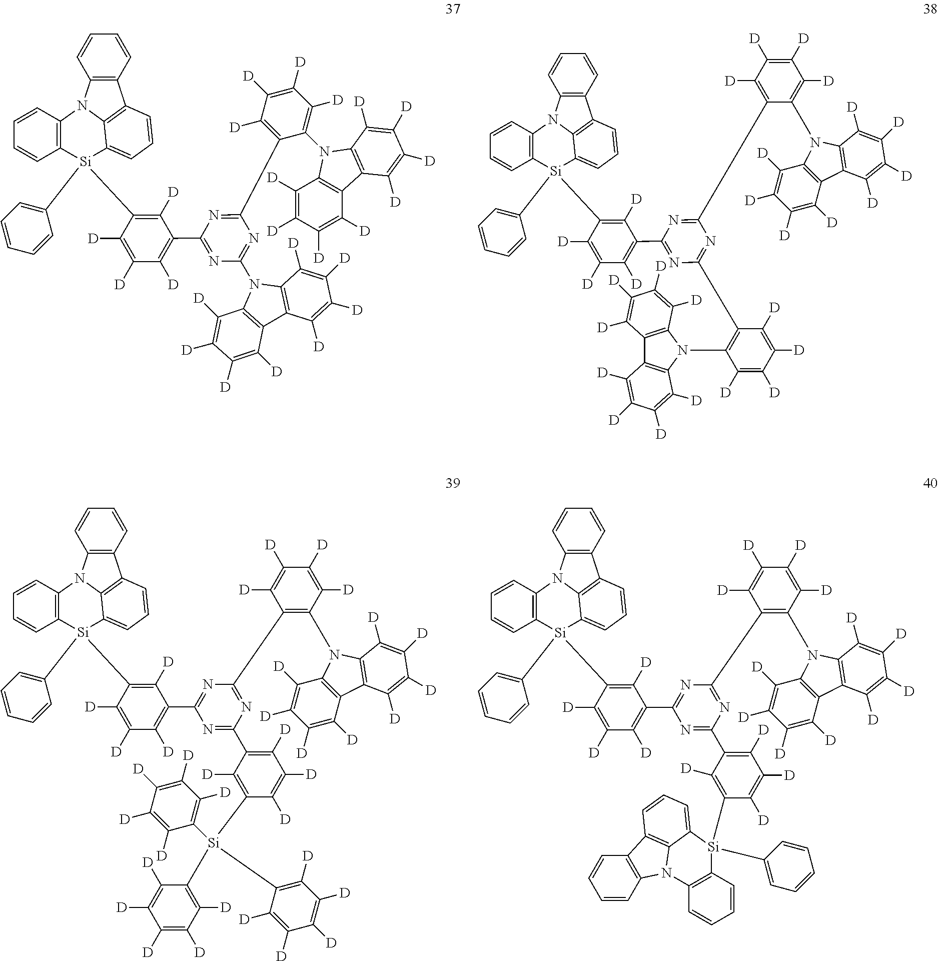

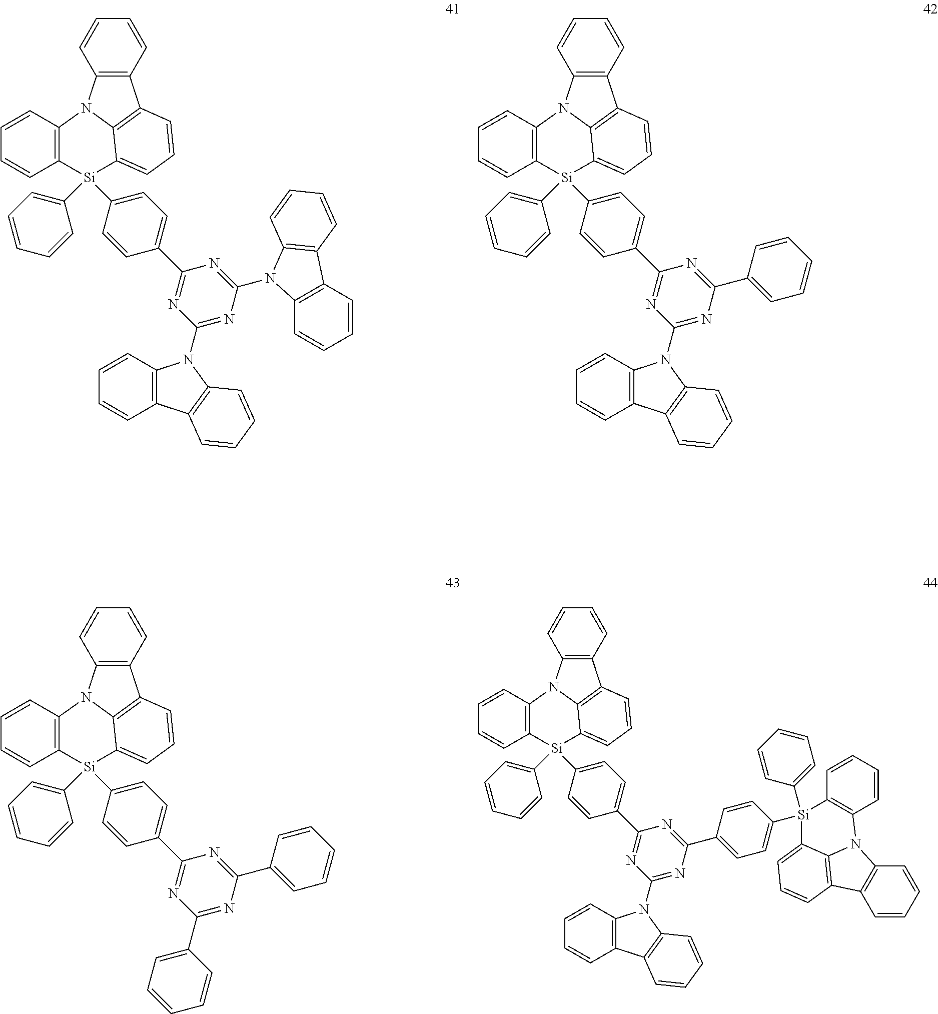 [SMILES: c1ccc([Si]2(c3ccc(-c4nc(-n5c6ccccc6c6ccccc65)nc(-n5c6ccccc6c6ccccc65)n4)cc3)c3ccccc3-n3c4ccccc4c4cccc2c43)cc1 ; c1ccc(-c2nc(-c3ccc([Si]4(c5ccccc5)c5ccccc5-n5c6ccccc6c6cccc4c65)cc3)nc(-n3c4ccccc4c4ccccc43)n2)cc1 ; c1ccc(-c2nc(-c3ccccc3)nc(-c3ccc([Si]4(c5ccccc5)c5ccccc5-n5c6ccccc6c6cccc4c65)cc3)n2)cc1 ; c1ccc([Si]2(c3ccc(-c4nc(-c5ccc([Si]6(c7ccccc7)c7ccccc7-n7c8ccccc8c8cccc6c87)cc5)nc(-n5c6ccccc6c6ccccc65)n4)cc3)c3ccccc3-n3c4ccccc4c4cccc2c43)cc1]

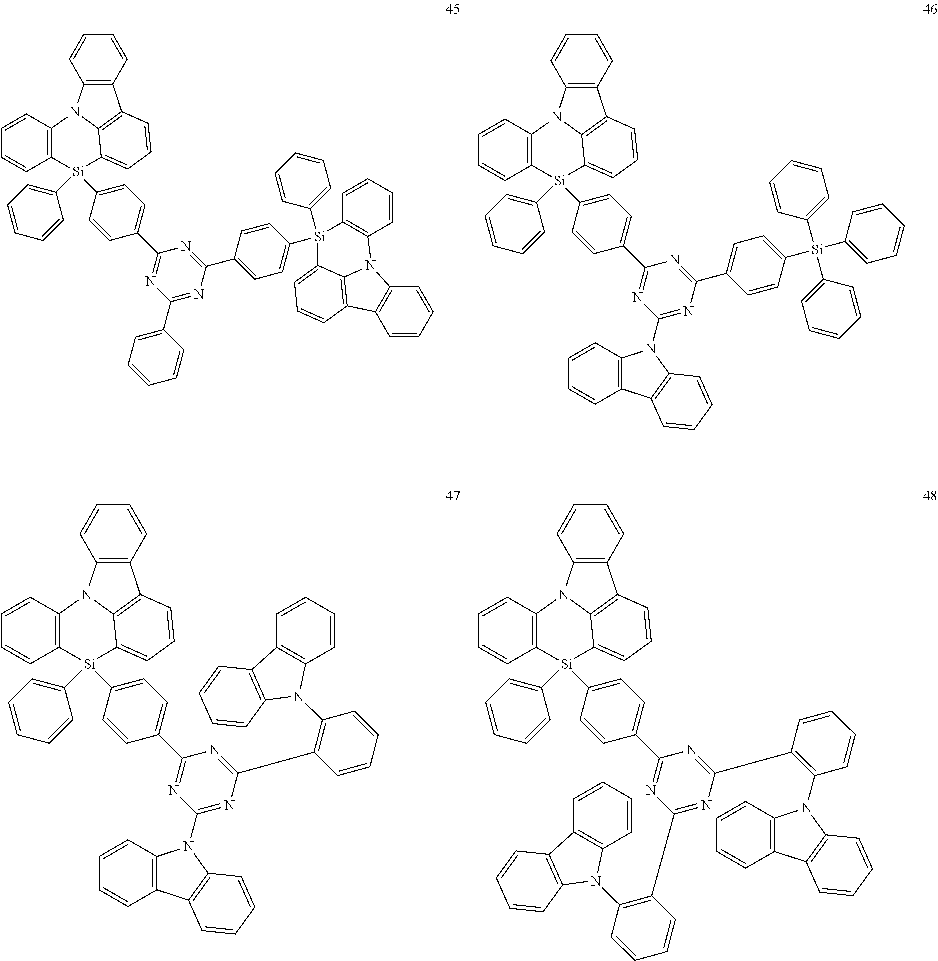

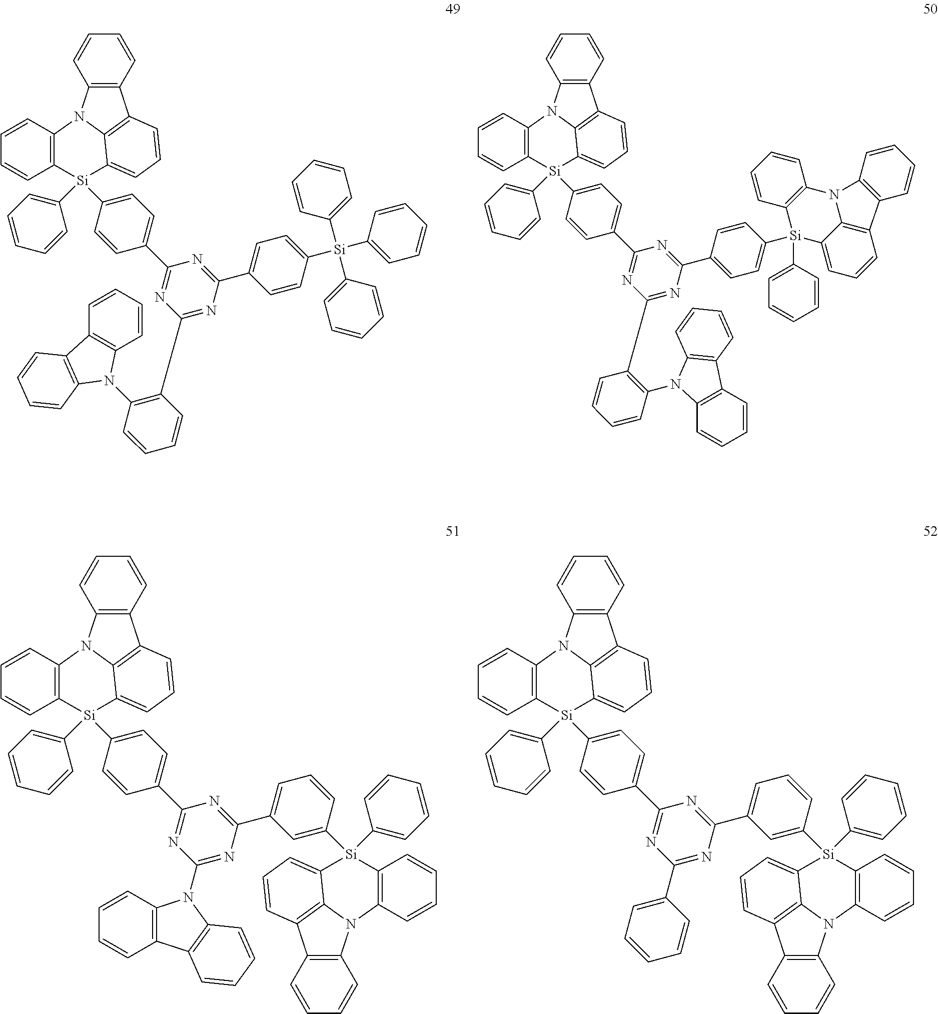

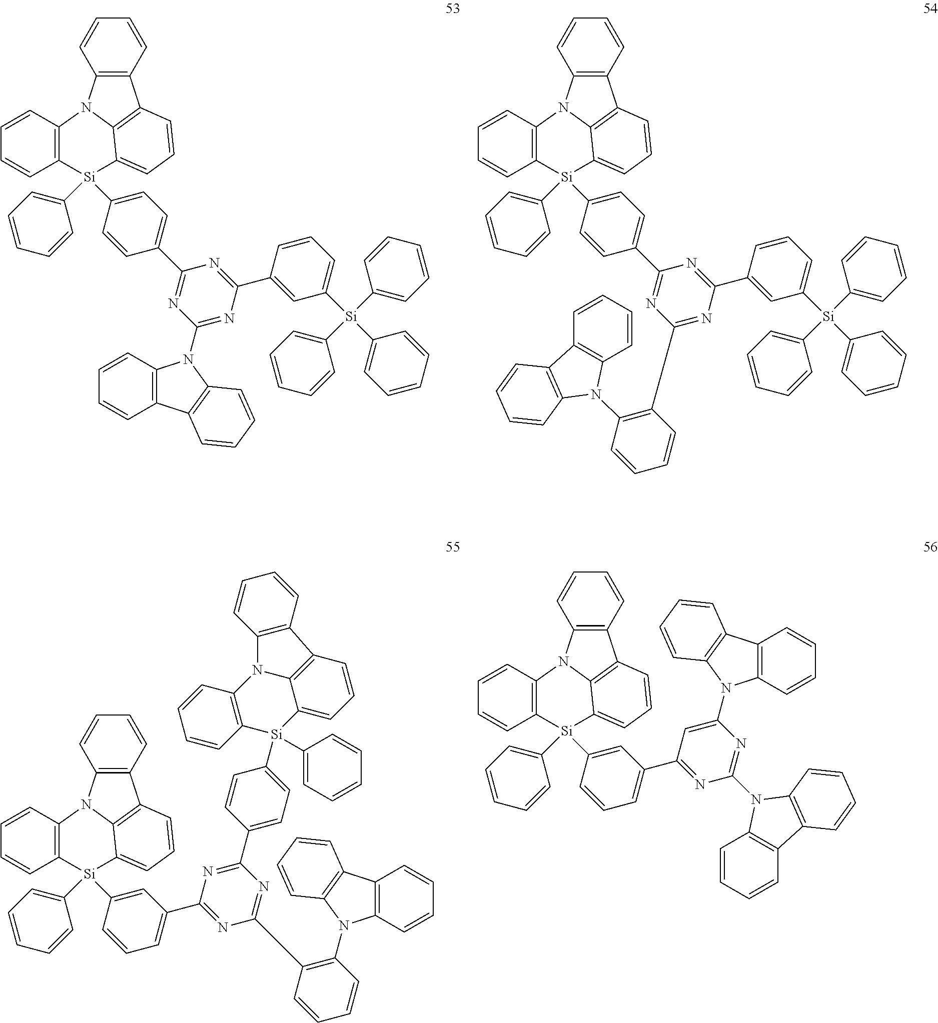

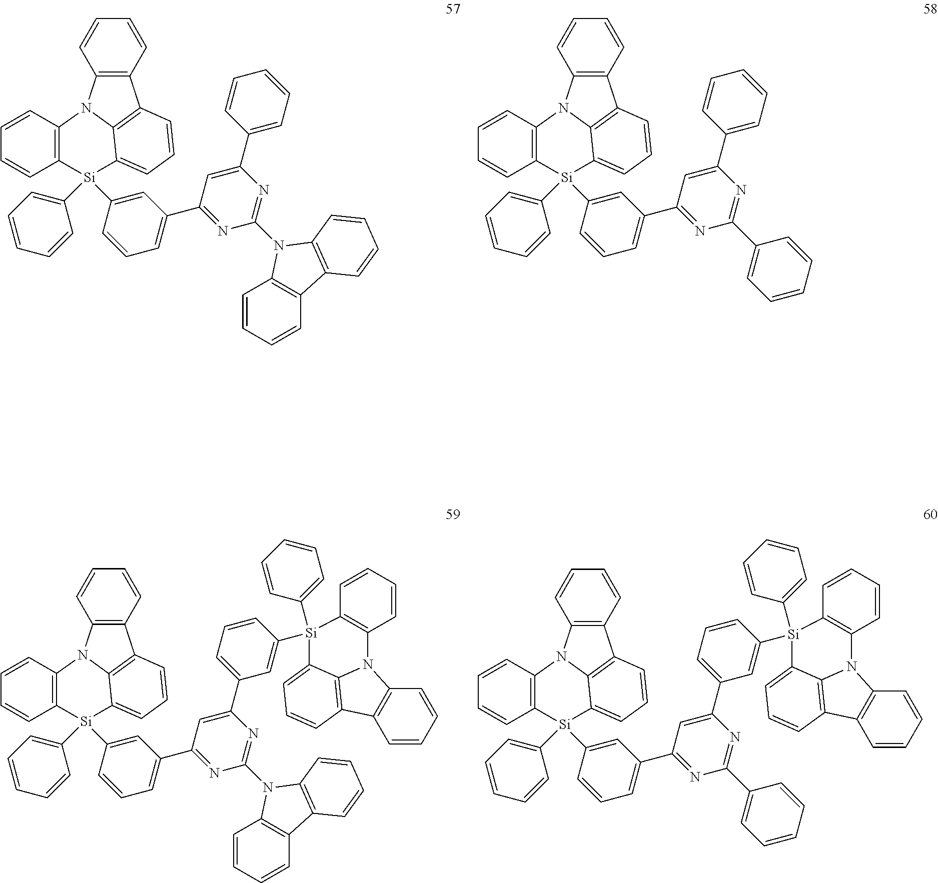

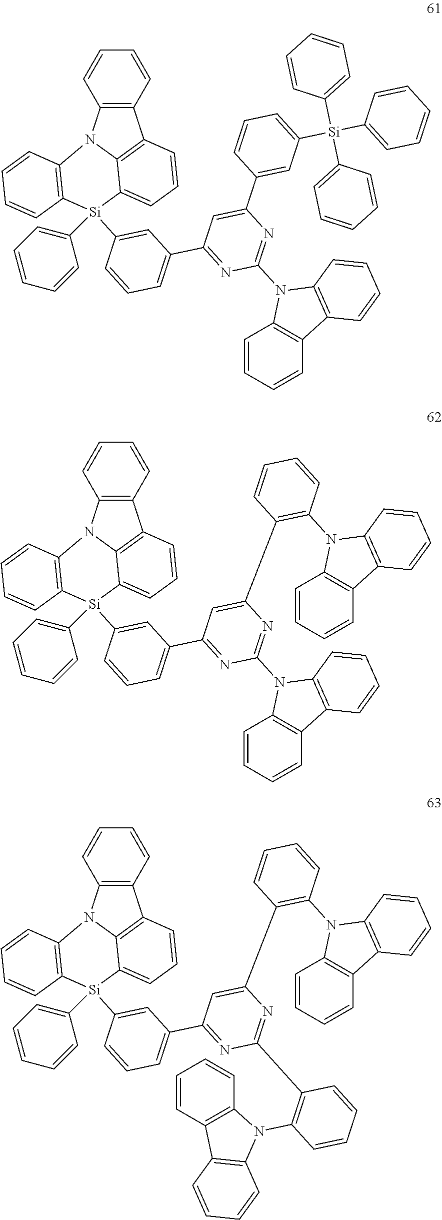 [SMILES: c1ccc([Si](c2ccccc2)(c2ccccc2)c2cccc(-c3cc(-c4cccc([Si]5(c6ccccc6)c6ccccc6-n6c7ccccc7c7cccc5c76)c4)nc(-n4c5ccccc5c5ccccc54)n3)c2)cc1 ; c1ccc([Si]2(c3cccc(-c4cc(-c5ccccc5-n5c6ccccc6c6ccccc65)nc(-n5c6ccccc6c6ccccc65)n4)c3)c3ccccc3-n3c4ccccc4c4cccc2c43)cc1 ; c1ccc([Si]2(c3cccc(-c4cc(-c5ccccc5-n5c6ccccc6c6ccccc65)nc(-c5ccccc5-n5c6ccccc6c6ccccc65)n4)c3)c3ccccc3-n3c4ccccc4c4cccc2c43)cc1]

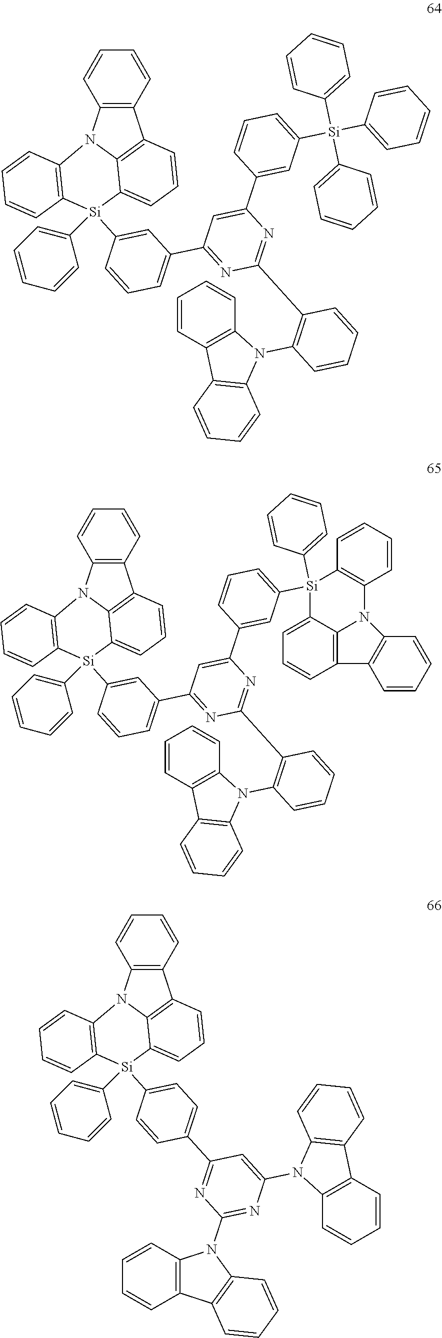 [SMILES: c1ccc([Si](c2ccccc2)(c2ccccc2)c2cccc(-c3cc(-c4cccc([Si]5(c6ccccc6)c6ccccc6-n6c7ccccc7c7cccc5c76)c4)nc(-c4ccccc4-n4c5ccccc5c5ccccc54)n3)c2)cc1 ; c1ccc([Si]2(c3cccc(-c4cc(-c5cccc([Si]6(c7ccccc7)c7ccccc7-n7c8ccccc8c8cccc6c87)c5)nc(-c5ccccc5-n5c6ccccc6c6ccccc65)n4)c3)c3ccccc3-n3c4ccccc4c4cccc2c43)cc1 ; c1ccc([Si]2(c3ccc(-c4cc(-n5c6ccccc6c6ccccc65)nc(-n5c6ccccc6c6ccccc65)n4)cc3)c3ccccc3-n3c4ccccc4c4cccc2c43)cc1]

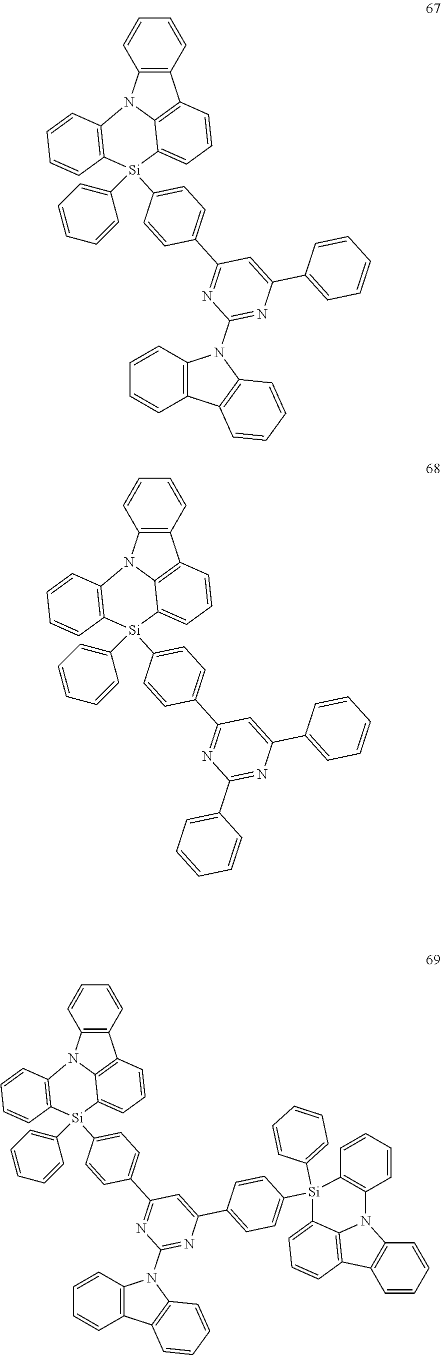 [SMILES: c1ccc(-c2cc(-c3ccc([Si]4(c5ccccc5)c5ccccc5-n5c6ccccc6c6cccc4c65)cc3)nc(-n3c4ccccc4c4ccccc43)n2)cc1 ; c1ccc(-c2cc(-c3ccc([Si]4(c5ccccc5)c5ccccc5-n5c6ccccc6c6cccc4c65)cc3)nc(-c3ccccc3)n2)cc1 ; c1ccc([Si]2(c3ccc(-c4cc(-c5ccc([Si]6(c7ccccc7)c7ccccc7-n7c8ccccc8c8cccc6c87)cc5)nc(-n5c6ccccc6c6ccccc65)n4)cc3)c3ccccc3-n3c4ccccc4c4cccc2c43)cc1]

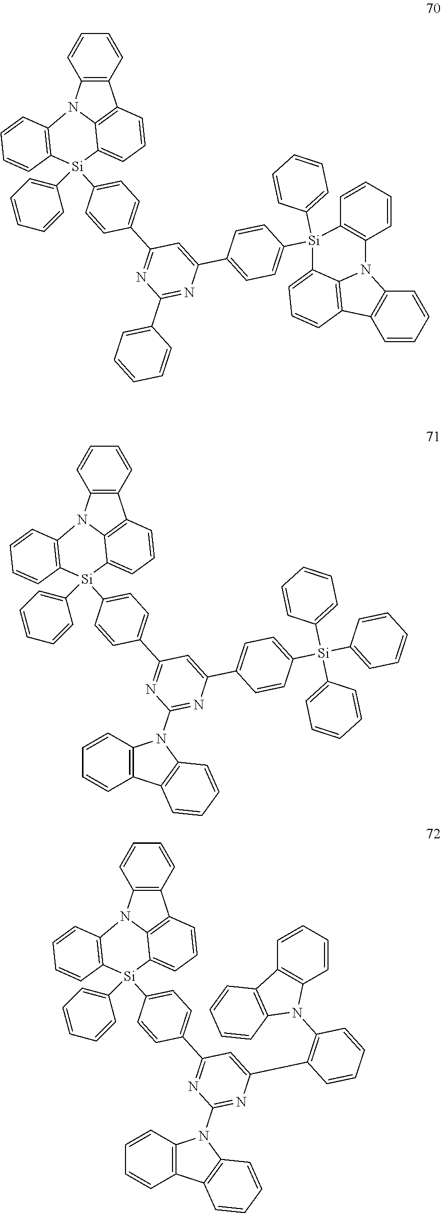

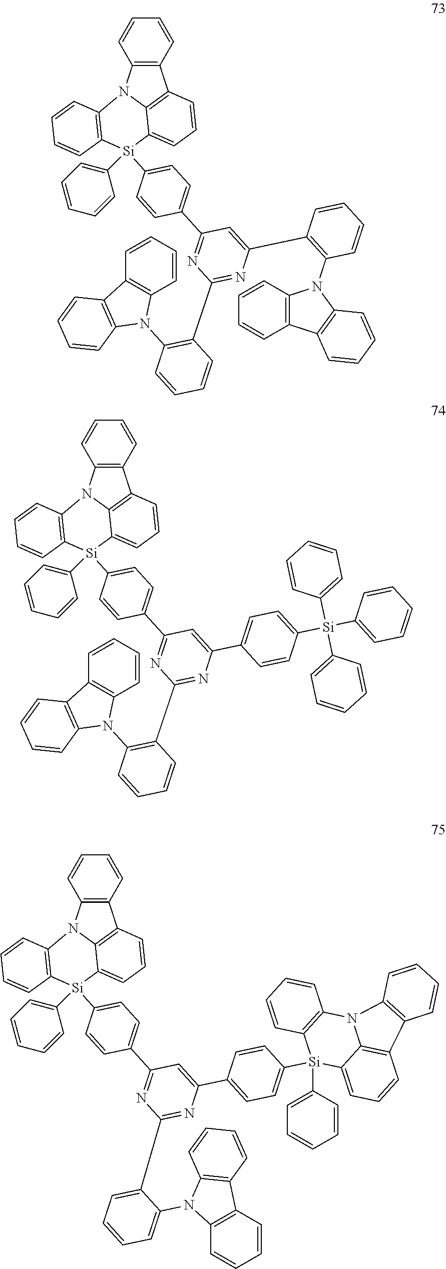 [SMILES: c1ccc([Si]2(c3ccc(-c4cc(-c5ccccc5-n5c6ccccc6c6ccccc65)nc(-c5ccccc5-n5c6ccccc6c6ccccc65)n4)cc3)c3ccccc3-n3c4ccccc4c4cccc2c43)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)cc2)cc1 ; c1ccc([Si]2(c3ccc(-c4cc(-c5ccc([Si]6(c7ccccc7)c7ccccc7-n7c8ccccc8c8cccc6c87)cc5)nc(-c5ccccc5-n5c6ccccc6c6ccccc65)n4)cc3)c3ccccc3-n3c4ccccc4c4cccc2c43)cc1]

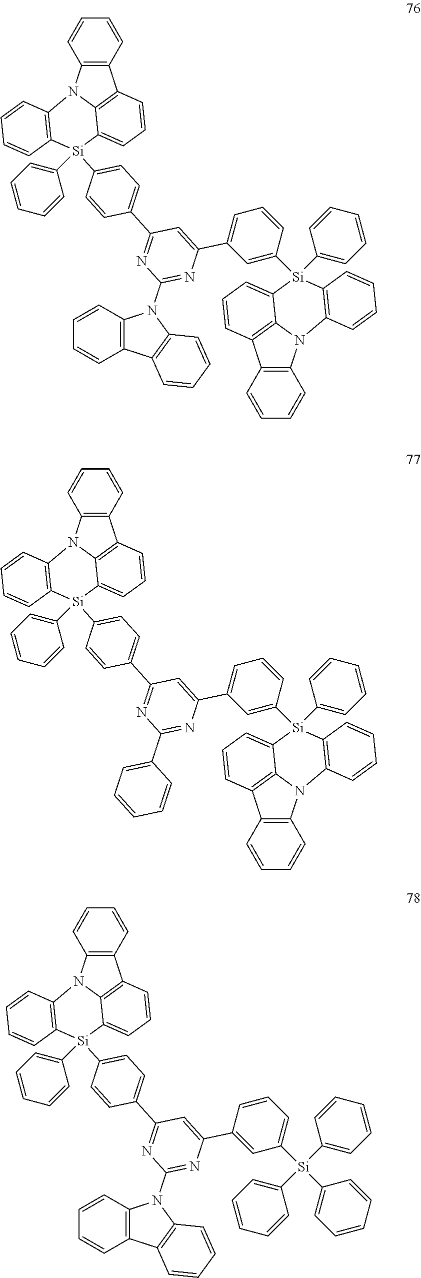 [SMILES: c1ccc([Si]2(c3ccc(-c4cc(-c5cccc([Si]6(c7ccccc7)c7ccccc7-n7c8ccccc8c8cccc6c87)c5)nc(-n5c6ccccc6c6ccccc65)n4)cc3)c3ccccc3-n3c4ccccc4c4cccc2c43)cc1 ; c1ccc(-c2nc(-c3ccc([Si]4(c5ccccc5)c5ccccc5-n5c6ccccc6c6cccc4c65)cc3)cc(-c3cccc([Si]4(c5ccccc5)c5ccccc5-n5c6ccccc6c6cccc4c65)c3)n2)cc1 ; c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-n4c5ccccc5c5ccccc54)n3)c2)cc1]

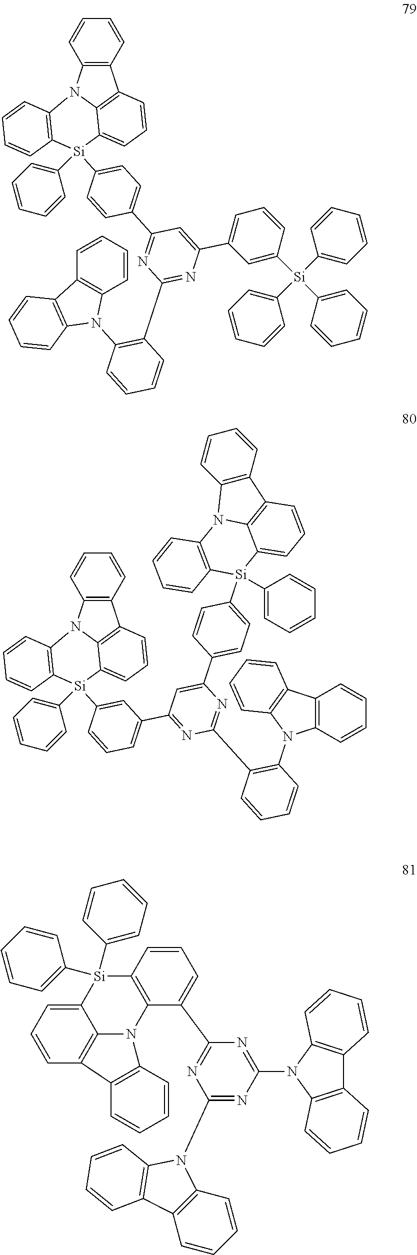 [SMILES: c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)c2)cc1 ; c1ccc([Si]2(c3ccc(-c4cc(-c5cccc([Si]6(c7ccccc7)c7ccccc7-n7c8ccccc8c8cccc6c87)c5)nc(-c5ccccc5-n5c6ccccc6c6ccccc65)n4)cc3)c3ccccc3-n3c4ccccc4c4cccc2c43)cc1 ; c1ccc([Si]2(c3ccccc3)c3cccc(-c4nc(-n5c6ccccc6c6ccccc65)nc(-n5c6ccccc6c6ccccc65)n4)c3-n3c4ccccc4c4cccc2c43)cc1]

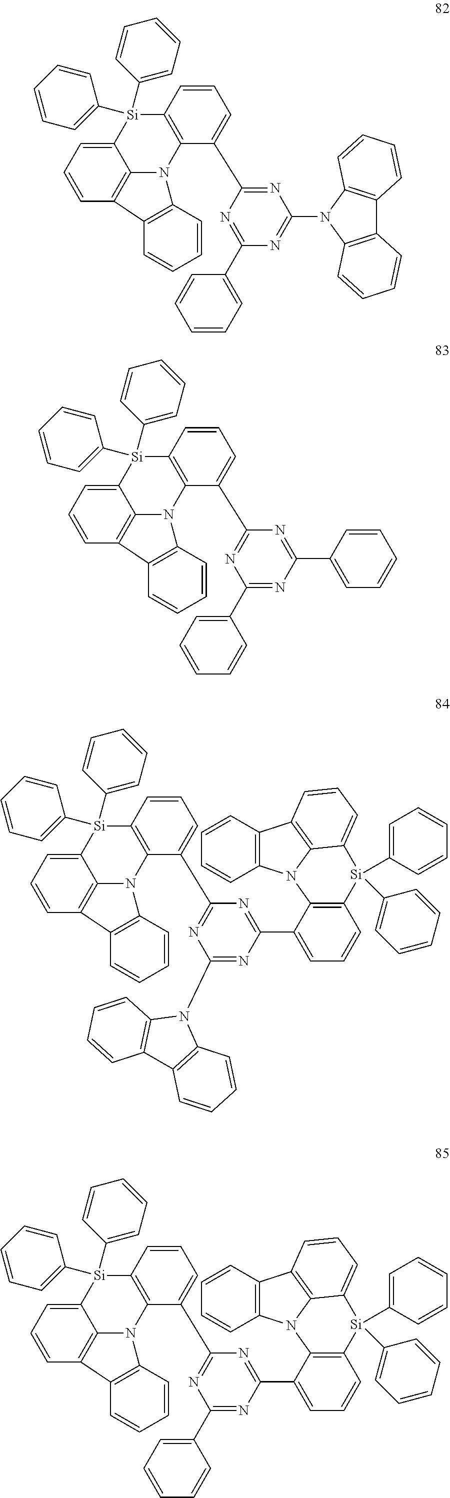

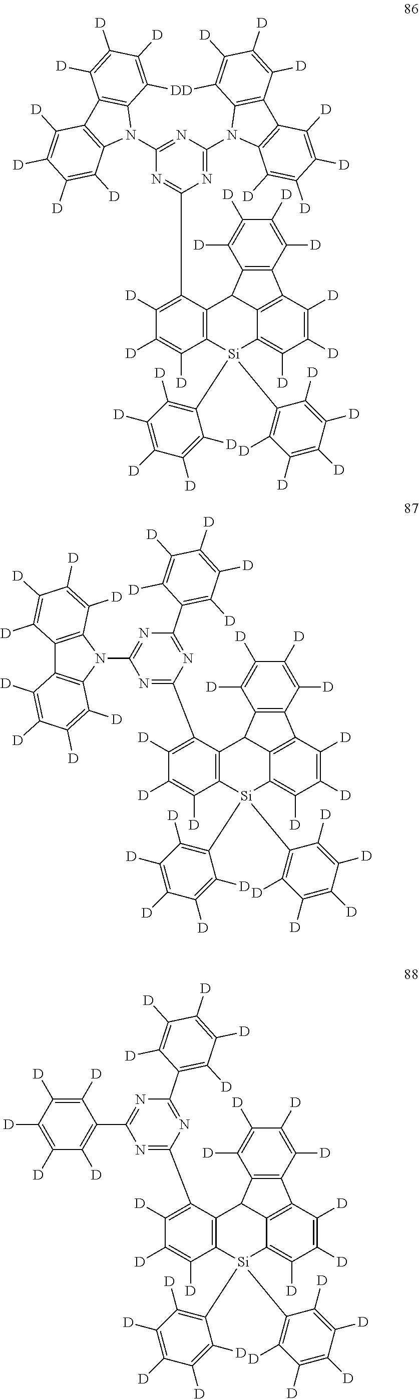

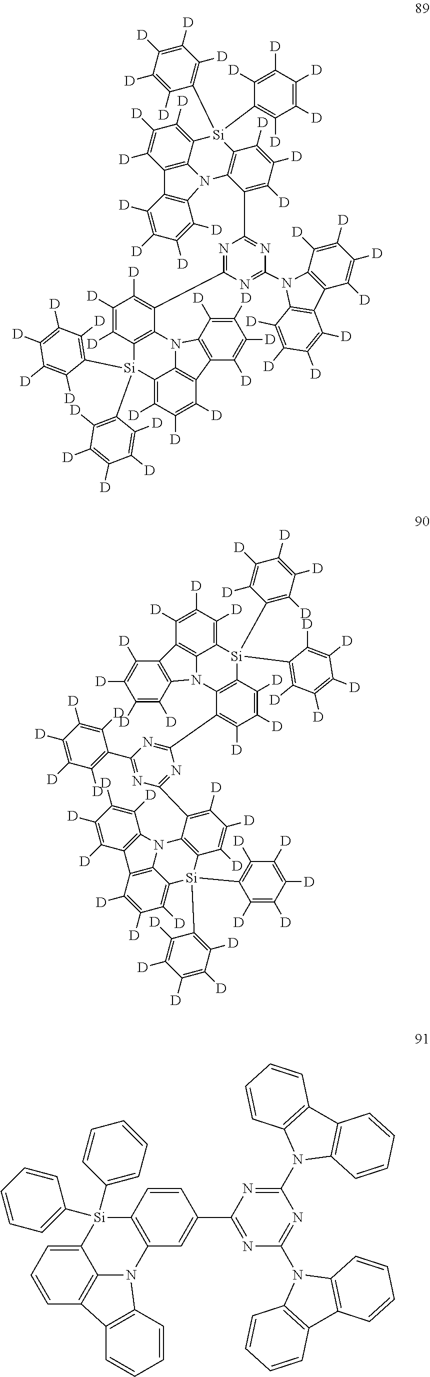

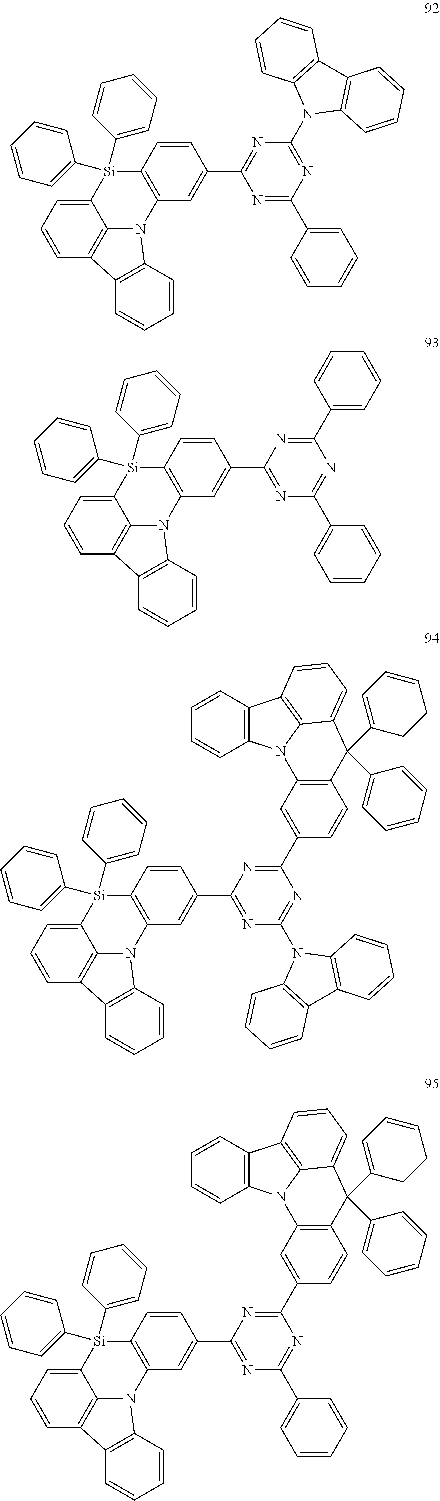

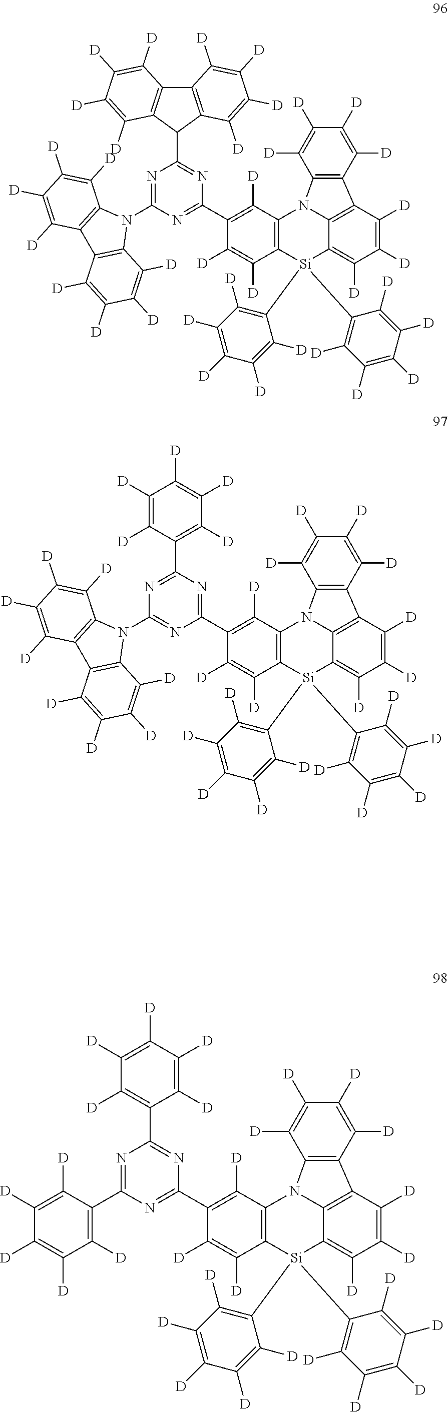

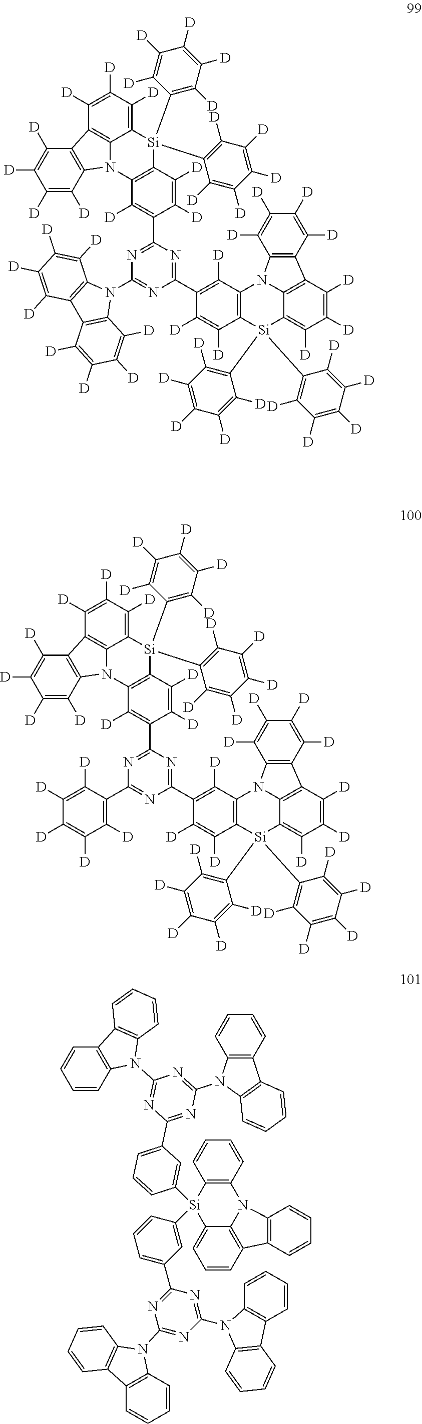

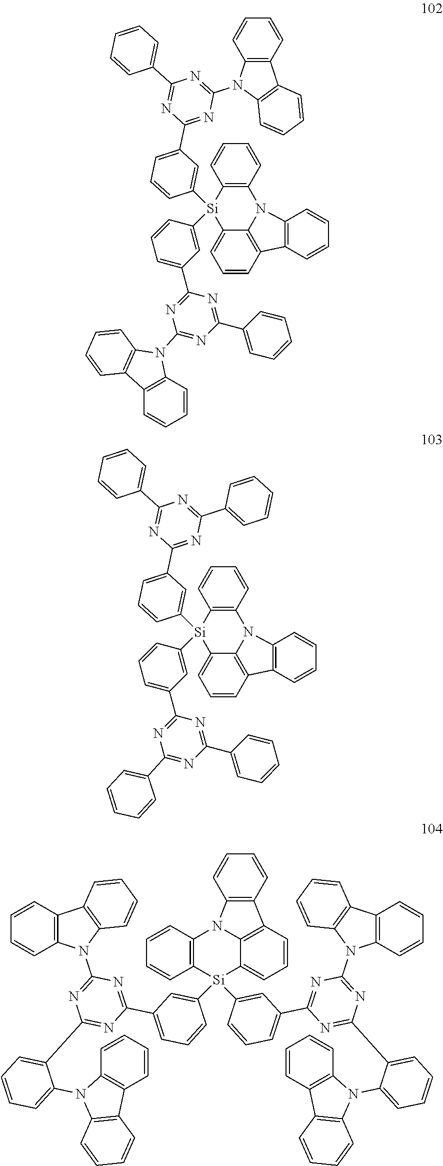 [SMILES: c1ccc(-c2nc(-c3cccc([Si]4(c5cccc(-c6nc(-c7ccccc7)nc(-n7c8ccccc8c8ccccc87)n6)c5)c5ccccc5-n5c6ccccc6c6cccc4c65)c3)nc(-n3c4ccccc4c4ccccc43)n2)cc1 ; c1ccc(-c2nc(-c3ccccc3)nc(-c3cccc([Si]4(c5cccc(-c6nc(-c7ccccc7)nc(-c7ccccc7)n6)c5)c5ccccc5-n5c6ccccc6c6cccc4c65)c3)n2)cc1 ; c1cc(-c2nc(-c3ccccc3-n3c4ccccc4c4ccccc43)nc(-n3c4ccccc4c4ccccc43)n2)cc([Si]2(c3cccc(-c4nc(-c5ccccc5-n5c6ccccc6c6ccccc65)nc(-n5c6ccccc6c6ccccc65)n4)c3)c3ccccc3-n3c4ccccc4c4cccc2c43)c1]

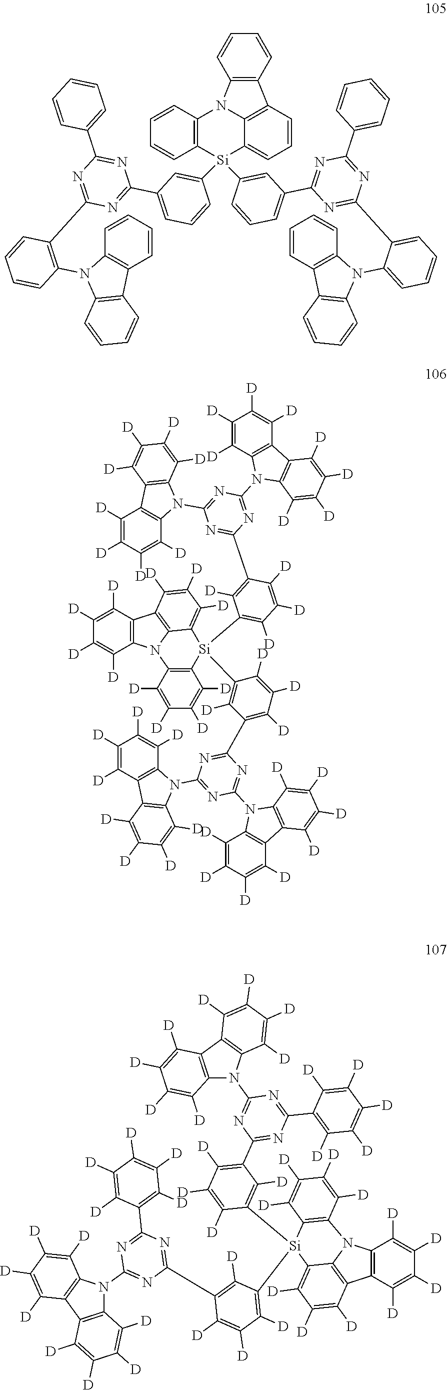

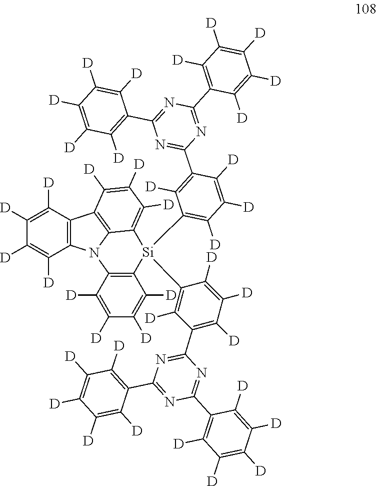 [SMILES: [2H]c1c([2H])c([2H])c(-c2nc(-c3c([2H])c([2H])c([2H])c([2H])c3[2H])nc(-c3c([2H])c([2H])c([2H])c([Si]4(c5c([2H])c([2H])c([2H])c(-c6nc(-c7c([2H])c([2H])c([2H])c([2H])c7[2H])nc(-c7c([2H])c([2H])c([2H])c([2H])c7[2H])n6)c5[2H])c5c([2H])c([2H])c([2H])c([2H])c5-n5c6c([2H])c([2H])c([2H])c([2H])c6c6c([2H])c([2H])c([2H])c4c65)c3[2H])n2)c([2H])c1[2H]]

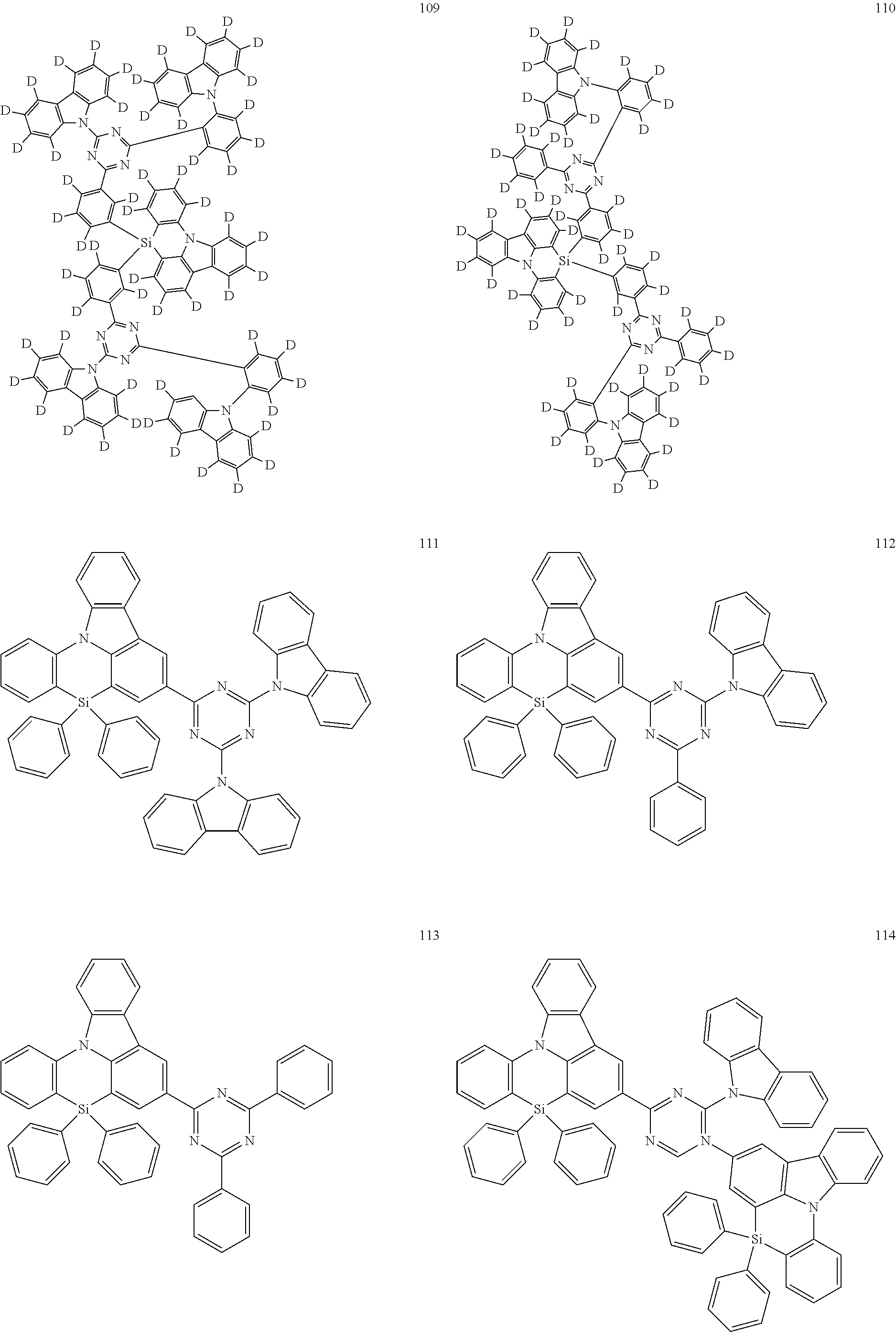

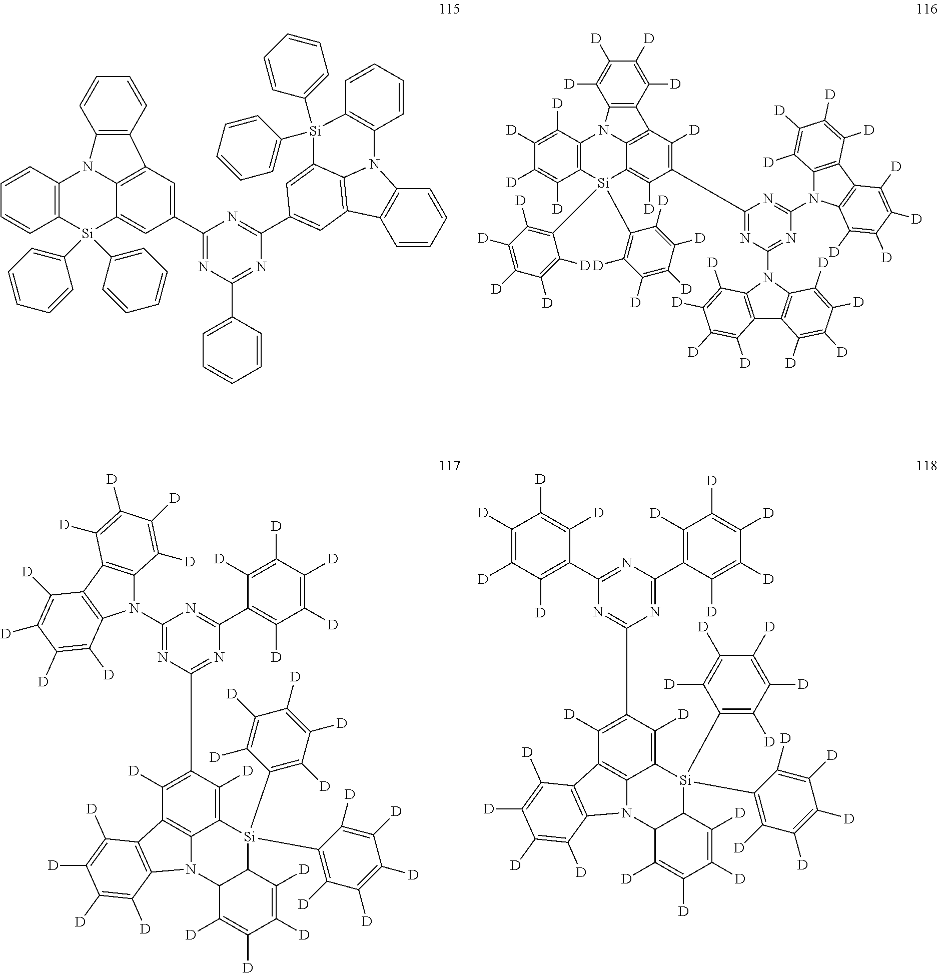

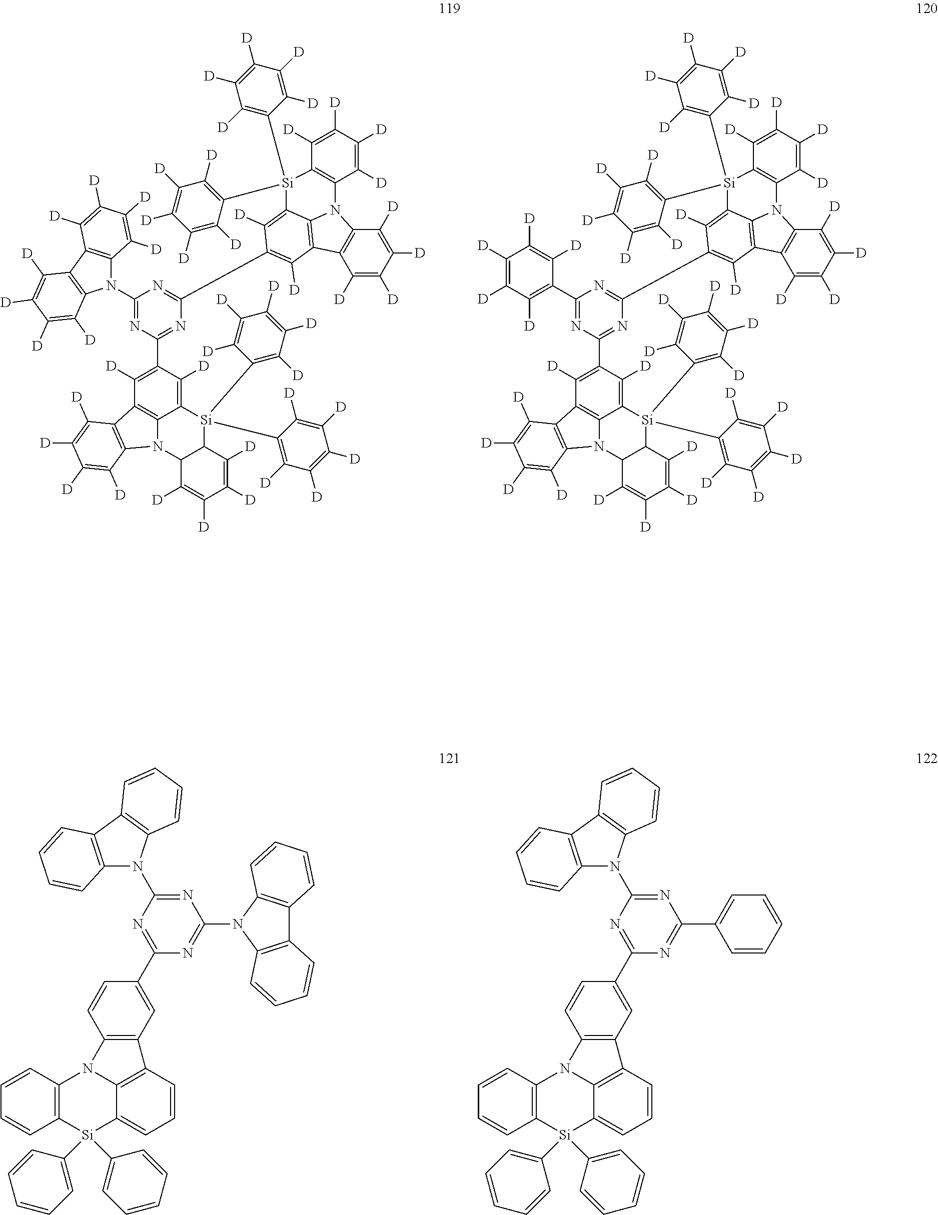

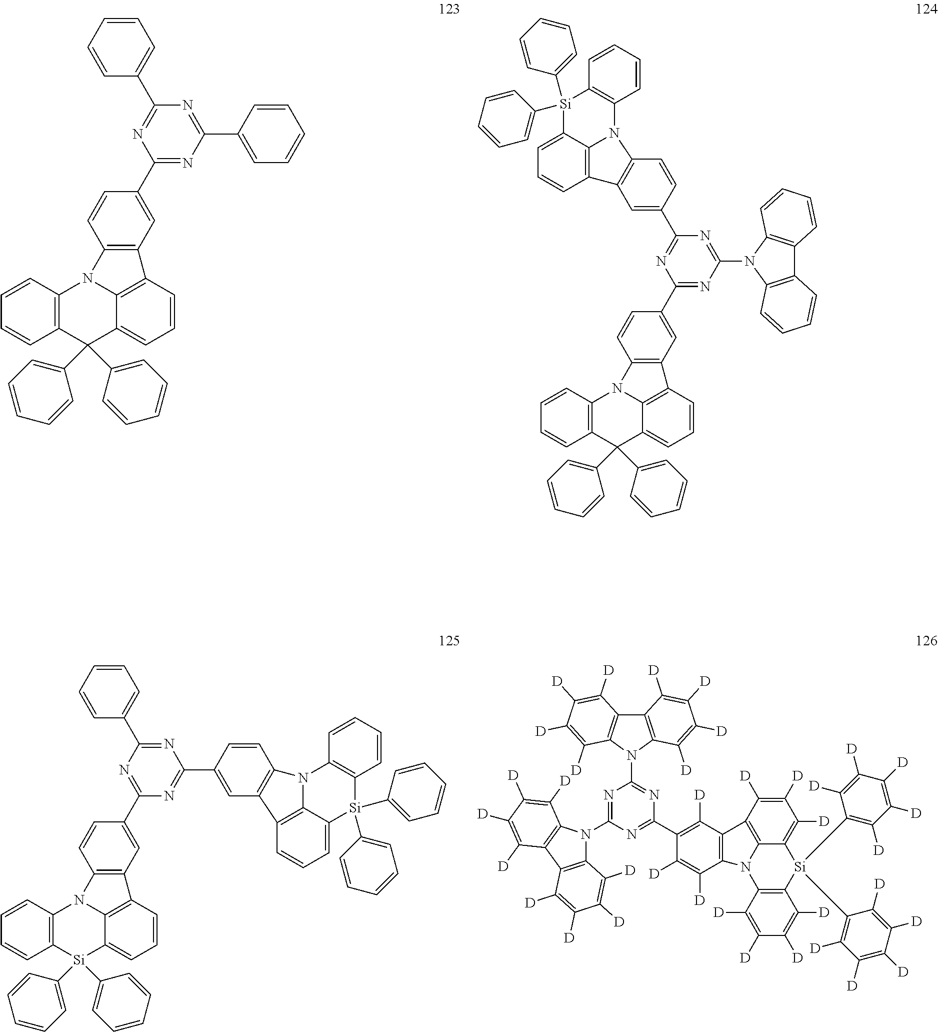

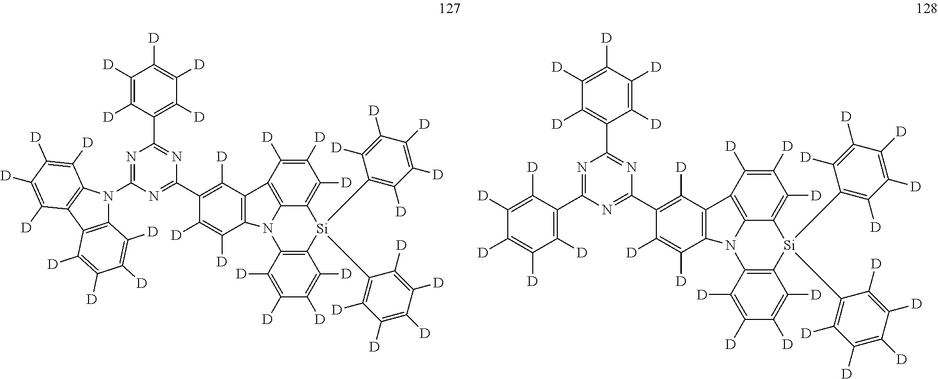

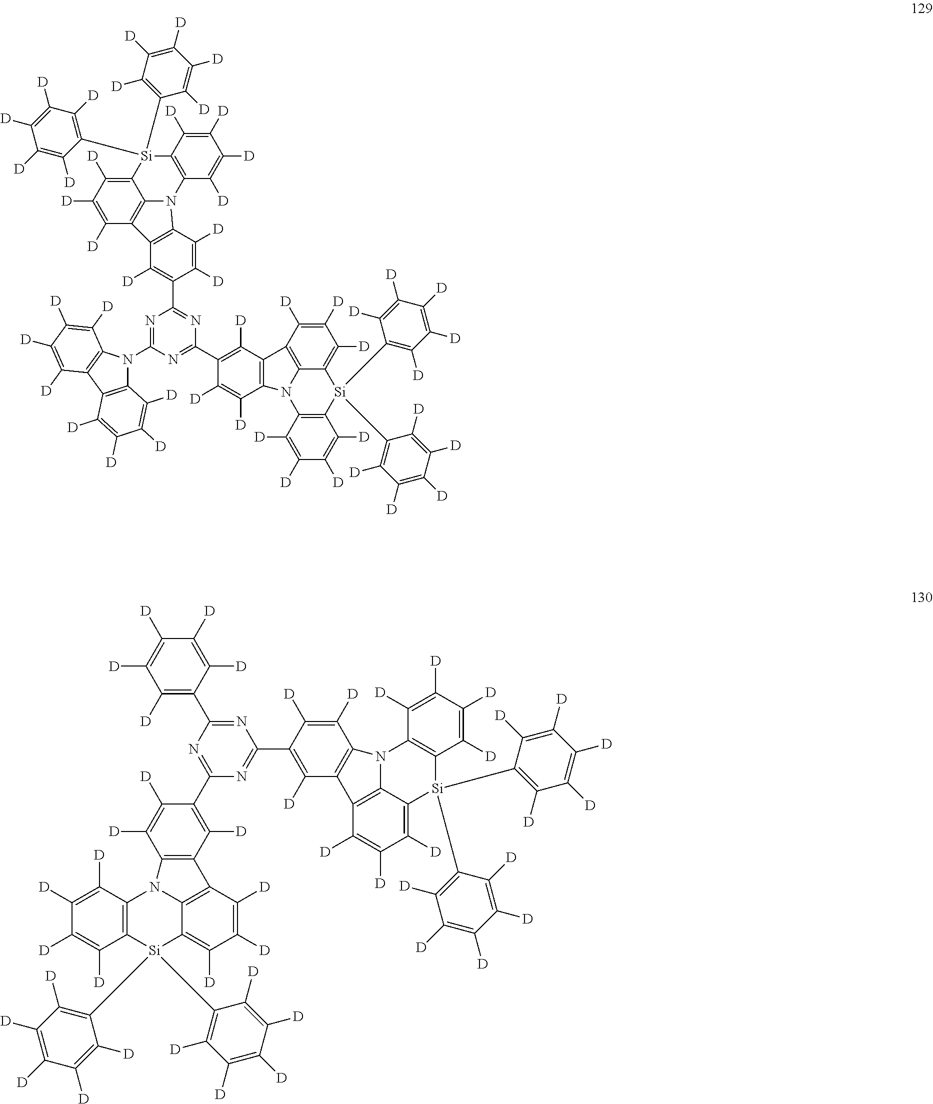

The polycyclic compound according to one or more embodiments has a bulky three-dimensional structure, and interference with an adjacent compound molecule may be minimized or reduced due to the aspect of the three-dimensional structure. Therefore, interaction of the polycyclic compound with other types (kinds) of compounds included in substantially the same layer may be reduced.

Because the polycyclic compound according to one or more embodiments has a high triplet energy level (T1 energy level) and thus may be utilized as a host material. The polycyclic compound according to one or more embodiments may be included in the emission layer EML with a phosphorescent dopant or a fluorescent dopant, and the polycyclic compound according to one or more embodiments may be utilized as a host material. For example, the polycyclic compound according to one or more embodiments may be utilized as a phosphorescent host.

The emission layer EML of the light-emitting element ED containing the polycyclic compound according to one or more embodiments may be to emit blue light. For example, the emission layer EML including the polycyclic compound according to one or more embodiments may be to emit deep blue light.

In one or more embodiments, in the polycyclic compound according to one or more embodiments, at least one of the hydrogen atoms may be substituted with a deuterium atom, and the polycyclic compound substituted with a deuterium atom may exhibit the high T1 energy level of about 2.8 electron volt (eV) or more.

For example, the polycyclic compound according to one or more embodiments contains Si, to thereby have a three-dimensional structure of a cyclized structure, and planarity thereof may be suppressed or reduced. Therefore, intermolecular interactions may decrease, and excellent or suitable material stability may be exhibited.

The light-emitting element according to one or more embodiments, containing the polycyclic compound according to one or more embodiments may have characteristics of high efficiency and a long lifespan. For example, interference with compounds formed from other materials is limited, and thus the light-emitting element may exhibit excellent or suitable color reproducibility if (e.g., when) the polycyclic compound according to one or more embodiments is included as the emission layer material.

In the light-emitting element according to one or more embodiments, the emission layer EML may be a phosphorescent emission layer including a host and a dopant. However, one or more embodiments of the present disclosure is not limited thereto, and the emission layer EML may further include a delayed fluorescent dopant, and the light-emitting element ED may be to emit delayed fluorescence.

The emission layer EML may include the polycyclic compound according to one or more embodiments as a host. In one or more embodiments, the polycyclic compound may be utilized as a phosphorescent host. The emission layer EML may include the polycyclic compound according to one or more embodiments and a phosphorescent dopant. The emission layer EML including, as a host, the polycyclic compound according to one or more embodiments may be to emit blue light.

In one or more embodiments, the emission layer EML may include the polycyclic compound according to one or more embodiments, and may include at least one among the second to fourth compounds, which will be described later. In one or more embodiments, the first compound included in the emission layer EML may be utilized as an electron-transporting host material.

In one or more embodiments, the emission layer EML may include the first compound, which is the polycyclic compound according to one or more embodiments, and the second compound, which is a phosphorescent dopant. The second compound may be an organic metal complex. For example, the emission layer EML may include, as a second compound, an organic metal complex, which contains platinum (Pt) as a core metal atom and ligands bonded to the core metal atom. In the light-emitting element ED according to one or more embodiments, the emission layer EML may contain a compound represented by Formula D-1 as the second compound.

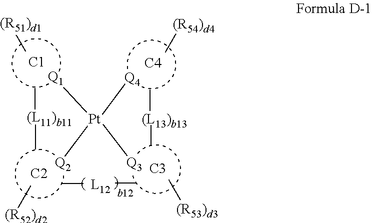

In Formula D-1, Q₁ to Q₄ may each independently be C or N. C₁ to C₄ may each independently be a substituted or unsubstituted hydrocarbon ring having 5 to 30 ring-forming carbon atoms, or a substituted or unsubstituted hetero ring having 2 to 30 ring-forming carbon atoms.

In Formula D-1, L₁₁ to L₁₃ may each independently be a direct linkage,

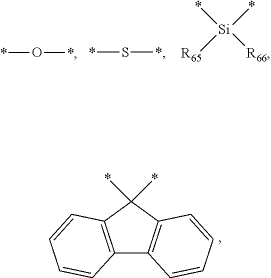

a substituted or unsubstituted divalent alkyl having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃,

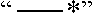

represents a portion connected to C1 to C4.

In Formula D-1, b11 to b13 may each independently be 0 or 1. When b11 is 0, C1 and C2 may not be connected to each other. When b12 is 0, C2 and C3 may not be connected to each other. When b13 is 0, C3 and C4 may not be connected to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when d1 to d4 are each 0, the fourth compound may be unsubstituted with R₆₁ to R₆₄. Cases where d1 to d4 are each 4 and R₆₁ to R₆₄ are each a hydrogen atom may each independently be the same as the cases where d1 to d4 are each 0. When d1 to d4 are each an integer of 2 or more, R₆₁s to R₆₆s provided in the plurality may be the same, or at least one among the plurality of R₆₁s to R₆₄s may be different.

In Formula D-1, C₁ to C₄ may each independently be a substituted or unsubstituted hydrocarbon ring or a substituted or unsubstituted hetero ring, which are represented by any one among C-1 to C-4.

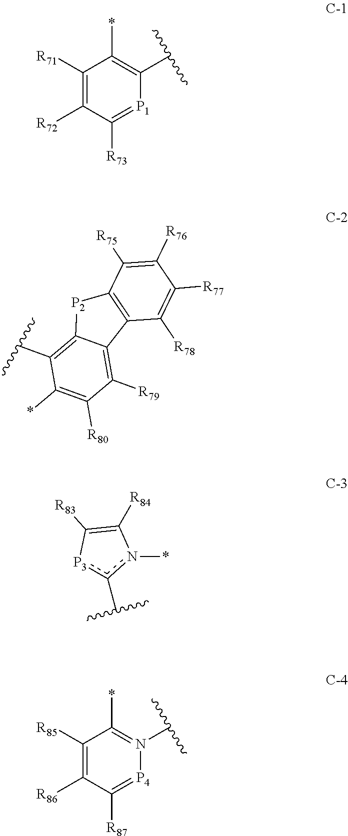

In C-1 to C-4, P1 may be

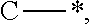

or CR₇₄, P₂ may be

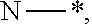

or NR₈₁, P₃ may be

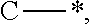

or NR₈₂, and P₄ may be

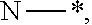

or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in C-1 to C-4,

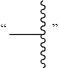

is a portion connected to Pt, which is a core metal atom,

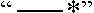

corresponds to a portion connected to an adjacent ring group (C1 to C4) or a linker (L₁₁ to L₁₃).

In one or more embodiments, the second compound represented by Formula D-1 may be represented by any one (e.g., one or at least one) selected from among compounds present in Compound Group 2. The emission layer EML may include, as a phosphorescent dopant, at least one (e.g., one or more) selected from among the compounds present in Compound Group 2. However, the phosphorescent dopant is not limited to the compounds in Compound Group 2.

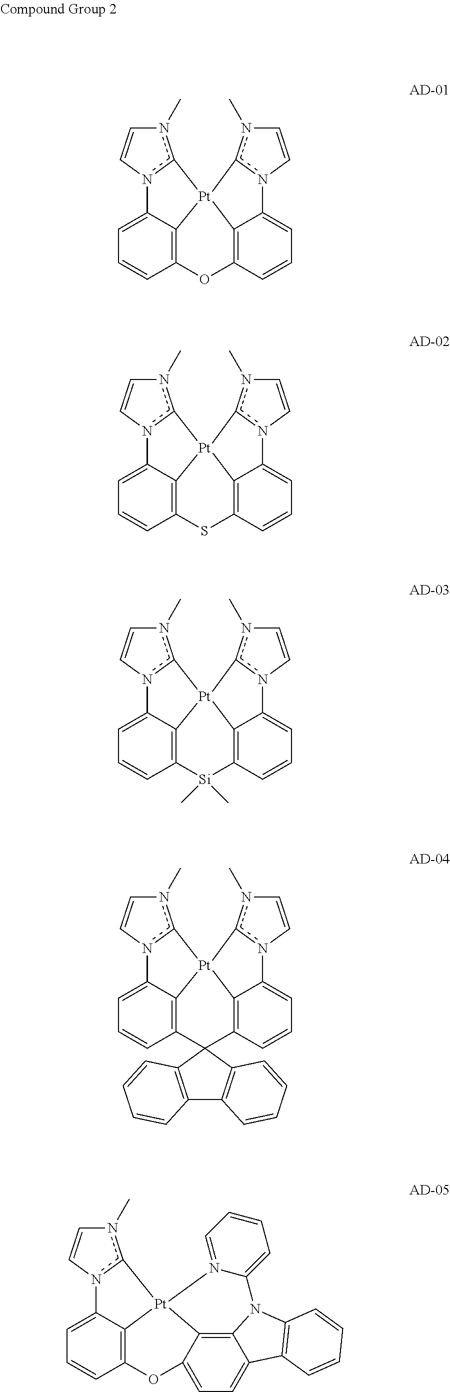

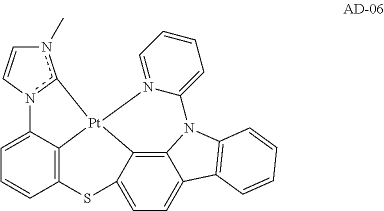

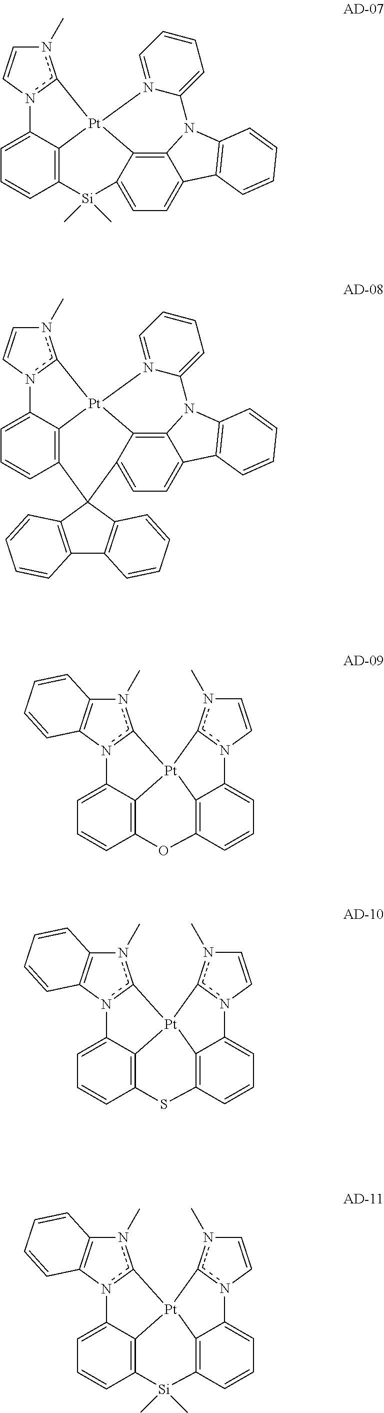

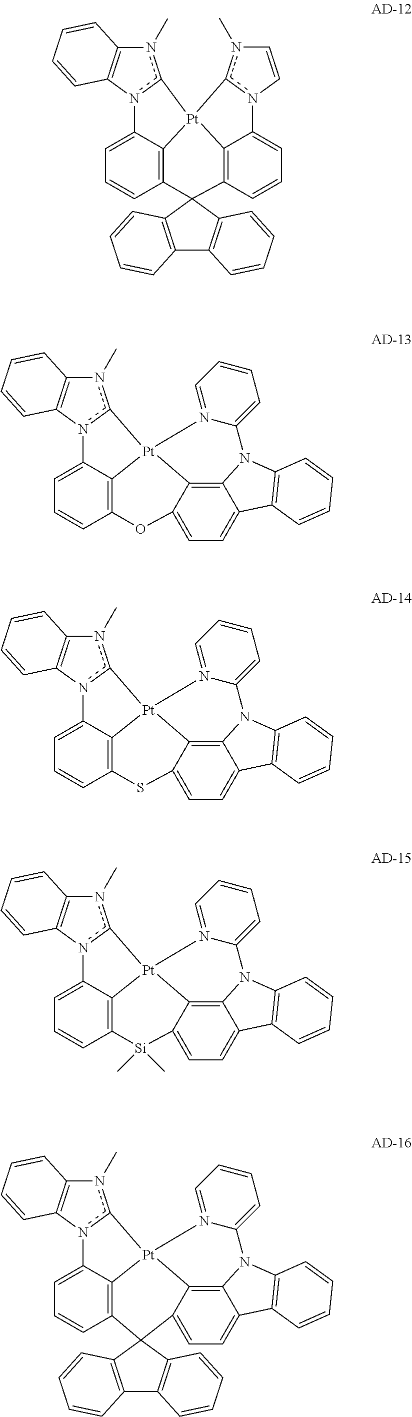

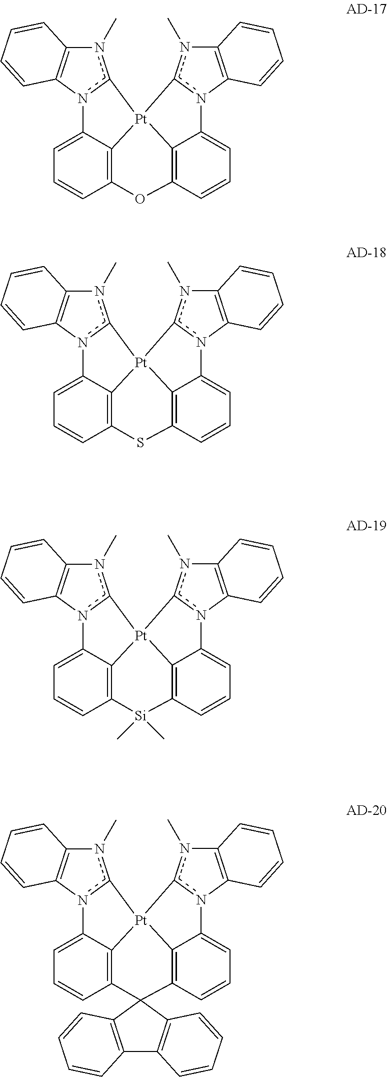

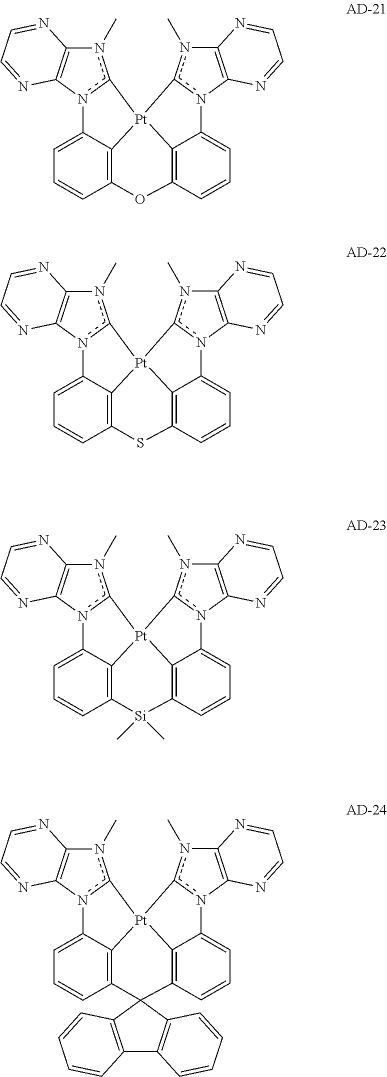

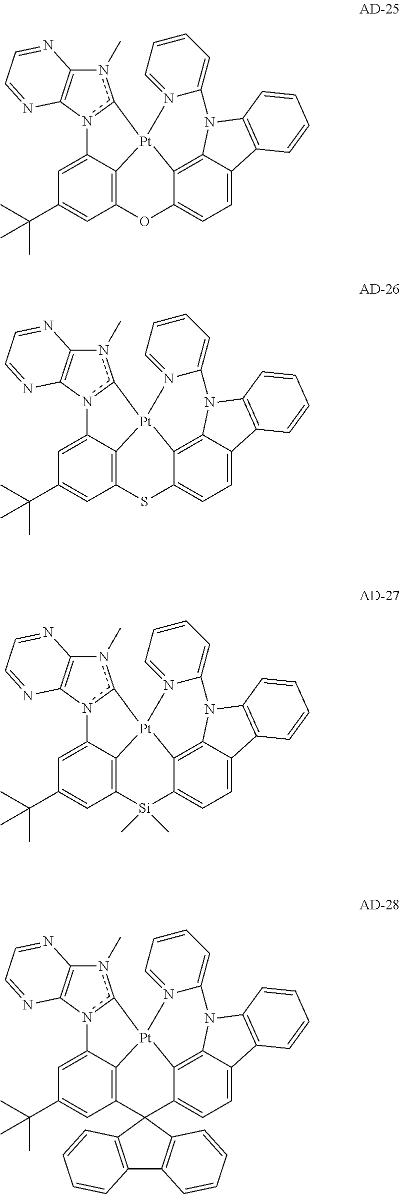

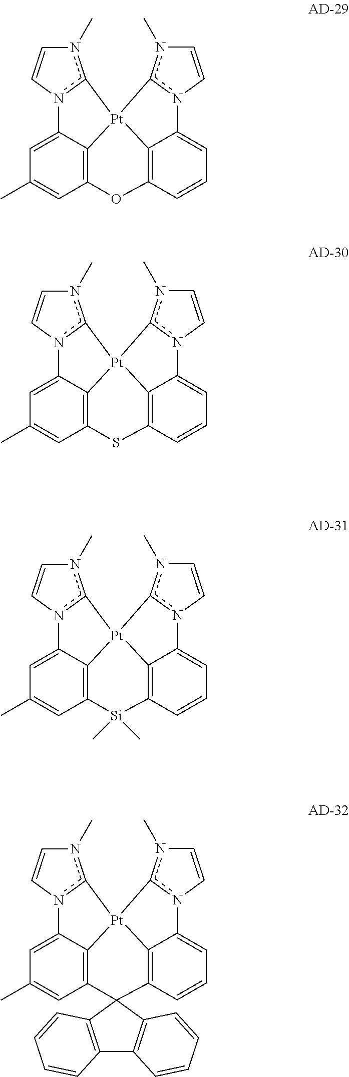

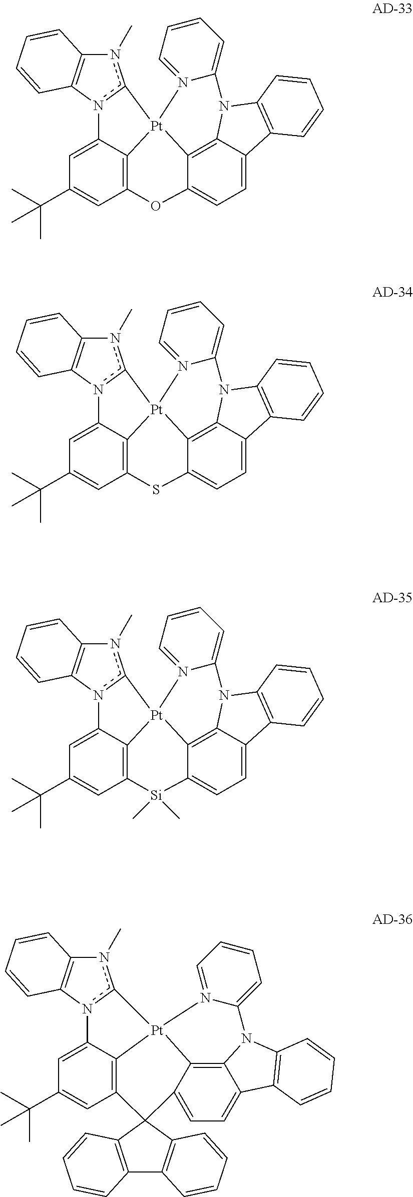

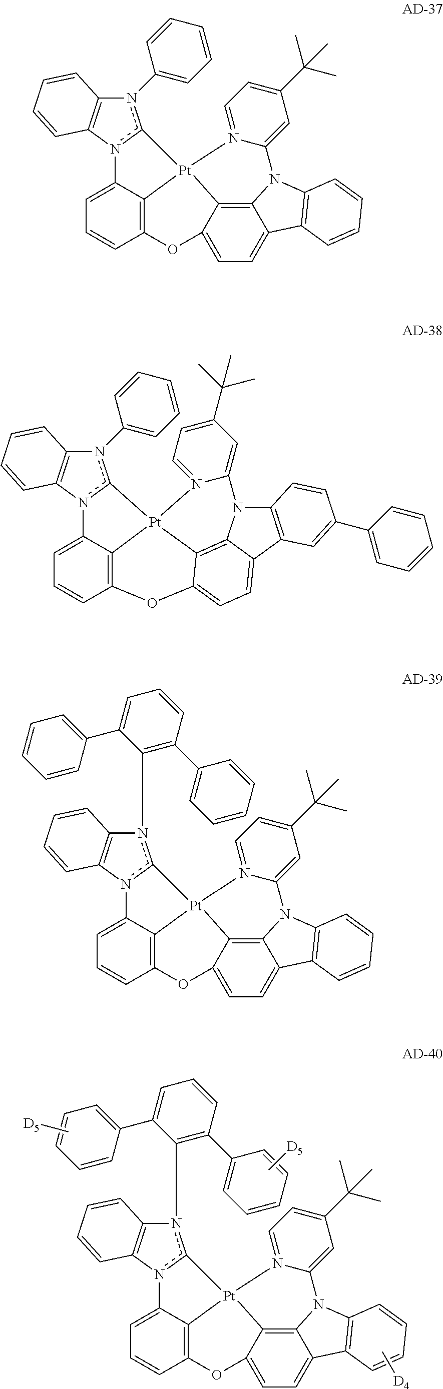

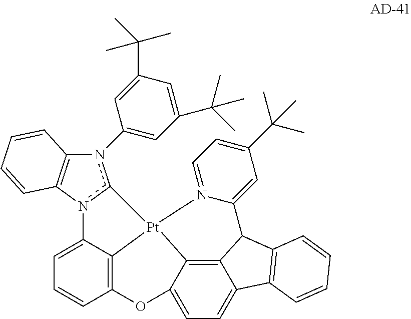

In specific example compounds suggested in Compound Group 2, “D” refers to a deuterium atom.

In one or more embodiments, in one or more embodiments, the second compound included in the emission layer EML may be utilized as a phosphorescent sensitizer. When the emission layer EML includes the first compound, which is the polycyclic compound according to one or more embodiments, the second compound, which is an organic metal complex, and the third compound and the fourth compound, which will be described later, the second compound may transfer energy, as the phosphorescent sensitizer, to the fourth compound. In this case, the fourth compound, as a dopant, may be to emit light.

In one or more embodiments, the emission layer EML may contain the third compound represented by Formula HT-1. For example, the third compound may be utilized as a hole-transporting host material of the emission layer EML.

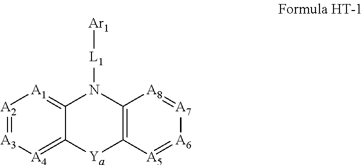

In Formula HT-1, A₁ to A₈ may each independently be N or CR₅₁. For example, all A₁ to A₈ may be CR₅₁. In one or more embodiments, at least one among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group and/or the like, but one or more embodiments of the present disclosure is not limited thereto.

In Formula HT-1, Yₐ may be a direct linkage, CR₅₂R₅₃, or SiR₅₄R₅₅. For example, it may refer to that two benzene rings bonded to a nitrogen atom of Formula HT-1 may be connected via a direct linkage,

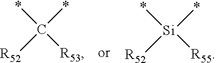

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, R₅₁ to R₅₅ may be each bonded to an adjacent group to form a ring. For example, R₅₁ to R₅₅ may each independently be a hydrogen atom, or a deuterium atom. R₅₁ to R₅₅ may each independently be an unsubstituted methyl group, or an unsubstituted phenyl group.

In one or more embodiments, the third compound represented by Formula HT-1 may be represented by any one (e.g., one) selected from among compounds present in Compound Group 3. The emission layer EML may include, as a hole-transporting host material, at least one (e.g., one or more) selected from among the compounds present in Compound Group 3.

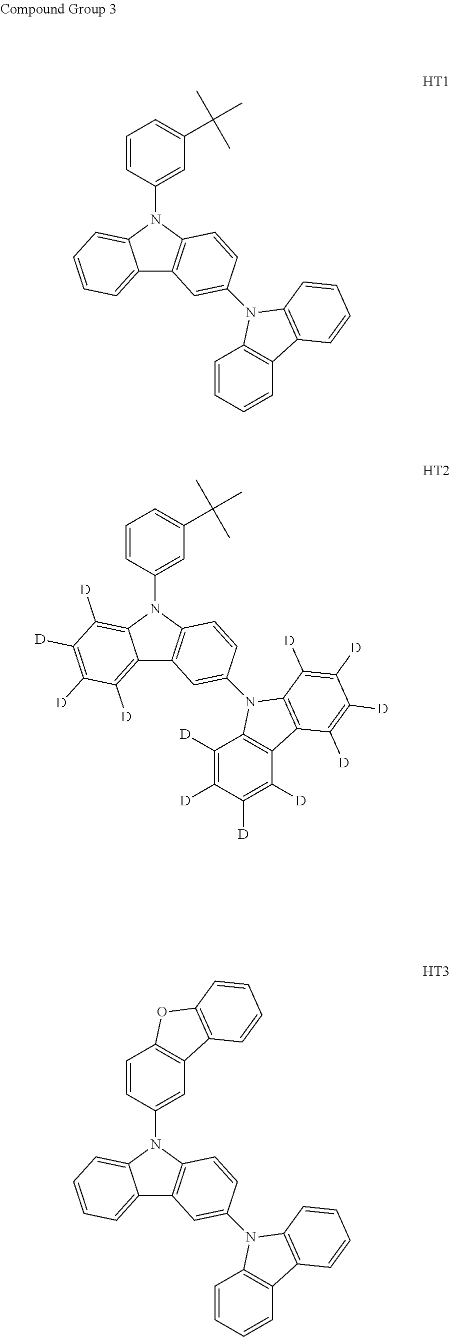 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

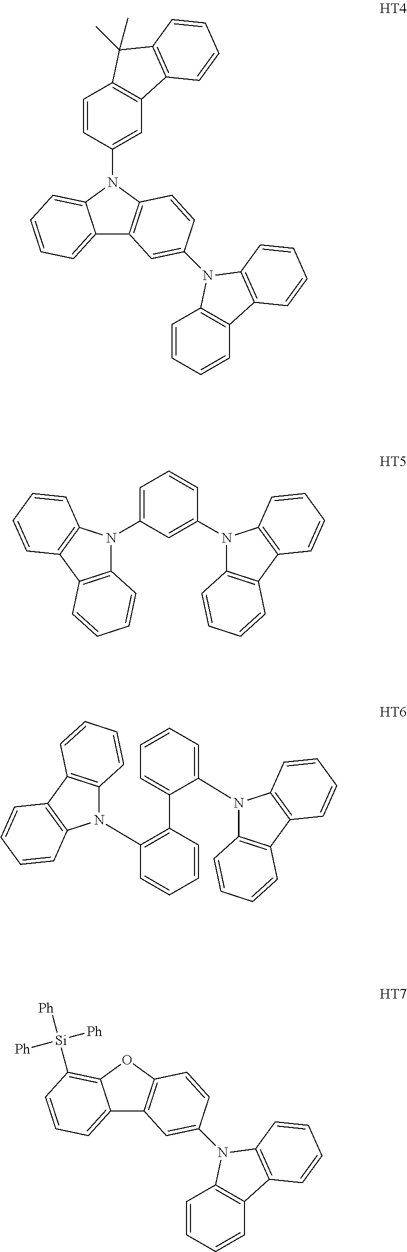 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

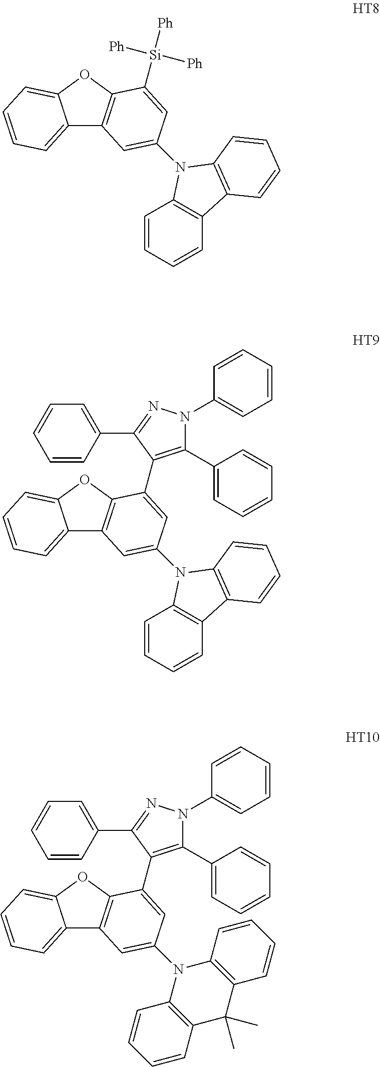 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

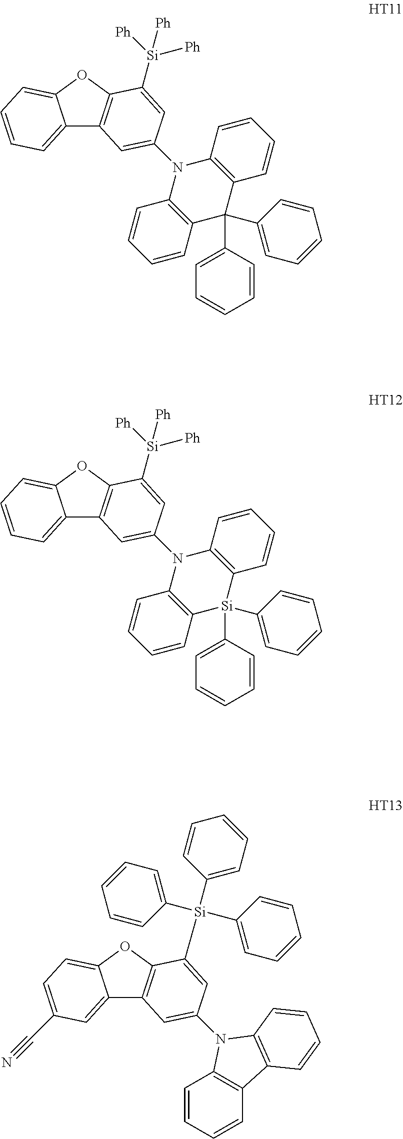 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

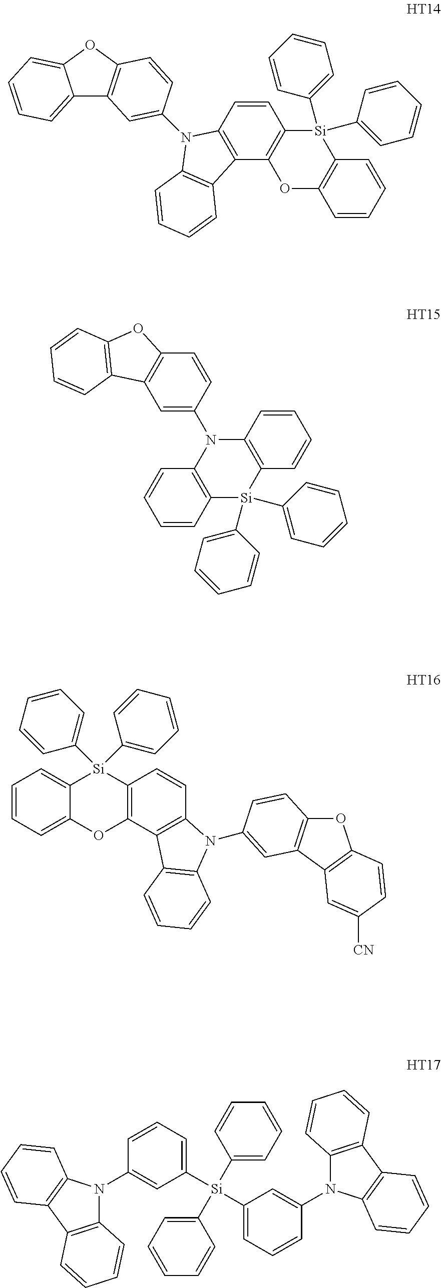 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

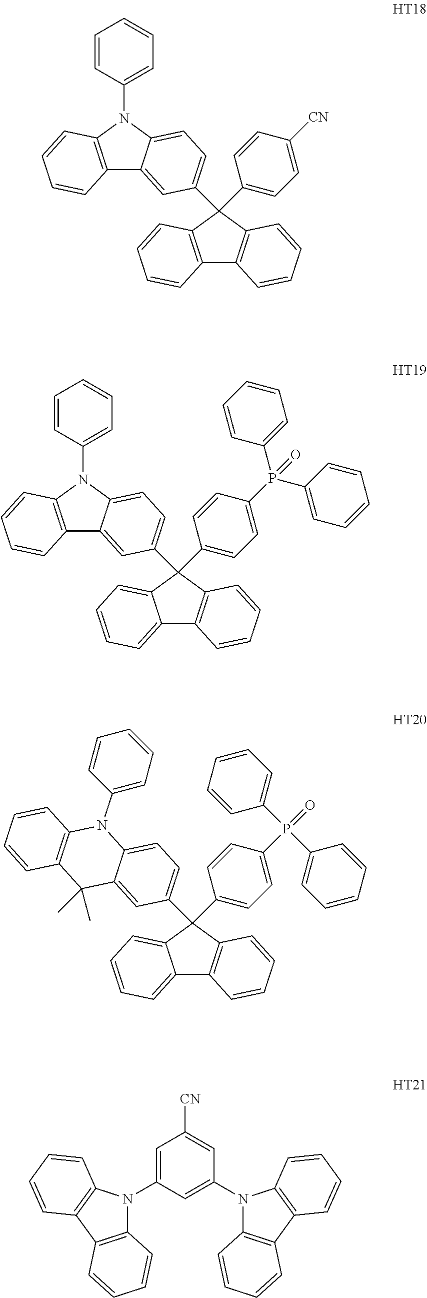 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

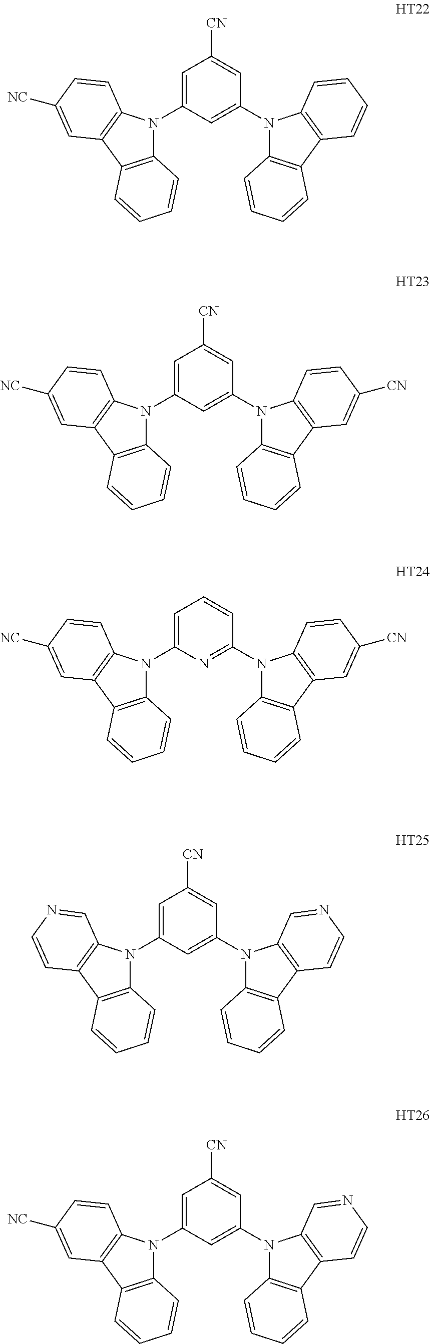 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

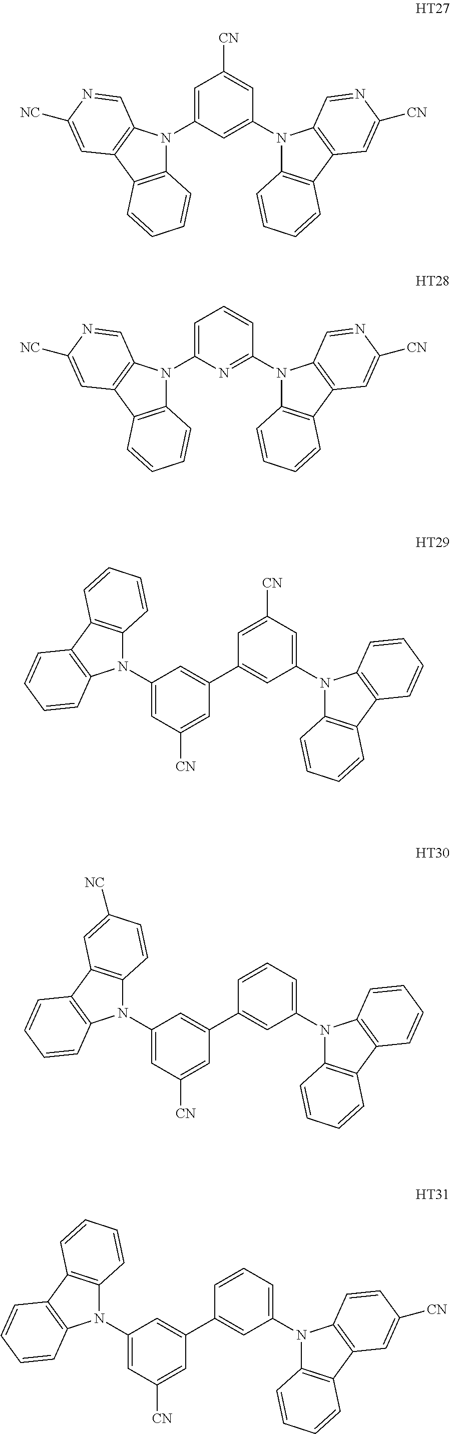 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

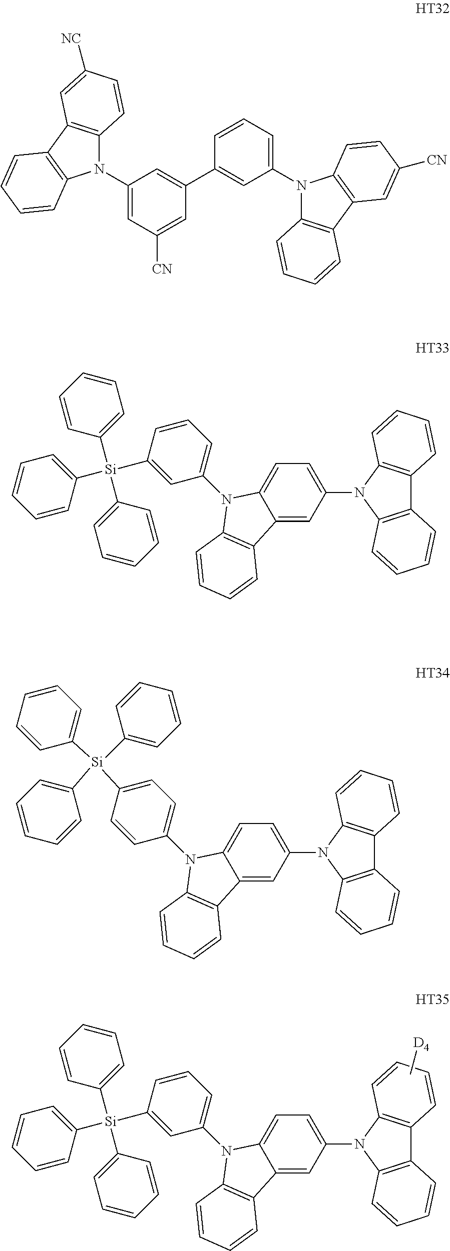

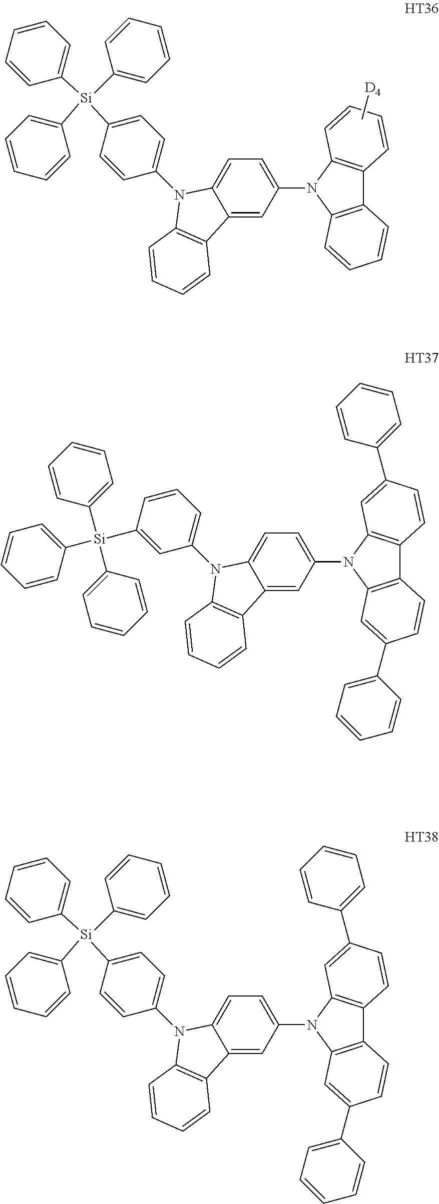

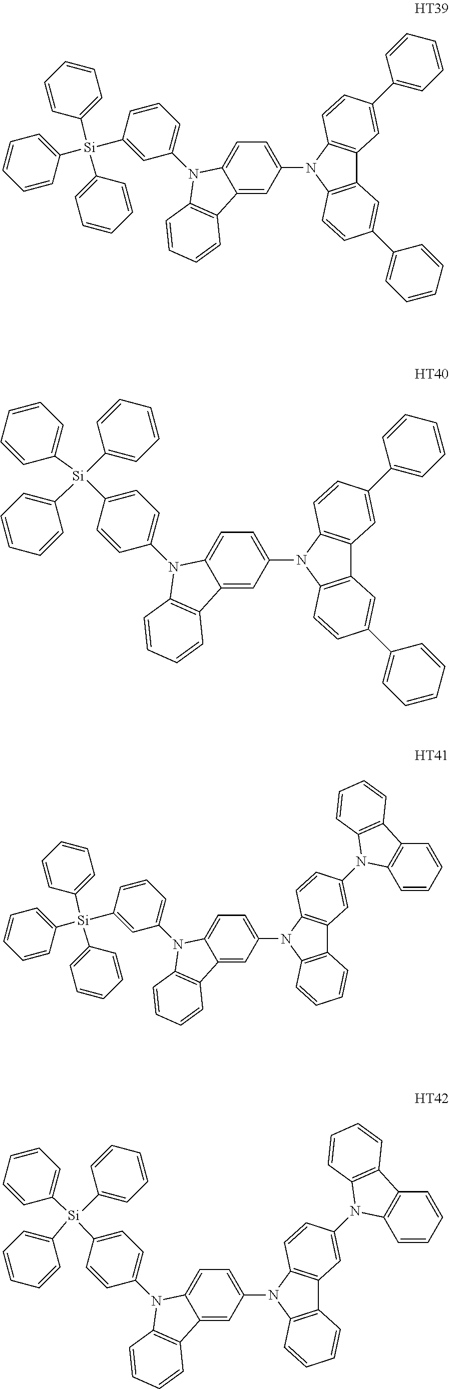 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

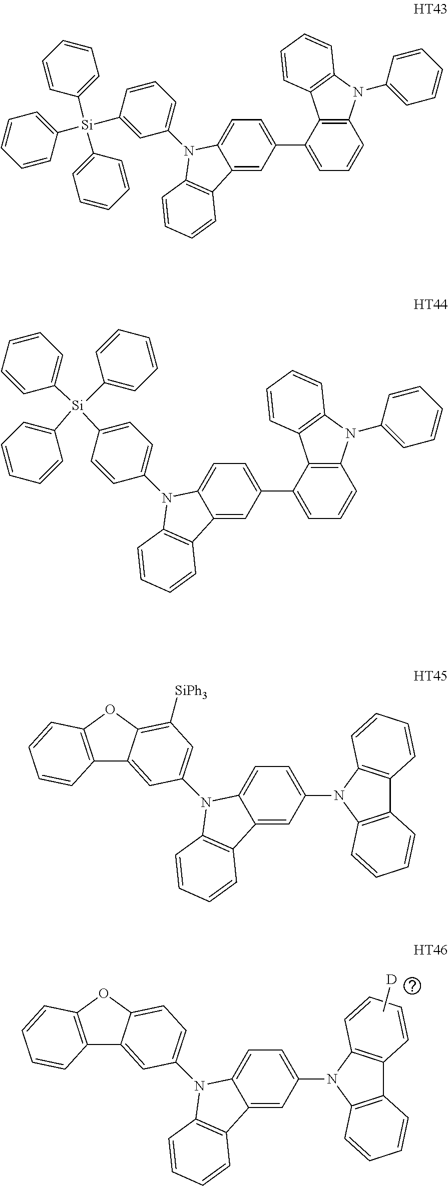

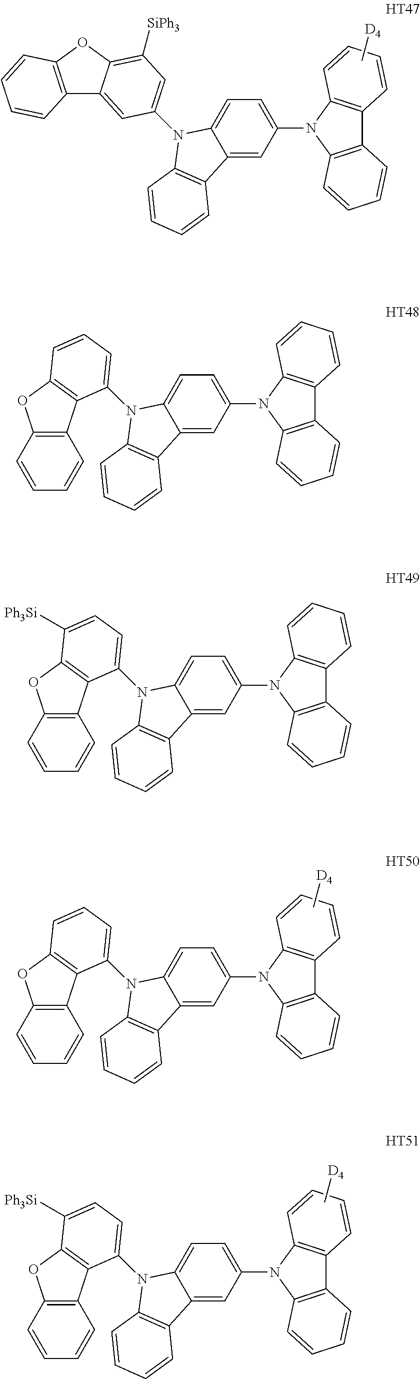

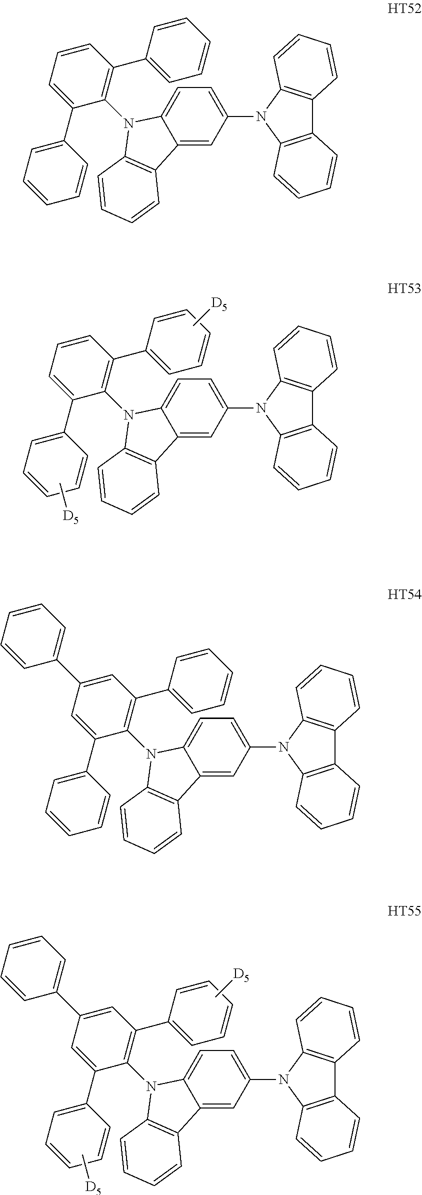

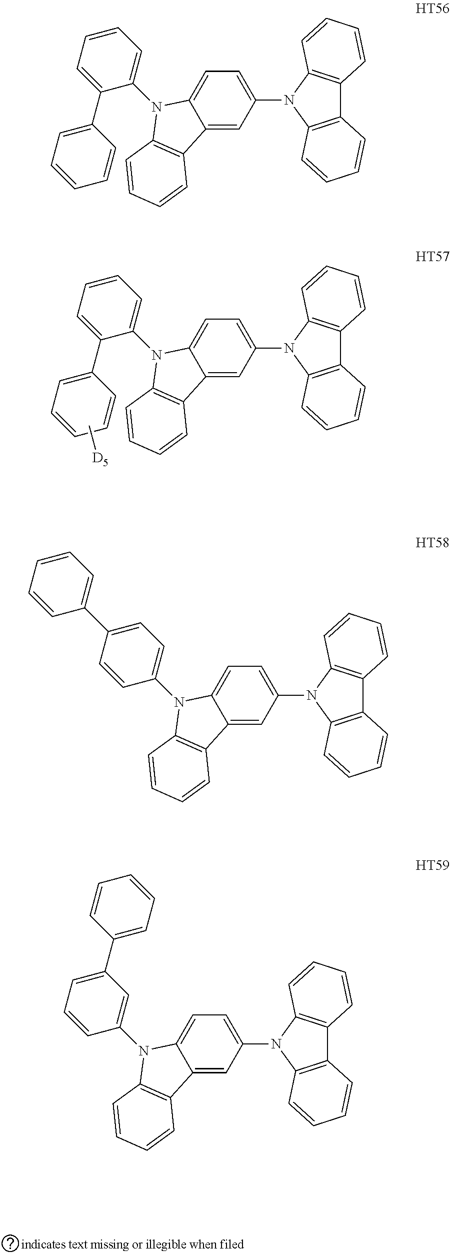

In specific example compounds suggested in Compound Group 3, “D” may refer to a deuterium atom, and “Ph” may refer to a substituted or unsubstituted phenyl group. For example, in the specific example compounds suggested in Compound Group 3, “Ph” may be an unsubstituted phenyl group.

In one or more embodiments, the third compound represented by Formula HT-1 may be included as a material of the hole transport region HTR.

In one or more embodiments, the emission layer EML may further include a fourth compound represented by Formula F-1.

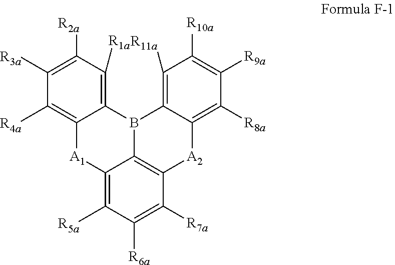

In Formula F-1, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ria to R₁₁ₐ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-1, A₁ and A₂ may each independently be bonded to substituents of an adjacent ring to form a fused ring. For example, if (e.g., when) Ai and A₂ may each independently be NRₘ, A₁ may be bonded to R₄ₐ or R₅ₐ to form a ring. In one or more embodiments, A₂ may be bonded to R₇ₐ or R₈ₐ to form a ring.

For example, the fourth compound represented by Formula F-1 may be included in the emission layer EML as a dopant. In one or more embodiments, the fourth compound represented by Formula F-1 may be a thermally activated delayed fluorescent dopant.

The fourth compound may be represented by any one (e.g., one) selected from among compounds in Compound Group 4.

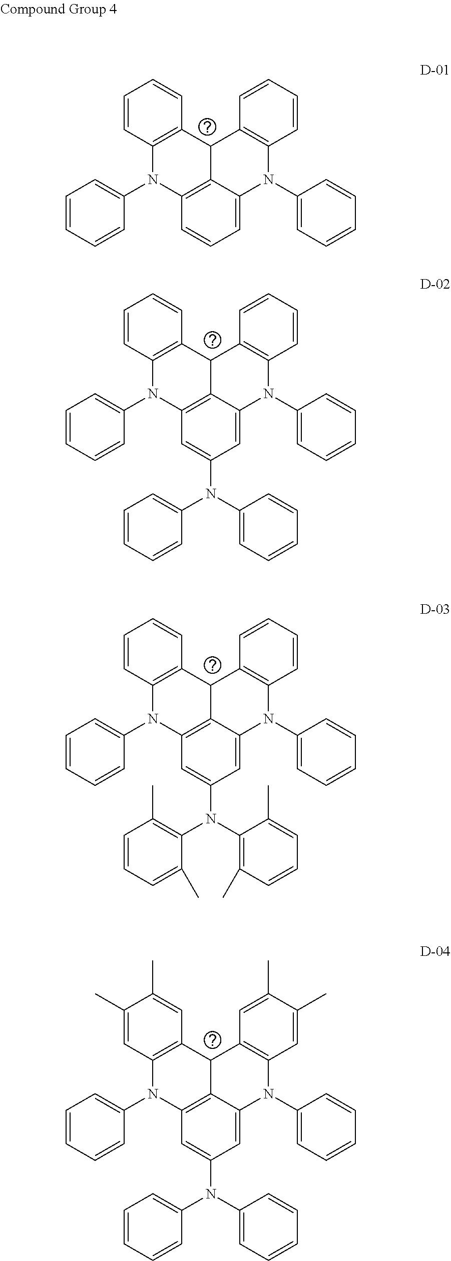 [SMILES: c1ccc(N2c3ccccc3C3c4ccccc4N(c4ccccc4)c4cccc2c43)cc1 ; c1ccc(N(c2ccccc2)c2cc3c4c(c2)N(c2ccccc2)c2ccccc2C4c2ccccc2N3c2ccccc2)cc1 ; Cc1cccc(C)c1N(c1cc2c3c(c1)N(c1ccccc1)c1ccccc1C3c1ccccc1N2c1ccccc1)c1c(C)cccc1C ; Cc1cc2c(cc1C)N(c1ccccc1)c1cc(N(c3ccccc3)c3ccccc3)cc3c1C2c1cc(C)c(C)cc1N3c1ccccc1]

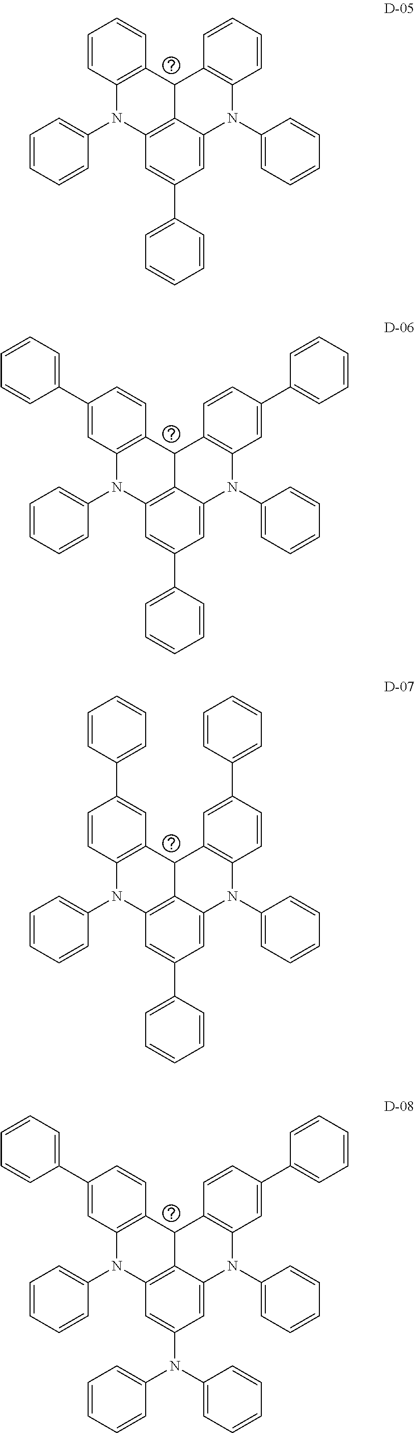 [SMILES: c1ccc(-c2cc3c4c(c2)N(c2ccccc2)c2ccccc2C4c2ccccc2N3c2ccccc2)cc1 ; c1ccc(-c2ccc3c(c2)N(c2ccccc2)c2cc(-c4ccccc4)cc4c2C3c2ccc(-c3ccccc3)cc2N4c2ccccc2)cc1 ; c1ccc(-c2ccc3c(c2)C2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2C3c2ccc(-c3ccccc3)cc2N4c2ccccc2)cc1]

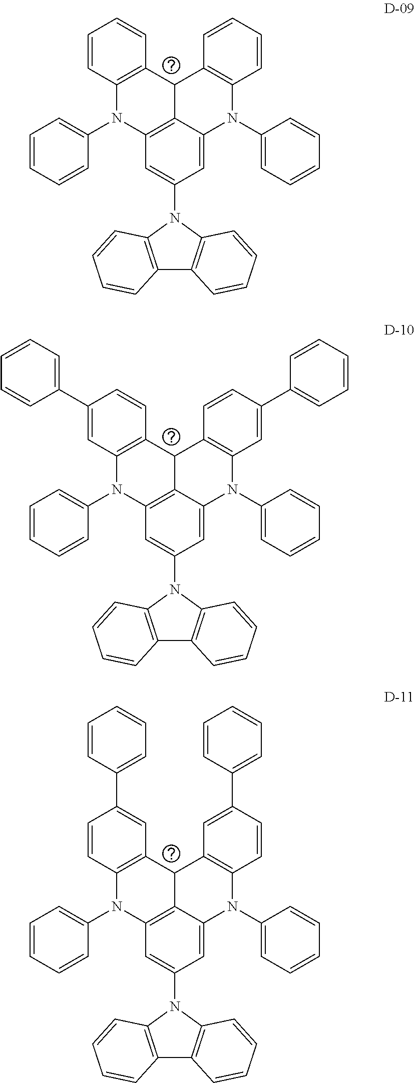

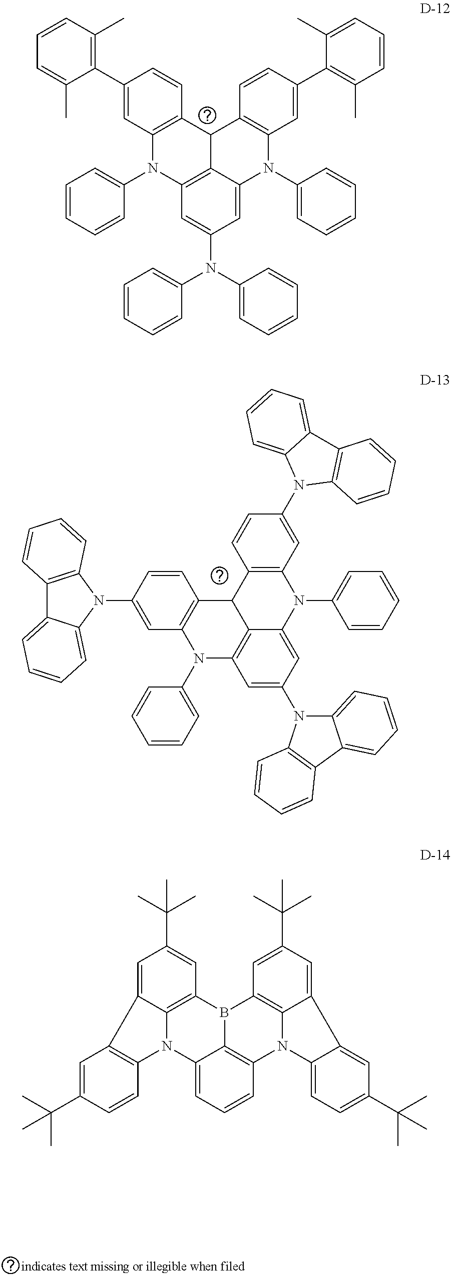 [SMILES: Cc1cccc(C)c1-c1ccc2c(c1)N(c1ccccc1)c1cc(N(c3ccccc3)c3ccccc3)cc3c1C2c1ccc(-c2c(C)cccc2C)cc1N3c1ccccc1 ; c1ccc(N2c3cc(-n4c5ccccc5c5ccccc54)ccc3C3c4ccc(-n5c6ccccc6c6ccccc65)cc4N(c4ccccc4)c4cc(-n5c6ccccc6c6ccccc65)cc2c43)cc1 ; CC(C)(C)c1ccc2c(c1)c1cc(C(C)(C)C)cc3c1n2-c1cccc2c1B3c1cc(C(C)(C)C)cc3c4cc(C(C)(C)C)ccc4n-2c13]

The fourth compound may be a delayed fluorescent dopant. For example, the fourth compound may be a thermally activated delayed fluorescent dopant. In one or more embodiments, types (kinds) of the fourth compound are not limited to the specific example compounds present in Compound Group 4, and in a case of the delayed fluorescent dopant material, in one or more embodiments, the fourth compound may be included in the emission layer as dopant materials with the polycyclic compound, which is the first compound.

The emission layer EML according to one or more embodiments may include at least one selected from among the first to fourth compounds, the first compound being a polycyclic compound. For example, the emission layer EML may include the first compound, the second compound, and the third compound.

In one or more embodiments, the emission layer EML may include each (e.g., all) of the first compound, the second compound, the third compound, and the fourth compound. For example, the emission layer EML may include a combination of two host materials and two dopant materials. In the light-emitting element ED according to one or more embodiments, the emission layer EML may concurrently (e.g., simultaneously) include the first compound and the third compound, which are different two hosts, the fourth compound emitting delayed fluorescence, and the second compound containing an organic metal complex, thereby having excellent or suitable luminous efficiency characteristics.

In the emission layer EML, an exciplex may be formed by a hole-transporting host and an electron-transporting host. In the emission layer EML, the first compound, and the third compound may form the exciplex. In this case, an energy of a triplet state of the exciplex formed by the hole-transporting host and the electron-transporting host may correspond to a difference between energy levels of a lowest unoccupied molecular orbital (LUMO) of the electron-transporting host and a highest occupied molecular orbital (HOMO) of the hole-transporting host.

In the emission layer EML, the first compound which is an electron-transporting host material, and the third compound which is a hole-transporting material may form an exciplex, and energy may be transferred from the exciplex to the second compound and the fourth compound, thereby causing light to be emitted. In one or more embodiments, the second compound may function as a sensitizer. In the light-emitting element ED according to one or more embodiments, the second compound included in the emission layer EML may function as a sensitizer and thus may serve to transfer energy from the host to the fourth compound which is an emission dopant. For example, the second compound which serves as an auxiliary dopant may accelerate energy transfer to the fourth compound which is an emission dopant, and thus an emission rate of the fourth compound may increase.

In the light-emitting element ED according to one or more embodiments, if (e.g., when) the emission layer EML includes the described first compound, second compound, and third compound, amounts of the first compound which is a host material, and the third compound, may be about 65 wt % to about 95 wt % with respect to the total weight of the first compound, the second compound, and the third compound.

In one or more embodiments, the emission layer EML may further include a compound represented by Formula ET-1. For example, a fifth compound represented by Formula ET-1 may be further included as an electron-transporting host material of the emission layer EML.

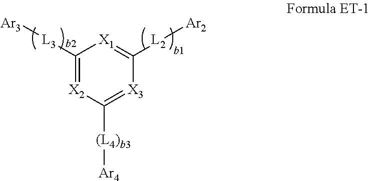

In Formula ET-1, at least one selected from among X₁ to X₃ may be N, and the rest may be CR₅₆. For example, any one selected from among X₁ to X₃ may be N, and the remaining two may each independently be CR₅₆. In this case, the third compound represented by Formula ET-1 may include a pyridine moiety. In one or more embodiments, two among X₁ to X₃ may be N, and the remaining one may be CR₅₆. In this case, the fifth compound represented by Formula ET-1 may include a pyrimidine moiety. In one or more embodiments, each (e.g., all) of X₁ to X₃ may be N. In this case, the fifth compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, when b1 to b3 are each an integer of 2 or more, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the fifth compound may be represented by any one selected from among compounds in Compound Group 5. The light-emitting element ED according to one or more embodiments may further include at least one selected from among the compounds in Compound Group 5.

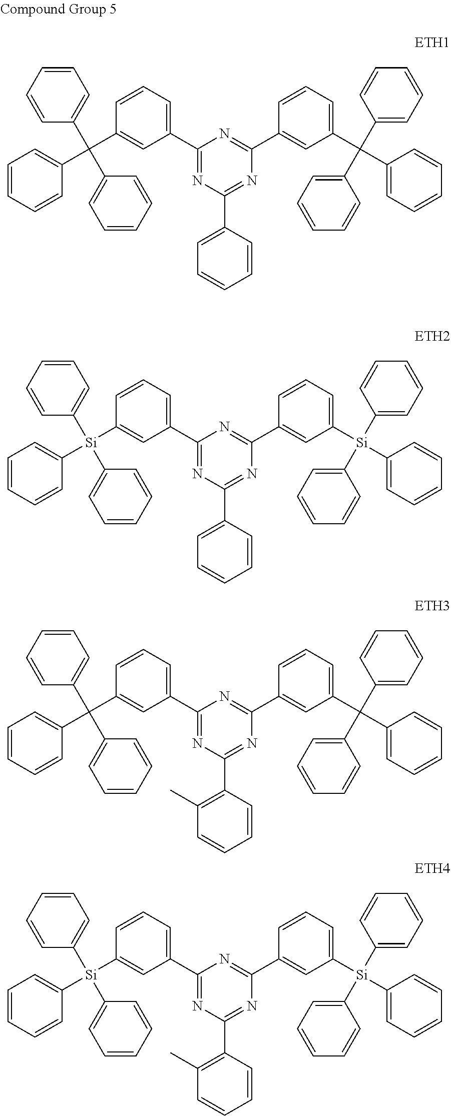 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

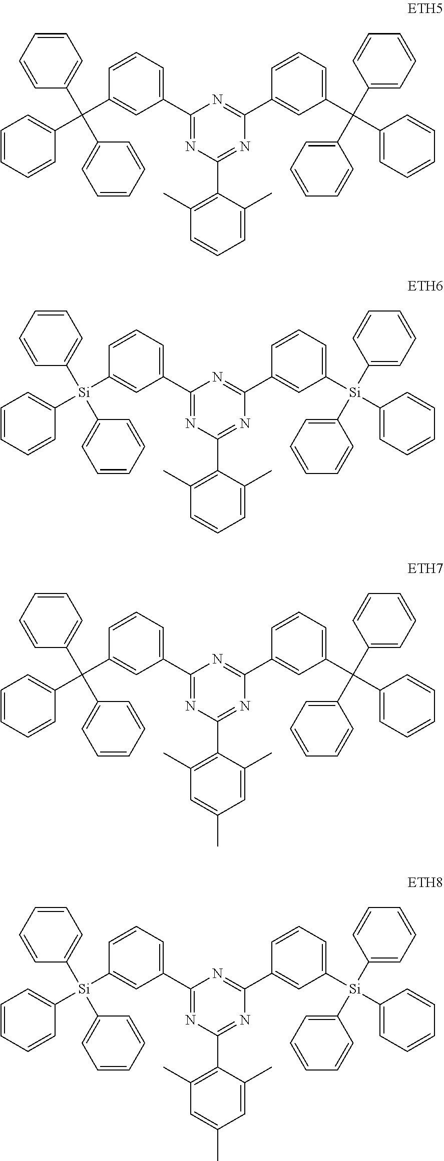 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

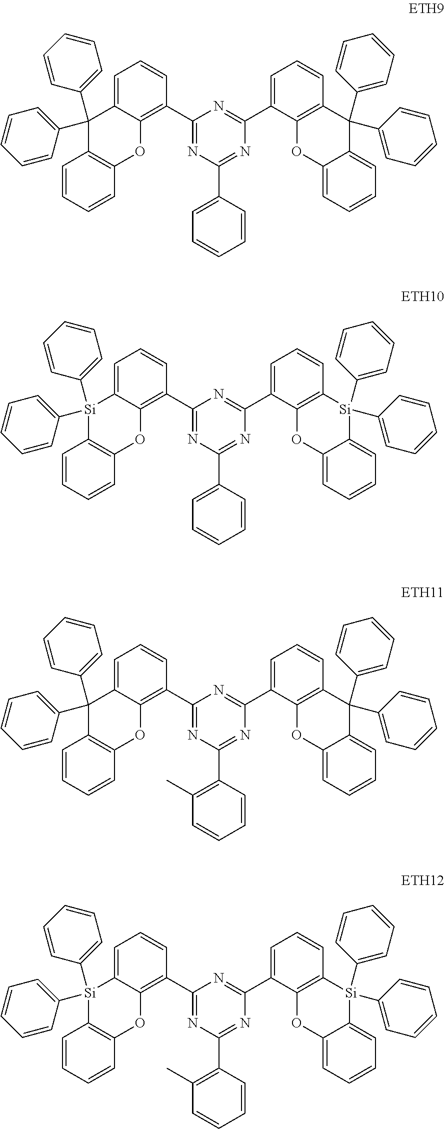 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

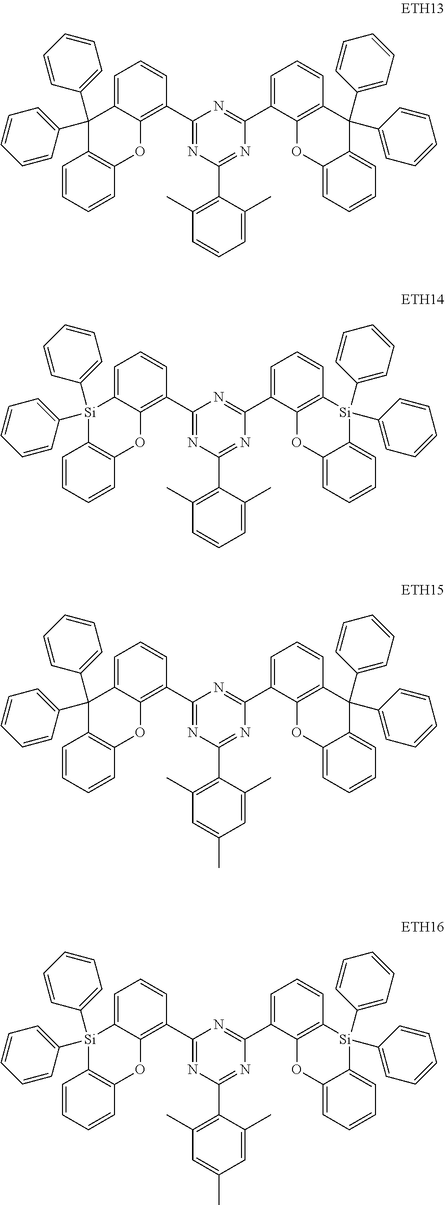 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

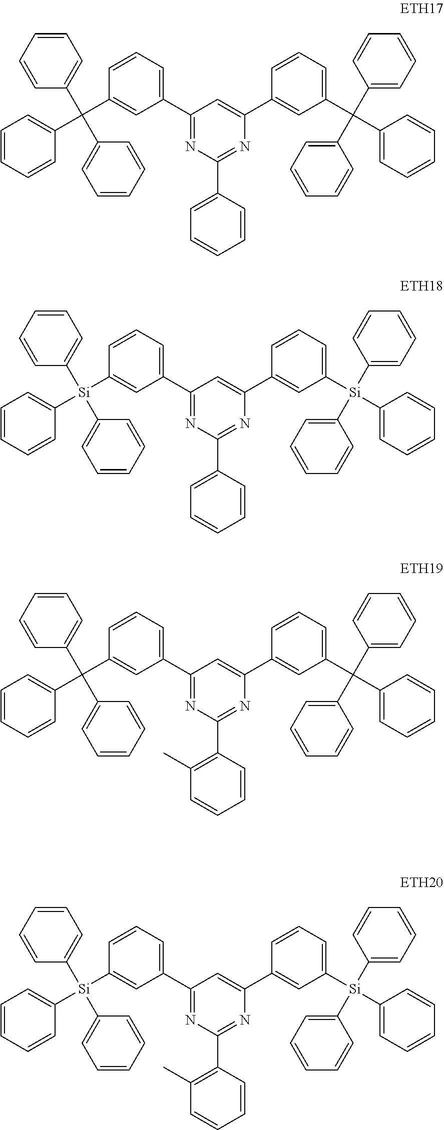 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

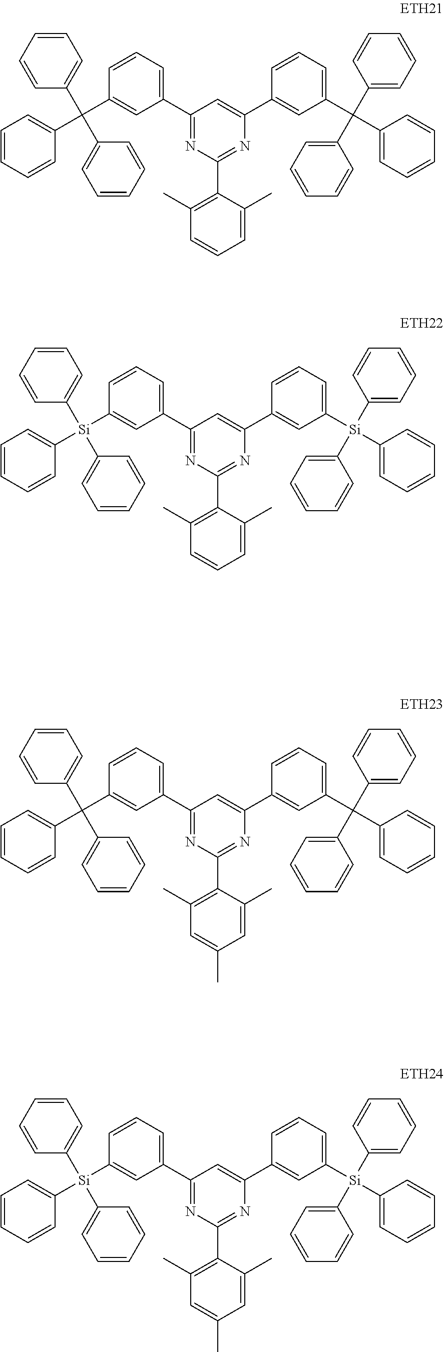 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

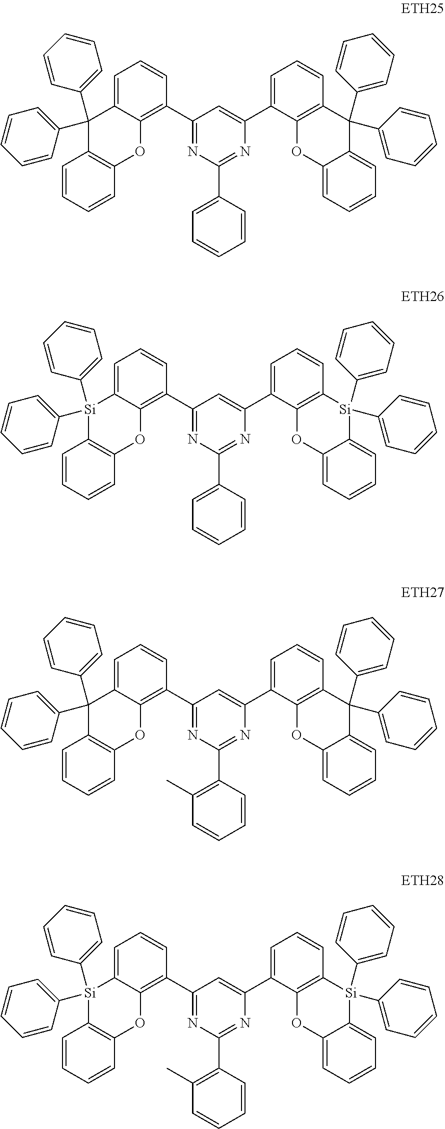 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

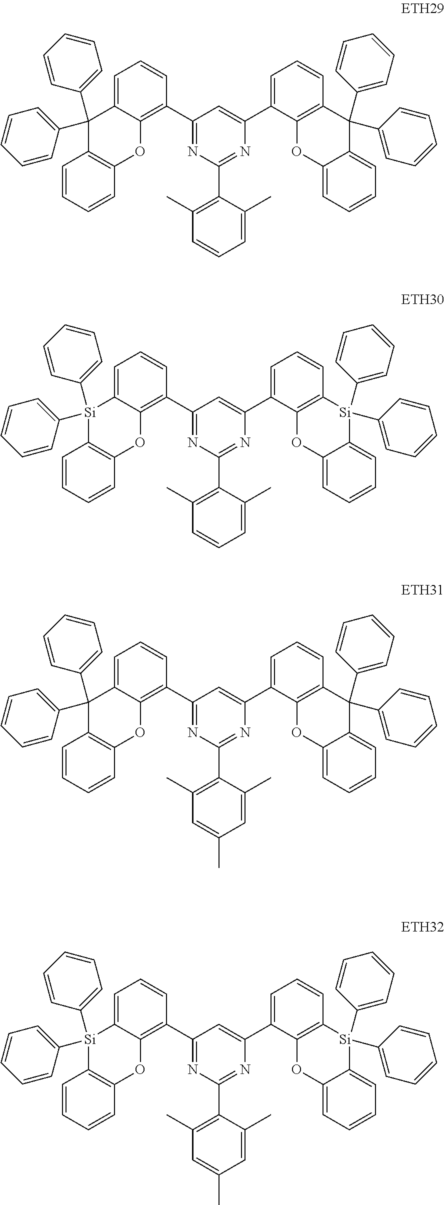 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

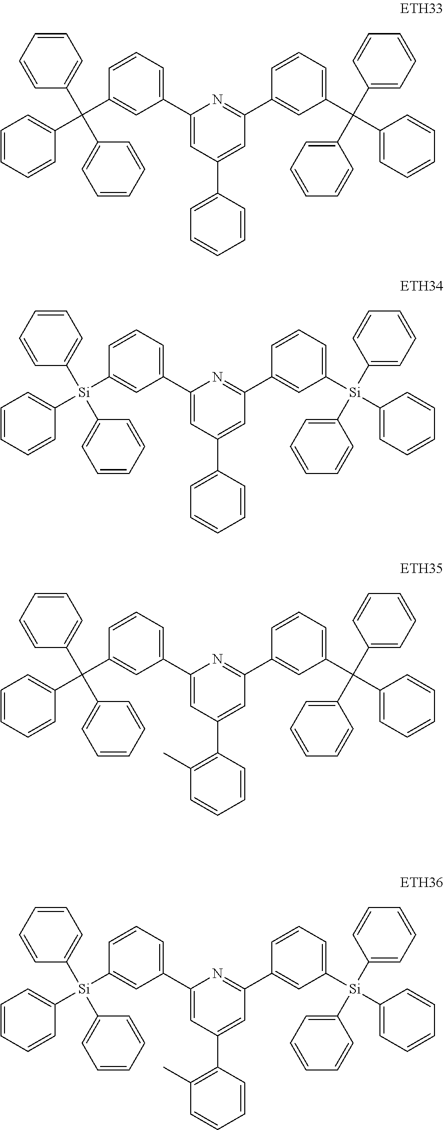 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

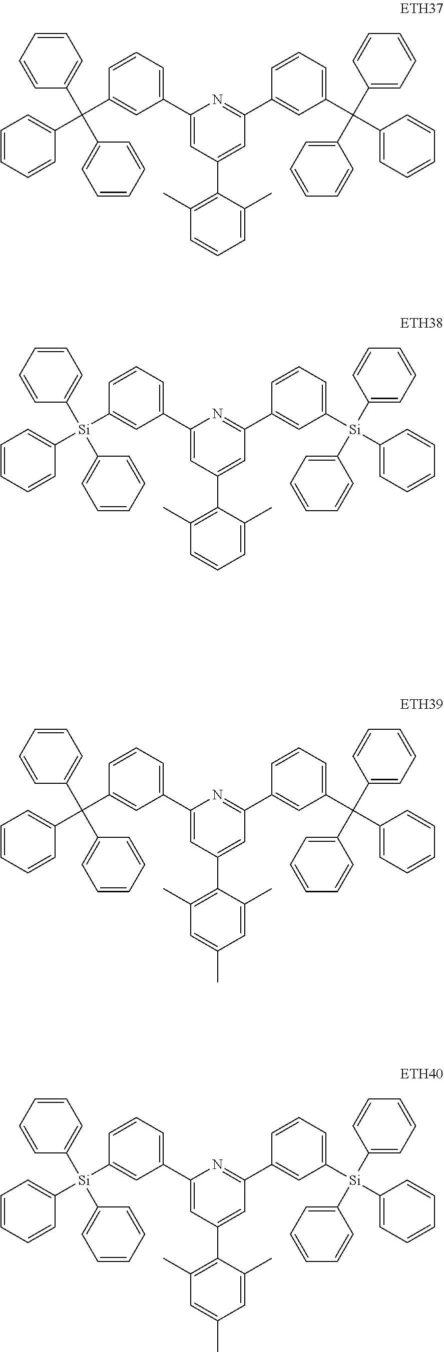 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

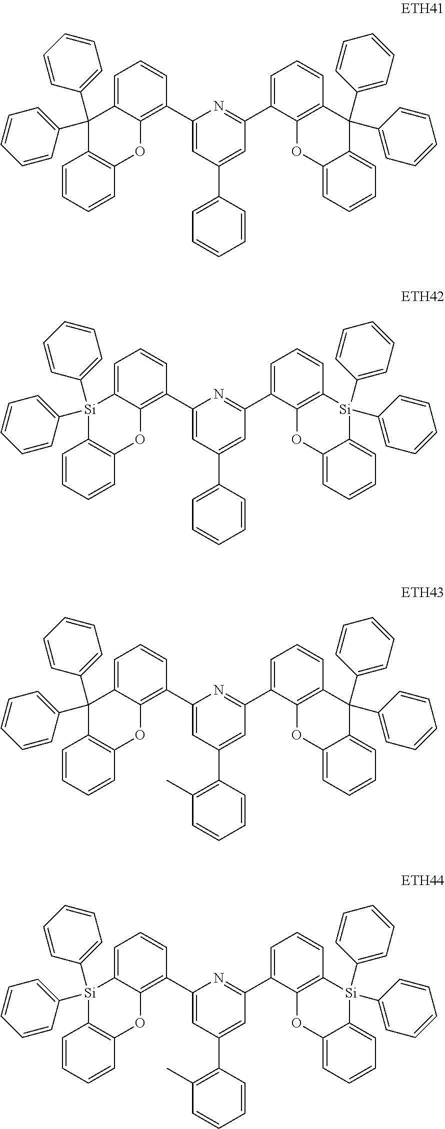 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

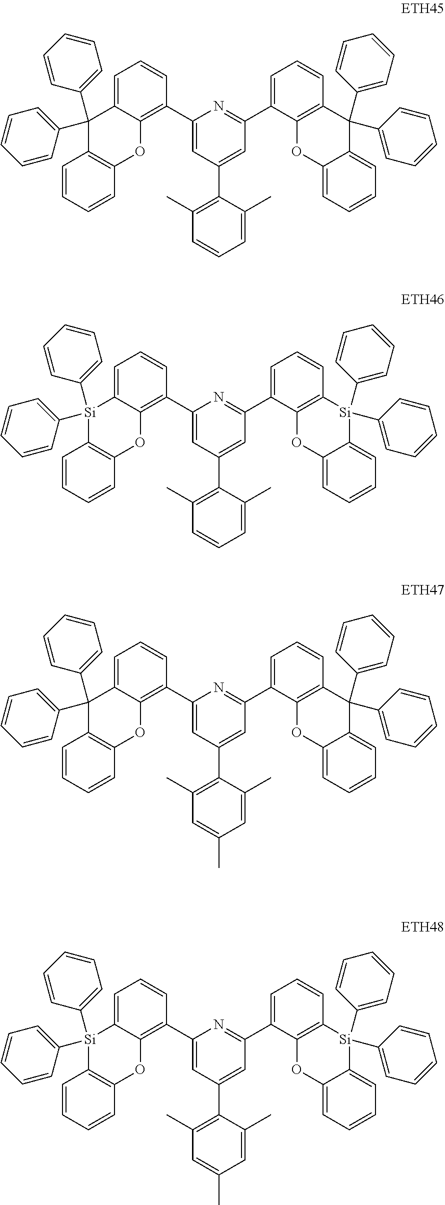 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

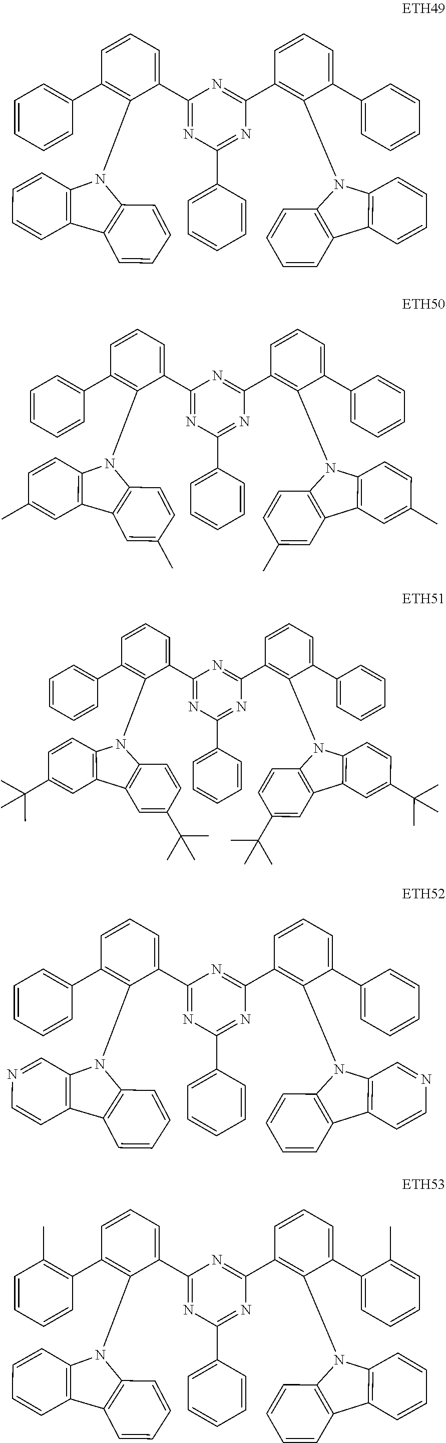

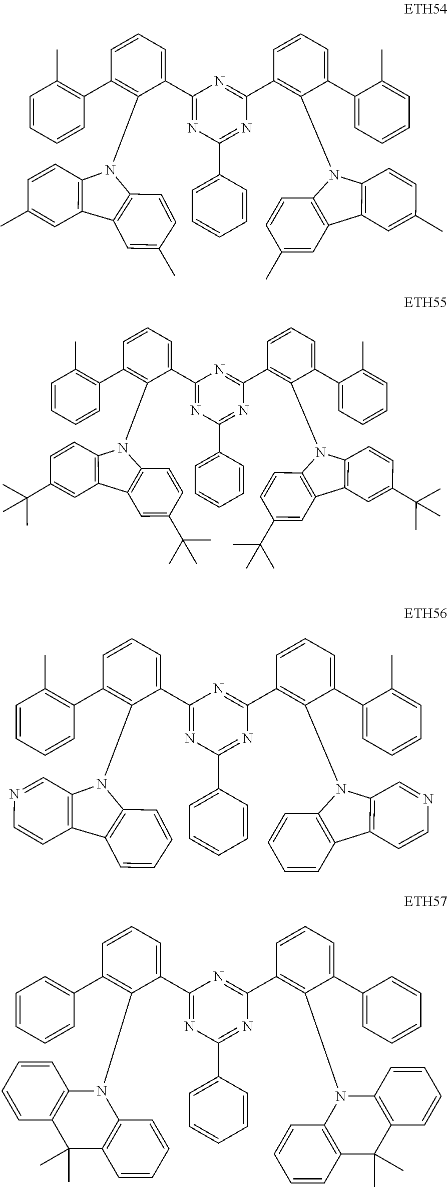

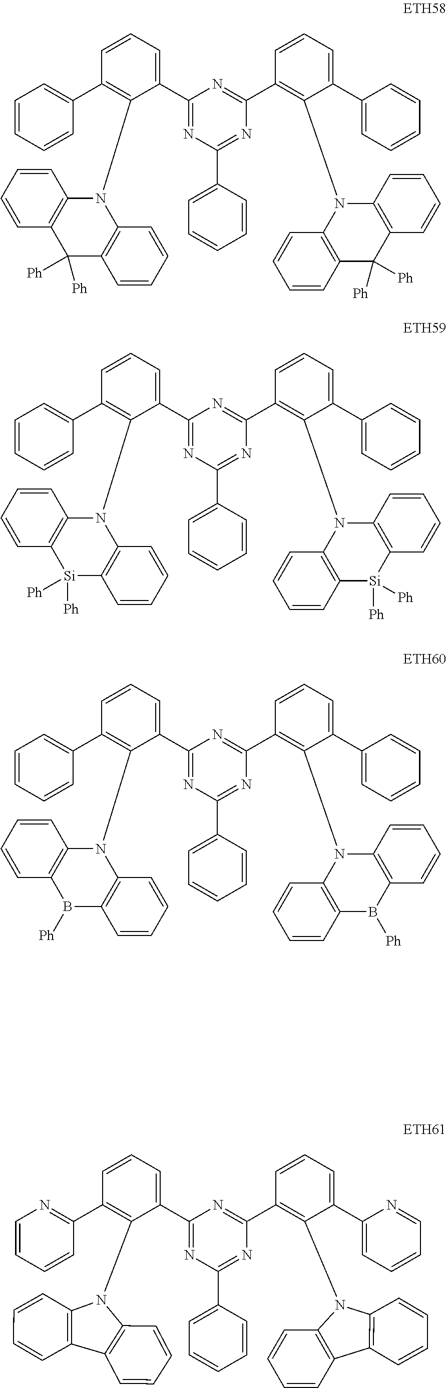

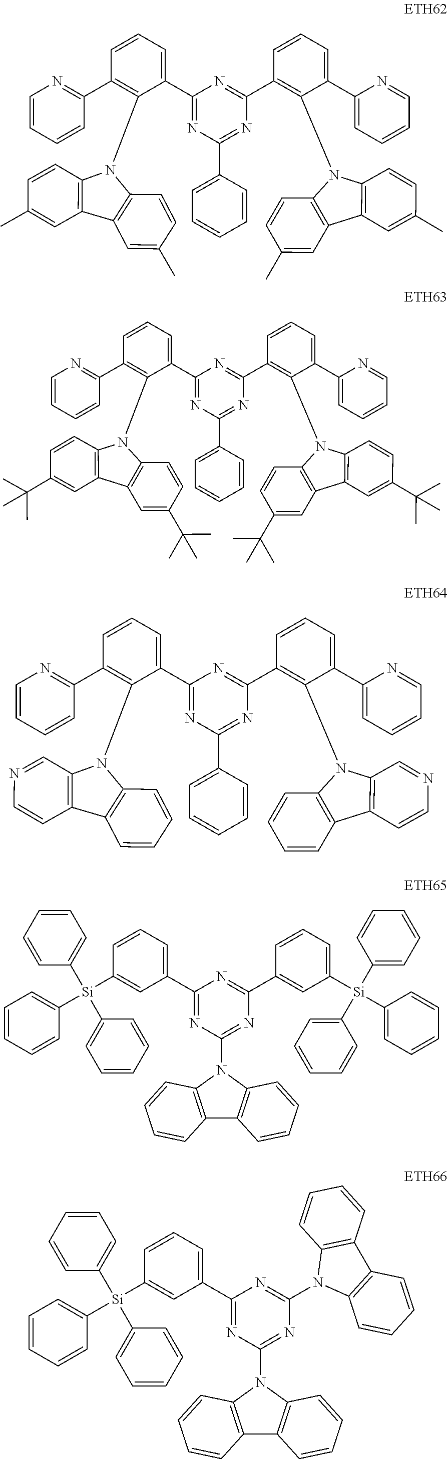

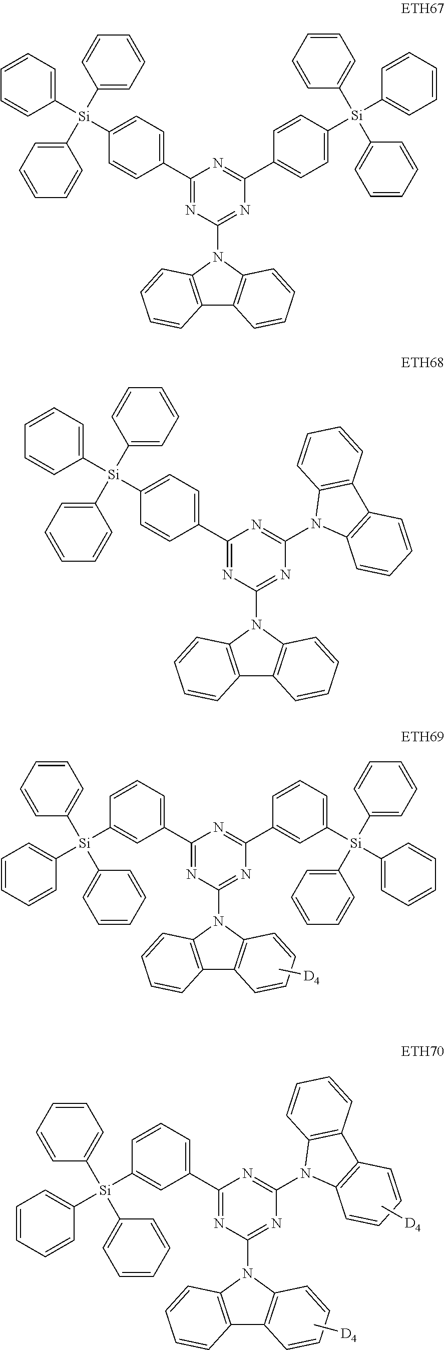

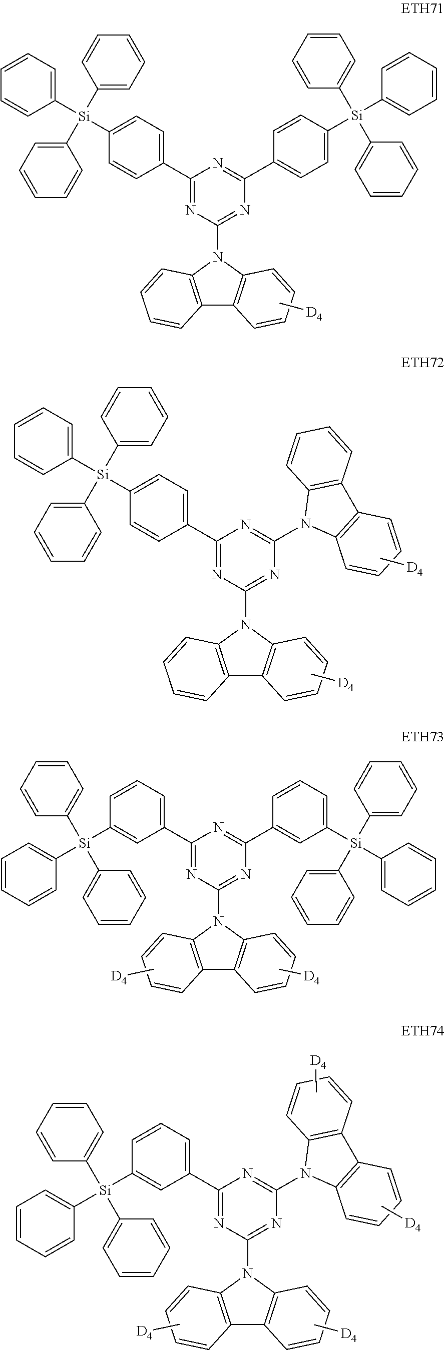

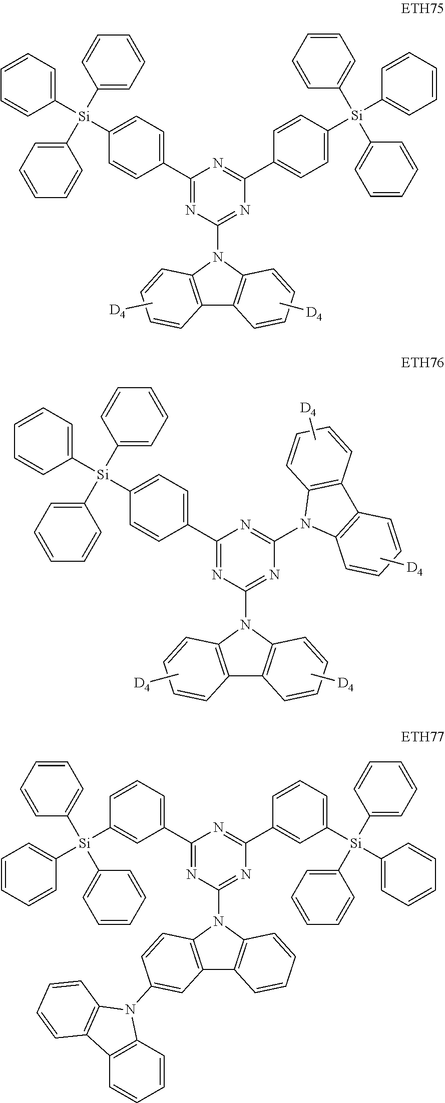

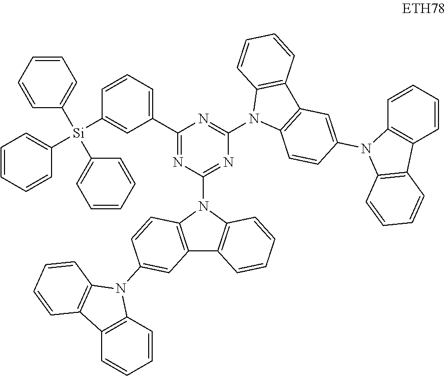 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

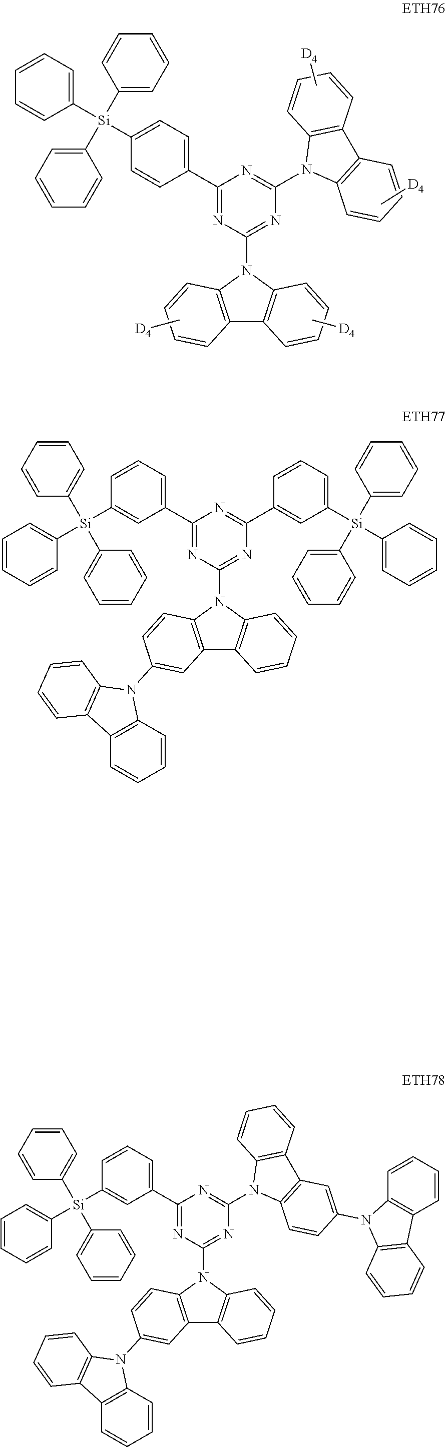

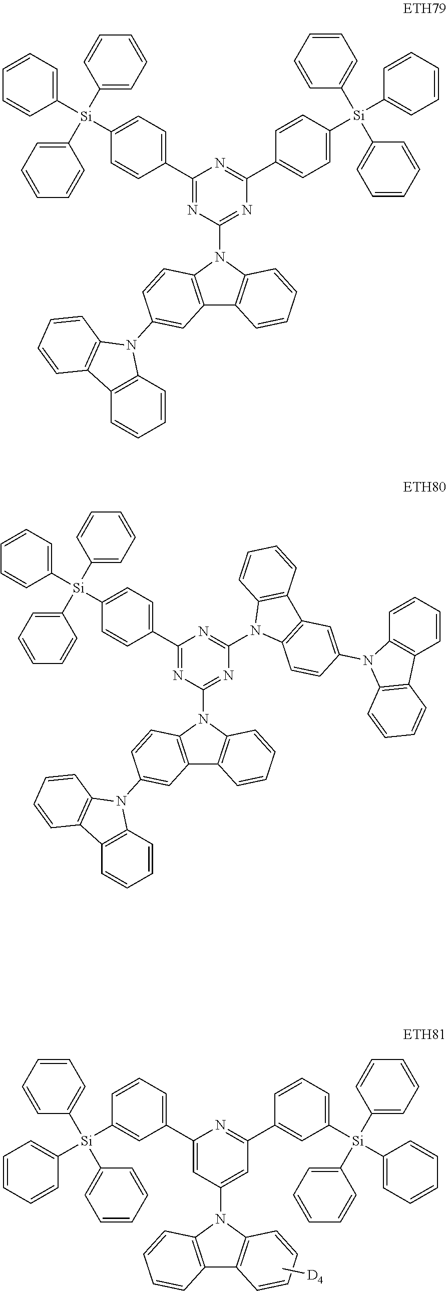

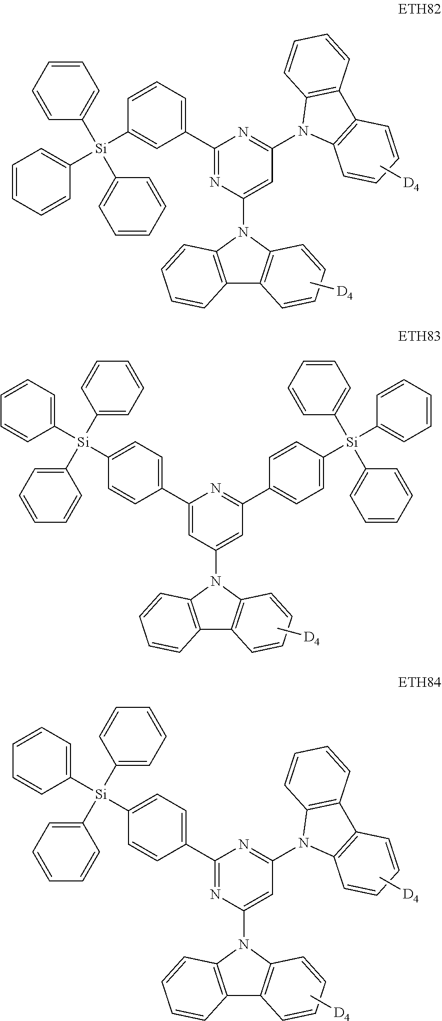

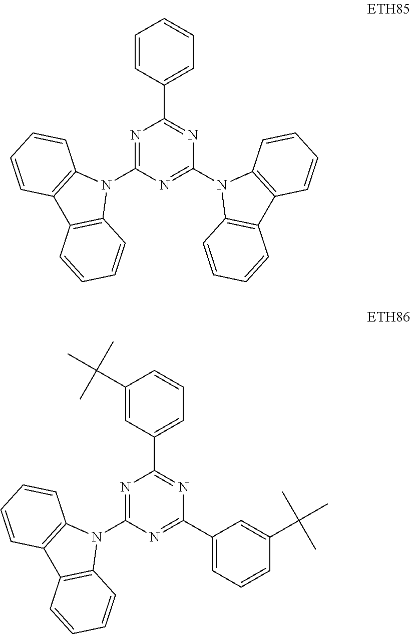 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the specific example compounds suggested in Compound Group 5, “D” refers to a deuterium atom, and “Ph” refers to an unsubstituted phenyl group.

The emission layer EML may have a thickness of, for example, about 100 Å to about 1000 Å, or about 100 Å to about 300 Å. The emission layer EML may have a single layer formed of a single material, a single layer formed of a plurality of different materials, or a multi-layered structure having a plurality of layers formed of a plurality of different materials.

In the light-emitting element ED illustrated in FIG. 3 to FIG. 7, the emission layer EML may include the described polycyclic compound according to one or more embodiments as a host. In one or more embodiments, in the light-emitting element ED illustrated in FIG. 3 to FIG. 7, according to one or more embodiments, the electron transport region ETR may include the polycyclic compound according to one or more embodiments.

In one or more embodiments, in the light-emitting element ED according to one or more embodiments, the emission layer EML may further include an anthracene derivative, a pyrene derivative, a fluoranthene derivative, a chrysene derivative, a dihydrobenzanthracene derivative, or a triphenylene derivative. For example, the emission layer EML may further include an anthracene derivative or a pyrene derivative.

In the light-emitting element ED illustrated in FIG. 3 to FIG. 7, according to one or more embodiments, the emission layer EML may further include a compound represented by Formula E-1. The compound represented by Formula E-1 may be utilized as a fluorescent host material.

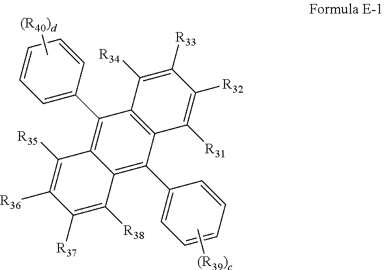

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, R₃₁ to R₄₀ may be bonded to an adjacent group to form a saturated hydrocarbon ring, an unsaturated hydrocarbon ring, a saturated hetero ring, or an unsaturated hetero ring.

In Formula E-1, c and d may each independently be an integer of 0 to 5.

Formula E-1 may be represented by any one selected from among Compounds E1 to E19.

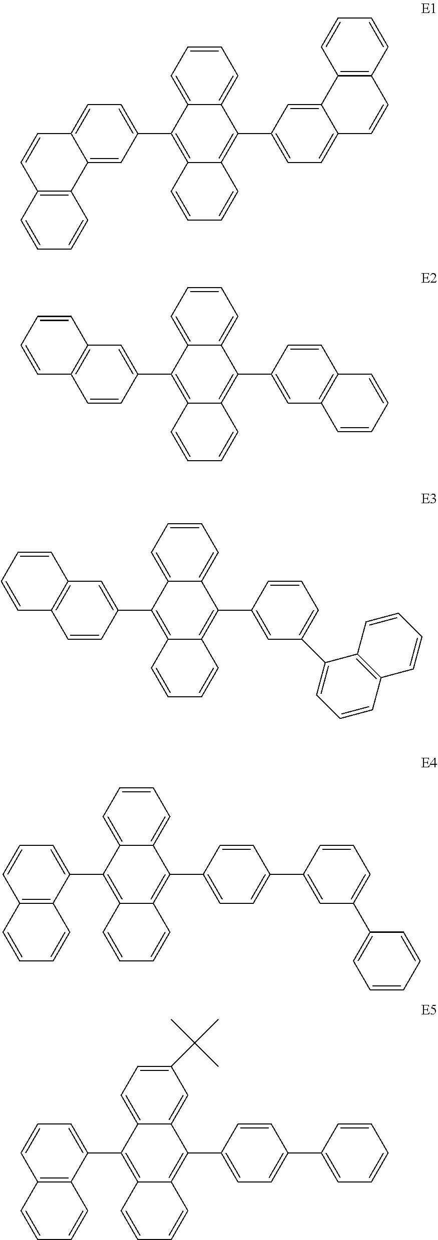

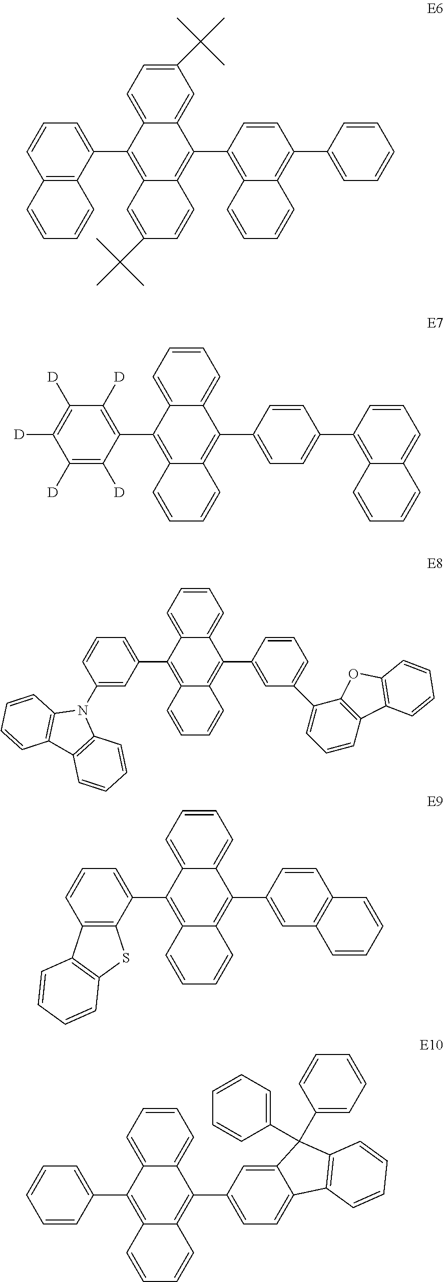

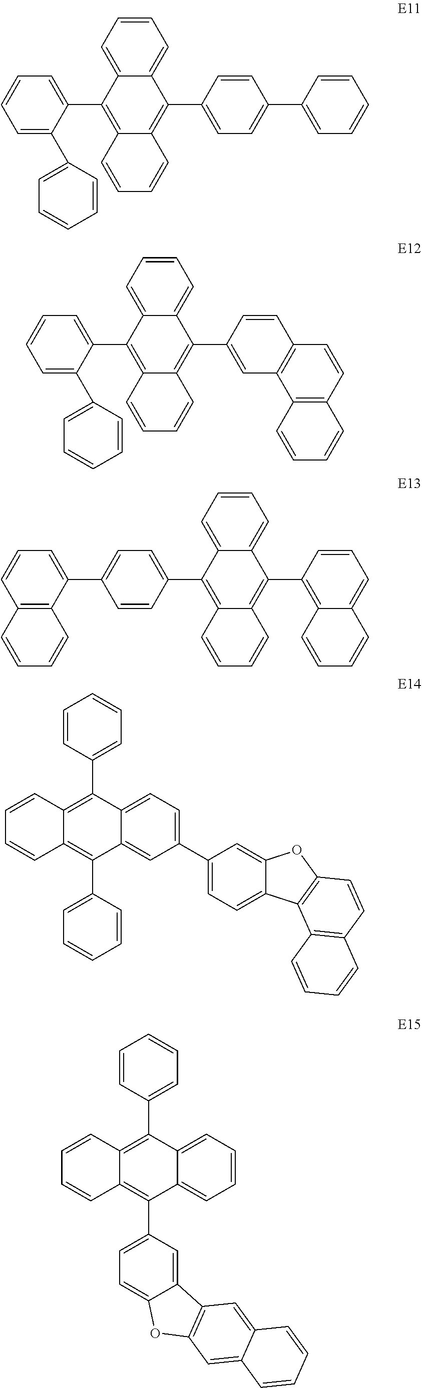

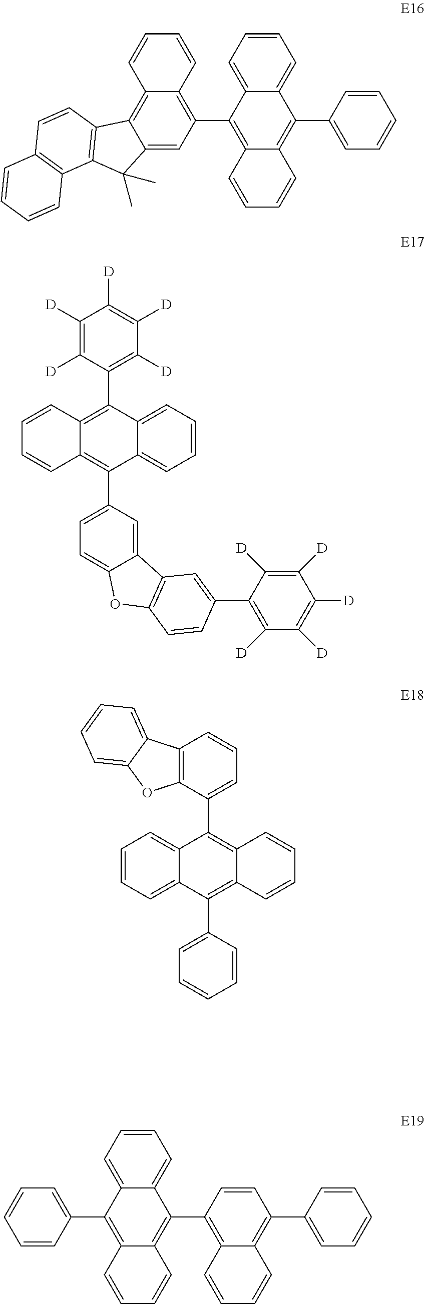

In one or more embodiments, the emission layer EML may further include a compound represented by Formula E-2a or Formula E-2b. The compound represented by Formula E-2a or Formula E-2b may be utilized as a phosphorescent host material.

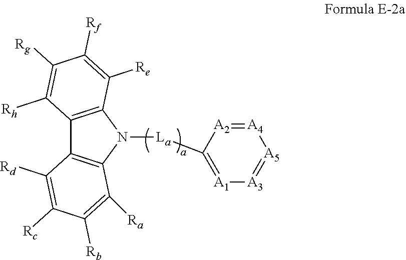

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, when a is an integer of 2 or more, a plurality of Las may each independently be a substituted or unsubstituted arylene group having 6 to 30 ring-forming carbon atoms, or a substituted or unsubstituted heteroarylene group having 2 to 30 ring-forming carbon atoms. In one or more embodiments, when a is an integer of 2 or more, the plurality of Las may each independently be a substituted or unsubstituted arylene group having 6 to 30 ring-forming carbon atoms, or a substituted or unsubstituted heteroarylene group having 2 to 30 ring-forming carbon atoms.

In one or more embodiments, in Formula E-2a, A₁ to A₄ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a hetero ring containing N, O, S, and/or the like as a ring-forming atom.

In one or more embodiments, in Formula E-2a, two or three selected from among A₁ to A₅ may be N, and the rest may be Crᵢ.

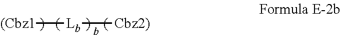

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer of 0 to 10, and when b is an integer of 2 or more, a plurality of L_{bs} may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among compounds in Compound Group E-2. However, the compounds present in Compound Group E-2 are shown as examples, and the compound represented by Formula E-2a or Formula E-2b is not limited to the compounds present in Compound Group E-2.

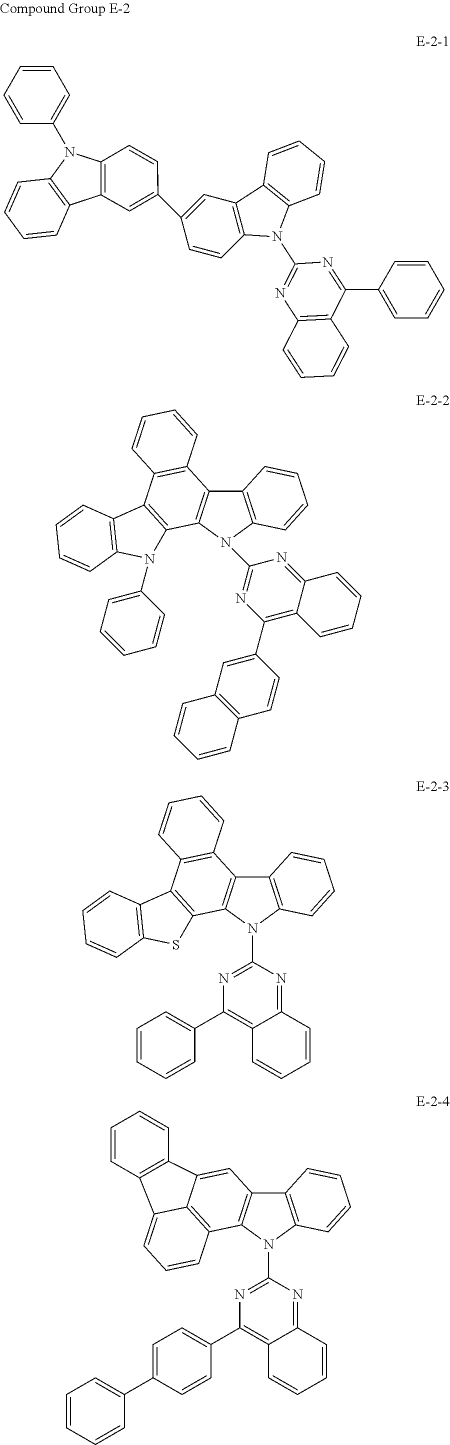

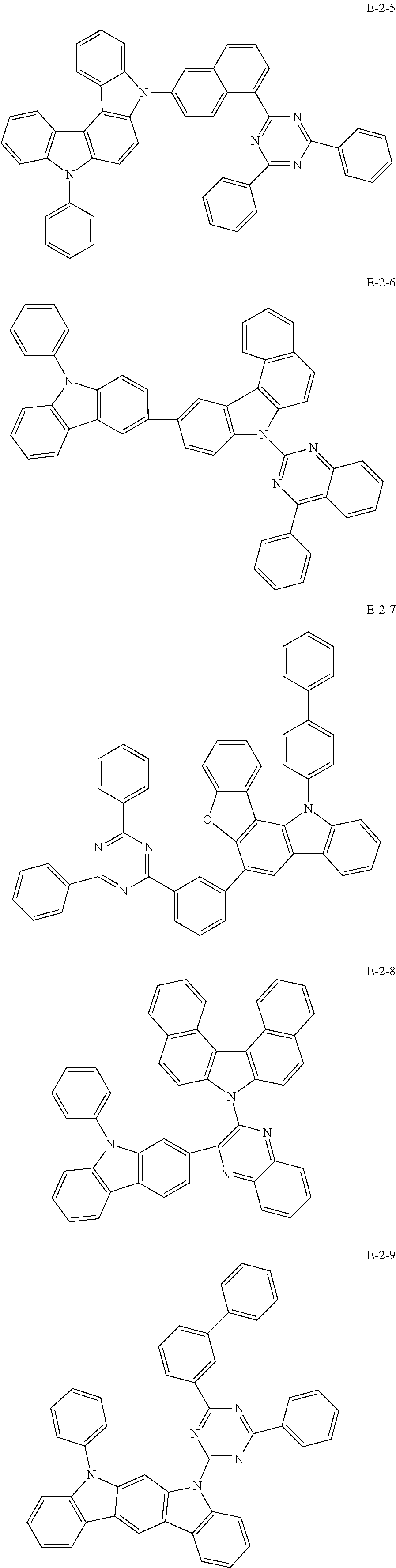 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

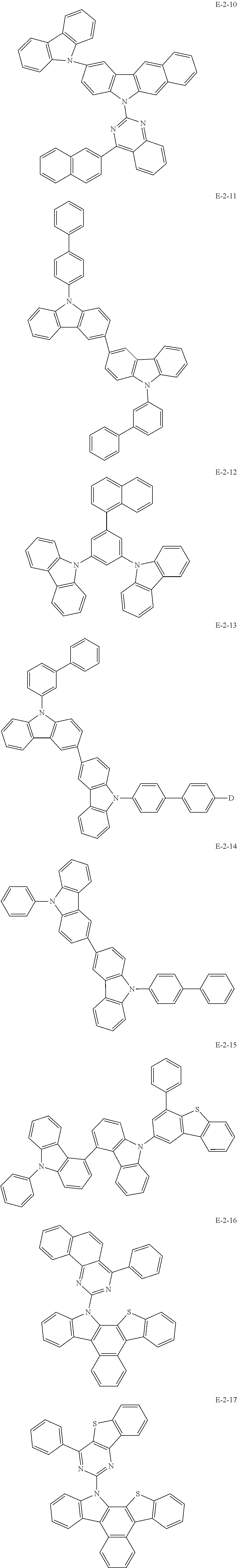

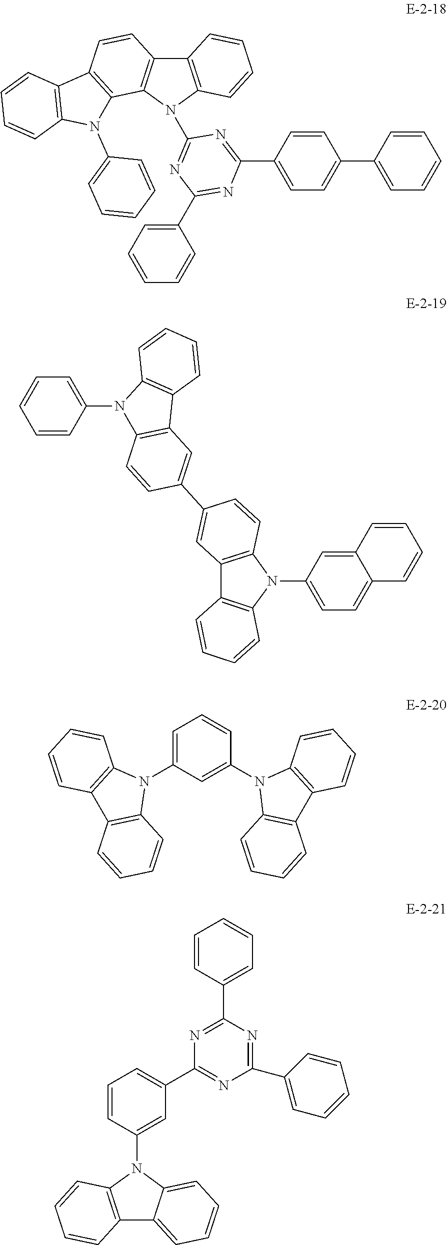 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

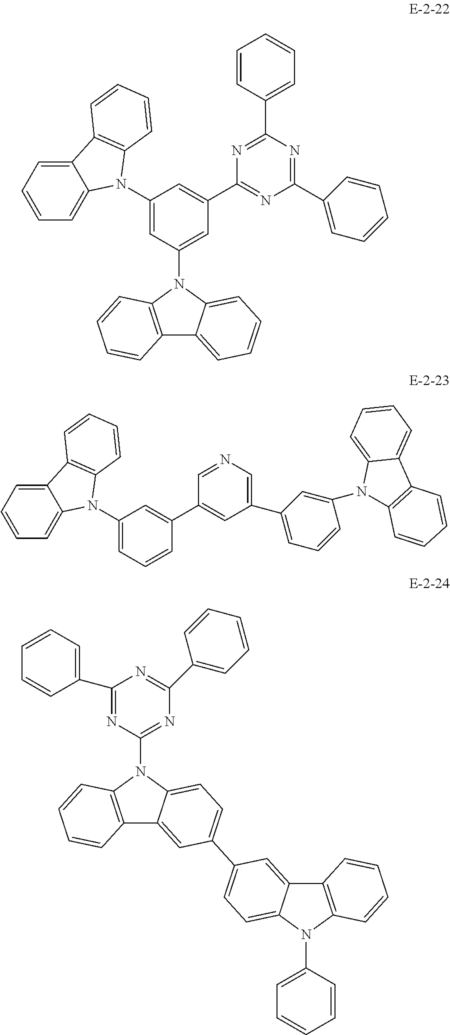 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a compound represented by Formula M-a. The compound represented by Formula M-a may be utilized as a phosphorescent dopant material.

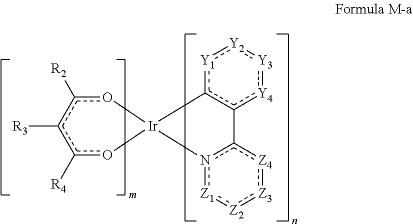

In Formula M-a, Y₁ to Y₄ and Z₁ to Z₄ may each independently be CR₁, or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compounds M-a1 to M-a25. However, Compounds M-a1 to M-a25 are shown as examples, and the compound represented by Formula M-a is not limited to the compounds present in Compounds M-a1 to M-a25.

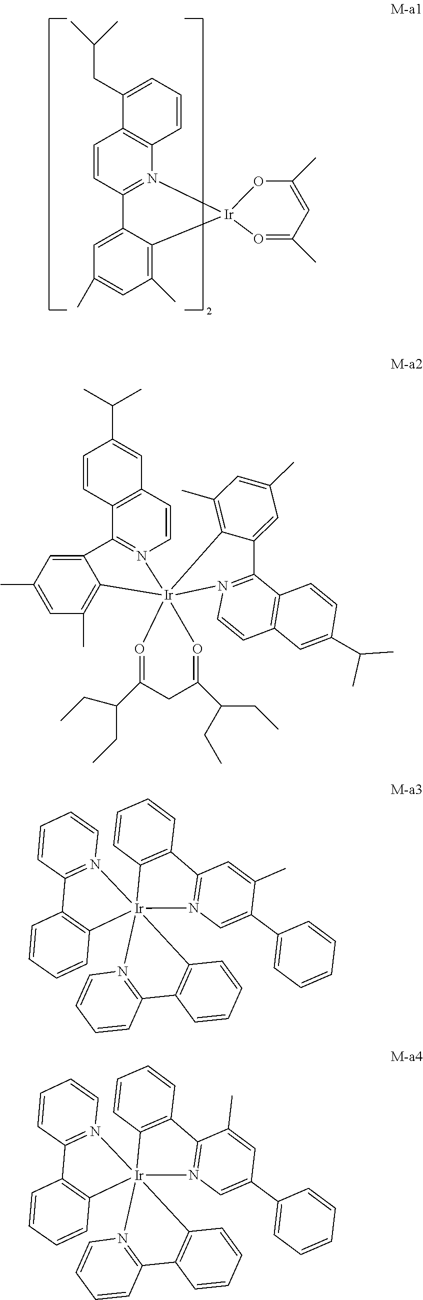

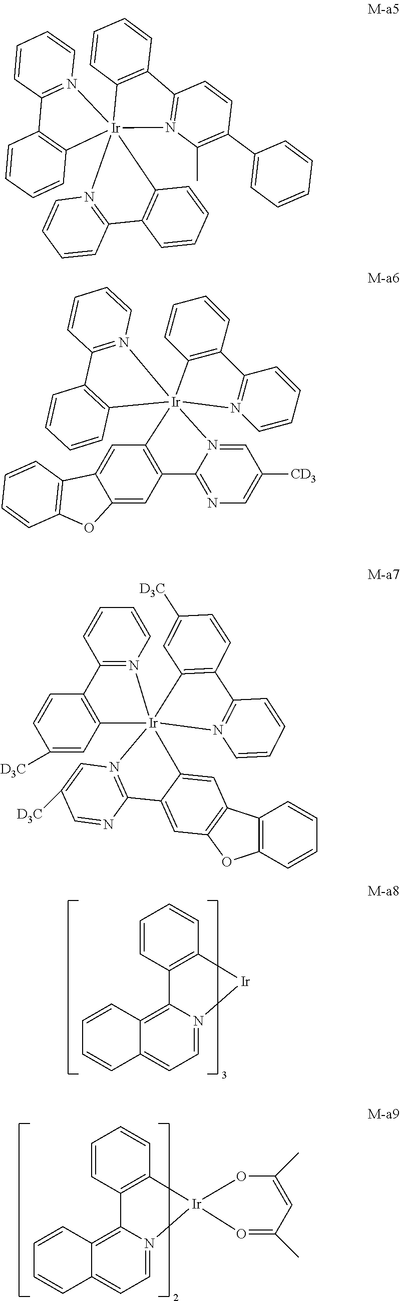

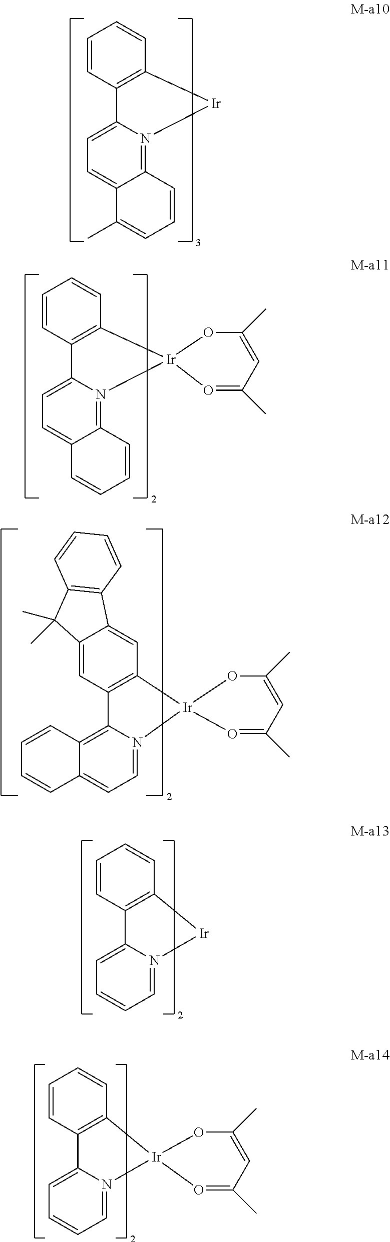

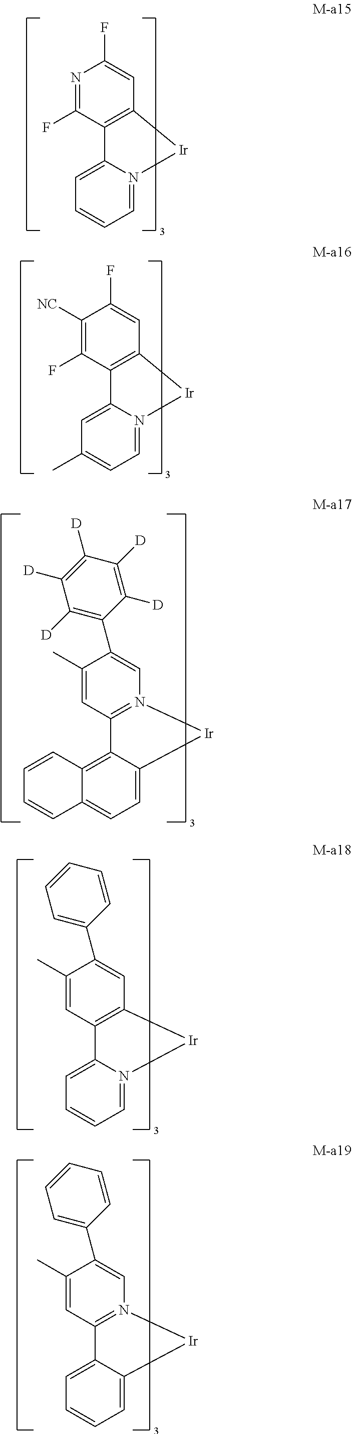

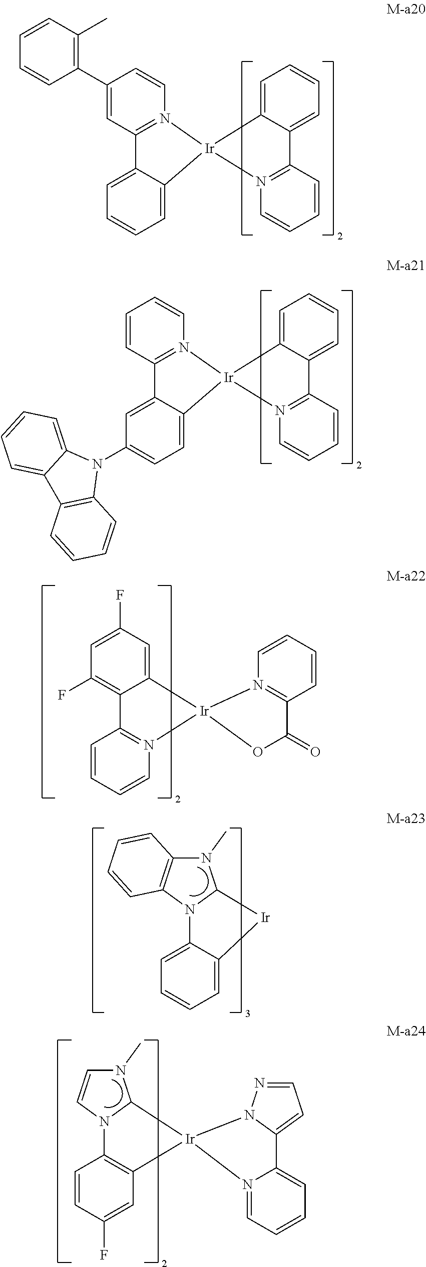

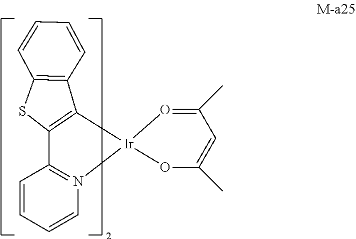

The emission layer EML may further contain a compound represented by any one selected from among Formula F-a to Formula F-c. The compound represented by Formula F-a to Formula F-c may be utilized as a fluorescent dopant material.

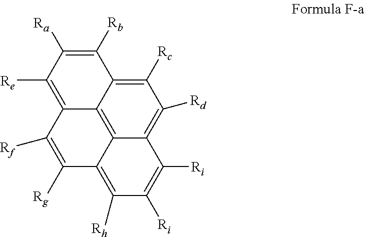

In Formula F-a, two selected from among Rₐ to R may each independently be substituted with

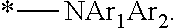

The rest which, among Rₐ to R, are unsubstituted with

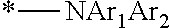

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In

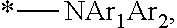

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one selected from among Ar₁ and Ar₂ may be a heteroaryl group containing O or S as a ring-forming atom.

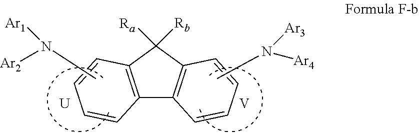

In Formula F-b, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted hetero ring having 2 to 30 ring-forming carbon atoms. At least one selected from among Ar to Ar₄ may be a heteroaryl group containing O or S as a ring-forming atom.

In Formula F-b, the number of rings represented by U and V may each independently be 0 or 1. For example, in Formula F-b, if (e.g., when) the number of U or V is 1, one ring constitutes a fused ring at a portion indicated by U or V, and if (e.g., when) the number of U or V is 0, it refers to that a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring of Formula F-b may be a cyclic compound with three rings. In one or more embodiments, if (e.g., when) each number of U and V is 1, the fused ring having a fluorene core in Formula F-b may be a cyclic compound with five rings.

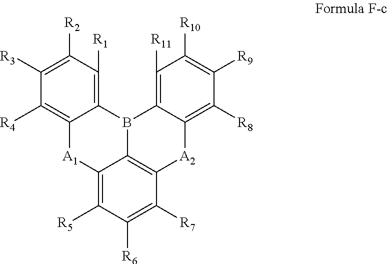

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formulas F-c, A₁ and A₂ may each independently be bonded to substituents of an adjacent group to form a fused ring. For example, when A₁ and A₂ may each independently be NRₘ, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl(DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescent dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized as the phosphorescent dopant. For example, iridium (111)bis(4,6-difluorophenylpyridinato-N,C2′)picolinate (Flrpic), bis(2,4-difluorophenylpyridinato)-tetrakis(1-pyrazolyl)borate iridium(Ill) (Fir6), or platinum octaethyl porphyrin (PtOEP) may be utilized as the phosphorescent dopant. However, the embodiment of the present disclosure is not limited thereto.

The emission layer EML may include a quantum dot material. The core of the quantum dots may be selected from among a Group II-VI compound, a Group I-II-VI compound, a Group II-IV-VI compound, a Group I-II-IV-VI compound, a Group II-IV-V compound, a Group Ill-VI compound, a Group I-Ill-VI compound, a Group Ill-V compound, a Group Ill-II-V compound, a Group IV-VI compound, a Group IV element, a Group IV compound, and/or a (e.g., any suitable) combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture (combination) thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a (e.g., any suitable) mixture thereof.

The Group III-VI compound may include a binary compound such as In₂S₃ or In₂Se₃, a ternary compound such as InGaS₃ or InGaSes, or a (e.g., any suitable) combination thereof.

The Group I-III-VI compound may be selected from among a ternary compound selected from among the group consisting of AgInS, AgInS₂, CuInS, CulnS₂, AgGaS₂, CuGaS₂ CuGaO₂, AgGaO₂, AgAlO₂, and a (e.g., any suitable) mixture thereof, or a quaternary compound such as AgInGaS₂ or CulnGaS₂.

The Group III-V compound may be selected from the group consisting of a binary compound selected from the group consisting of GaN, GaP, GaAs, GaSb, AlN, AIP, AIAs, AISb, InN, InP, InAs, InSb, and a (e.g., any suitable) mixture thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and a (e.g., any suitable) mixture thereof, and a quaternary compound selected from the group consisting of GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, InAIPSb, and a (e.g., any suitable) mixture thereof. In one or more embodiments, the Group Ill-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture (e.g., any suitable) thereof, a ternary compound selected from the group consisting of SnSeS, SnSeTe, SnSTe, PbSeS, PbSeTe, PbSTe, SnPbS, SnPbSe, SnPbTe, and a mixture (e.g., any suitable) thereof, and a quaternary compound selected from the group consisting of SnPbSSe, SnPbSeTe, SnPbSTe, and a (e.g., any suitable) mixture thereof. The Group IV element may be selected from the group consisting of Si, Ge, and a mixture thereof. The Group IV compound may be a binary compound selected from the group consisting of SiC, SiGe, and a (e.g., any suitable) mixture thereof.

Each element included in a polynary compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In one or more embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An interface between the core and the shell may have a concentration gradient in which the concentration of an element present in the shell becomes lower towards the center.

An example of the shell of the quantum dots may include a metal or non-metal oxide, a semiconductor compound, and/or a (e.g., any suitable) combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, and/or the like, or a ternary compound such as MgAl₂O₄, CoFe₂O₄, NiFe₂O₄, CoMn₂O₄, and/or the like, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, and/or the like, but the embodiment of the present disclosure is not limited thereto.

Each element included in a polynary compound such as the binary compound, or the ternary compound may be present in a particle with a substantially uniform or non-substantially uniform concentration distribution. For example, the preceding formulae may refer to the types (kinds) of elements included in the compounds, and the elemental ratio in the compound may be different.

The quantum dot may have a full width of half maximum (FWHM) of an emission wavelength spectrum of about 45 nm or less, about 40 nm or less, or about 30 nm or less, and color purity or color reproducibility may be improved in the described range(s). In one or more embodiments, light emitted through such a quantum dot is emitted in each (e.g., any or all) direction(s), and thus a wide viewing angle may be improved.

In one or more embodiments, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as described herein (utilizing different sizes of quantum dots or different elemental ratios in the quantum dot compound) is utilized, and thus the light emitting element, which emits light in one or more suitable wavelengths, may be implemented. For example, the adjustment of the size of the quantum dot or the elemental ratio in the quantum dot compound may be selected to emit red, green, and/or blue light. In one or more embodiments, the quantum dots may be configured to emit white light by combining one or more suitable colors of light.

In each of the light emitting devices ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In one or more embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2.

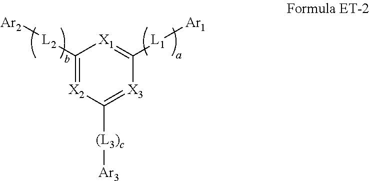

In Formula ET-2, at least one selected from among X₁ to X₃ is N, and the rest (e.g., any remaining selected from among X₁ to X₃) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1 H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or mixtures thereof.

The electron transport region ETR may include at least one selected from among Compound ET1 to Compound ET36.

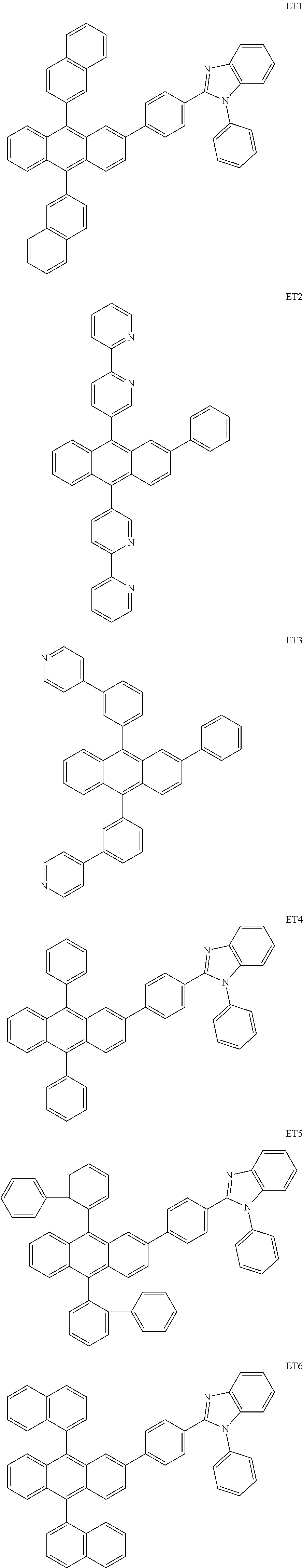

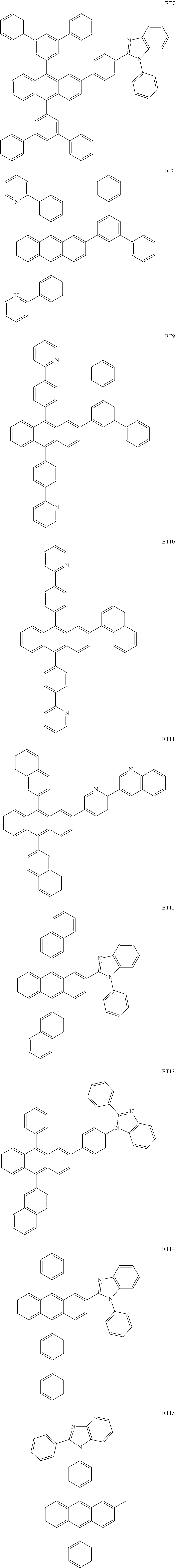

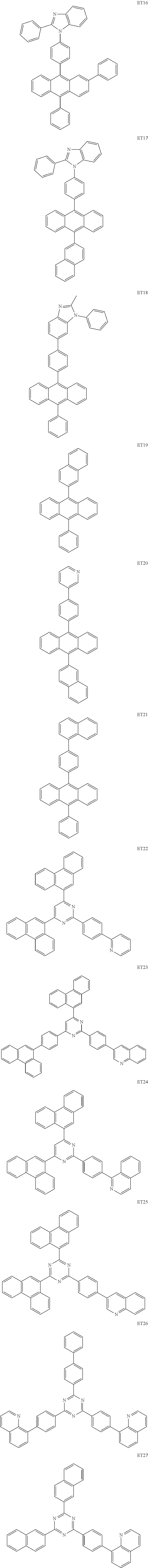

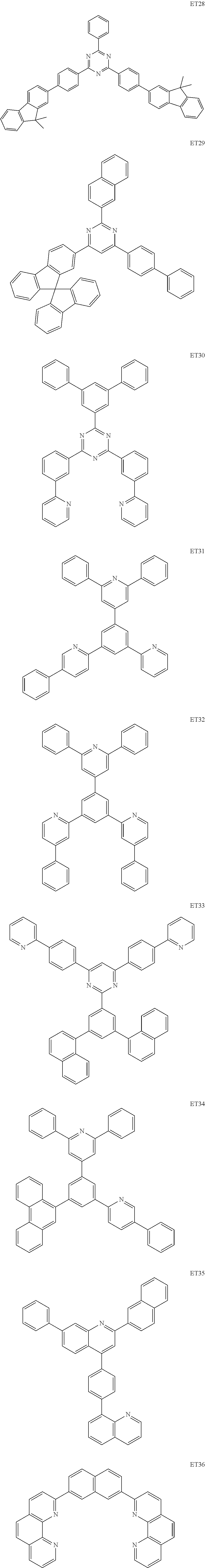

In one or more embodiments, the electron transport region ETR may include a metal halide such as LiF, NaCl, CsF, RbCl, Rbl, Cul, and KI, a lanthanide metal such as Yb, and a co-deposited material of the metal halide and the lanthanide metal. For example, the electron transport region ETR may include KI:Yb, Rbl:Yb, LiF:Yb, and/or the like, as a co-deposited material. In one or more embodiments, the electron transport region ETR may be formed utilizing a metal oxide such as Li₂O or BaO, or 8-hydroxyl-lithium quinolate (Liq), and/or the like, but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) (e.g., at least one selected from among 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen)) in addition to the herein described materials, but the embodiment of the present disclosure is not limited thereto.

The electron transport region ETR may include the—described compounds of the hole transport region in at least one of the electron injection layer EIL, the electron transport layer ETL, or the hole blocking layer HBL

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the herein-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgAg). In one or more embodiments, the second electrode EL2 may have a multilayer structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

In one or more embodiments, the second electrode EL2 may be connected with an auxiliary electrode. When the second electrode EL2 is connected with the auxiliary electrode, the resistance of the second electrode EL2 may be decreased.

In one or more embodiments, a capping layer CPL may further be arranged on the second electrode EL2 of the light emitting device ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, if (e.g., when) the capping layer CPL includes an organic material, the organic material may include a-NPD, NPB, TPD, m-MTDATA, Alq3, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, the embodiment of the present disclosure is not limited thereto, and the capping layer CPL may include at least one among selected from among Compounds P1 to P5.

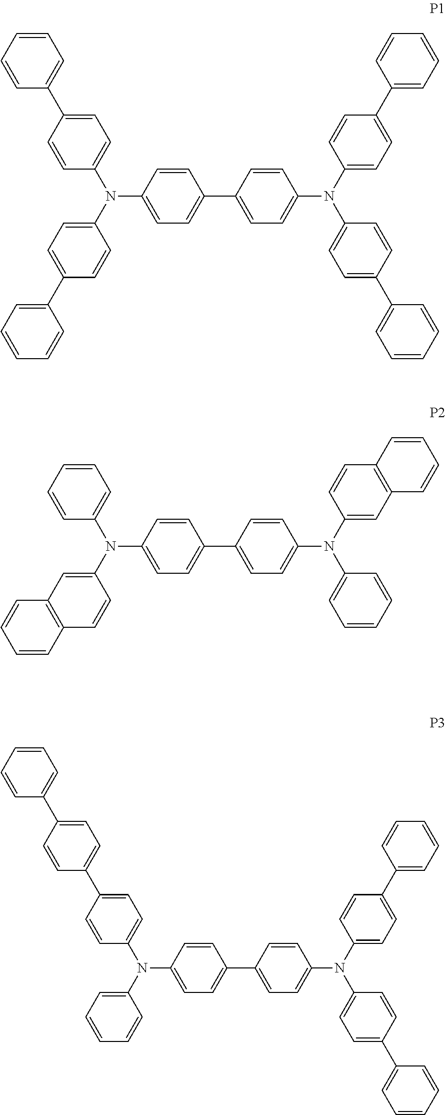 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

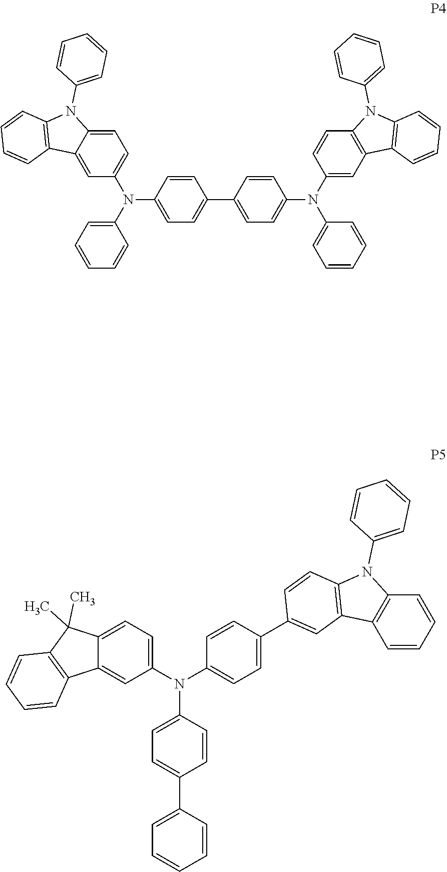 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL may be about 1.6 or more with respect to light in a wavelength range of about 550 nanometer (nm) to about 660 nm.

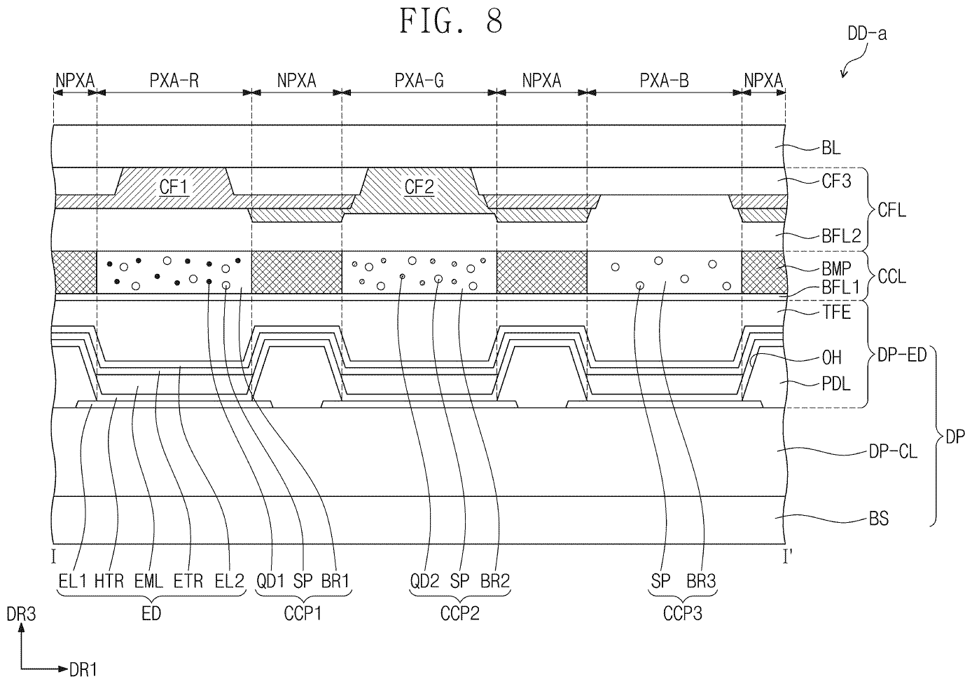

Each of FIGS. 8 to 11 is a cross-sectional view of a display device according to one or more embodiments of the present disclosure. Hereinafter, in describing the display devices of embodiments with reference to FIGS. 8 to 11, the duplicated features which have been described in FIGS. 1 to 7 are not described again, but their differences will be mainly described in more detail.

Referring to FIG. 8, the display device DD-a according to one or more embodiments may include a display panel DP including a display device layer DP-ED, a light control layer CCL arranged on the display panel DP, and a color filter layer CFL. In one or more embodiments illustrated in FIG. 8, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structures of the light emitting elements of FIGS. 3 to 7 as described herein may be equally applied to the structure of the light emitting element ED illustrated in FIG. 8. The light-emitting element ED illustrated in FIG. 8 may include the polycyclic compound according to one or more embodiments. The light-emitting element ED according to one or more embodiments includes the polycyclic compound according to one or more embodiments in the emission layer EML, thereby exhibiting characteristics of excellent or suitable color reproductivity and long lifespan, and thus a display device according to one or more embodiments may exhibit excellent or suitable display quality.

Referring to FIG. 8, the emission layer EML may be arranged in an opening OH defined in a pixel defining layer PDL. For example, the emission layer EML which is divided by the pixel defining layer PDL and provided corresponding to each light emitting regions PXA-R, PXA-G, and PXA-B may be to emit light in substantially the same wavelength range. In the display device DD-a of one or more embodiments, the emission layer EML may be to emit blue light. In one or more embodiments, unlike the configuration illustrated, in one or more embodiments, the emission layer EML may be provided as a common layer in the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 8, divided patterns BMP may be arranged between the light control parts CCP1, CCP2 and CCP3 which are spaced and/or apart from each other, but the embodiment of the present disclosure is not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In one or more embodiments, the barrier layer BFL1 may cover the light control parts CCP1, CCP2, and CCP3. In one or more embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed of a single layer or a plurality of layers.

In the display device DD-a of one or more embodiments, the color filter layer CFL may be arranged on the light control layer CCL. For example, the color filter layer CFL may be directly arranged on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In one or more embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3. Also, in one or more embodiments, the light shielding part may be formed of a blue filter.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CFL. The base substrate BL may be a member which provides a base surface in which the color filter layer CFL, the light control layer CCL, and/or the like are arranged. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In one or more embodiments, unlike the configuration illustrated, in one or more embodiments, the base substrate BL may not be provided.

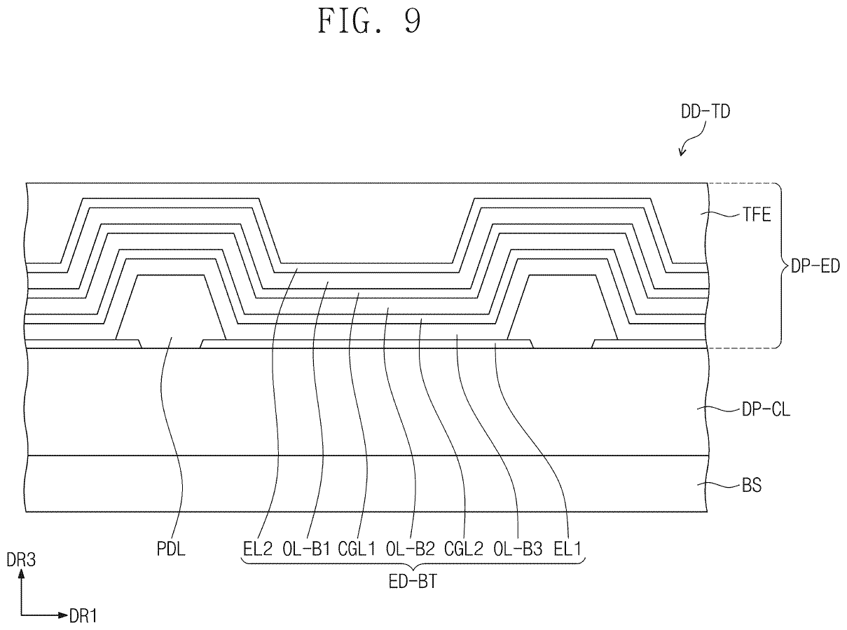

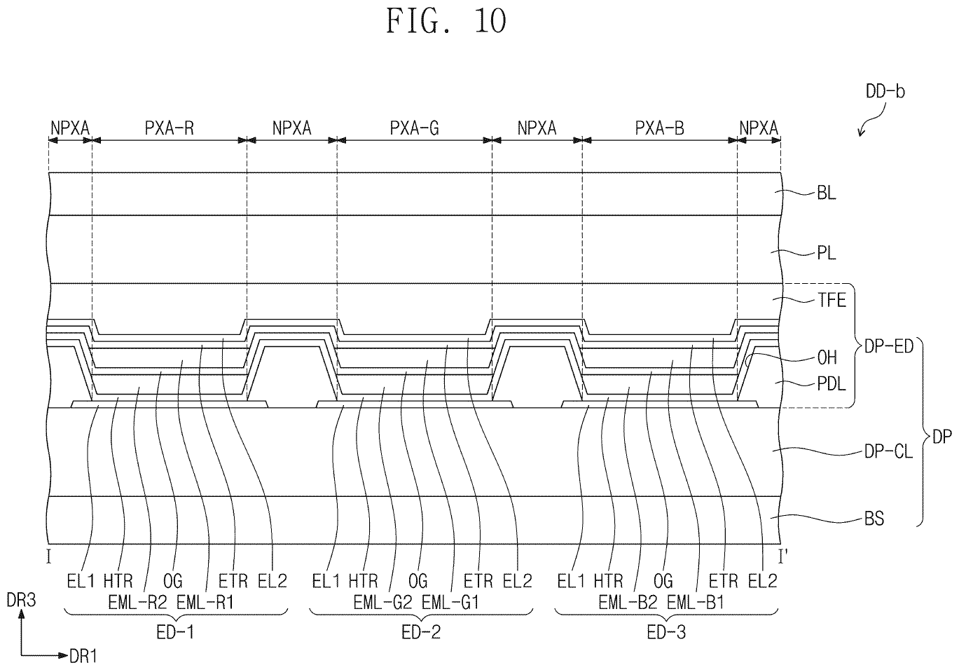

FIG. 9 is a cross-sectional view illustrating a portion of the display device according to one or more embodiments. In a display device DD-TD according to one or more embodiments, a light-emitting element ED-BT may include a plurality of light-emitting structures OL-B1, OL-B2, and OL-B3. At least one of the plurality of light-emitting structures OL-B1, OL-B2, and OL-B3 may contain the polycyclic compound according to one or more embodiments. The light-emitting element ED-BT according to one or more embodiments may exhibit characteristics of excellent or suitable color reproductivity and a long lifespan. The display device DD-TD according to one or more embodiments includes the light-emitting element ED-BT containing the polycyclic compound according to one or more embodiments, and thus may exhibit excellent or suitable display quality.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR arranged with the emission layer EML (FIG. 8) located therebetween. For example, the light emitting element ED-BT included in the display device DD-TD of one or more embodiments may be a light emitting element having a tandem structure and including a plurality of emission layers.

In one or more embodiments illustrated in FIG. 9, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit white light.

A charge generating layer CGL1 and CGL2 may be arranged between the neighboring light-emitting structures OL-B1, OL-B2 and OL-B3. The charge generating layer CGL1 and CGL2 may include a p-type or kind charge generating layer (e.g., p-charge generating layer) and/or an n-type or kind charge generating layer (e.g., n-charge generating layer).

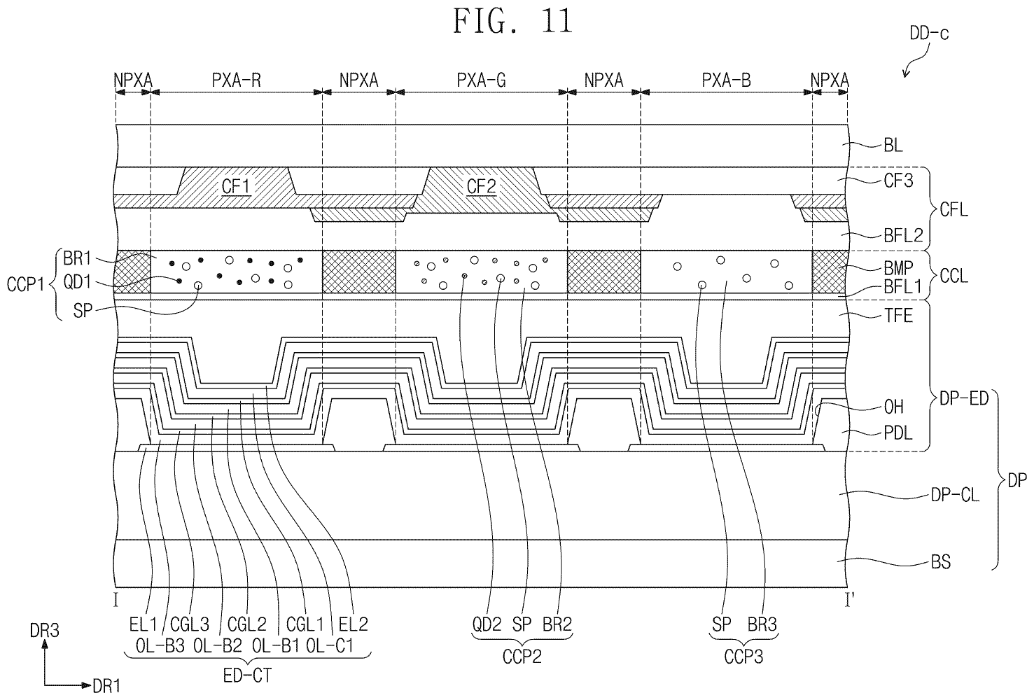

Referring to FIG. 10, a display device DD-b according to one or more embodiments may include light-emitting elements ED-1, ED-2, and ED-3, in which two emission layers are stacked. At least one among the light-emitting elements ED-1, ED-2, and ED-3 may include the polycyclic compound according to one or more embodiments. Therefore, the first compound which is the polycyclic compound according to one or more embodiments and at least one among the second to fourth compounds may be included. Therefore, the light-emitting elements ED-1, ED-2, and ED-3 may exhibit characteristics of excellent or suitable color reproductivity and long lifespan.

Compared with the display device DD of one or more embodiments illustrated in FIG. 2, one or more embodiments illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may be to emit light in substantially the same wavelength region.

The first light emitting element ED-1 may include a first red emission layer EML-R₁ and a second red emission layer EML-R2. The second light emitting element ED-2 may include a first green emission layer EML-G1 and a second green emission layer EML-G2. In one or more embodiments, the third light emitting element ED-3 may include a first blue emission layer EML-B1 and a second blue emission layer EML-B2. An emission auxiliary part OG may be arranged between the first red emission layer EML-R₁ and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining layer PDL.

The first red emission layer EML-R₁, the first green emission layer EML-G1, and the first blue emission layer EML-B1 may be arranged between the electron transport region ETR and the emission auxiliary part OG. The second red emission layer EML-R2, the second green emission layer EML-G2, and the second blue emission layer EML-B2 may be arranged between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R₁, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer PL may be arranged on the display device layer DP-ED. The optical auxiliary layer PL may include a polarizing layer. The optical auxiliary layer PL may be arranged on the display panel DP and control reflected light in the display panel DP due to external light. Unlike the configuration illustrated, the optical auxiliary layer PL in the display device according to one or more embodiments may not be provided.

Unlike FIGS. 9 and 10, the display device DD-c of FIG. 11 is illustrated to include four light emitting structures OL-B1, OL-B2, OL-B3, and OL-C1. The light emitting element ED-BT may include the first electrode EL1 and the second electrode EL2 facing each other, and the first to fourth light emitting structures OL-B1, OL-B2, OL-B3, and OL-C1 sequentially stacked in a thickness direction between the first electrode EL1 and the second electrode EL2. At least one among the first to fourth light-emitting structures OL-B1, OL-B2, OL-B3, and OL-C1 may contain the polycyclic compound according to one or more embodiments. Therefore, a light-emitting element ED-CT may exhibit characteristics of excellent or suitable color reproductivity and long lifespan.

Charge generation layers CGL1, CGL2, and CGL3 may be arranged between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions. The charge generation layers CGL1, CGL2, and CGL3 arranged between adjacent light emitting structures OL-B1, OL-B2, OL-B3, and OL-C1 may include a p-type or kind charge generation layer (e.g., p-charge generating layer) and/or an n-type or kind charge generation layer (e.g., n-charge generating layer).

In one or more embodiments, the electronic apparatus may include a display device including a plurality of light emitting elements, and a control part which controls the display device. The electronic apparatus of one or more embodiments may be a device that is activated according to an electrical signal. The electronic apparatus may include display device of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

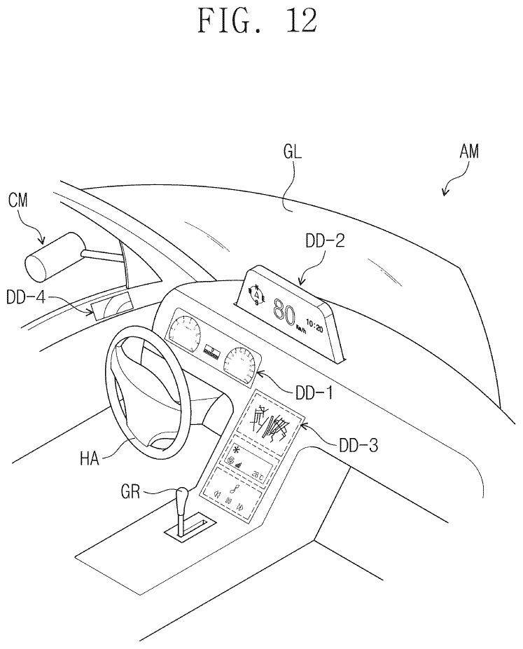

FIG. 12 is a view illustrating a vehicle AM in which first to fourth display devices DD-1, DD-2, DD-3, and DD-4 are arranged. At least one among the first to fourth display devices DD-1, DD-2, DD-3, and DD-4 may include the same constitution of display devices DD, DD-TD, DD-a, DD-b, and DD-c, according to one or more embodiments, described with reference to FIGS. 1, 2, and 8 to 11.

FIG. 12 illustrates a vehicle AM, but this is merely an example, and the first to fourth display devices DD-1, DD-2, DD-3, and DD-4 may be arranged in another transportation vehicle, such as bicycles, motorcycles, trains, ships, and airplanes. In one or more embodiments, at least one among the first to fourth display devices DD-1, DD-2, DD-3, and DD-4 including the same configuration as the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In one or more embodiments, these are merely provided as embodiments, and thus may be employed in other electronic apparatuses unless departing from the present disclosure.

At least one selected from among the first to fourth display devices DD-1, DD-2, DD-3, and DD-4 may include the light-emitting element ED described with reference to FIG. 3 to FIG. 7. At least one selected from among the first to fourth display devices DD-1, DD-2, DD-3, and DD-4 may contain the polycyclic compound according to one or more embodiments and at least one among the second to fourth compounds. Therefore, the first to fourth display devices DD-1, DD-2, DD-3, and DD-4 containing the polycyclic compound according to one or more embodiments may have improved color reproductivity, display quality, and display lifespan.

Referring to FIG. 12, the vehicle AM may include a steering wheel HA and a gear GR for driving the vehicle AM. In one or more embodiments, the vehicle AM may include a front window GL arranged so as to face the driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display device DD-2 may be arranged in a second region facing the driver's seat and overlapping the front window GL. The driver's seat may be a seat in which the steering wheel HA is arranged. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be arranged in a third region adjacent to the gear GR. For example, the third display device DD-3 may be arranged between the driver's seat and the passenger seat and may be a center information display (CID) for a vehicle for displaying third information. The passenger seat may be a seat spaced and/or apart from the driver's seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart from the steering wheel HA and the gear GR, and may be arranged in a fourth region adjacent to the side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The herein-described first to fourth information may be examples, and the first to fourth display devices DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, with reference to Examples and Comparative Examples, a polycyclic compound according to one or more embodiments of the present disclosure and a light-emitting element according to one or more embodiments will be described in more detail. In one or more embodiments, Examples described are shown only for understanding the present disclosure, and the scope of the present disclosure is not limited thereto.

### Examples

### (1). Synthesis of polycyclic compound according to one or more embodiments

Synthetic methods of polycyclic compounds according to one or more embodiments will be described in more detail by exemplifying synthetic methods of Compounds 1, 2, 5, 21, 43, 56, and 103. In one or more embodiments, the synthetic methods of the polycyclic compounds, which will be described hereinafter, are provided as examples, and thus the synthetic methods of the polycyclic compounds according to one or more embodiments of the present disclosure are not limited to Examples.

### (1) Synthesis of Compound 1

Polycyclic Compound 1 according to one or more embodiments may be synthesized, for example, by steps (e.g., acts or tasks) shown in Reaction Scheme 1-1 to Reaction Scheme 1-3.

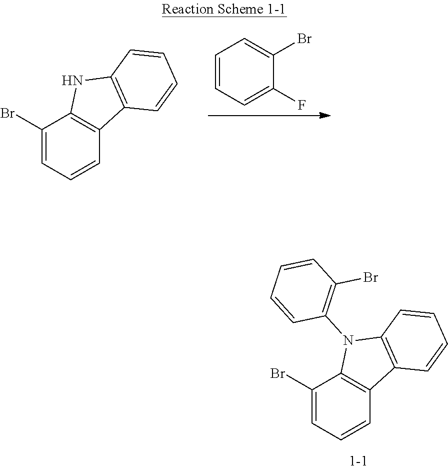

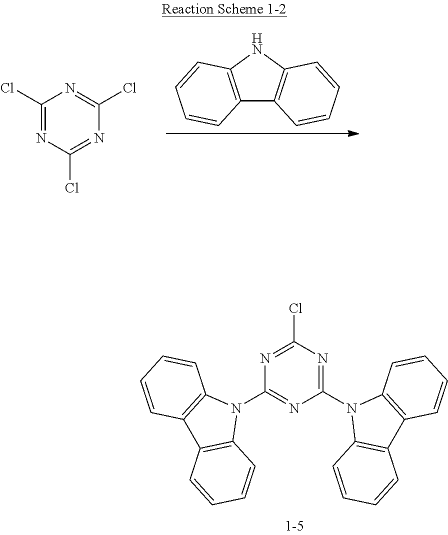 [SMILES: Clc1nc(Cl)nc(Cl)n1 ; c1ccc2c(c1)[nH]c1ccccc12 ; Clc1nc(-n2c3ccccc3c3ccccc32)nc(-n2c3ccccc3c3ccccc32)n1]

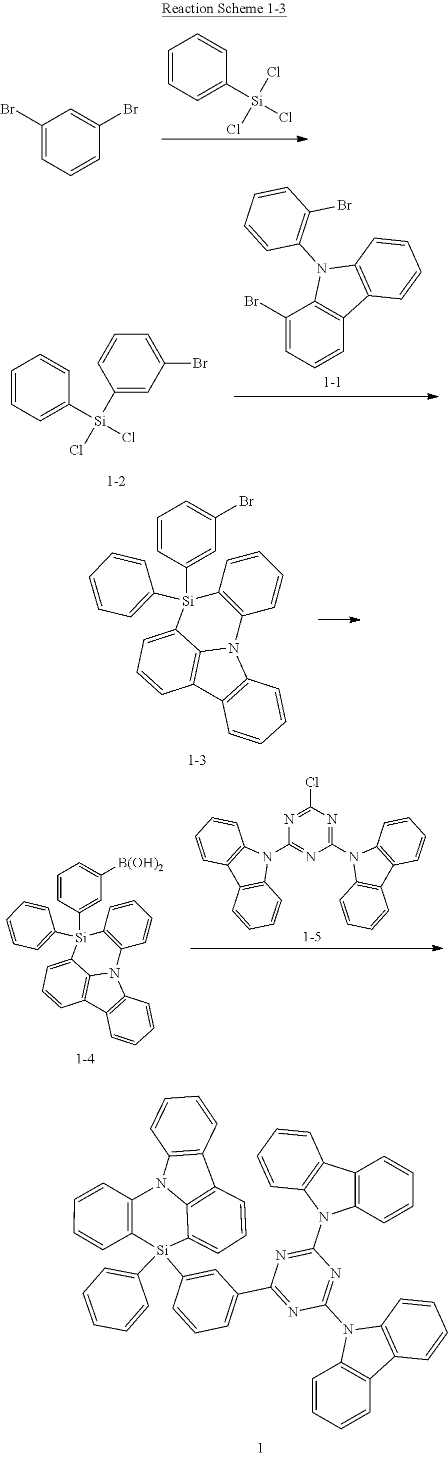

### 1) Synthesis of Intermediate 1-1

K₃PO₄ and a DMF solvent were put into 1-bromo-9H-carbazole (CAS #: 16807-11-7), and 1-bromo-2-fluorobenzene (CAS #: 1072-85-1), and the mixture was stirred overnight at about 100° C. to obtain Intermediate 1-1. An identified value with LC-MS of the obtained Intermediate 1-1 is as follows.

C₁₈H₁₁Br₂N M+1:401.93

### 2) Synthesis of Intermediate 1-2 and Intermediate 1-3

1,3-dibromobenzene (CAS #: 108-36-1) was reacted with n-BuLi, then trichloro(phenyl)silane(CAS #: 98-13-5) was added, and the mixture was stirred for about 2 hours. Intermediate 1-1 was reacted with n-BuLi, then the reactant previously obtained was added, and the mixture was stirred overnight at room temperature to obtain Intermediate 1-3. An identified value with LC-MS of the obtained Intermediate 1-3 is as follows.

C₃₀H₂₀BrNSi M+1:504.11

### 3) Synthesis of Intermediate 1-4

Intermediate 1-3 was reacted n-BuLi, then trimethyl borate (CAS #:121-43-7) was added and the mixture was stirred overnight at room temperature, and then H₂O was put to obtain Intermediate 1-4. An identified value with LC-MS of the obtained Intermediate 1-4 is as follows.

C₃₀H₂₂BNO₂Si M+1:468.16

### 4) Synthesis of Intermediate 1-5

9H-carbazole (CAS #: 86-74-8) was reacted with n-BuLi, then Cyanuric chloride (CAS #: 108-77-0) was added and the mixture was stirred overnight at about 70° C. to obtain Intermediate 1-5. An identified value with LC-MS of the obtained Intermediate 1-5 is as follows.

C₂₇H₁₆CIN₅M+1:446.14

### 5) Synthesis of Compound 1

2.5 g of Intermediate 1-5, 2.88 g of Intermediate 1-4, 0.26 g of Pd(PPh₃)₄, 1.94 g of K₂CO₃ (in 7 mL of H₂O), 7 mL of EtOH, 28 mL of toluene were put into a round-bottomed flask (RBF), and the mixture was stirred overnight at about 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 2.94 g of Compound 1 (yield: 63%). An identified value with LC-MS of the obtained Compound 1 is as follows.

C₅₇H₃₆N₆Si M+1:833.28

### (2) Synthesis of Compound 2

9 Polycyclic Compound 2 according to one or more embodiments may be synthesized by, for example, the steps shown in Reaction Scheme

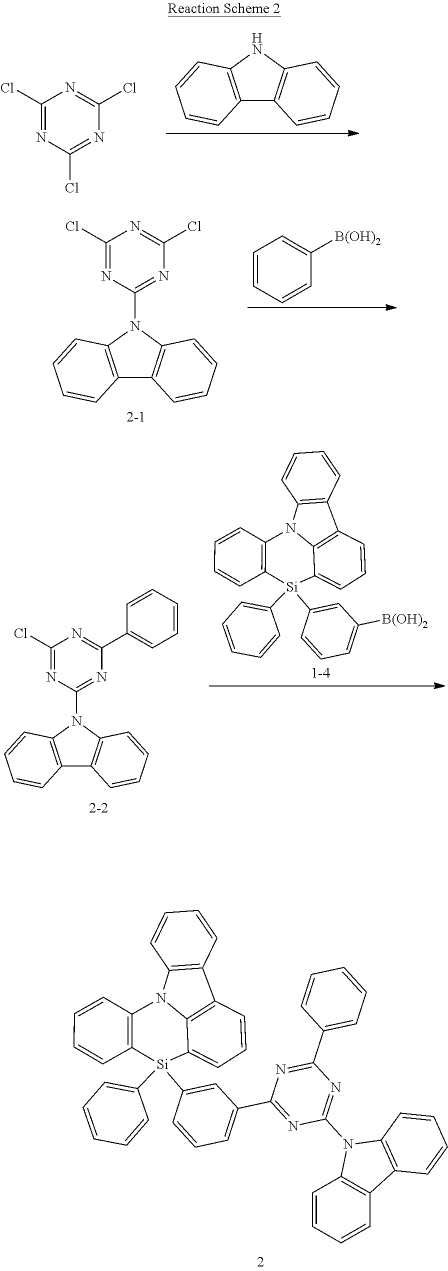

### 1) Synthesis of Intermediate 2-1

9H-carbazole (CAS #: 86-74-8) was reacted with n-BuLi, then Cyanuric chloride (CAS #: 108-77-0) was added, and the mixture was stirred at about 70° C. for about 2 hours, and then was stirred overnight at room temperature to obtain Intermediate 2-1. An identified value with LC-MS of the obtained Intermediate 2-1 is as follows.

C₁₅H₈Cl₂N₄M+1:315.01

### 2) Synthesis of Intermediate 2-2

Intermediate 2-1, and phenylboronic acid (CAS #: 98-80-6) were stirred overnight under Pd catalytic conditions to obtain Intermediate 2-2. An identified value with LC-MS of the obtained Intermediate 2-2 is as follows.

C₂₁H₁₃ClN₄M+1:357.10

### 3) Synthesis of Compound 2

2.0 g of Intermediate 2-2, 2.88 g of Intermediate 1-4, 0.26 g of Pd(PPh₃)₄, 1.94 g of K₂CO₃ (in 7 mL of H₂O), 7 mL of EtOH, 28 mL of toluene were put into RBF and the mixture was stirred overnight at about 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 2.54 g of Compound 2 (yield: 61%). An identified value with LC-MS of the obtained Compound 2 is as follows.

C₅₁H₃₃N₅Si M+1:745.26

### (3) Synthesis of Compound 5

Polycyclic Compound 5 according to one or more embodiments, may be synthesized by, for example, the steps shown in Reaction Scheme 3.

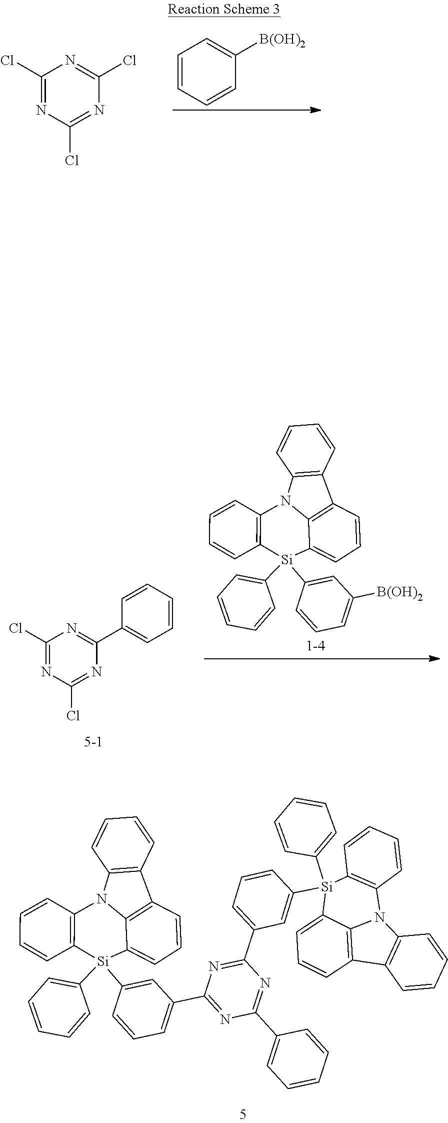 [SMILES: Clc1nc(Cl)nc(Cl)n1 ; OB(O)c1ccccc1 ; Clc1nc(Cl)nc(-c2ccccc2)n1 ; OB(O)c1cccc([Si]2(c3ccccc3)c3ccccc3-n3c4ccccc4c4cccc2c43)c1 ; c1ccc(-c2nc(-c3cccc([Si]4(c5ccccc5)c5ccccc5-n5c6ccccc6c6cccc4c65)c3)nc(-c3cccc([Si]4(c5ccccc5)c5ccccc5-n5c6ccccc6c6cccc4c65)c3)n2)cc1]

### 1) Synthesis of Intermediate 5-1

Cyanuric chloride (CAS #: 108-77-0) and phenylboronic acid (CAS #: 98-80-6) were stirred overnight under Pd catalytic conditions to obtain Intermediate 5-1. An identified value with LC-MS of the obtained Intermediate 5-1 is as follows.

C₉H₅Cl₂N₃M+1:225.99

### 2) Synthesis of Compound 5

1.0 g of Intermediate 5-1, 34 g of Intermediate 1-4, 0.41 g of Pd(PPh₃)₄, 3.06 g of K₂CO₃ (in 11 mL of H₂O), 11 mL of EtOH, 44 mL of toluene were put into RBF and the mixture was stirred overnight at about 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 2.26 g of Compound 5 (yield: 51%). An identified value with LC-MS of the obtained Compound 5 is as follows.

C₆₉H₄₅N₅Si₂M+1:1001.33

### (4) Synthesis of Compound 21

Polycyclic compound 21 according to one or more embodiments may be synthesized by, for example, the steps shown in Reaction Scheme 4.

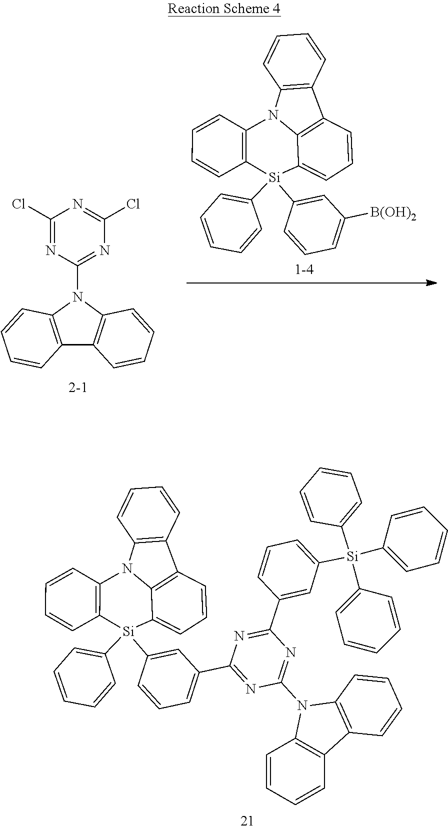 [SMILES: Clc1nc(Cl)nc(-n2c3ccccc3c3ccccc32)n1 ; OB(O)c1cccc([Si]2(c3ccccc3)c3ccccc3-n3c4ccccc4c4cccc2c43)c1 ; c1ccc([Si](c2ccccc2)(c2ccccc2)c2cccc(-c3nc(-c4cccc([Si]5(c6ccccc6)c6ccccc6-n6c7ccccc7c7cccc5c76)c4)nc(-n4c5ccccc5c5ccccc54)n3)c2)cc1]

1.5 g of Intermediate 2-1, 4.13 g of Intermediate 1-4, 0.39 g of Pd(PPh₃)₄, 2.91 g of K₂CO₃ (in 10 mL of H₂O), 10 mL of EtOH, 40 mL of toluene were put into RBF and the mixture was stirred overnight at about 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 2.02 g of Compound 21 (yield: 48%). An identified value with LC-MS of the obtained Compound 21 is as follows.

C₆₉H₄₇N₅Si₂M+1:1003.34

### (5) Synthesis of Compound 43

Polycyclic Compound 43 according to one or more embodiments may be synthesized by, for example, the steps shown in Reaction Scheme 5.

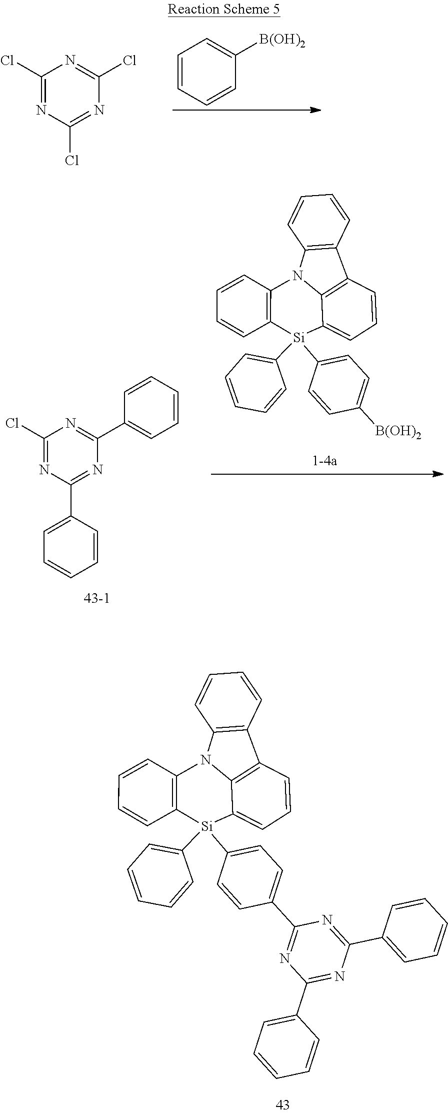 [SMILES: Clc1nc(Cl)nc(Cl)n1 ; OB(O)c1ccccc1 ; Clc1nc(-c2ccccc2)nc(-c2ccccc2)n1 ; OB(O)c1ccc([Si]2(c3ccccc3)c3ccccc3-n3c4ccccc4c4cccc2c43)cc1 ; c1ccc(-c2nc(-c3ccccc3)nc(-c3ccc([Si]4(c5ccccc5)c5ccccc5-n5c6ccccc6c6cccc4c65)cc3)n2)cc1]

### 1) Synthesis of Intermediate 43-1

Cyanuric chloride (CAS #: 108-77-0) and phenylboronic acid (CAS #: 98-80-6) were stirred overnight under Pd catalytic conditions to obtain Intermediate 43-1. An identified value with LC-MS of the obtained Intermediate 43-1 is as follows.

C₁₅H₁₀ClN₃M+1:269.05

### 2) Synthesis of Compound 43

2.0 g of Intermediate 43-1, 84 g of Intermediate 1-4a, 0.35 g of Pd(PPh₃)₄, 2.58 g of K₂CO₃ (in 9 mL of H₂O), 9 mL of EtOH, 36 mL of toluene were put into RBF and the mixture was stirred overnight at about 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 2.98 g of Compound 43 (yield: 61%). An identified value with LC-MS of the obtained Compound 43 is as follows.

C₄₅H₃₀N₄Si M+1:655.23

### (6) Synthesis of Compound 56

Polycyclic Compound 56 according to one or more embodiments may be synthesized by, for example, the steps shown in FIG. 6.

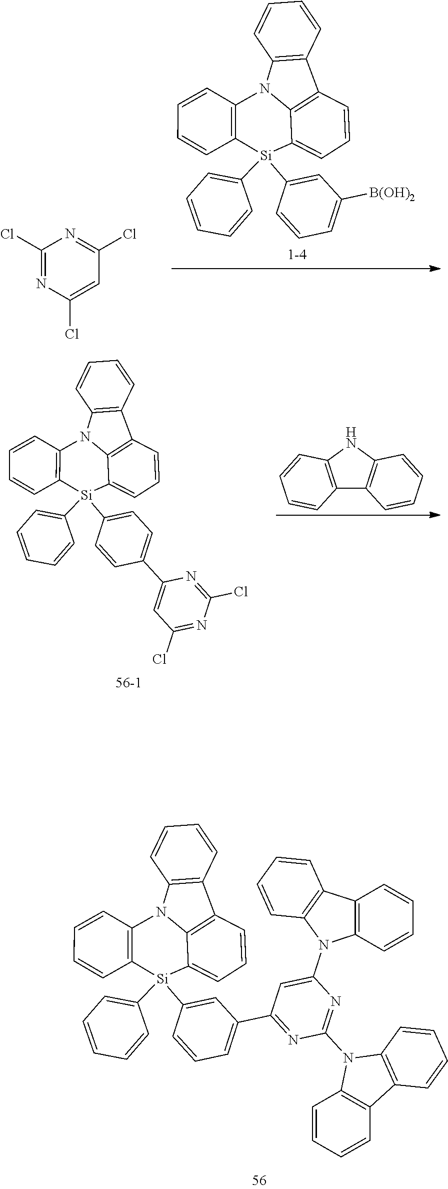

### 1) Synthesis of Intermediate 56-1

2,4,6-trichloropyrimidine (CAS #: 3764-01-0) was reacted with Intermediate 1-4 under Pd catalytic conditions to obtain Intermediate 56-1. An identified value with LC-MS of the obtained Intermediate 56-1 is as follows.

C₃₄H₂₁Cl₂N₃Si M+1:572.09

### 2) Synthesis of Compound 56

3.0 g of Intermediate 56-1, 1.85 g of 9H-carbazole (CAS #: 86-74-8), 0.24 g of Pd₂(dba)₃, 0.45 g of S-Phos, 3.18 g of NaOtBu, 27 mL of o-xylene were put into RBF, the mixture was stirred overnight at about 150° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 1.97 g of Compound 56 (yield: 45%). An identified value with LC-MS of the obtained Compound 56 is as follows.

C₅₈H₃₇N₅Si M+1:832.28

### (7) Synthesis of Compound 103

Polycyclic Compound 103 may be synthesized by, for example, the steps shown in Reaction Scheme 7.

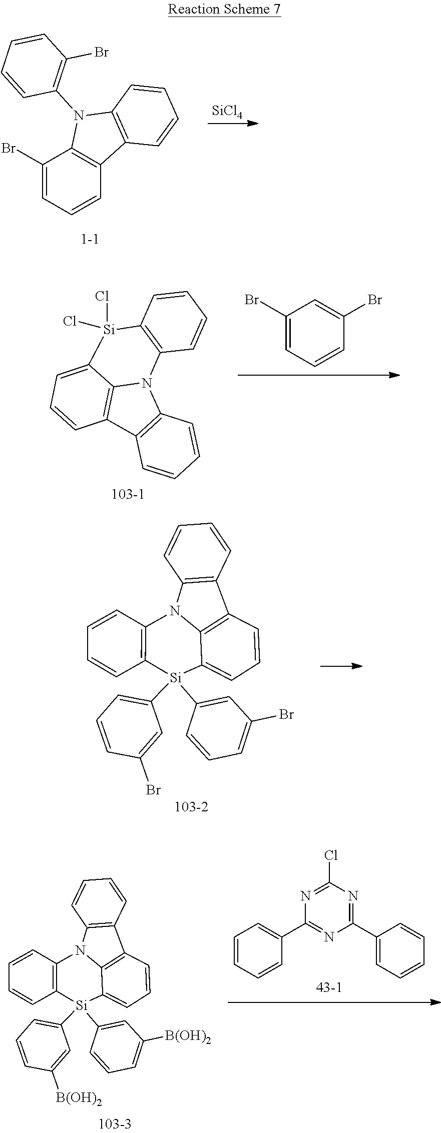

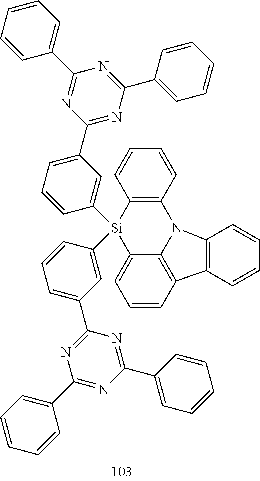 [SMILES: c1ccc(-c2nc(-c3ccccc3)nc(-c3cccc([Si]4(c5cccc(-c6nc(-c7ccccc7)nc(-c7ccccc7)n6)c5)c5ccccc5-n5c6ccccc6c6cccc4c65)c3)n2)cc1]

### 1) Synthesis of Intermediate 103-1 and Intermediated 103-2

Intermediate 1-1 was reacted with n-BuLi, then the reactant was put into silicon tetrachloride (CAS #: 10026-04-7), and the mixture was stirred at about 0° C. for about 2 hours. 1,3-dibromobenzene (CAS #: 108-36-1) was reacted with n-BuLi, then the reactant previously obtained was put thereto, and the mixture was stirred overnight at room temperature to obtain Intermediate 103-2. An identified value with LC-MS of the obtained Intermediate 103-2 is as follows.

1C₃₀H₁₉Br₂NSi M+1:581.97

### 2) Synthesis of Intermediate 103-3

Intermediate 103-2 was reacted with n-BuLi, then trimethyl borate (CAS #:121-43-7) was added, the mixture was stirred overnight at room temperature, and H₂O was put to obtain Intermediate 103-3. An identified value with LC-MS of the obtained Intermediate 103-3 is as follows.

C₃₀H₂₃B₂NO₄Si M+1:512.16

### 3) Synthesis of Compound 103

2.0 g of Intermediate 43-1, 1.91 g of Intermediate 103-3, 0.35 g of Pd(PPh₃)₄, 2.58 g of K₂CO₃ (in 9 mL of H₂O), 9 mL of EtOH, 36 mL of toluene were put into RBF and the mixture was stirred overnight at 120° C. After completion of the reaction, a reaction solution was extracted with ethyl acetate, a collected organic layer was dried over magnesium sulfate, and a solvent was evaporated. Thereafter, the residue obtained was separated by silica gel column chromatography and purified to obtain 1.72 g of Compound 103 (yield: 52%). An identified value with LC-MS of the obtained Compound 103 is as follows.

C₆₀H₃₉N₇Si M+1:886.31

### 2. Manufacture and Evaluation of Light-emitting Element

### (1) Manufacture of Light-emitting Element

Light-emitting elements according to one or more embodiments including polycyclic compounds according to one or more embodiments, or comparative example compounds, in an emission layer were manufactured utilizing a method described herein. Light-emitting elements according to Examples 1 to 7 were manufactured including polycyclic compounds according to one or more embodiments, respectively, as one of host materials in the emission layer. Light-emitting elements according to Comparative Example 1 to Comparative Example 3 were manufactured utilizing Comparative Example Compounds C-1 to C-3, respectively, as one of host materials in the emission layer.

A glass substrate (a product of Corning), on which an indium tin oxide (ITO) electrode of about 15 ohm per square centimeter (0/cm²) (1,200 angstrom (Å)) was formed as the first electrode, was cut to a size of about 50 millimeter (mm)×50 mm×0.5 mm, subjected to ultrasonic cleaning utilizing isopropyl alcohol and pure water for 5 minutes each, then ultraviolet irradiation for 30 minutes and then exposed to ozone for cleaning. Then, the glass substrate was mounted on a vacuum deposition apparatus.

HATCN was deposited on the first electrode to form a hole injection layer having a thickness of about 100 Å, Compound H-1-1 having a thickness of about 600 Å was deposited on the hole injection layer, and then, HT33 having a thickness of about 50 Å was deposited to form a hole transport layer.

HT33, Examples or Comparative Examples Compounds, and AD-41 were co-deposited on the hole transport layer at a weight ratio of about 60:27:13 to form an emission layer having a thickness of about 350 Å. HT33 was utilized as a hole-transporting host, Examples or Comparative Examples Compounds were each utilized as an electron-transporting host, and AD-41 was utilized as a phosphorescent dopant.

ETH2 having a thickness of about 50 Å was deposited, on the emission layer, then ETH2 and LiQ were co-deposited at a weight ratio of about 1:1 to form a layer having a thickness of about 350 Å, thereby forming an electron transport layer. LiF was deposited on the electron transport layer to form an electron injection layer having a thickness of about 15 Å, and Al was deposited on the electron injection layer to form a second electrode having a thickness of about 80 Å, to thereby manufacture a light-emitting element.

The compounds utilized in the manufacturing of the light-emitting element were as follows. Example Compounds and Comparative Example Compounds utilized in the manufacturing of the light-emitting elements are listed in Table 1.

Materials commonly utilized in manufacturing of light-emitting elements

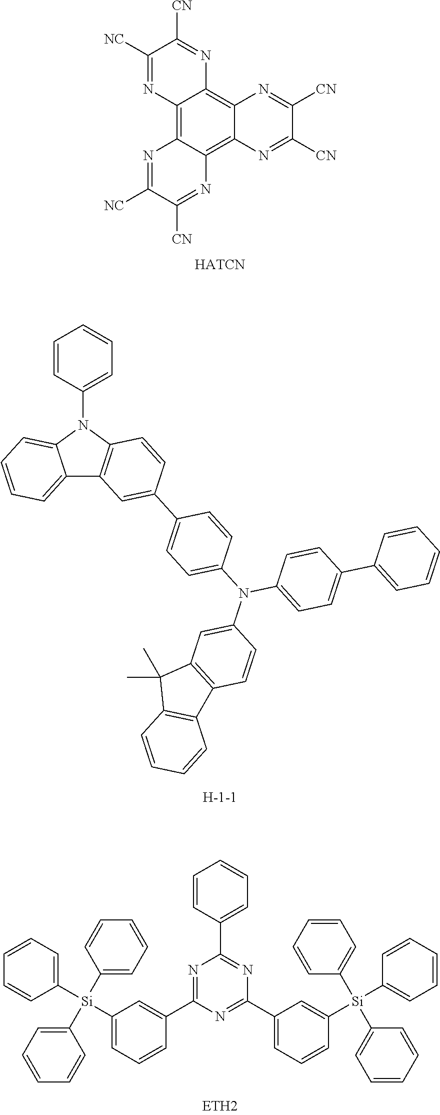

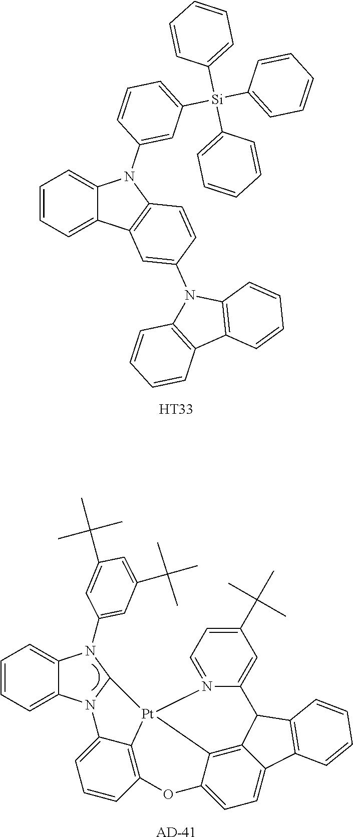

### Dopant Materials of Examples and Comparative Examples Utilized in Manufacturing of Light-Emitting Elements

TABLE 1

| | | |
|---|---|---|
| Example 1 | 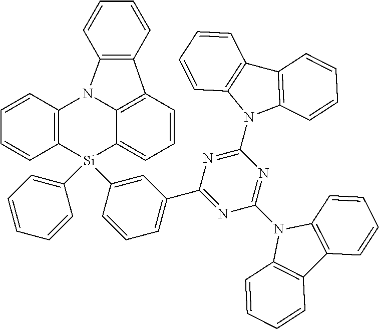 [SMILES: c1ccc([Si]2(c3cccc(-c4nc(-n5c6ccccc6c6ccccc65)nc(-n5c6ccccc6c6ccccc65)n4)c3)c3ccccc3-n3c4ccccc4c4cccc2c43)cc1] | 1 |
| Example 2 | 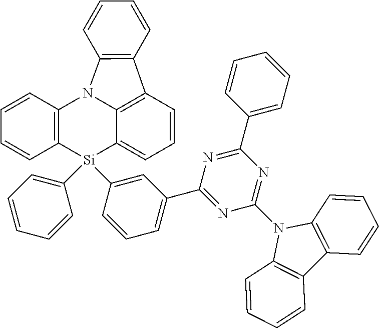 [SMILES: c1ccc(-c2nc(-c3cccc([Si]4(c5ccccc5)c5ccccc5-n5c6ccccc6c6cccc4c65)c3)nc(-n3c4ccccc4c4ccccc43)n2)cc1] | 2 |
| Example 3 | 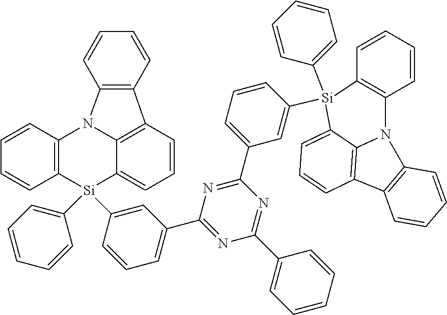 [SMILES: c1ccc(-c2nc(-c3cccc([Si]4(c5ccccc5)c5ccccc5-n5c6ccccc6c6cccc4c65)c3)nc(-c3cccc([Si]4(c5ccccc5)c5ccccc5-n5c6ccccc6c6cccc4c65)c3)n2)cc1] | 5 |
| Example 4 | 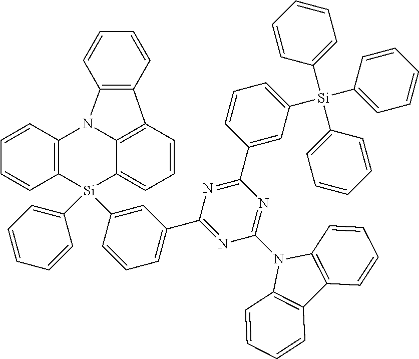 [SMILES: c1ccc([Si](c2ccccc2)(c2ccccc2)c2cccc(-c3nc(-c4cccc([Si]5(c6ccccc6)c6ccccc6-n6c7ccccc7c7cccc5c76)c4)nc(-n4c5ccccc5c5ccccc54)n3)c2)cc1] | 21 |
| Example 5 | 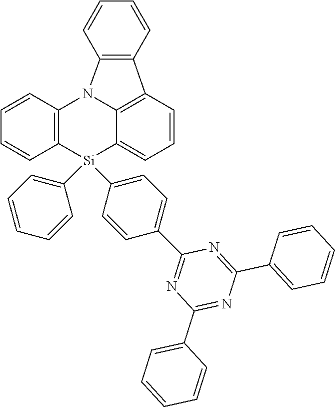 [SMILES: c1ccc(-c2nc(-c3ccccc3)nc(-c3ccc([Si]4(c5ccccc5)c5ccccc5-n5c6ccccc6c6cccc4c65)cc3)n2)cc1] | 43 |
| Example 6 | 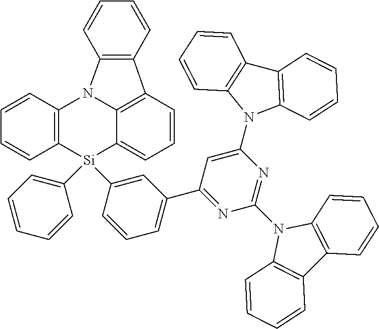 [SMILES: c1ccc([Si]2(c3cccc(-c4cc(-n5c6ccccc6c6ccccc65)nc(-n5c6ccccc6c6ccccc65)n4)c3)c3ccccc3-n3c4ccccc4c4cccc2c43)cc1] | 56 |
| Example 7 | 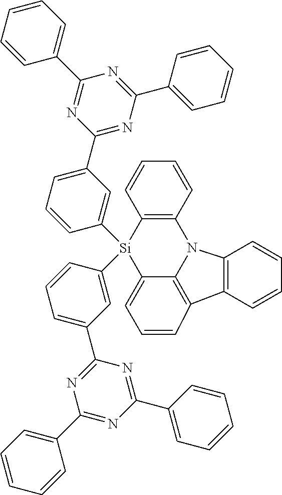 [SMILES: c1ccc(-c2nc(-c3ccccc3)nc(-c3cccc([Si]4(c5cccc(-c6nc(-c7ccccc7)nc(-c7ccccc7)n6)c5)c5ccccc5-n5c6ccccc6c6cccc4c65)c3)n2)cc1] | 103 |
| Comparative Example 1 | 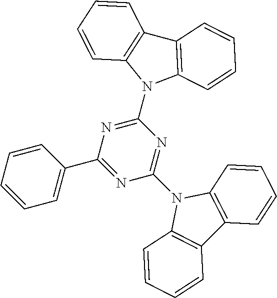 [SMILES: c1ccc(-c2nc(-n3c4ccccc4c4ccccc43)nc(-n3c4ccccc4c4ccccc43)n2)cc1] | C-1 |
| Comparative Example 2 | 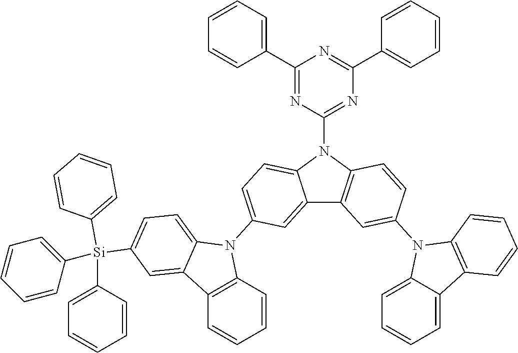 [SMILES: c1ccc(-c2nc(-c3ccccc3)nc(-n3c4ccc(-n5c6ccccc6c6ccccc65)cc4c4cc(-n5c6ccccc6c6cc([Si](c7ccccc7)(c7ccccc7)c7ccccc7)ccc65)ccc43)n2)cc1] | C-2 |
| Comparative Example 3 | 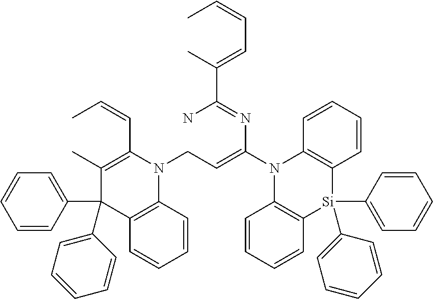 [SMILES: C\C=C/C=C(C)/C(N)=N/C(=C\CN1C(/C=C\C)=C(C)C(c2ccccc2)(c2ccccc2)c2ccccc21)N1c2ccccc2[Si](c2ccccc2)(c2ccccc2)c2ccccc21] | C-3 |

(2) Evaluation of light-emitting Elements

Light-emitting elements according to Examples and Comparative Examples were evaluated and the results were listed in Table 2. A driving voltage (V) and maximum quantum efficiency of the light-emitting elements according to Examples and Comparative Examples were measured at a current density of 10 milliampere per square centimeter (mA/cm²). The driving voltage of the light emitting element was measured with a source meter (Keithley Instrument, Inc., 2400 series), and the maximum quantum efficiency was measured with the external quantum efficiency measurement system (Hamamatsu Photonics K. K, Model No. C9920-2-12). Luminance/current density was measured utilizing a luminance meter, in which wavelength sensitivity was calibrated, and the measured value was converted by assuming an angular luminance distribution (Lambertian reflectance), which refers to that a diffusely reflecting surface was assumed, to obtain the maximum quantum efficiency. A lifespan of the light-emitting element according to Comparative Example 1 was considered as 100%, and relative values of lifespans of the light-emitting elements according to Examples and Comparative Examples except for Comparative Example 1 with respect to the lifespan of the light-emitting element according to Comparative Example 1 were calculated as relative lifespans.

TABLE 2

| | | Maximum | | |
|---|---|---|---|---|
| | Driving | quantum | Relative | Emission |
| Classification | voltage (V) | efficiency (%) | lifespan (%) | color |
| Example 1 | 4.1 | 27.1 | 150 | Blue |
| Example 2 | 4.0 | 27.0 | 132 | Blue |
| Example 3 | 4.2 | 25.3 | 130 | Blue |
| Example 4 | 4.2 | 26.2 | 135 | Blue |
| Example 5 | 3.8 | 25.7 | 100 | Blue |
| Example 6 | 4.1 | 24.8 | 116 | Blue |
| Example 7 | 4.1 | 25.1 | 110 | Blue |
| Comparative | 3.9 | 24.7 | 100 | Blue |
| Example 1 | | | | |
| Comparative | 4.4 | 15.8 | 13 | Blue |
| Example 2 | | | | |
| Comparative | 4.5 | 13.2 | 6 | Blue |
| Example 3 | | | | |

Referring to the results listed in Table 2, each (e.g., all) of the light-emitting elements according to Examples and Comparative Examples exhibit emission color characteristics of blue light. Each of the Example Compounds having a bulky structure, interacts less with adjacent compounds than Comparative Example Compound C-1 and/or the like utilized in the light-emitting element according to Comparative Example 1, and thus has no aspect on emission characteristics. As a result, it may be thought that the light-emitting elements according to Examples have similar emission color characteristics to the light-emitting elements according to Comparative Examples. In one or more embodiments, the light-emitting elements according to Examples have similar driving voltage characteristics when compared to the light-emitting elements according to Comparative Examples. The light-emitting elements according to Examples exhibit more excellent or suitable maximum quantum efficiency than the light-emitting elements according to Comparative Examples. For example, the light-emitting elements according to Examples exhibit significantly improved lifespan characteristics compared to the light-emitting elements according to Comparative Examples, and it may be considered without being bound by any particular theory, it is believed that it is because the light-emitting elements according to Examples have more excellent or suitable material stability than the light-emitting elements according to Comparative Examples (e.g., due to a three-dimensional structural characteristic of Example Compounds).

Without being bound by any particular theory, it is believed that the polycyclic compound according to one or more embodiments may include a heteroaryl ring in which at least two among carbon atoms of a fused cyclic ring, which contains Si and N as ring-forming atoms, and a benzene ring are substituted with N. The polycyclic compound according to one or more embodiments may have a bulky three-dimensional structure by containing a fused cyclic ring, in which a portion of a silyl group containing Si is bonded to a carbazole group to form a ring. The polycyclic compound according to one or more embodiments may interact less with an adjacent compound molecule due to characteristics of the three-dimensional structure. For example, a phenomenon of interference of the polycyclic compound according to one or more embodiments with a dopant and/or the like utilized together may be minimized or reduced and thus have no aspect on emission characteristics of the dopant, thereby minimizing or reducing changes in the emission color of the dopant. As a result, the polycyclic compound according to one or more embodiments may have the improved color reproductivity of the light-emitting element. In one or more embodiments, the polycyclic compound according to one or more embodiments includes a portion of a silyl group, and thus exhibits bipolar characteristics, thereby having excellent or suitable material stability.

A light-emitting element according to one or more embodiments includes the polycyclic compound according to one or more embodiments, and thus may exhibit characteristics of long lifespan and excellent or suitable color reproductivity. In one or more embodiments, a display device according to one or more embodiments includes the light-emitting element having excellent or suitable color reproductivity and excellent or suitable efficiency and lifespan characteristics, and thus may exhibit improved display quality.

The light-emitting element according to one or more embodiments includes the polycyclic compound according to one or more embodiments, and thus may exhibit characteristics of excellent or suitable color reproductivity and long lifespan.

The polycyclic compound according to one or more embodiments may contribute to improvements in the color purity and the long lifespan of the light-emitting element.

The display device according to one or more embodiments may exhibit excellent or suitable display quality.

Hitherto, although the embodiments of the present disclosure have been described, it is understood that the present disclosure should not be limited to these embodiments but one or more suitable changes and modifications can be made by one ordinary skilled in the art within the spirit and technical scope of the present disclosure as hereinafter claimed.

Therefore, the technical scope of the present disclosure is not intended to be limited to the contents set forth in the detailed description of the specification, but is intended to be defined by the appended claims, and equivalents thereof.

What is claimed is:

1. A light-emitting element comprising:
a first electrode;
a second electrode on the first electrode; and
a functional layer between the first electrode and the second electrode, and comprising a first compound represented by Formula 1: 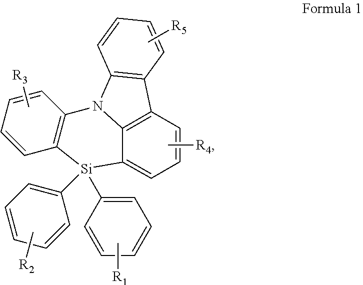
in Formula 1,
at least one selected from among R₁ to R₅ is represented by Formula 2, and any remaining selected from among R₁ to R₅ are each a hydrogen atom or a deuterium atom: 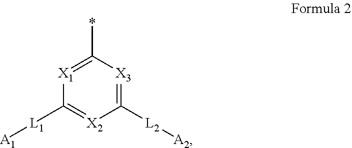
in Formula 2,
X₁ to X₃ are each independently N, CH, or CD,
at least two selected from among X₁ to X₃ are each N,
L₁ and L₂ are each independently a direct linkage, a substituted or unsubstituted arylene group having 6 to 30 ring-forming carbon atoms, or a substituted or unsubstituted heteroarylene group having 3 to 30 ring-forming carbon atoms,
A₁ and A₂ are each independently a substituted or unsubstituted aryl group having 6 to 30 ring-forming carbon atoms, a substituted or unsubstituted heterocyclic group having 3 to 30 ring-forming carbon atoms, or a substituted or unsubstituted silyl group, and 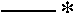 [SMILES: *C]
is a portion connected to Formula 1.

2. The light-emitting element of claim 1, wherein:
the functional layer comprises an emission layer, a hole transport region between the first electrode and the emission layer, and an electron transport region between the emission layer and the second electrode, and
at least one selected from among the emission layer and the electron transport region comprises the first compound.

3. The light-emitting element of claim 2, wherein the emission layer comprises the first compound and a phosphorescent dopant.

4. The light-emitting element of claim 2, wherein the emission layer comprises the first compound, a second compound represented by Formula D-1, and a third compound represented by Formula HT-1: 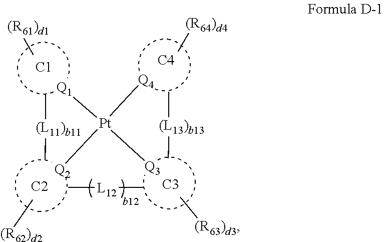
in Formula D-1,
Q₁ to Q₄ are each independently C or N,
C₁ to C₄ are each independently a substituted or unsubstituted hydrocarbon ring having 5 to 30 ring-forming carbon atoms, or a substituted or unsubstituted hetero ring having 2 to 30 ring-forming carbon atoms,
L₁₁ to L₁₃ are each independently a direct linkage, 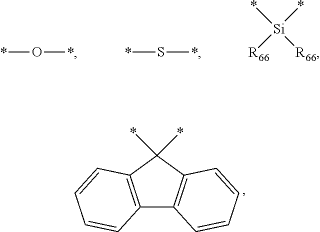
a substituted or unsubstituted divalent alkyl having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 are each independently an integer of 0 to 4: 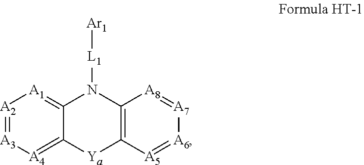
in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring.

5. The light-emitting element of claim 4, wherein the emission layer further comprises a fourth compound represented by Formula F-1: 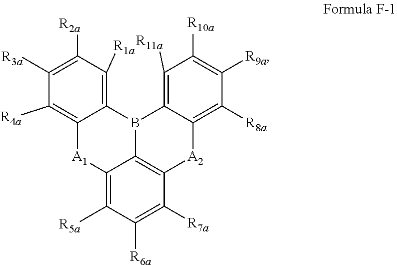
in Formula F-1,
A₁ and A₂ are each independently O, S, Se, or NRₘ,
Rₘ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁ₐ to R₁₁ₐ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

6. The light-emitting element of claim 3, wherein the emission layer is configured to emit blue light.

7. The light-emitting element of claim 1, wherein Formula 2 is represented by Formula 2-1 or Formula 2-2: 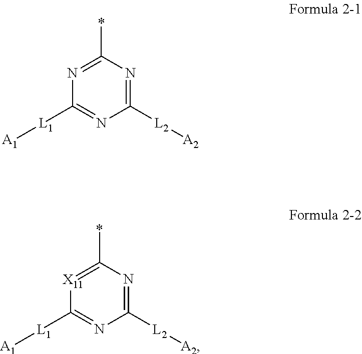
in Formula 2-2, X₁₁ is CH or CD, and
in Formula 2-1 and Formula 2-2, L₁, L₂, A₁, and A₂ are as defined in Formula 2.

8. The light-emitting element of claim 1, wherein:
A₁ and A₂ in Formula 2 are each independently
a substituted or unsubstituted phenyl group,
a substituted or unsubstituted carbazole group, or
a substituted or unsubstituted triphenylsilyl group; or
A₁ and A₂ in Formula 2 are represented by Formula SG and any one ring selected from among C₁ to C₅ is connected to L₁ or L₂:

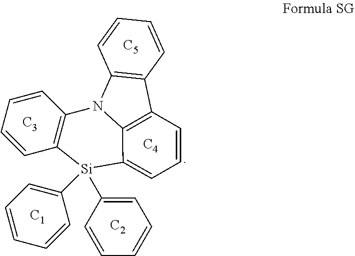

9. The light-emitting element of claim 1, wherein any one selected from among hydrogen atoms of the first compound is substituted with a deuterium atom.

10. The light-emitting element of claim 1, wherein the first compound is represented by any one selected from among compounds in Compound Group 1 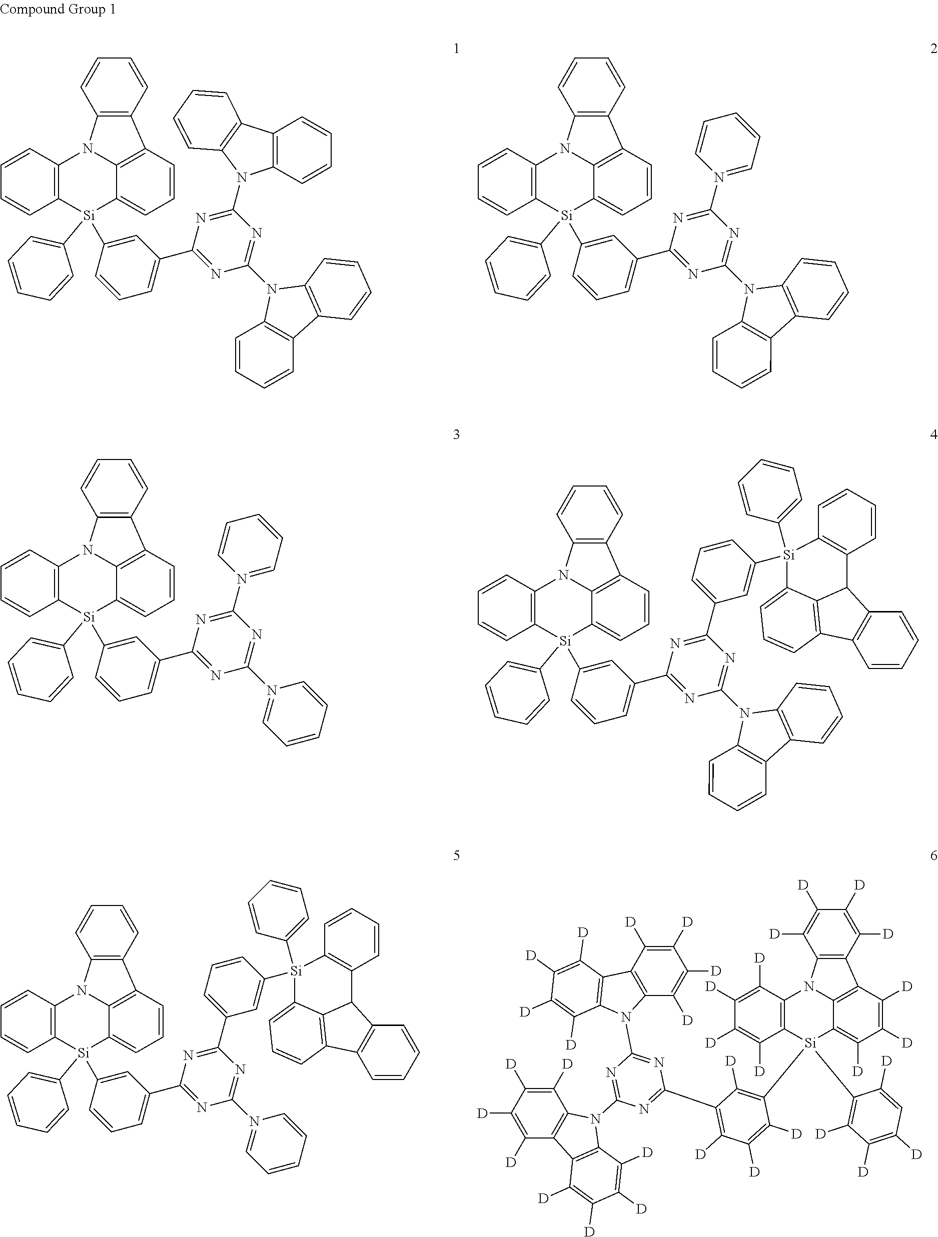 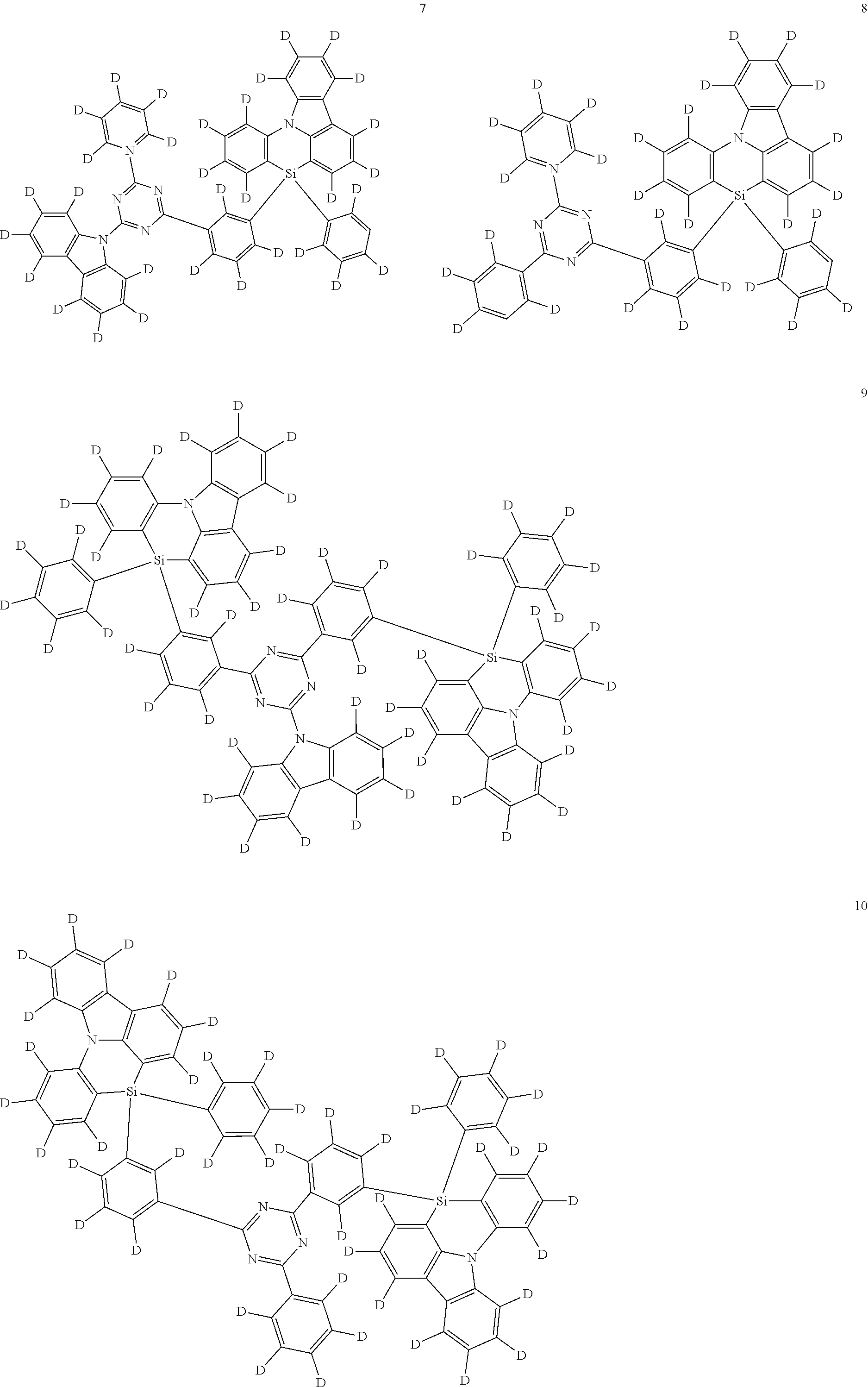 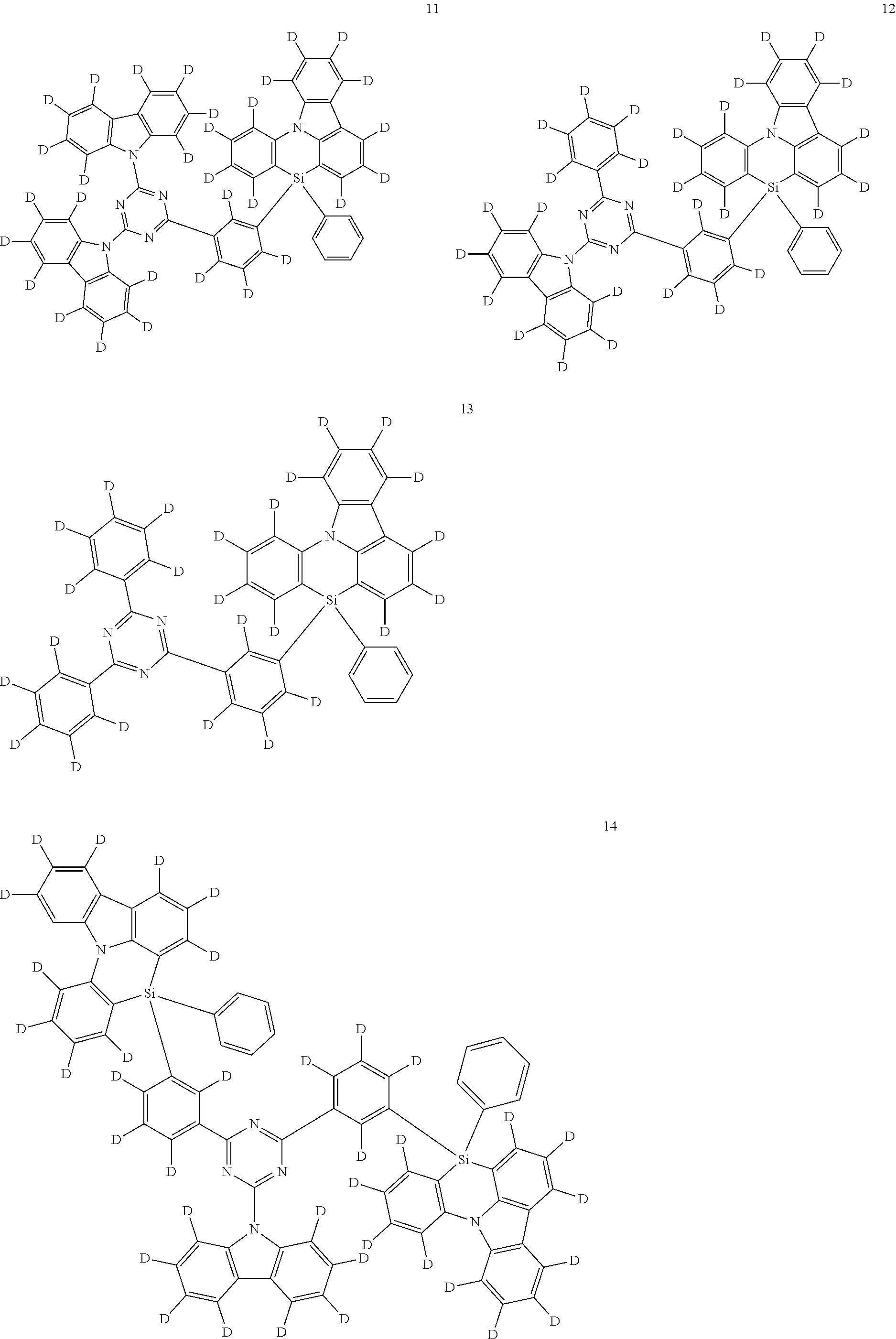 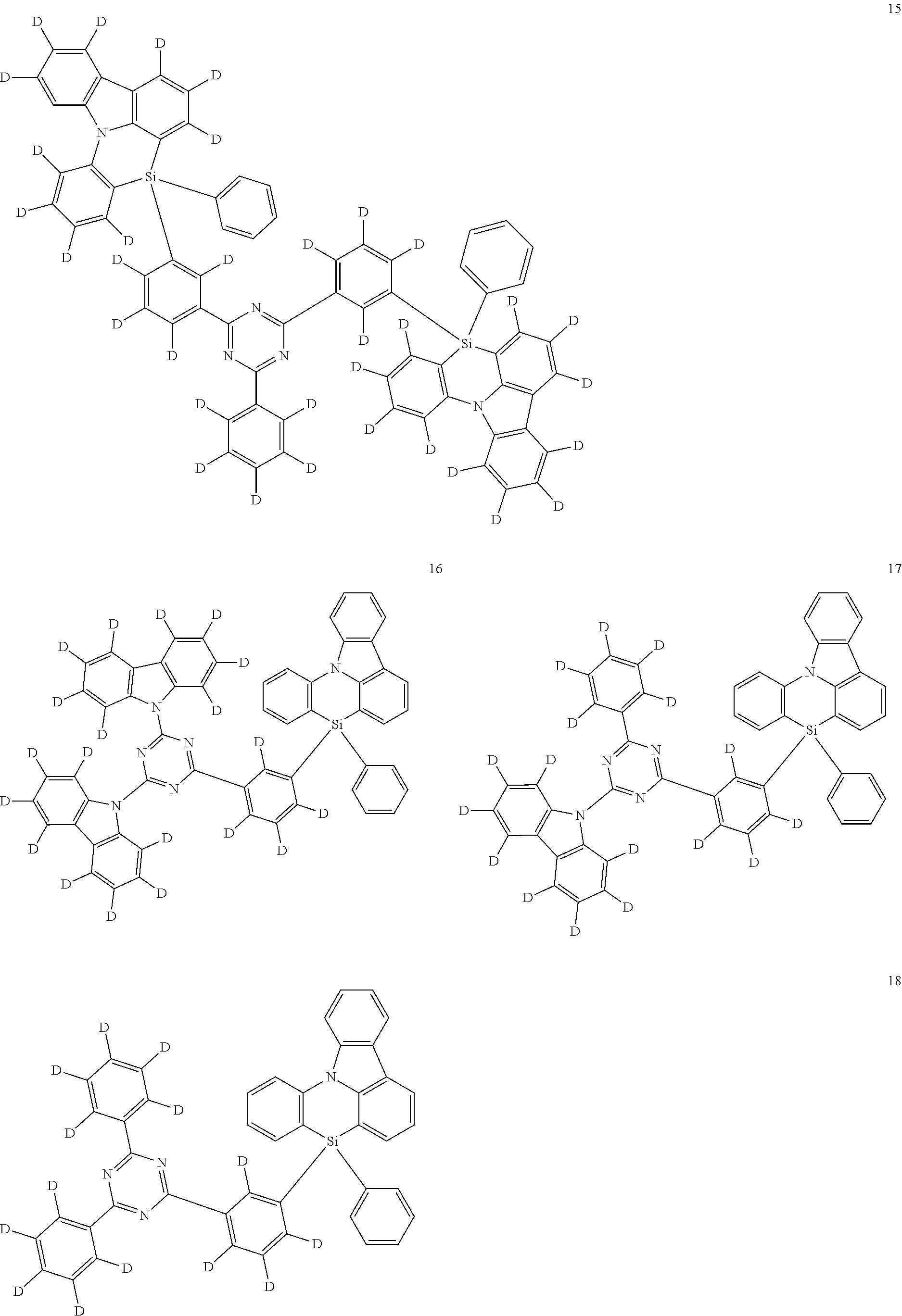 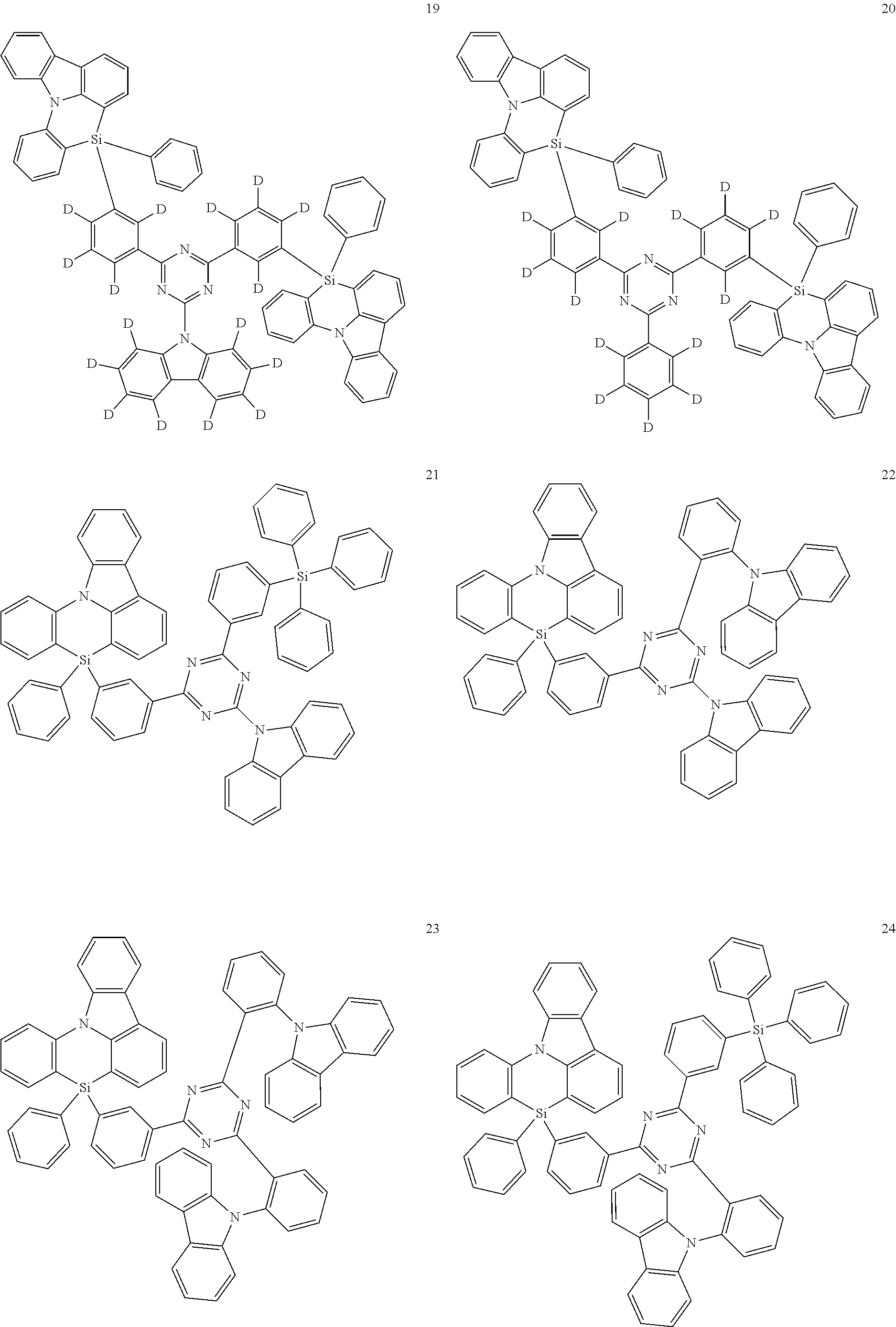 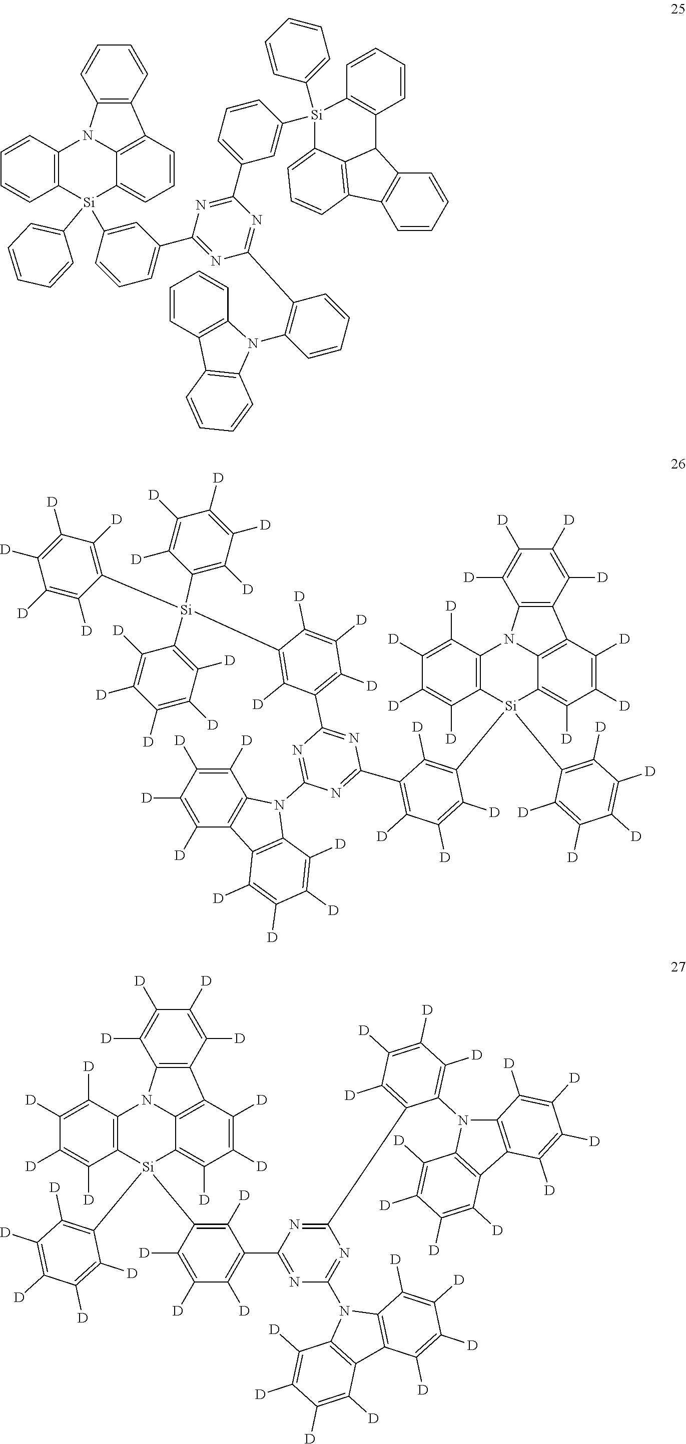 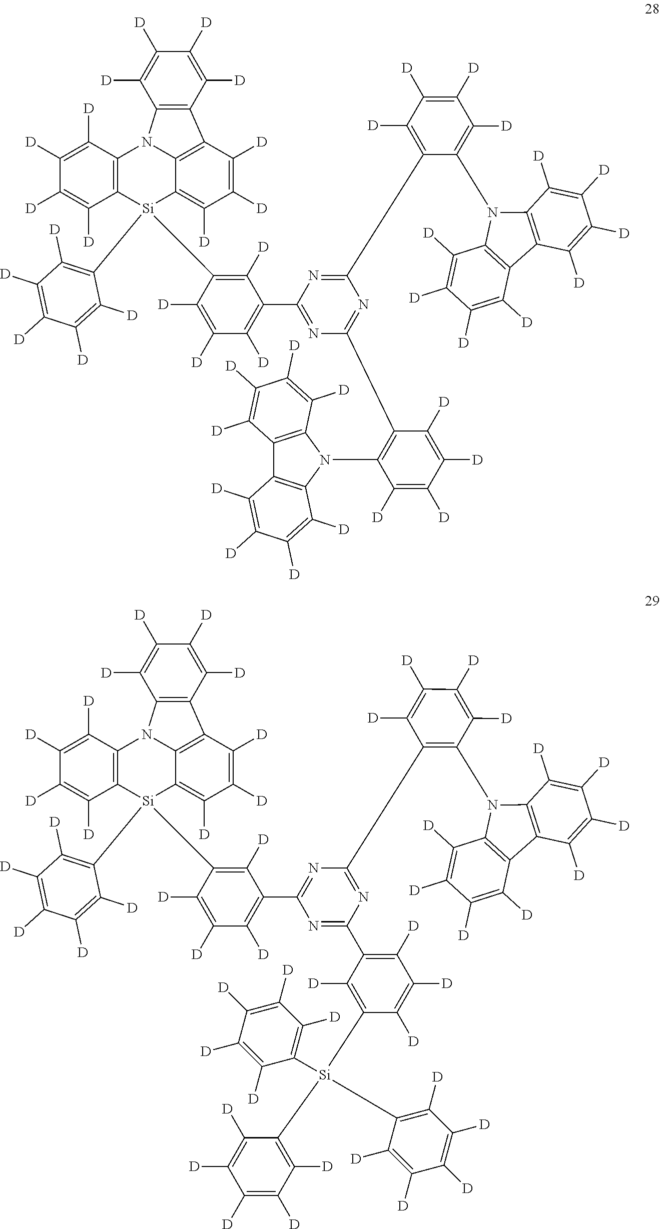 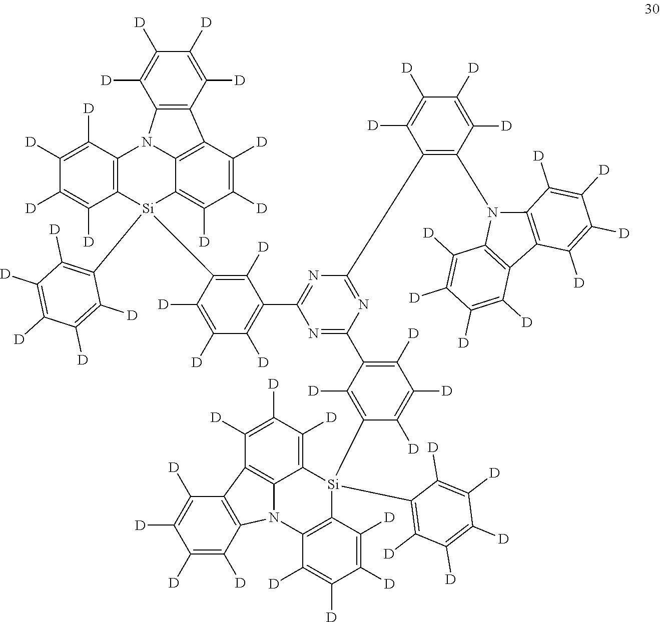 [SMILES: [2H]c1c([2H])c([2H])c([Si]2(c3c([2H])c([2H])c([2H])c(-c4nc(-c5c([2H])c([2H])c([2H])c([Si]6(c7c([2H])c([2H])c([2H])c([2H])c7[2H])c7c([2H])c([2H])c([2H])c([2H])c7-n7c8c([2H])c([2H])c([2H])c([2H])c8c8c([2H])c([2H])c([2H])c6c87)c5[2H])nc(-c5c([2H])c([2H])c([2H])c([2H])c5-n5c6c([2H])c([2H])c([2H])c([2H])c6c6c([2H])c([2H])c([2H])c([2H])c65)n4)c3[2H])c3c([2H])c([2H])c([2H])c([2H])c3-n3c4c([2H])c([2H])c([2H])c([2H])c4c4c([2H])c([2H])c([2H])c2c43)c([2H])c1[2H]] 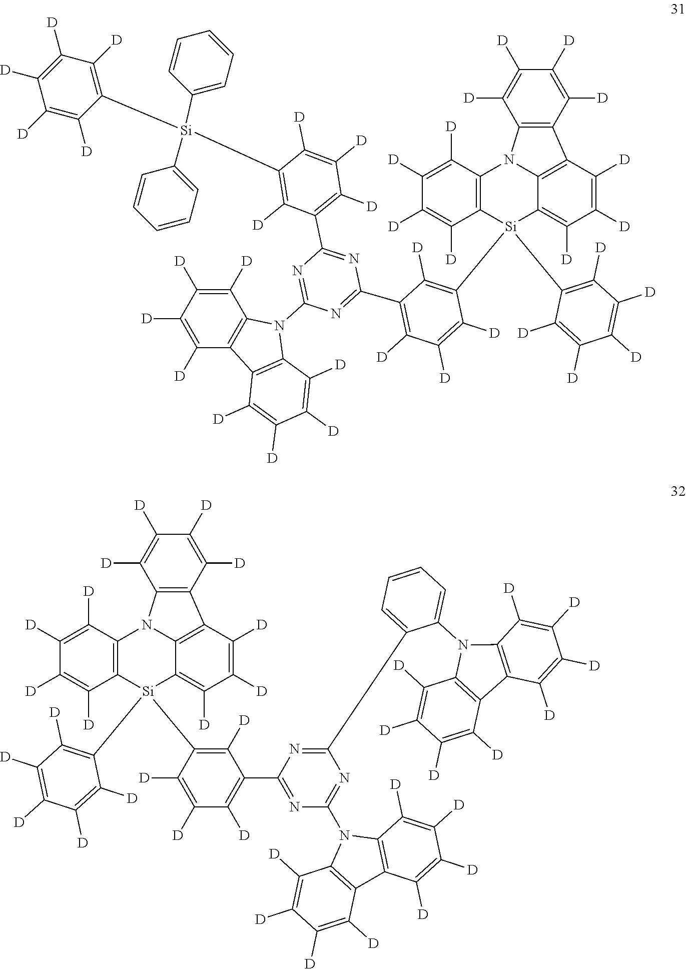 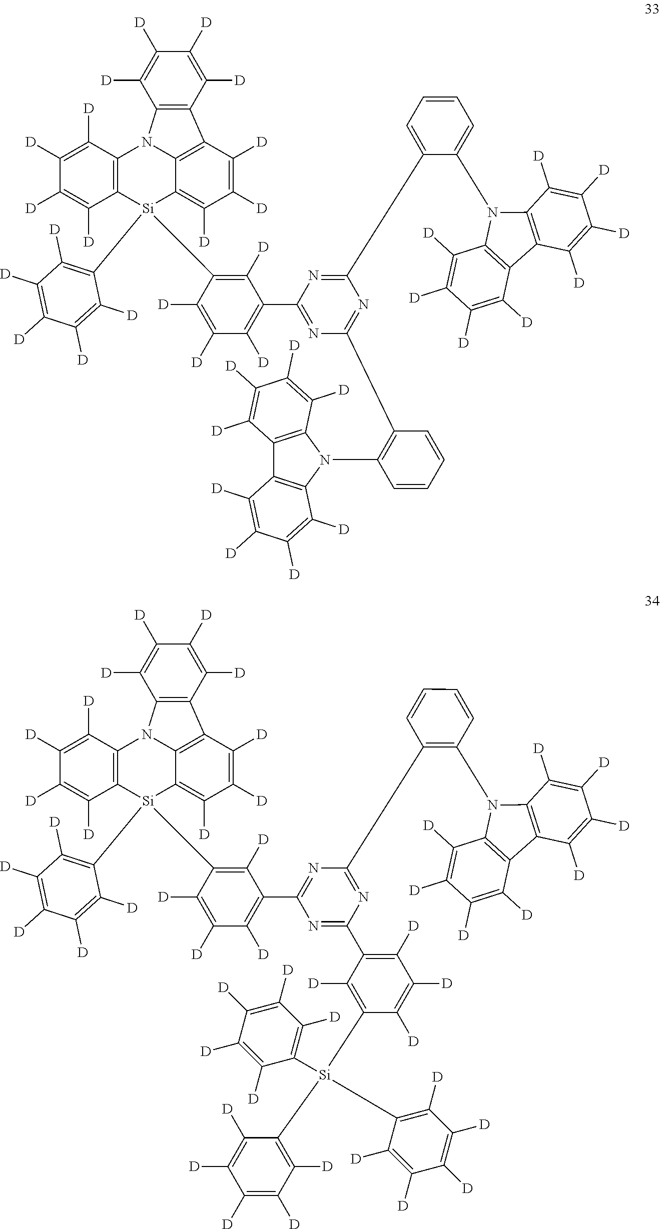 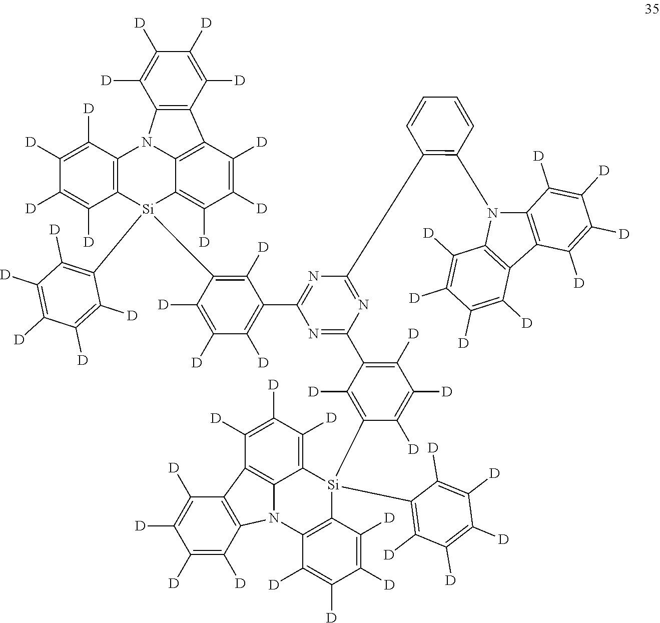 [SMILES: [2H]c1c([2H])c([2H])c([Si]2(c3c([2H])c([2H])c([2H])c(-c4nc(-c5ccccc5-n5c6c([2H])c([2H])c([2H])c([2H])c6c6c([2H])c([2H])c([2H])c([2H])c65)nc(-c5c([2H])c([2H])c([2H])c([Si]6(c7c([2H])c([2H])c([2H])c([2H])c7[2H])c7c([2H])c([2H])c([2H])c([2H])c7-n7c8c([2H])c([2H])c([2H])c([2H])c8c8c([2H])c([2H])c([2H])c6c87)c5[2H])n4)c3[2H])c3c([2H])c([2H])c([2H])c([2H])c3-n3c4c([2H])c([2H])c([2H])c([2H])c4c4c([2H])c([2H])c([2H])c2c43)c([2H])c1[2H]] 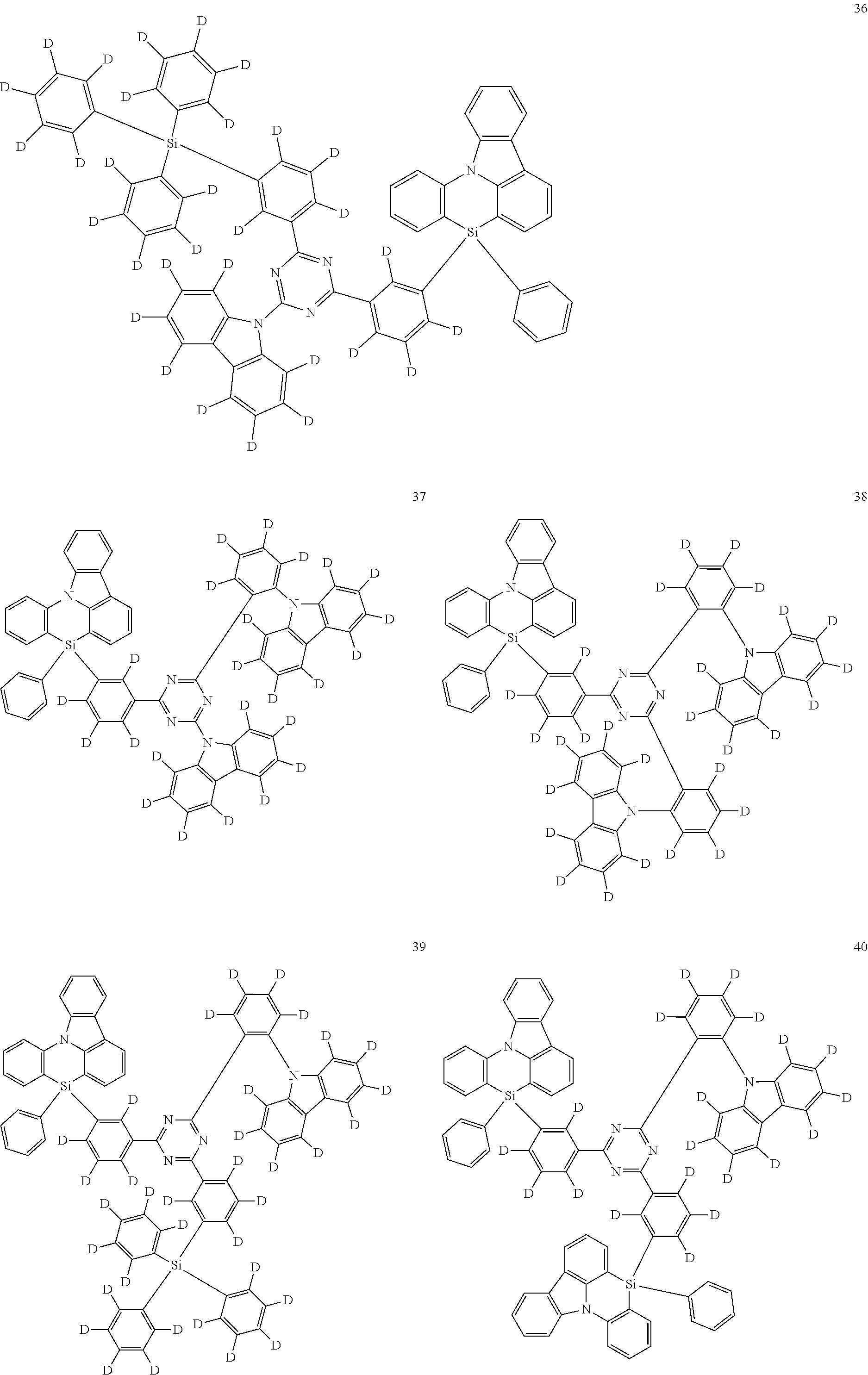 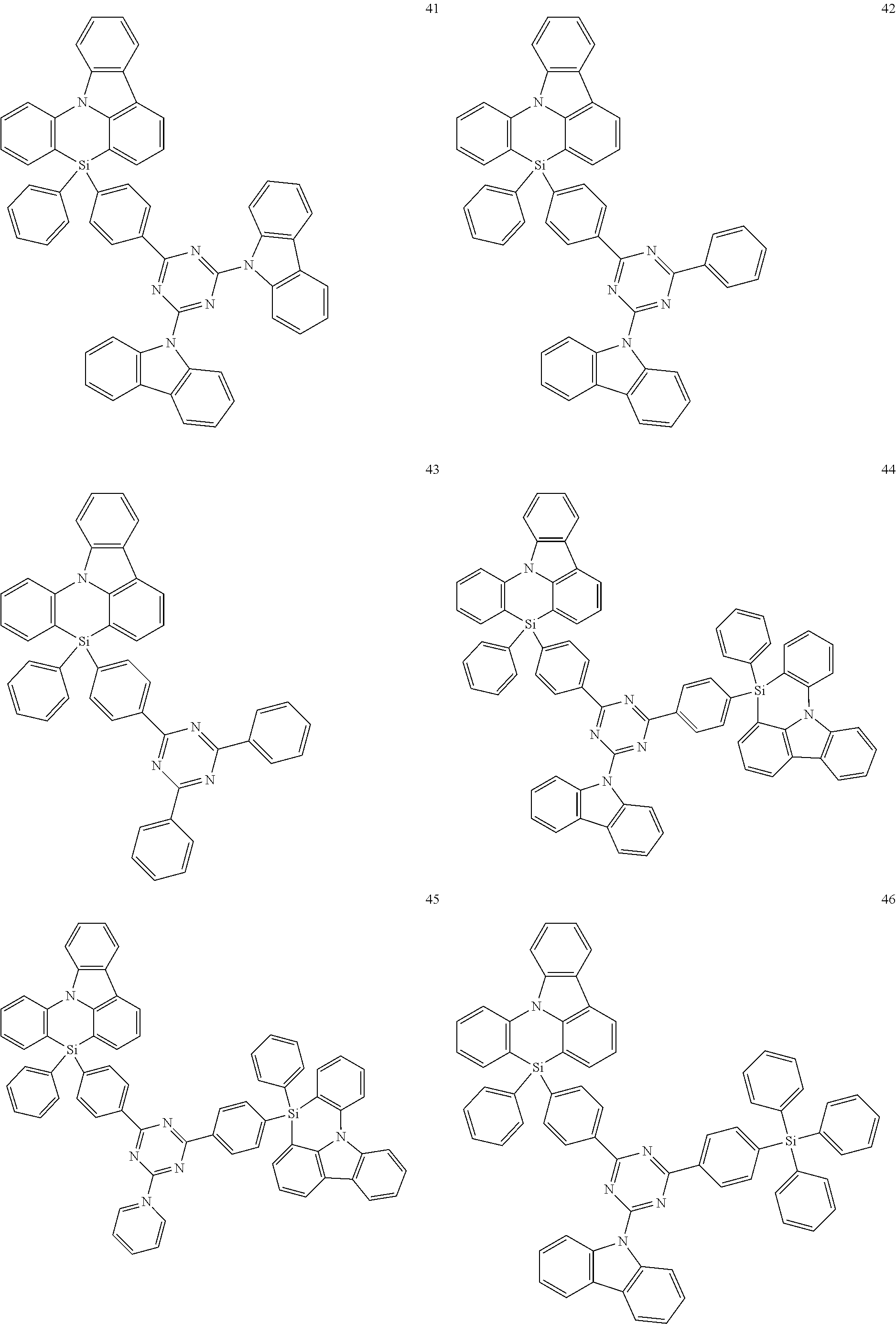 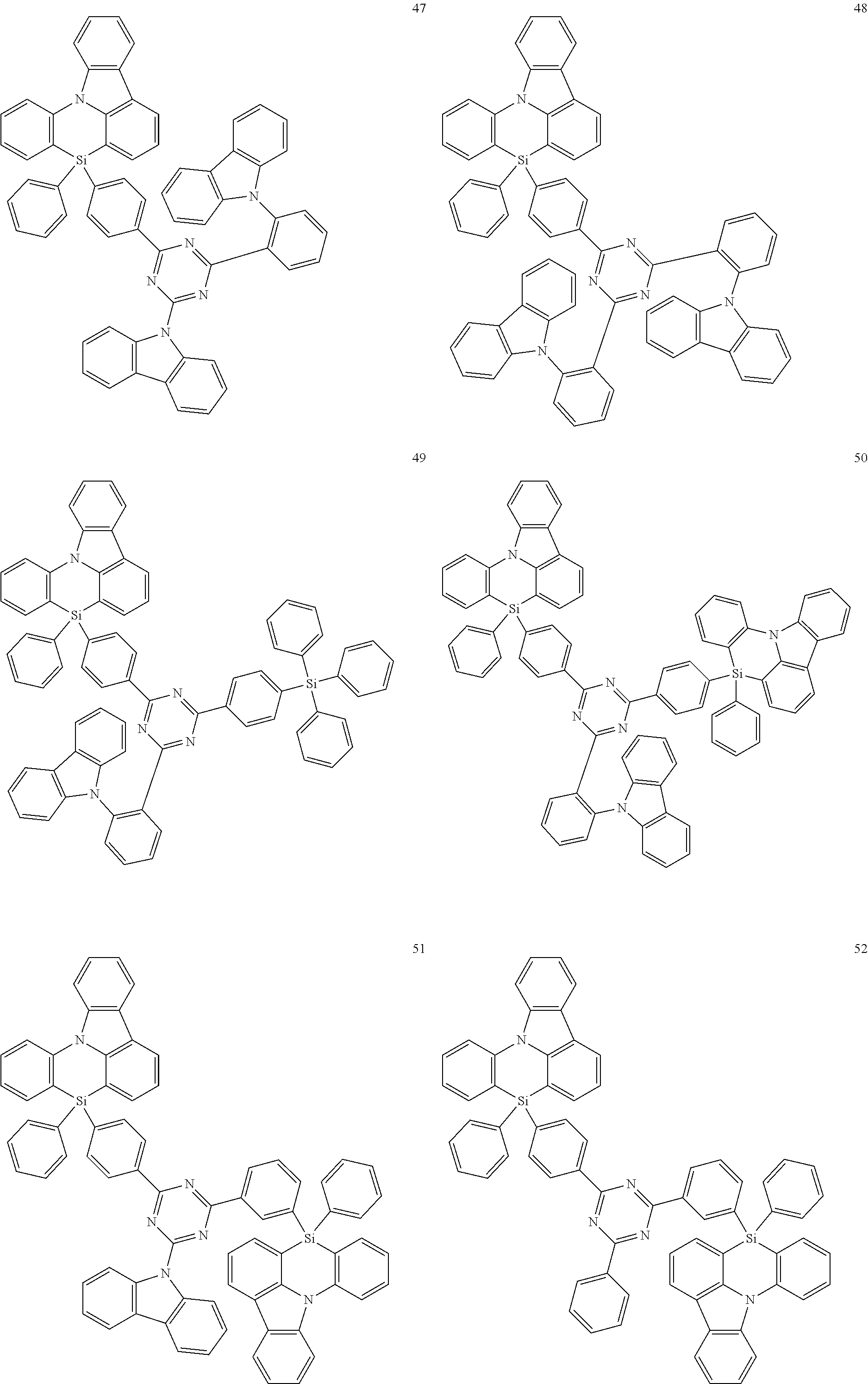 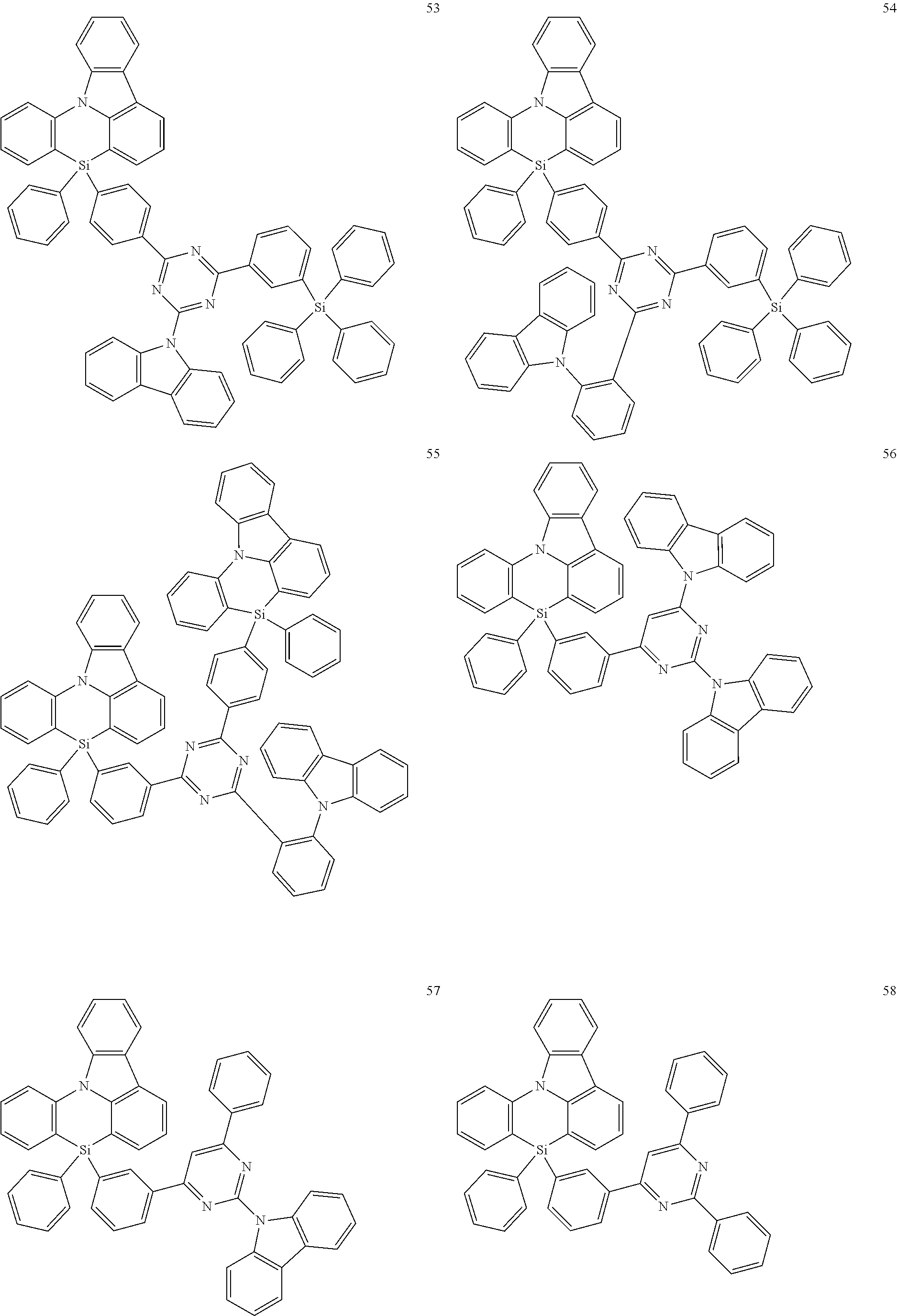 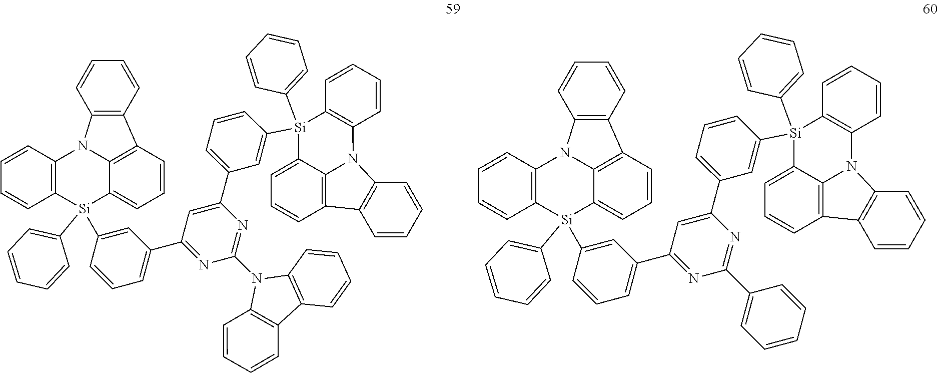 [SMILES: c1ccc([Si]2(c3cccc(-c4cc(-c5cccc([Si]6(c7ccccc7)c7ccccc7-n7c8ccccc8c8cccc6c87)c5)nc(-n5c6ccccc6c6ccccc65)n4)c3)c3ccccc3-n3c4ccccc4c4cccc2c43)cc1 ; c1ccc(-c2nc(-c3cccc([Si]4(c5ccccc5)c5ccccc5-n5c6ccccc6c6cccc4c65)c3)cc(-c3cccc([Si]4(c5ccccc5)c5ccccc5-n5c6ccccc6c6cccc4c65)c3)n2)cc1] 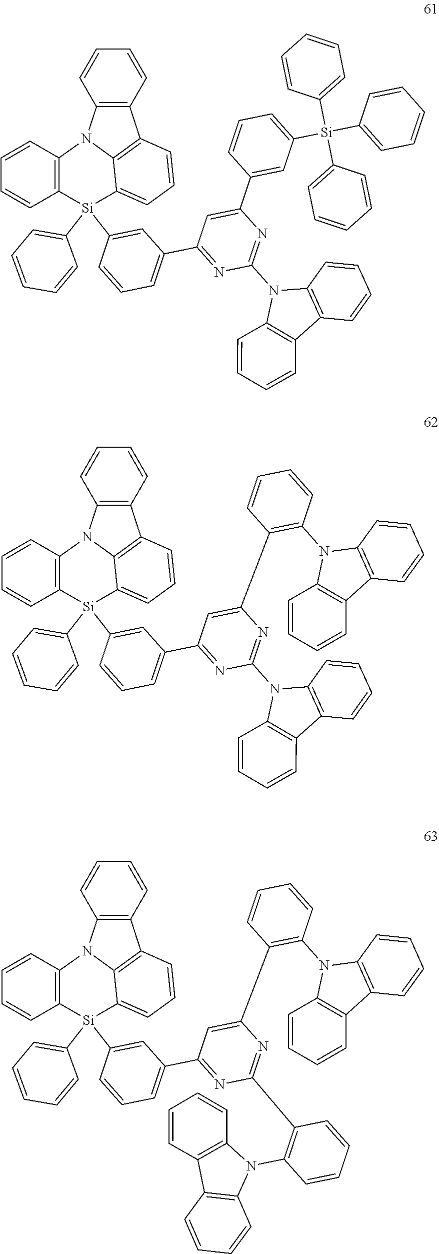 [SMILES: c1ccc([Si](c2ccccc2)(c2ccccc2)c2cccc(-c3cc(-c4cccc([Si]5(c6ccccc6)c6ccccc6-n6c7ccccc7c7cccc5c76)c4)nc(-n4c5ccccc5c5ccccc54)n3)c2)cc1 ; c1ccc([Si]2(c3cccc(-c4cc(-c5ccccc5-n5c6ccccc6c6ccccc65)nc(-n5c6ccccc6c6ccccc65)n4)c3)c3ccccc3-n3c4ccccc4c4cccc2c43)cc1 ; c1ccc([Si]2(c3cccc(-c4cc(-c5ccccc5-n5c6ccccc6c6ccccc65)nc(-c5ccccc5-n5c6ccccc6c6ccccc65)n4)c3)c3ccccc3-n3c4ccccc4c4cccc2c43)cc1] 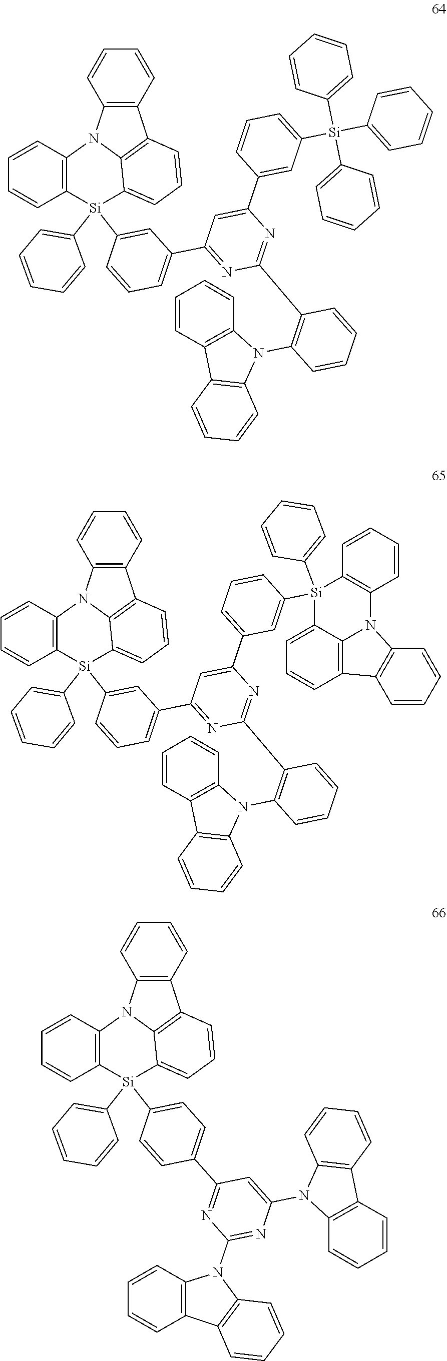 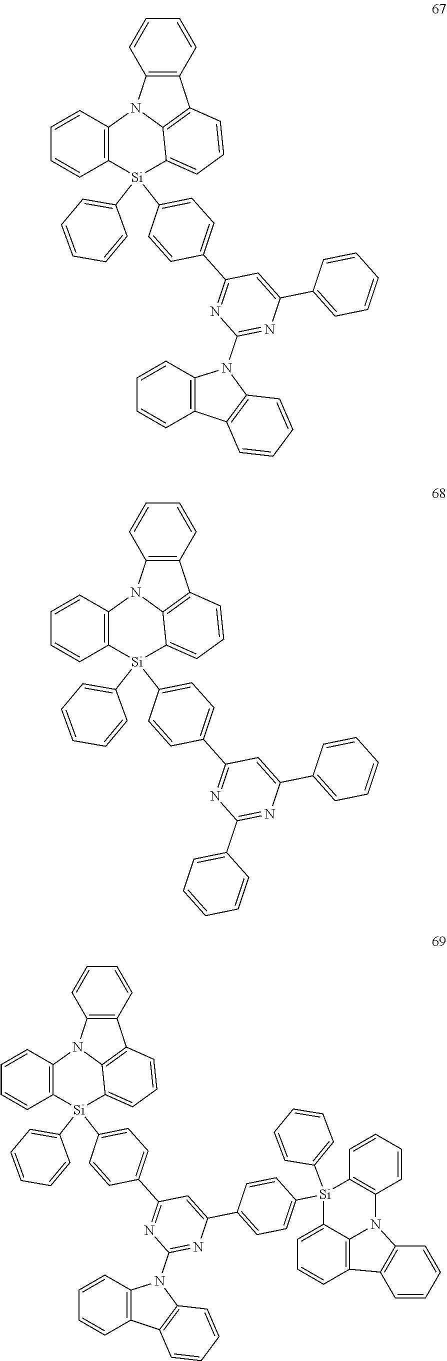 [SMILES: c1ccc(-c2cc(-c3ccc([Si]4(c5ccccc5)c5ccccc5-n5c6ccccc6c6cccc4c65)cc3)nc(-n3c4ccccc4c4ccccc43)n2)cc1 ; c1ccc(-c2cc(-c3ccc([Si]4(c5ccccc5)c5ccccc5-n5c6ccccc6c6cccc4c65)cc3)nc(-c3ccccc3)n2)cc1 ; c1ccc([Si]2(c3ccc(-c4cc(-c5ccc([Si]6(c7ccccc7)c7ccccc7-n7c8ccccc8c8cccc6c87)cc5)nc(-n5c6ccccc6c6ccccc65)n4)cc3)c3ccccc3-n3c4ccccc4c4cccc2c43)cc1] 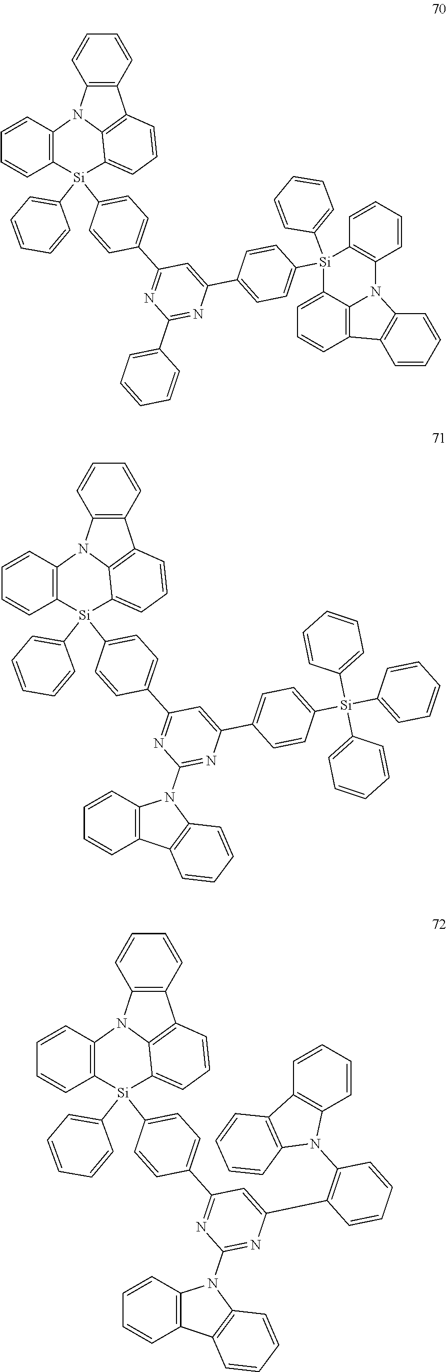 [SMILES: c1ccc(-c2nc(-c3ccc([Si]4(c5ccccc5)c5ccccc5-n5c6ccccc6c6cccc4c65)cc3)cc(-c3ccc([Si]4(c5ccccc5)c5ccccc5-n5c6ccccc6c6cccc4c65)cc3)n2)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-n4c5ccccc5c5ccccc54)n3)cc2)cc1 ; c1ccc([Si]2(c3ccc(-c4cc(-c5ccccc5-n5c6ccccc6c6ccccc65)nc(-n5c6ccccc6c6ccccc65)n4)cc3)c3ccccc3-n3c4ccccc4c4cccc2c43)cc1] 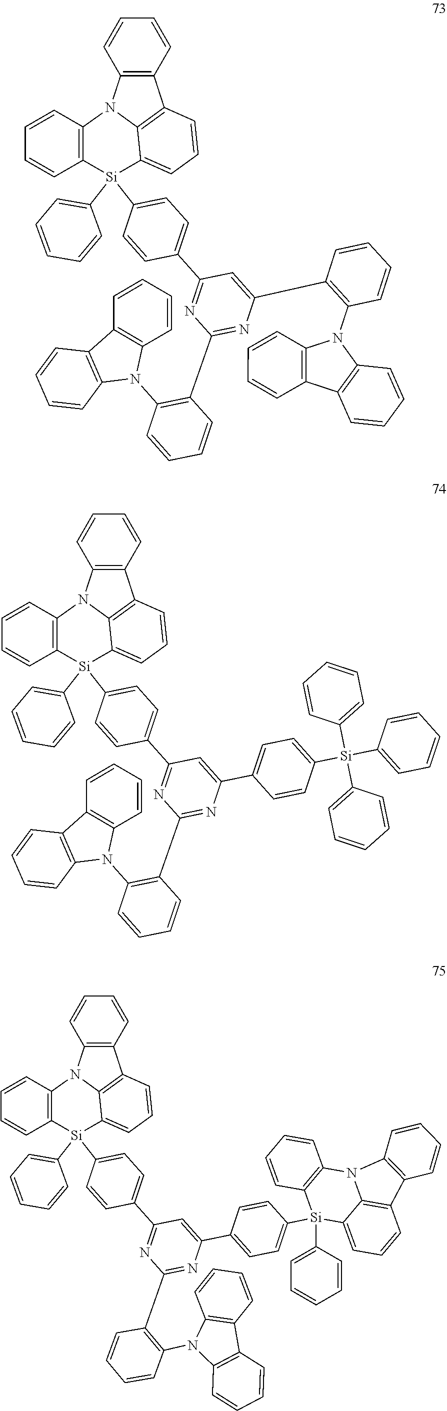 [SMILES: c1ccc([Si]2(c3ccc(-c4cc(-c5ccccc5-n5c6ccccc6c6ccccc65)nc(-c5ccccc5-n5c6ccccc6c6ccccc65)n4)cc3)c3ccccc3-n3c4ccccc4c4cccc2c43)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)cc2)cc1 ; c1ccc([Si]2(c3ccc(-c4cc(-c5ccc([Si]6(c7ccccc7)c7ccccc7-n7c8ccccc8c8cccc6c87)cc5)nc(-c5ccccc5-n5c6ccccc6c6ccccc65)n4)cc3)c3ccccc3-n3c4ccccc4c4cccc2c43)cc1] 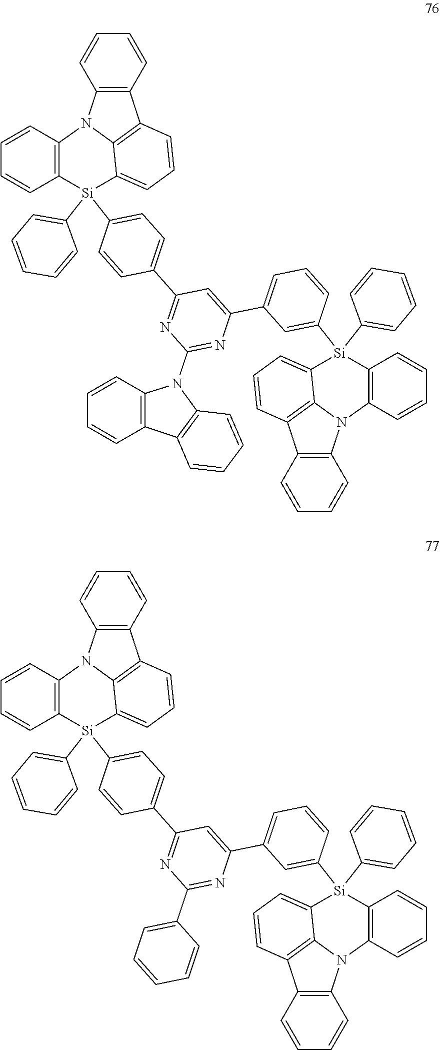 [SMILES: c1ccc([Si]2(c3ccc(-c4cc(-c5cccc([Si]6(c7ccccc7)c7ccccc7-n7c8ccccc8c8cccc6c87)c5)nc(-n5c6ccccc6c6ccccc65)n4)cc3)c3ccccc3-n3c4ccccc4c4cccc2c43)cc1 ; c1ccc(-c2nc(-c3ccc([Si]4(c5ccccc5)c5ccccc5-n5c6ccccc6c6cccc4c65)cc3)cc(-c3cccc([Si]4(c5ccccc5)c5ccccc5-n5c6ccccc6c6cccc4c65)c3)n2)cc1] 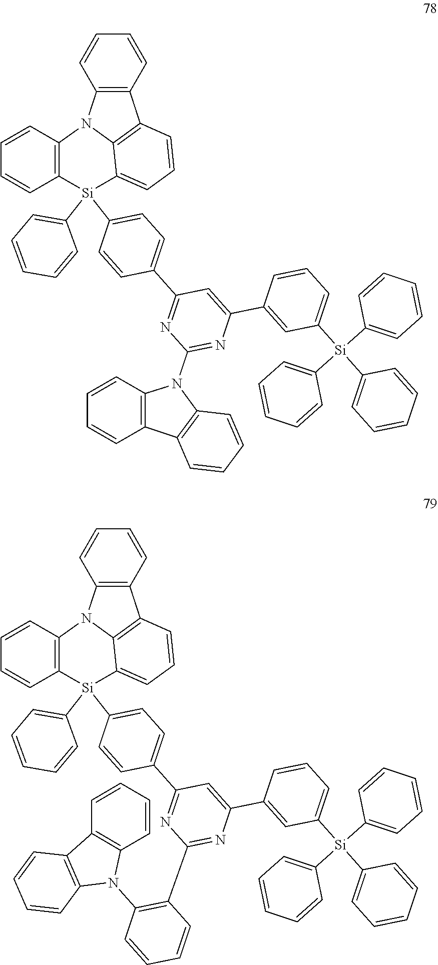 [SMILES: c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-n4c5ccccc5c5ccccc54)n3)c2)cc1 ; c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)c2)cc1] 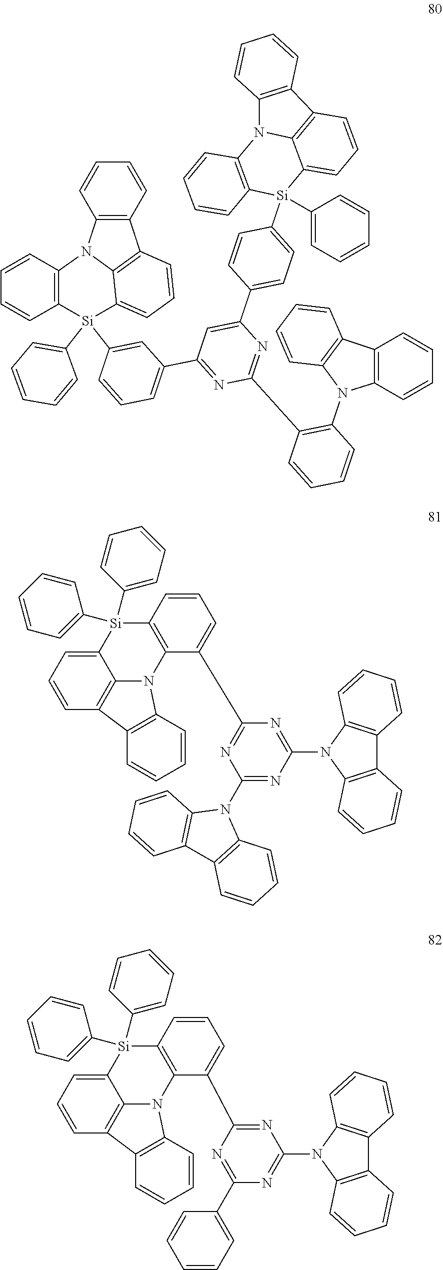 [SMILES: c1ccc([Si]2(c3ccc(-c4cc(-c5cccc([Si]6(c7ccccc7)c7ccccc7-n7c8ccccc8c8cccc6c87)c5)nc(-c5ccccc5-n5c6ccccc6c6ccccc65)n4)cc3)c3ccccc3-n3c4ccccc4c4cccc2c43)cc1 ; c1ccc([Si]2(c3ccccc3)c3cccc(-c4nc(-n5c6ccccc6c6ccccc65)nc(-n5c6ccccc6c6ccccc65)n4)c3-n3c4ccccc4c4cccc2c43)cc1 ; c1ccc(-c2nc(-c3cccc4c3-n3c5ccccc5c5cccc(c53)[Si]4(c3ccccc3)c3ccccc3)nc(-n3c4ccccc4c4ccccc43)n2)cc1] 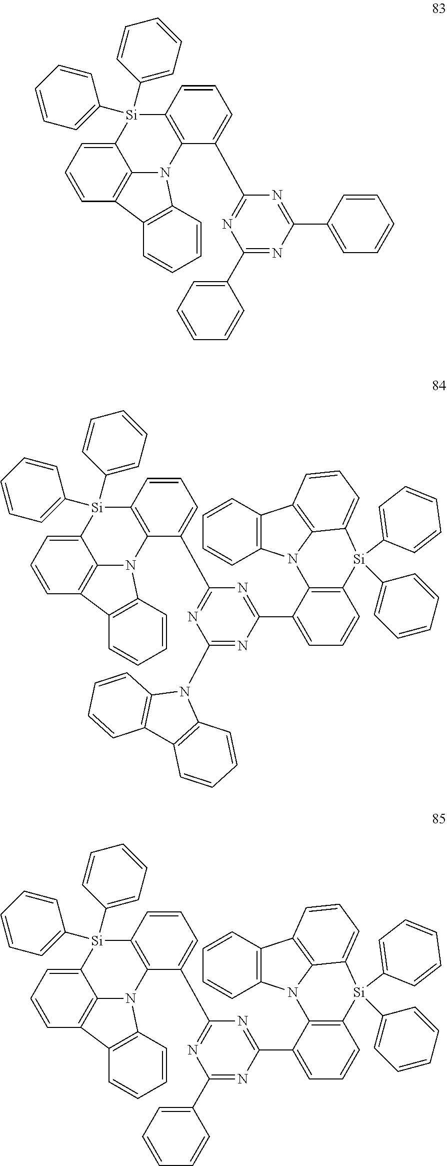 [SMILES: c1ccc(-c2nc(-c3ccccc3)nc(-c3cccc4c3-n3c5ccccc5c5cccc(c53)[Si]4(c3ccccc3)c3ccccc3)n2)cc1 ; c1ccc([Si]2(c3ccccc3)c3cccc(-c4nc(-c5cccc6c5-n5c7ccccc7c7cccc(c75)[Si]6(c5ccccc5)c5ccccc5)nc(-n5c6ccccc6c6ccccc65)n4)c3-n3c4ccccc4c4cccc2c43)cc1 ; c1ccc(-c2nc(-c3cccc4c3-n3c5ccccc5c5cccc(c53)[Si]4(c3ccccc3)c3ccccc3)nc(-c3cccc4c3-n3c5ccccc5c5cccc(c53)[Si]4(c3ccccc3)c3ccccc3)n2)cc1] 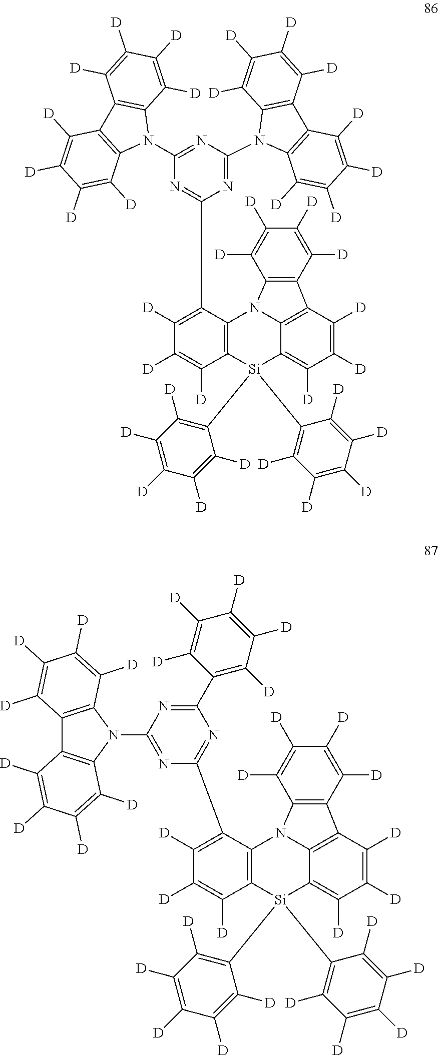 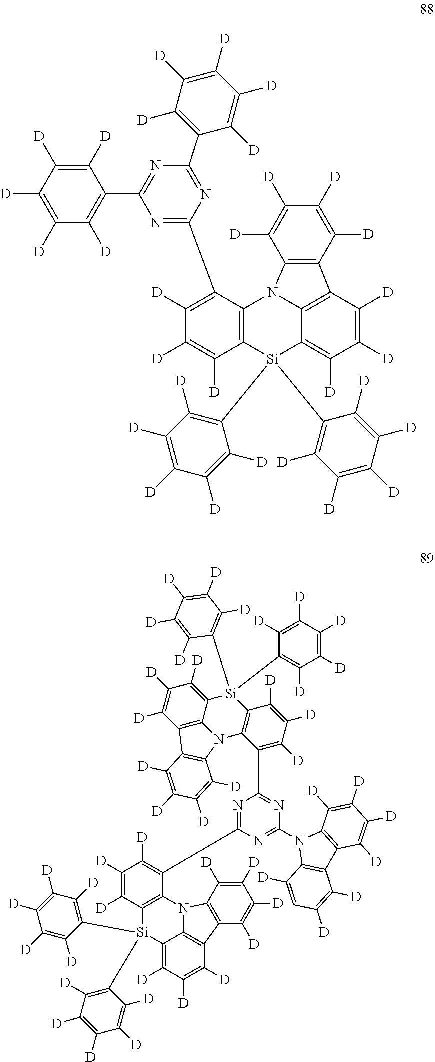 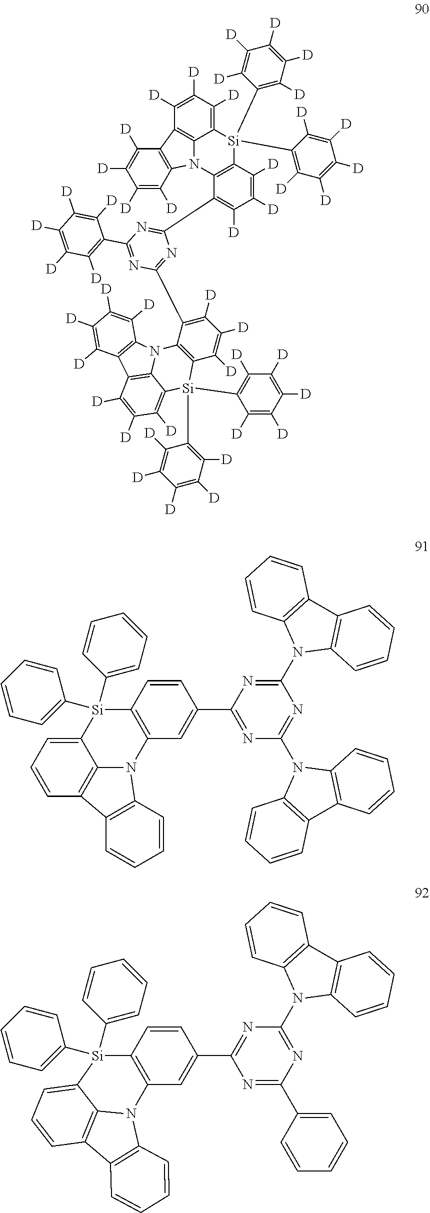 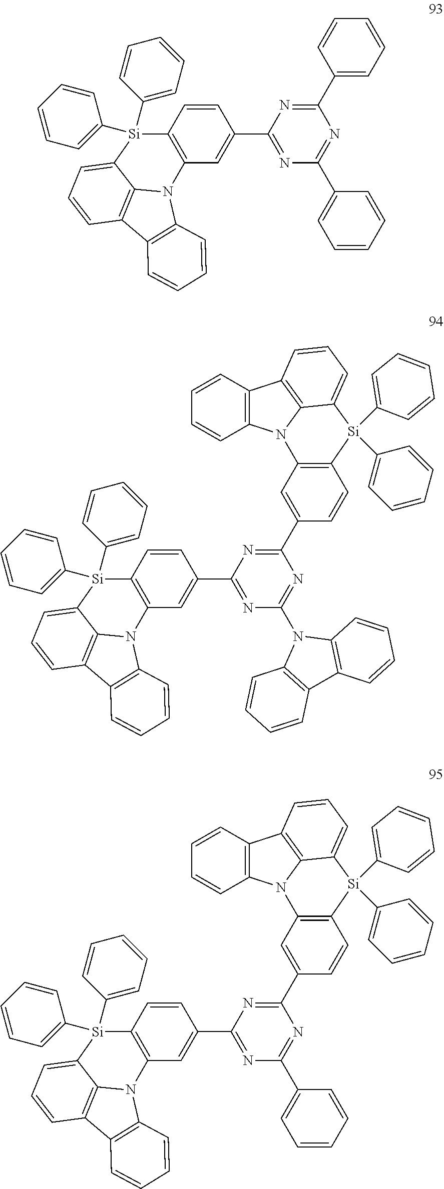 [SMILES: c1ccc(-c2nc(-c3ccccc3)nc(-c3ccc4c(c3)-n3c5ccccc5c5cccc(c53)[Si]4(c3ccccc3)c3ccccc3)n2)cc1 ; c1ccc([Si]2(c3ccccc3)c3ccc(-c4nc(-c5ccc6c(c5)-n5c7ccccc7c7cccc(c75)[Si]6(c5ccccc5)c5ccccc5)nc(-n5c6ccccc6c6ccccc65)n4)cc3-n3c4ccccc4c4cccc2c43)cc1 ; c1ccc(-c2nc(-c3ccc4c(c3)-n3c5ccccc5c5cccc(c53)[Si]4(c3ccccc3)c3ccccc3)nc(-c3ccc4c(c3)-n3c5ccccc5c5cccc(c53)[Si]4(c3ccccc3)c3ccccc3)n2)cc1] 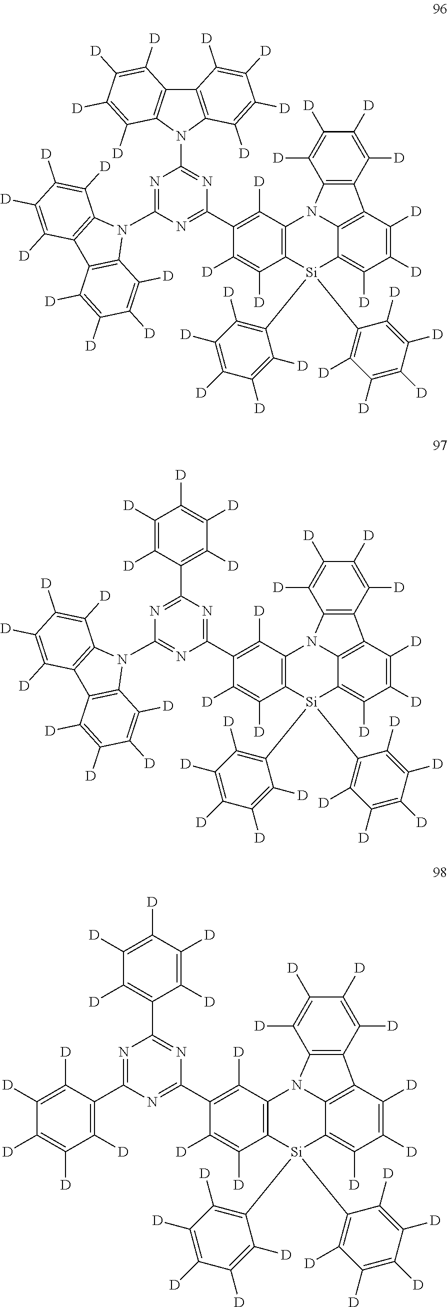 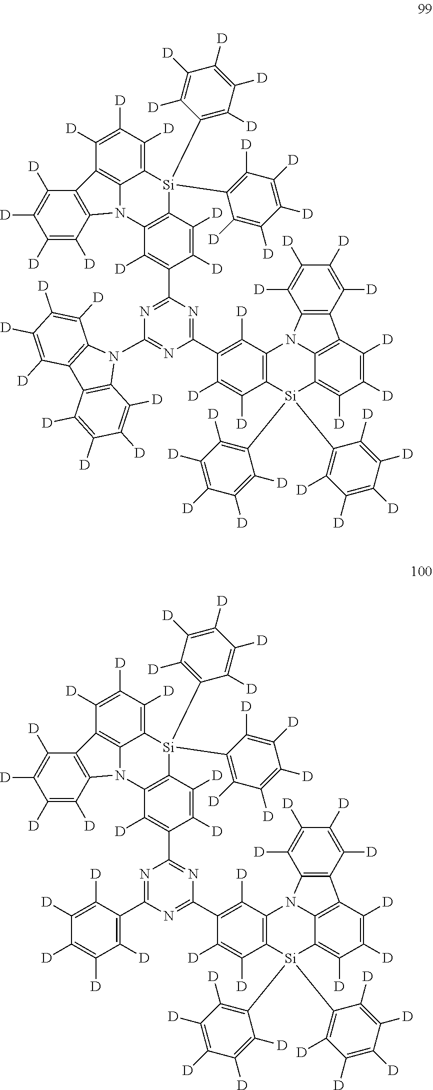 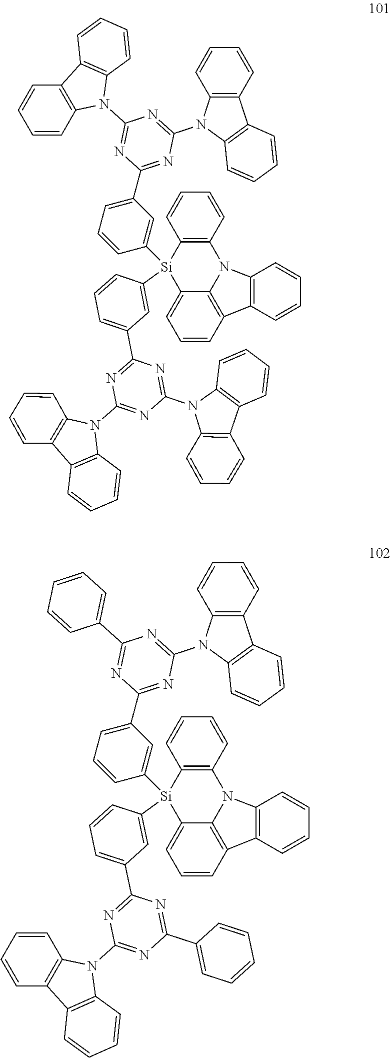 [SMILES: c1cc(-c2nc(-n3c4ccccc4c4ccccc43)nc(-n3c4ccccc4c4ccccc43)n2)cc([Si]2(c3cccc(-c4nc(-n5c6ccccc6c6ccccc65)nc(-n5c6ccccc6c6ccccc65)n4)c3)c3ccccc3-n3c4ccccc4c4cccc2c43)c1 ; c1ccc(-c2nc(-c3cccc([Si]4(c5cccc(-c6nc(-c7ccccc7)nc(-n7c8ccccc8c8ccccc87)n6)c5)c5ccccc5-n5c6ccccc6c6cccc4c65)c3)nc(-n3c4ccccc4c4ccccc43)n2)cc1] 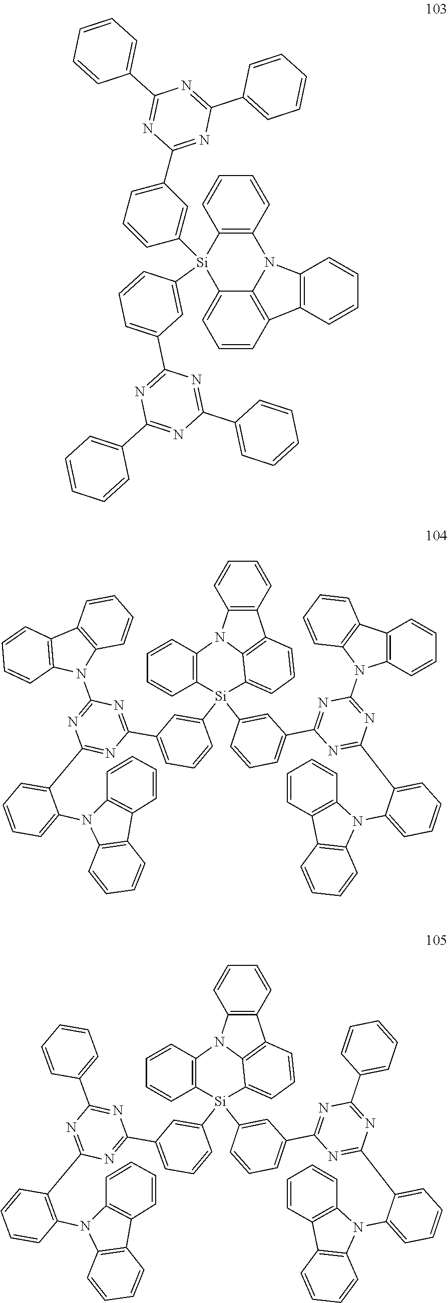 [SMILES: c1ccc(-c2nc(-c3ccccc3)nc(-c3cccc([Si]4(c5cccc(-c6nc(-c7ccccc7)nc(-c7ccccc7)n6)c5)c5ccccc5-n5c6ccccc6c6cccc4c65)c3)n2)cc1 ; c1cc(-c2nc(-c3ccccc3-n3c4ccccc4c4ccccc43)nc(-n3c4ccccc4c4ccccc43)n2)cc([Si]2(c3cccc(-c4nc(-c5ccccc5-n5c6ccccc6c6ccccc65)nc(-n5c6ccccc6c6ccccc65)n4)c3)c3ccccc3-n3c4ccccc4c4cccc2c43)c1 ; c1ccc(-c2nc(-c3cccc([Si]4(c5cccc(-c6nc(-c7ccccc7)nc(-c7ccccc7-n7c8ccccc8c8ccccc87)n6)c5)c5ccccc5-n5c6ccccc6c6cccc4c65)c3)nc(-c3ccccc3-n3c4ccccc4c4ccccc43)n2)cc1] 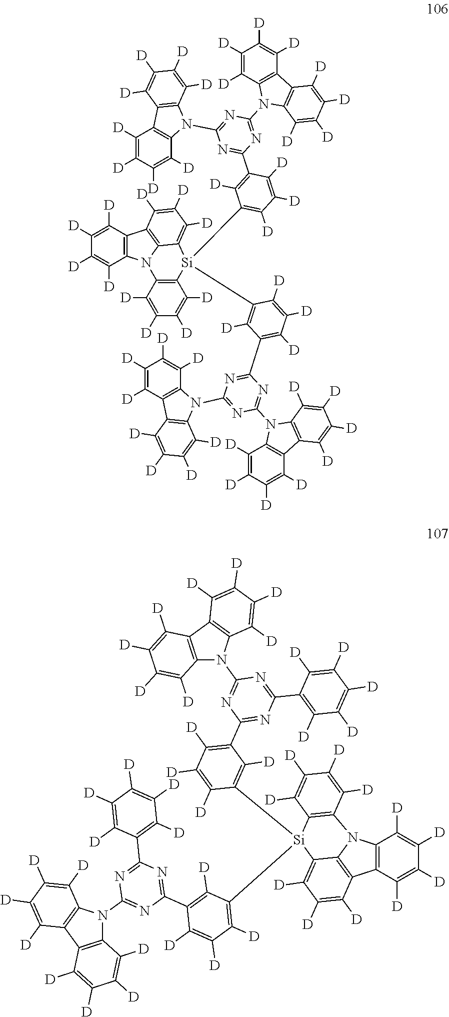 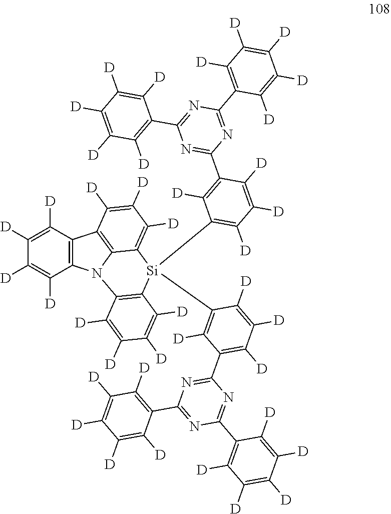 [SMILES: [2H]c1c([2H])c([2H])c(-c2nc(-c3c([2H])c([2H])c([2H])c([2H])c3[2H])nc(-c3c([2H])c([2H])c([2H])c([Si]4(c5c([2H])c([2H])c([2H])c(-c6nc(-c7c([2H])c([2H])c([2H])c([2H])c7[2H])nc(-c7c([2H])c([2H])c([2H])c([2H])c7[2H])n6)c5[2H])c5c([2H])c([2H])c([2H])c([2H])c5-n5c6c([2H])c([2H])c([2H])c([2H])c6c6c([2H])c([2H])c([2H])c4c65)c3[2H])n2)c([2H])c1[2H]] 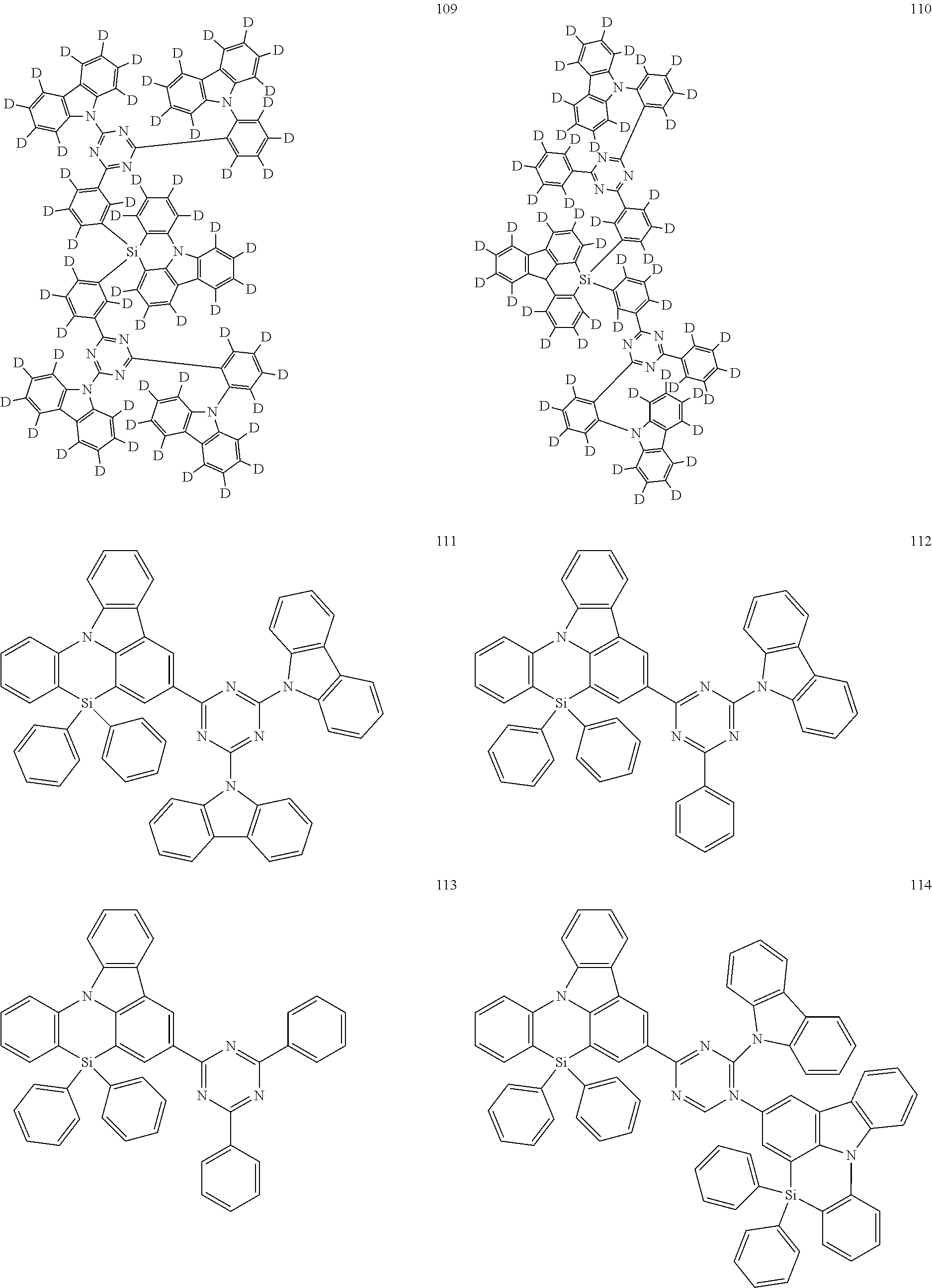 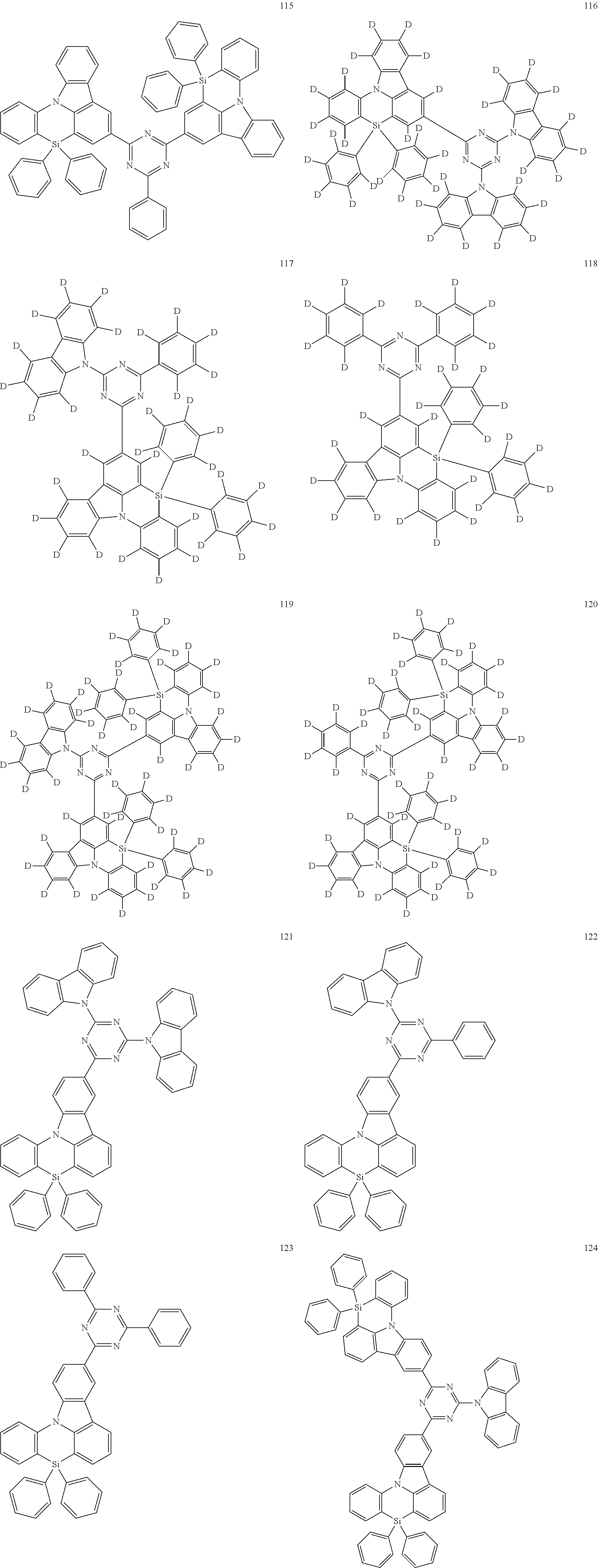 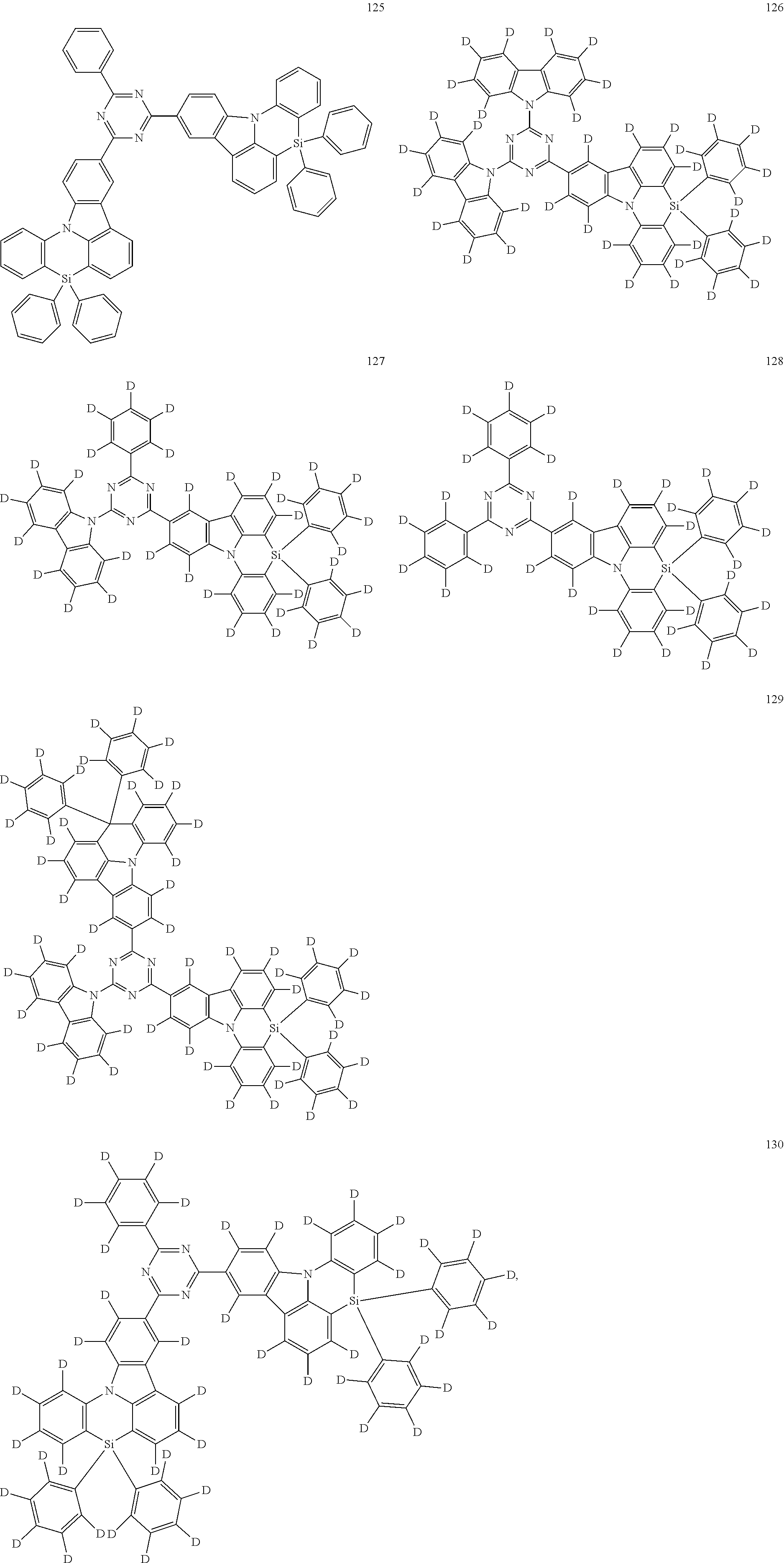
in compound Group 1, D is a deuterium atom.

11. A polycyclic compound represented by Formula 1: 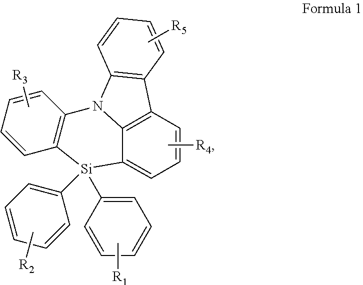
in Formula 1,
at least one selected from among R₁ to R₅ is represented by Formula 2, and any remaining selected from among R₁ to R₅ are each a hydrogen atom or a deuterium atom: 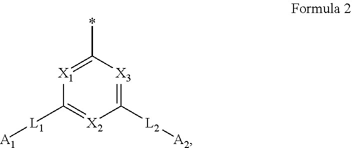
in Formula 2,
X₁ to X₃ are each independently N, CH, or CD,
at least two selected from among X₁ to X₃ are each N,
L₁ and L₂ are each independently a direct linkage, a substituted or unsubstituted arylene group having 6 to 30 ring-forming carbon atoms, or a substituted or unsubstituted heteroarylene group having 3 to 30 ring-forming carbon atoms,
A₁ and A₂ are each independently a substituted or unsubstituted aryl group having 6 to 30 ring-forming carbon atoms, a substituted or unsubstituted heterocyclic group having 3 to 30 ring-forming carbon atoms, or a substituted or unsubstituted silyl group, and 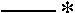 [SMILES: *C]
is a portion connected to Formula 1.

12. The polycyclic compound of claim 11, wherein Formula 2 is represented by Formula 2-1 or Formula 2-2: 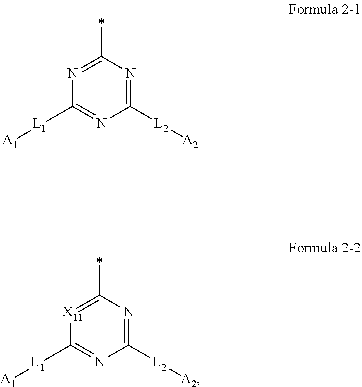
in Formula 2-2, X₁₁ is CH, or CD, and
in Formula 2-1 and Formula 2-2, Li, L₂, A₁, and A₂ are as defined in Formula 2.

13. The polycyclic compound of claim 11, wherein in Formula 2:
A₁ and A₂ are each independently
a substituted or unsubstituted phenyl group,
a substituted or unsubstituted carbazole group,
a substituted or unsubstituted triphenyl silyl group; or
A₁ and A₂ are represented by Formula SG and
any one ring selected from among C₁ to C₅ is connected to L₁ or L₂:

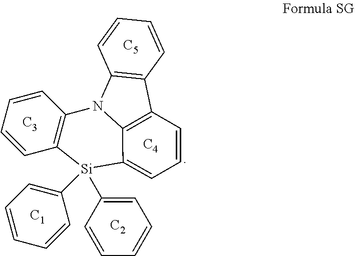

14. The polycyclic compound of claim 13, wherein any one selected from among A₁ and A₂ is represented by Formula SG, and any remaining selected from among A₁ and A₂ is a substituted or unsubstituted phenyl group, a substituted or unsubstituted carbazole group, or a substituted or unsubstituted triphenyl silyl group.

15. The polycyclic compound of claim 11, wherein L₁ and L₂ in Formula 2 are each independently a direct linkage, or a substituted or unsubstituted phenylene group.

16. The polycyclic compound of claim 11, wherein at least one selected from among hydrogen atoms of the compound represented by Formula 1 is substituted with a deuterium atom.

17. The polycyclic compound of claim 11, wherein the compound represented by Formula 1 is a phosphorescent host.

18. The polycyclic compound of claim 11, wherein the polycyclic compound is represented by any one selected from among compounds in Compound Group 1: 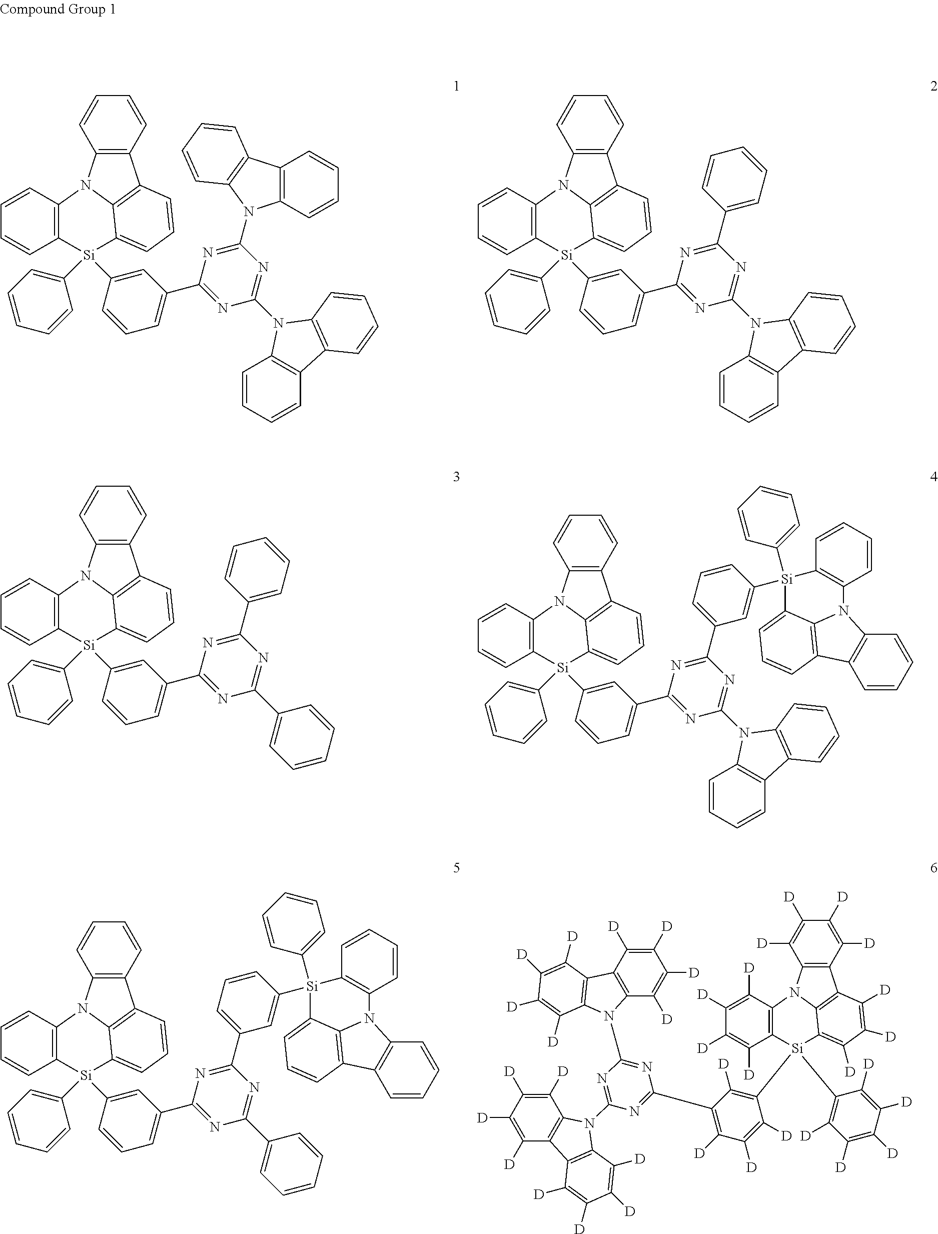 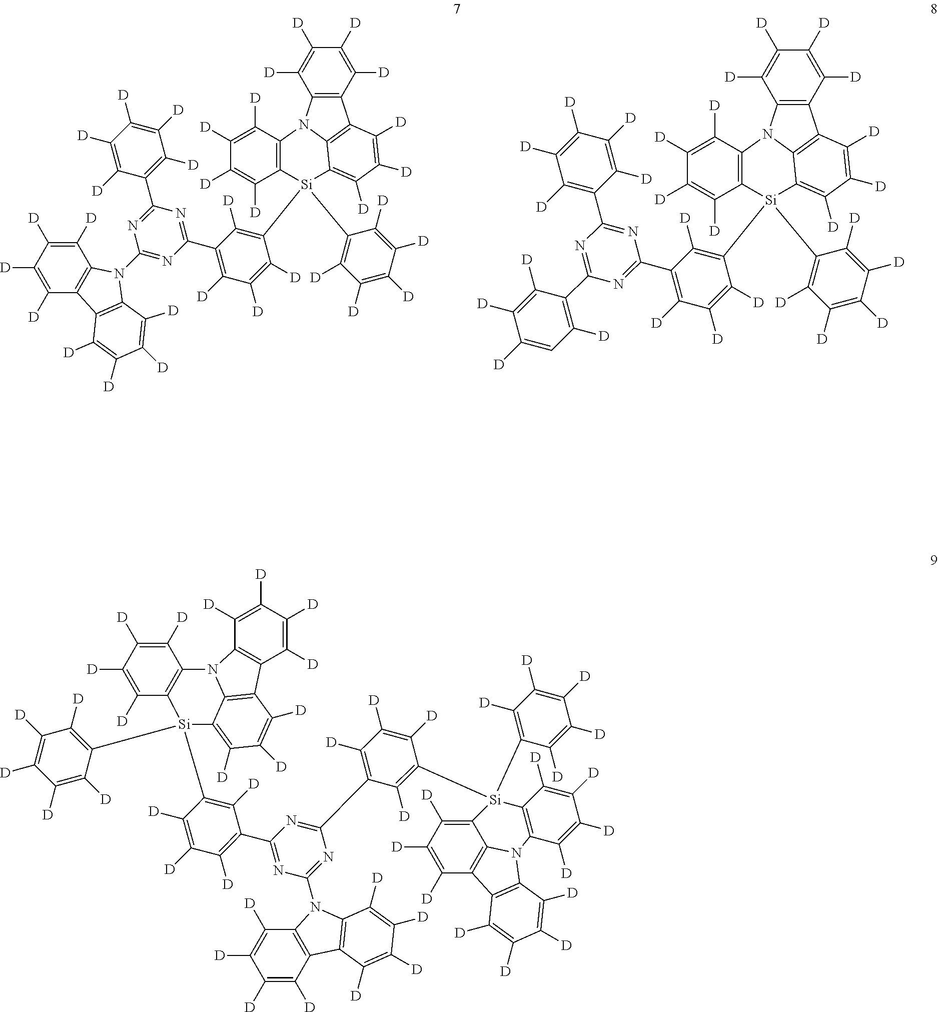 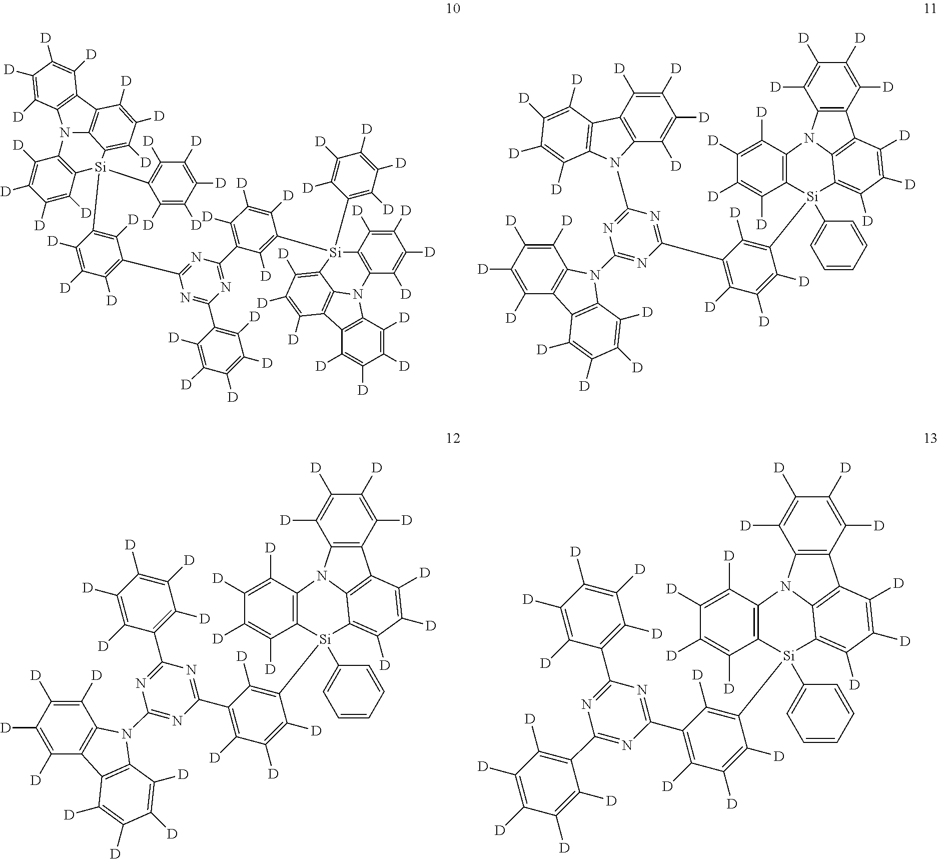 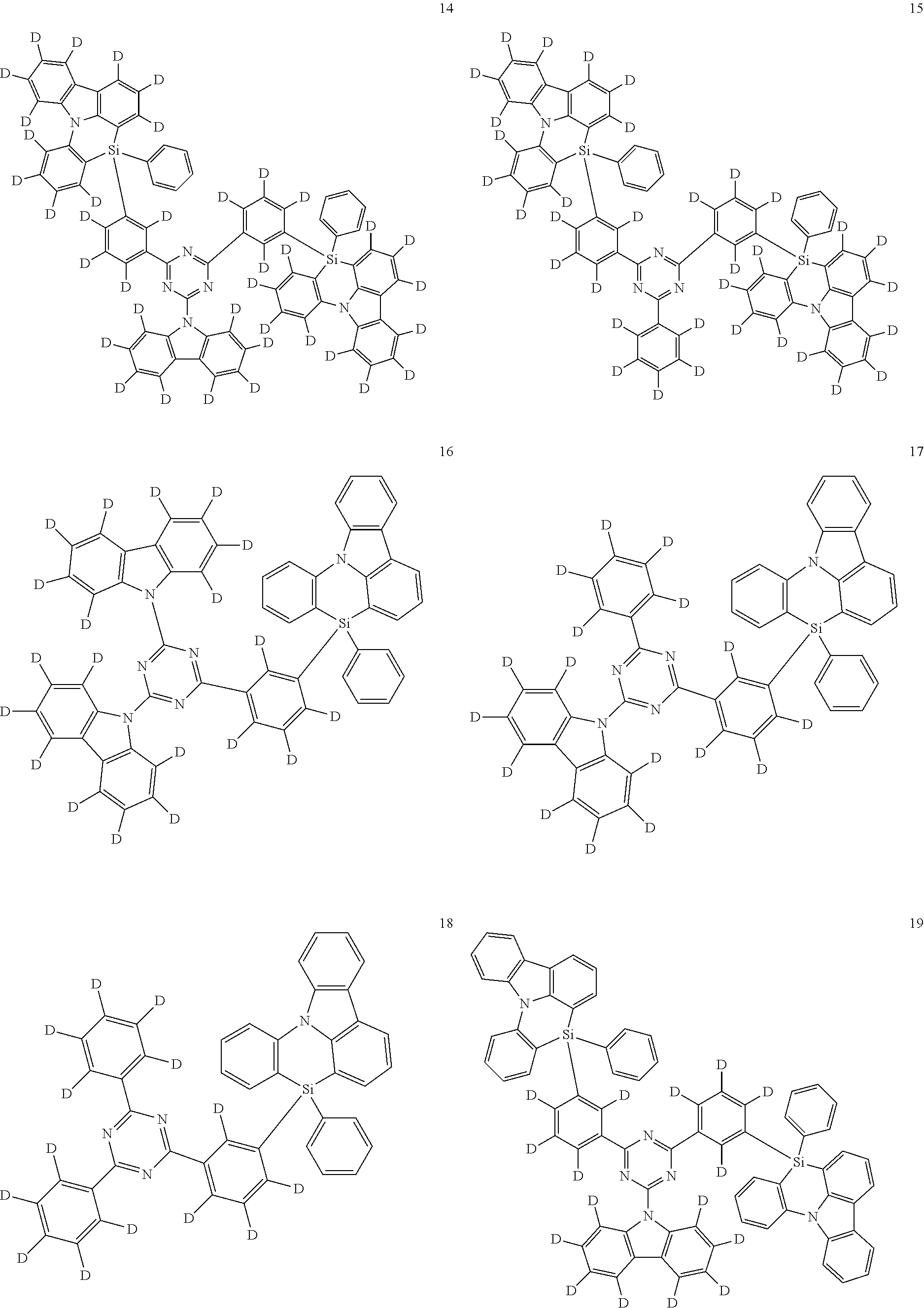 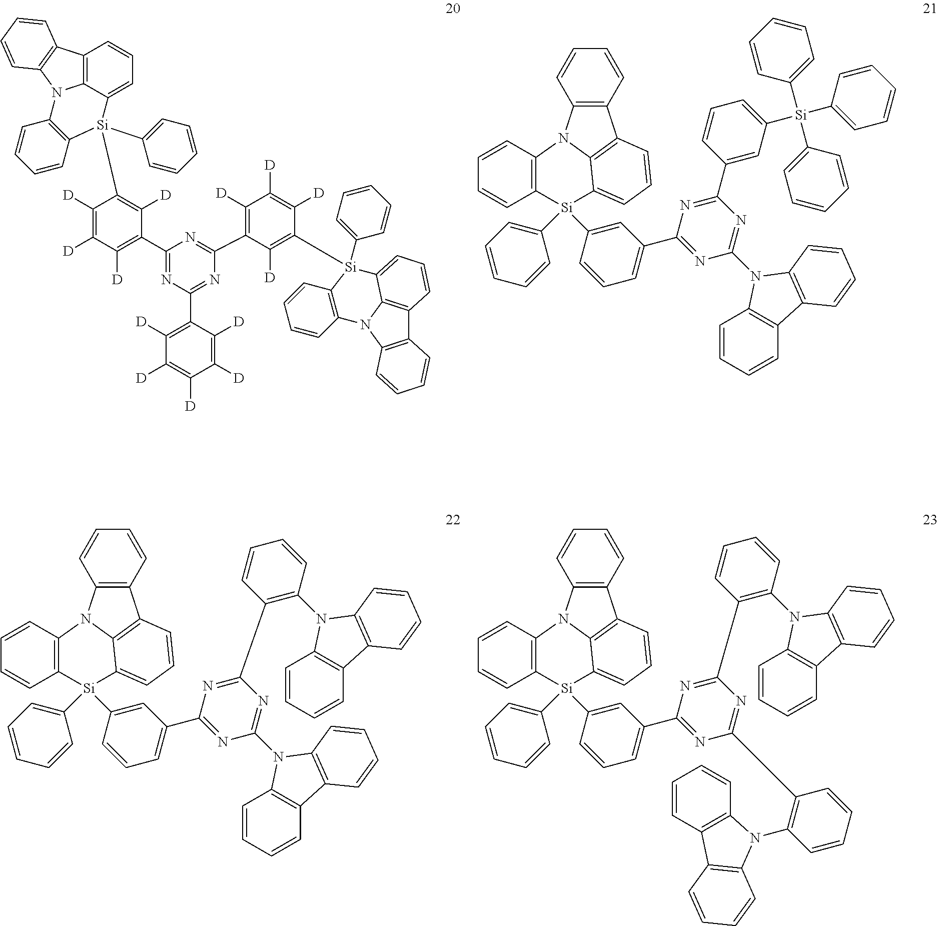 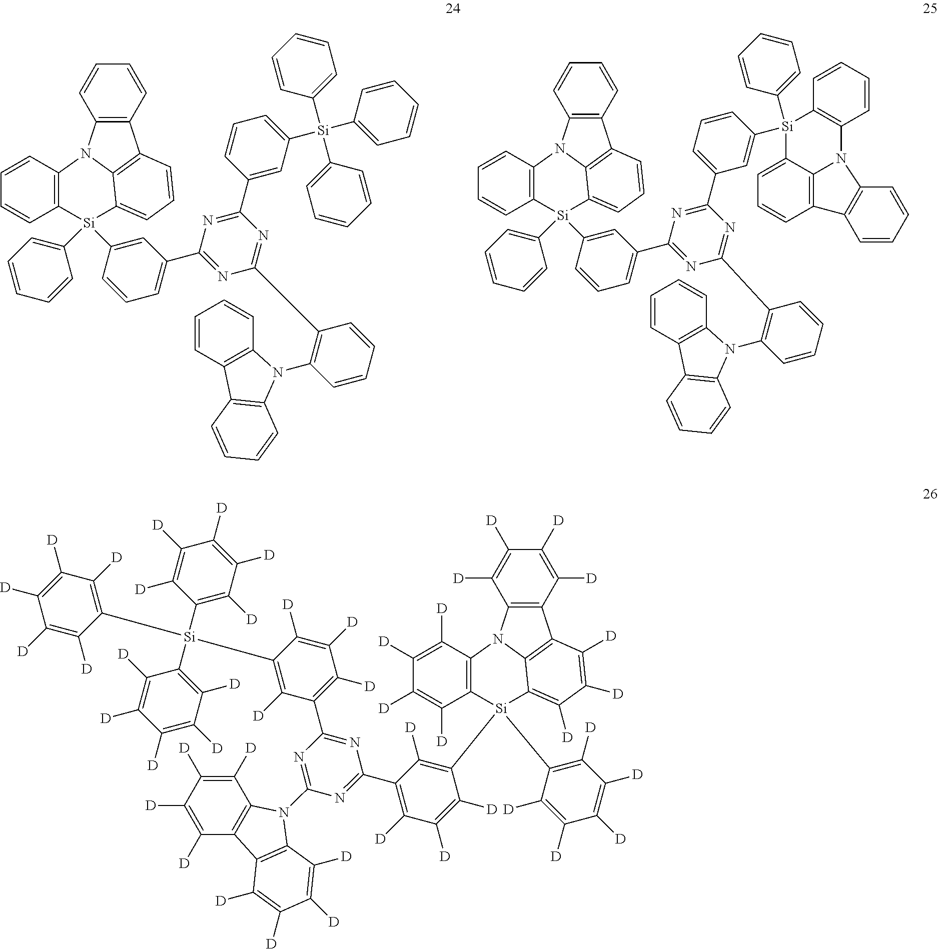 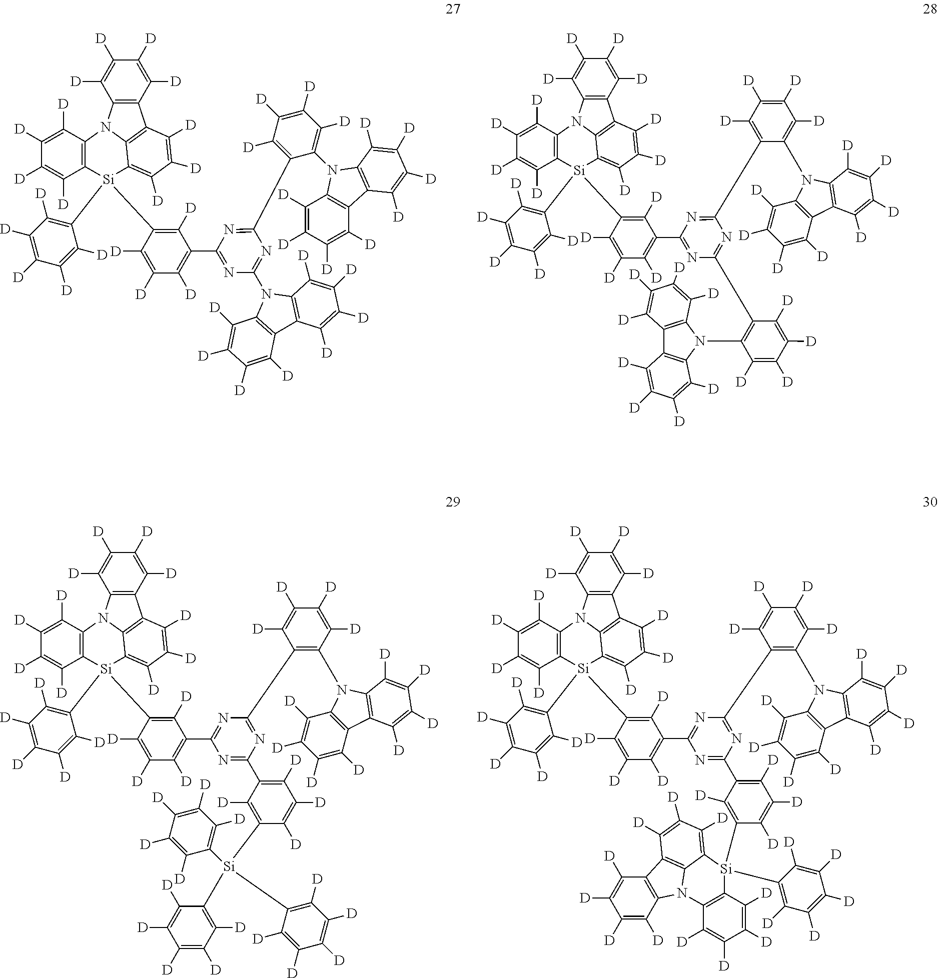 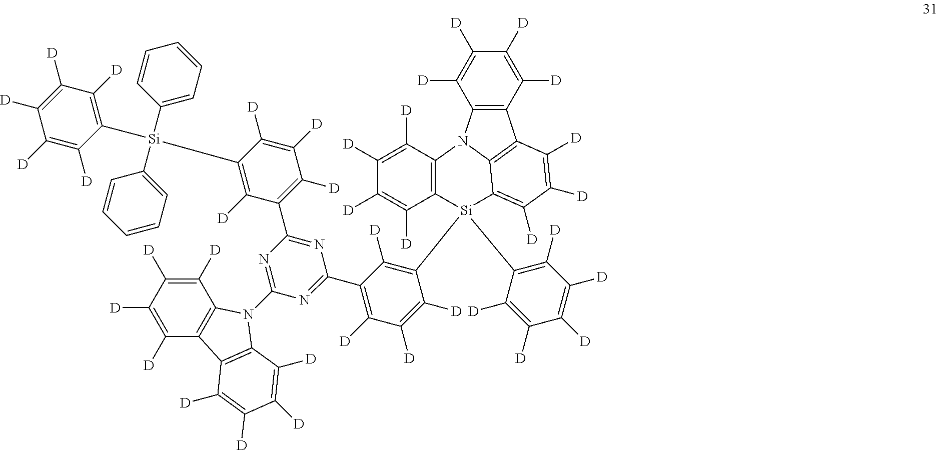 [SMILES: [2H]c1c([2H])c([2H])c([Si](c2ccccc2)(c2ccccc2)c2c([2H])c([2H])c([2H])c(-c3nc(-c4c([2H])c([2H])c([2H])c([Si]5(c6c([2H])c([2H])c([2H])c([2H])c6[2H])c6c([2H])c([2H])c([2H])c([2H])c6-n6c7c([2H])c([2H])c([2H])c([2H])c7c7c([2H])c([2H])c([2H])c5c76)c4[2H])nc(-n4c5c([2H])c([2H])c([2H])c([2H])c5c5c([2H])c([2H])c([2H])c([2H])c54)n3)c2[2H])c([2H])c1[2H]] 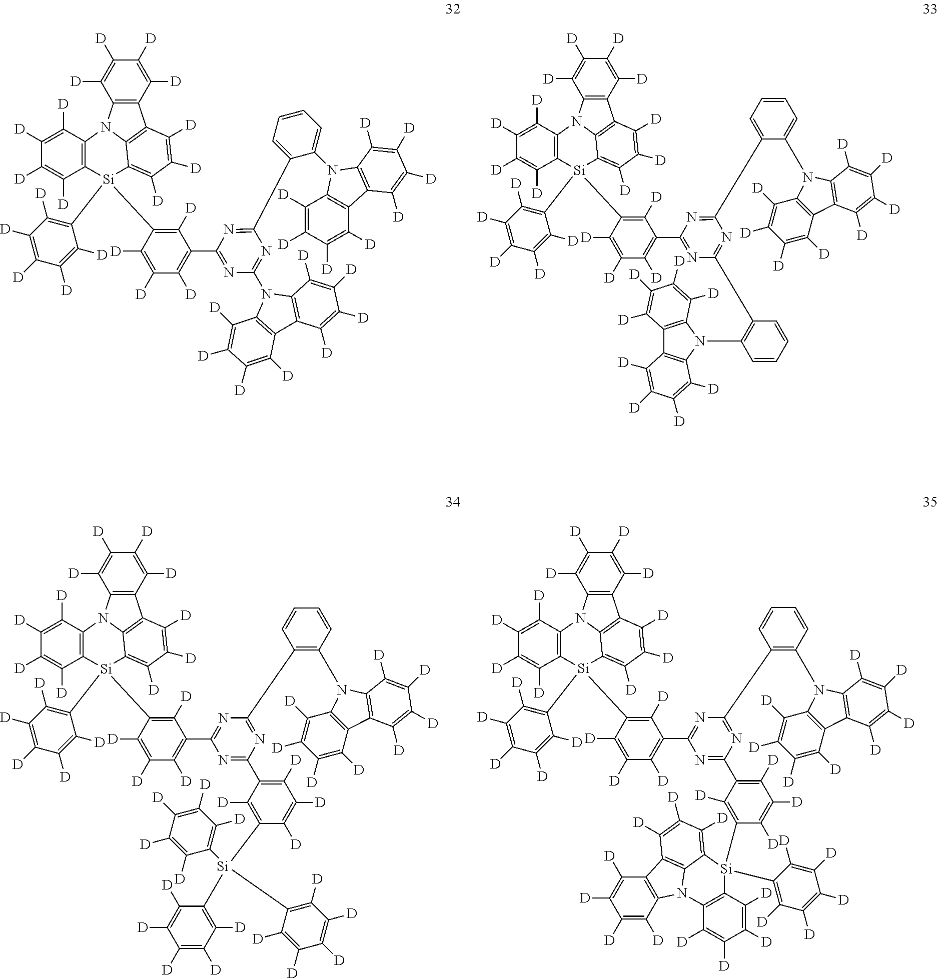 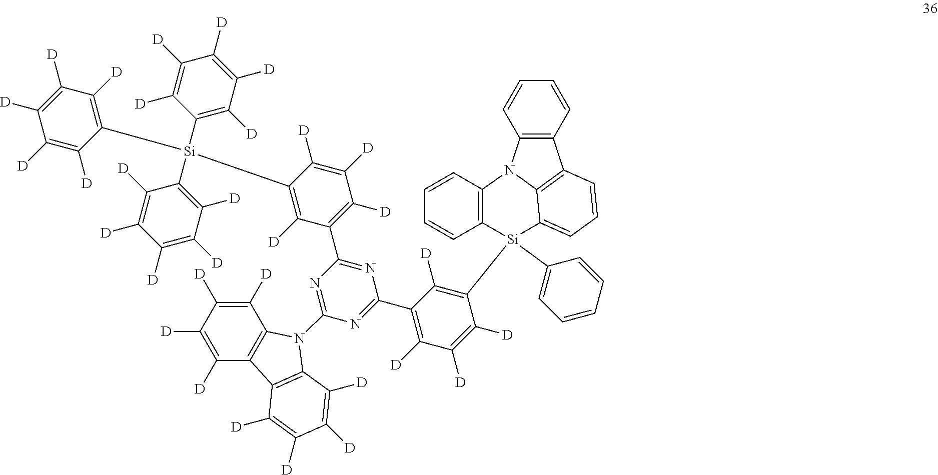 [SMILES: [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(-c3nc(-c4c([2H])c([2H])c([2H])c([Si]5(c6ccccc6)c6ccccc6-n6c7ccccc7c7cccc5c76)c4[2H])nc(-n4c5c([2H])c([2H])c([2H])c([2H])c5c5c([2H])c([2H])c([2H])c([2H])c54)n3)c2[2H])c([2H])c1[2H]] 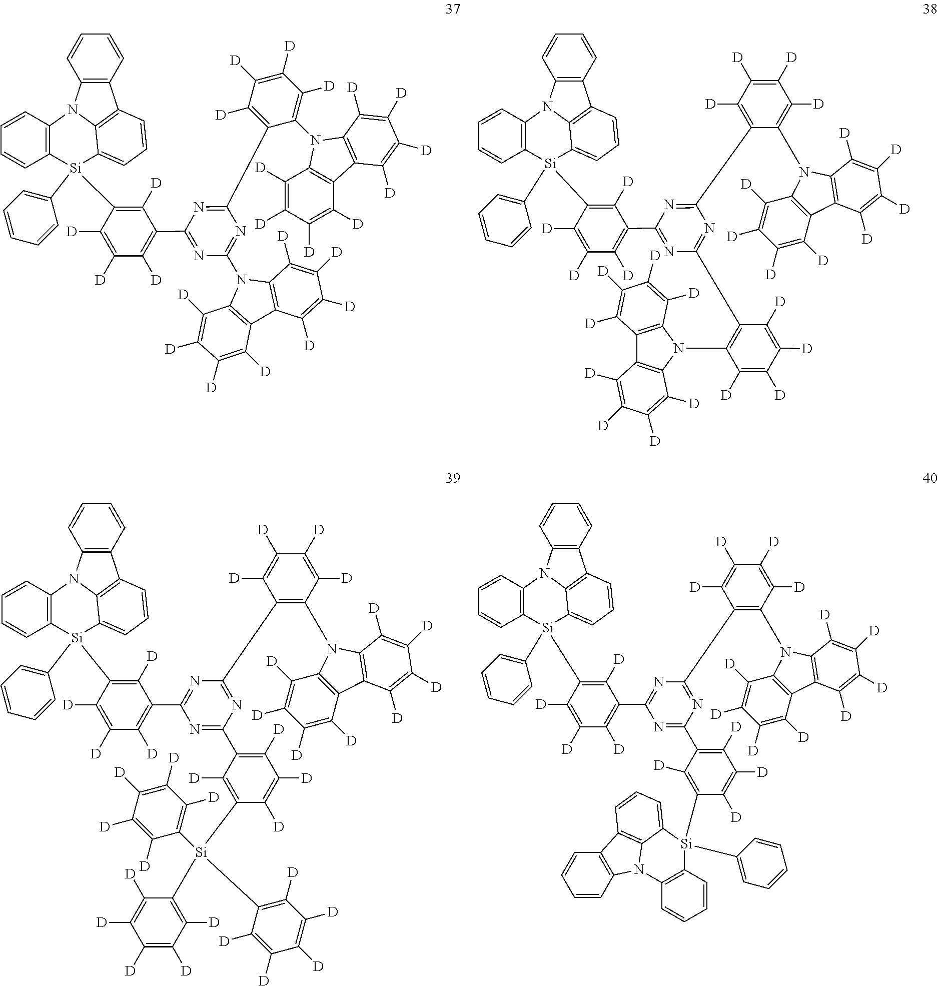 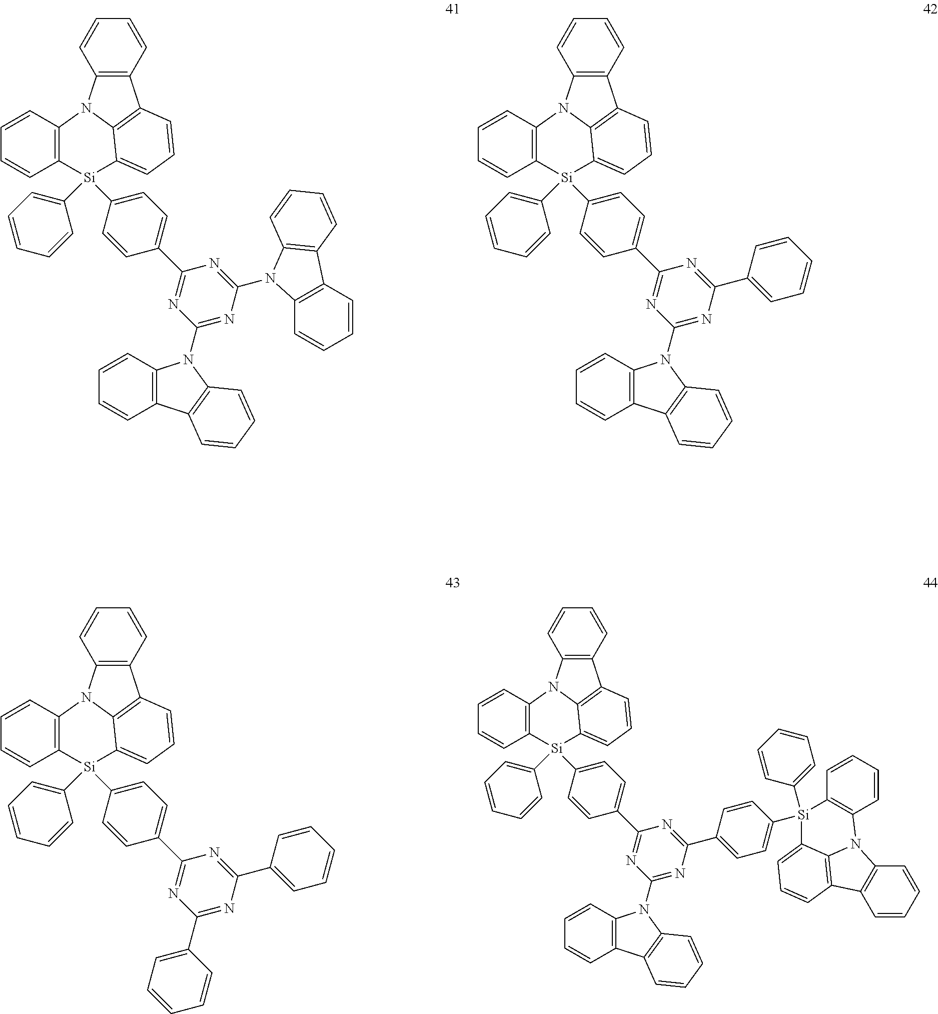 [SMILES: c1ccc([Si]2(c3ccc(-c4nc(-n5c6ccccc6c6ccccc65)nc(-n5c6ccccc6c6ccccc65)n4)cc3)c3ccccc3-n3c4ccccc4c4cccc2c43)cc1 ; c1ccc(-c2nc(-c3ccc([Si]4(c5ccccc5)c5ccccc5-n5c6ccccc6c6cccc4c65)cc3)nc(-n3c4ccccc4c4ccccc43)n2)cc1 ; c1ccc(-c2nc(-c3ccccc3)nc(-c3ccc([Si]4(c5ccccc5)c5ccccc5-n5c6ccccc6c6cccc4c65)cc3)n2)cc1 ; c1ccc([Si]2(c3ccc(-c4nc(-c5ccc([Si]6(c7ccccc7)c7ccccc7-n7c8ccccc8c8cccc6c87)cc5)nc(-n5c6ccccc6c6ccccc65)n4)cc3)c3ccccc3-n3c4ccccc4c4cccc2c43)cc1] 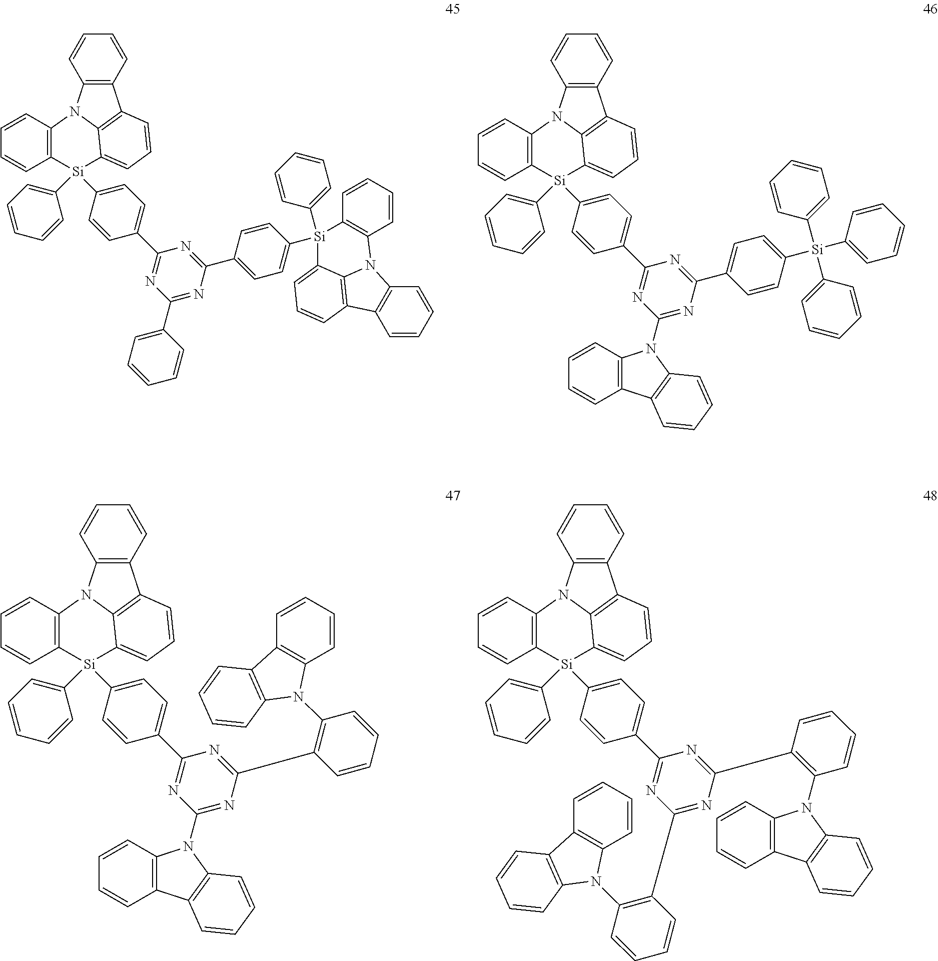 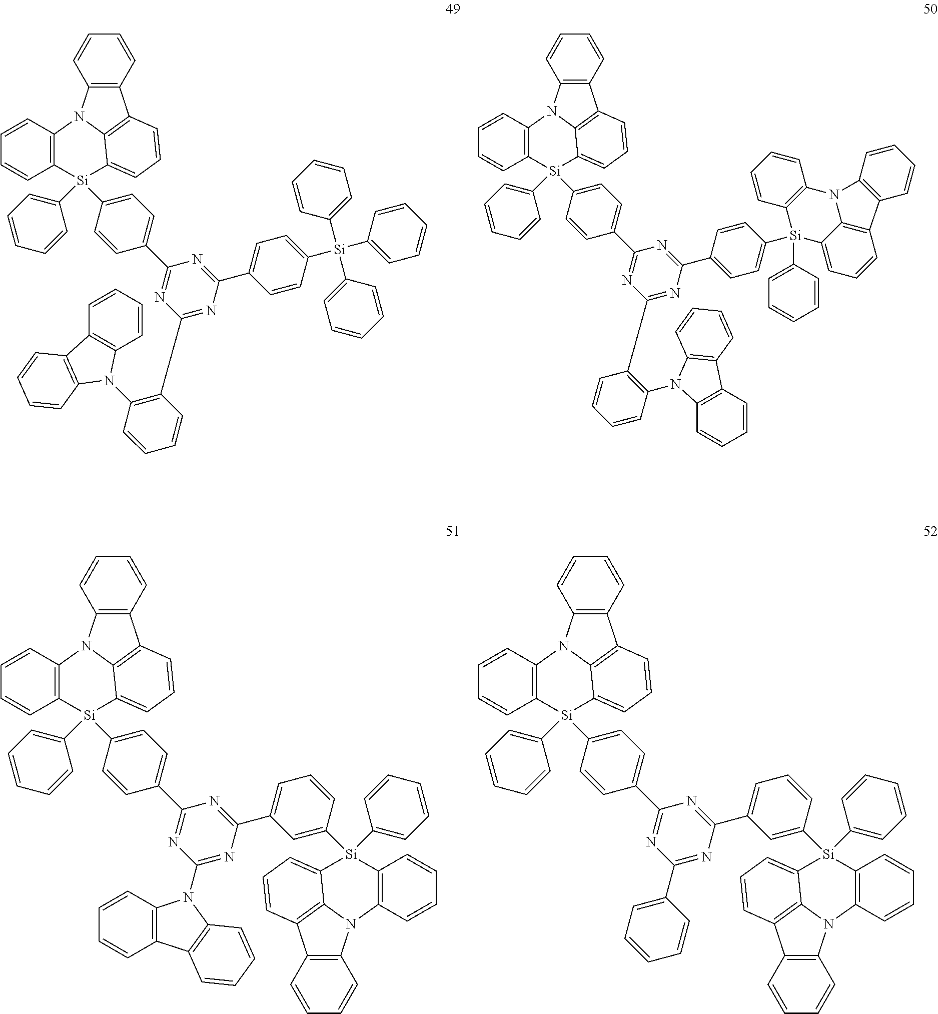 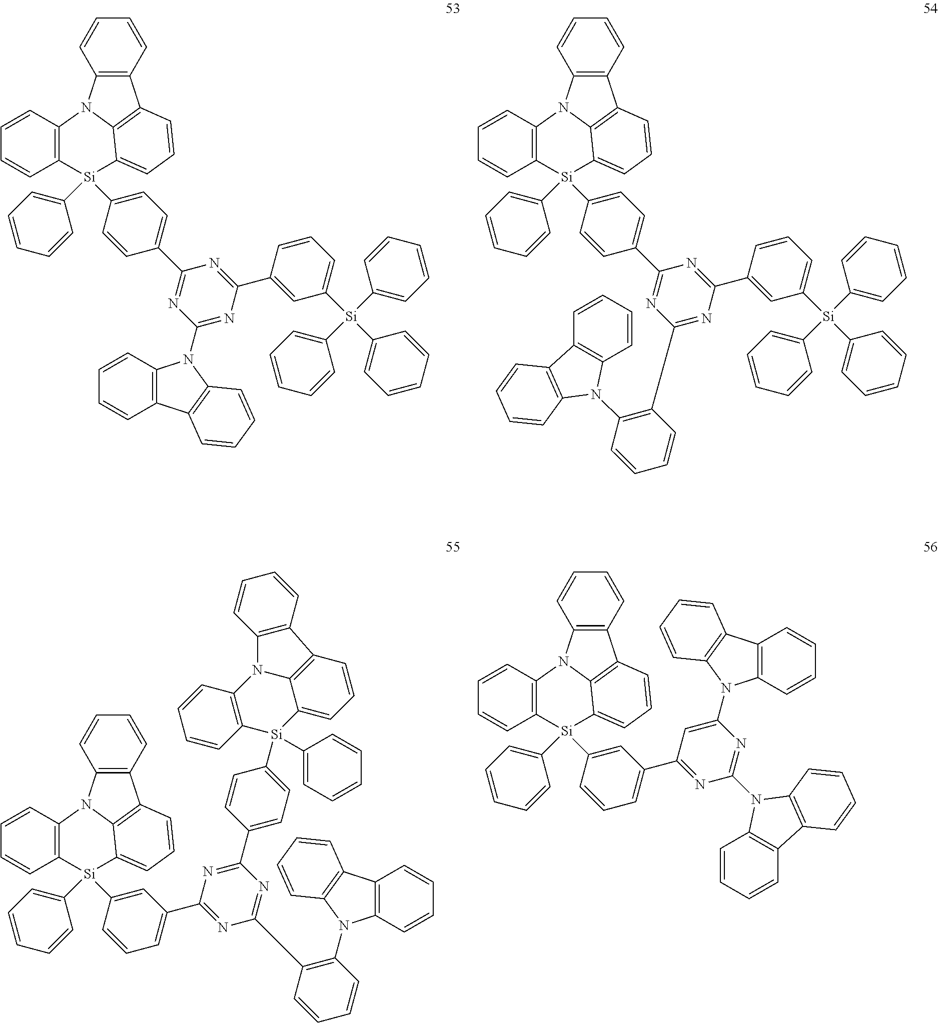 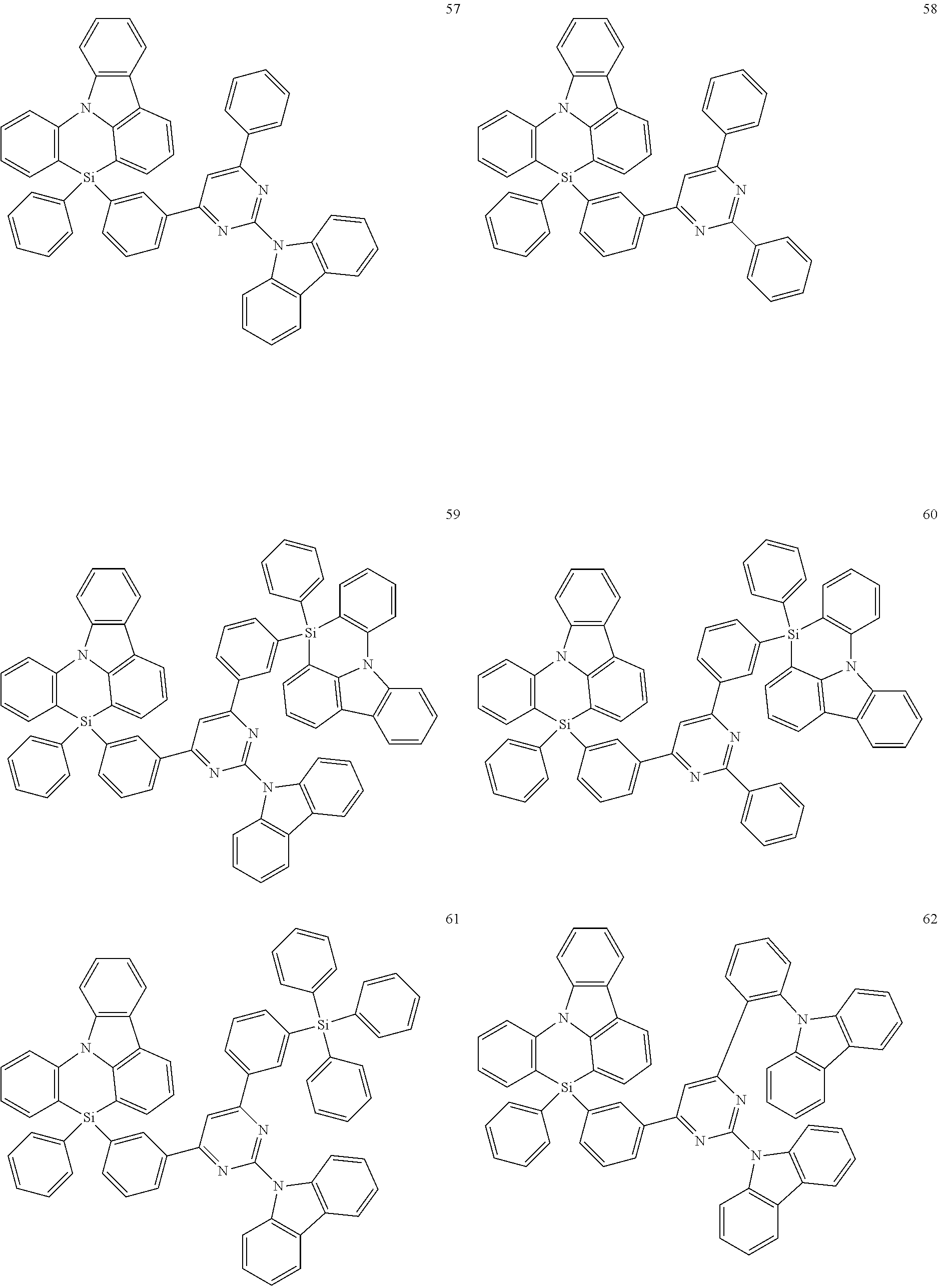 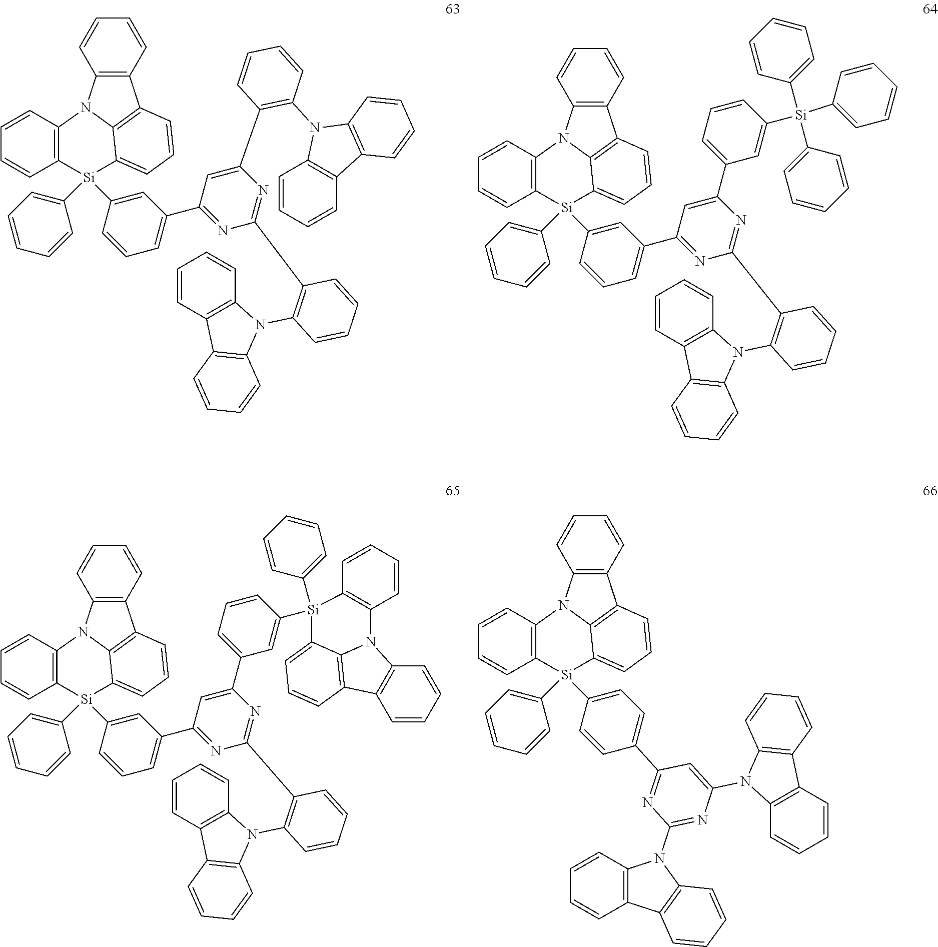 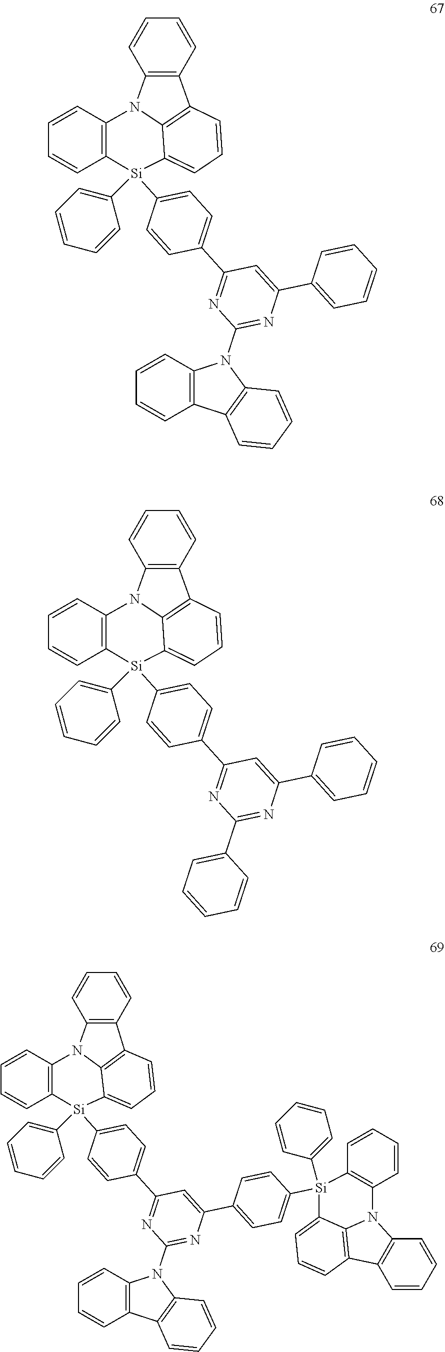 [SMILES: c1ccc(-c2cc(-c3ccc([Si]4(c5ccccc5)c5ccccc5-n5c6ccccc6c6cccc4c65)cc3)nc(-n3c4ccccc4c4ccccc43)n2)cc1 ; c1ccc(-c2cc(-c3ccc([Si]4(c5ccccc5)c5ccccc5-n5c6ccccc6c6cccc4c65)cc3)nc(-c3ccccc3)n2)cc1 ; c1ccc([Si]2(c3ccc(-c4cc(-c5ccc([Si]6(c7ccccc7)c7ccccc7-n7c8ccccc8c8cccc6c87)cc5)nc(-n5c6ccccc6c6ccccc65)n4)cc3)c3ccccc3-n3c4ccccc4c4cccc2c43)cc1] 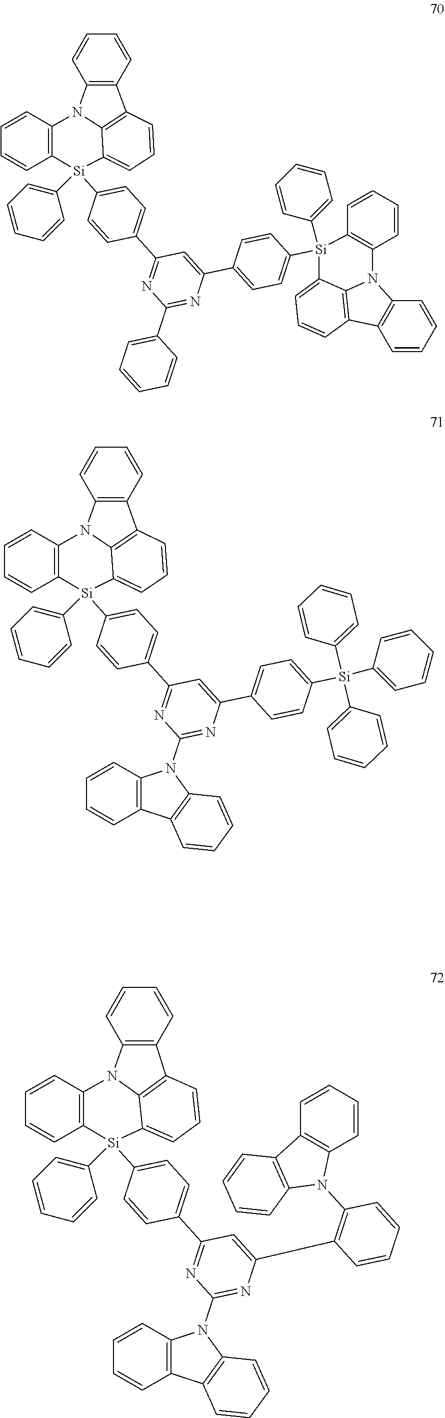 [SMILES: c1ccc(-c2nc(-c3ccc([Si]4(c5ccccc5)c5ccccc5-n5c6ccccc6c6cccc4c65)cc3)cc(-c3ccc([Si]4(c5ccccc5)c5ccccc5-n5c6ccccc6c6cccc4c65)cc3)n2)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-n4c5ccccc5c5ccccc54)n3)cc2)cc1 ; c1ccc([Si]2(c3ccc(-c4cc(-c5ccccc5-n5c6ccccc6c6ccccc65)nc(-n5c6ccccc6c6ccccc65)n4)cc3)c3ccccc3-n3c4ccccc4c4cccc2c43)cc1] 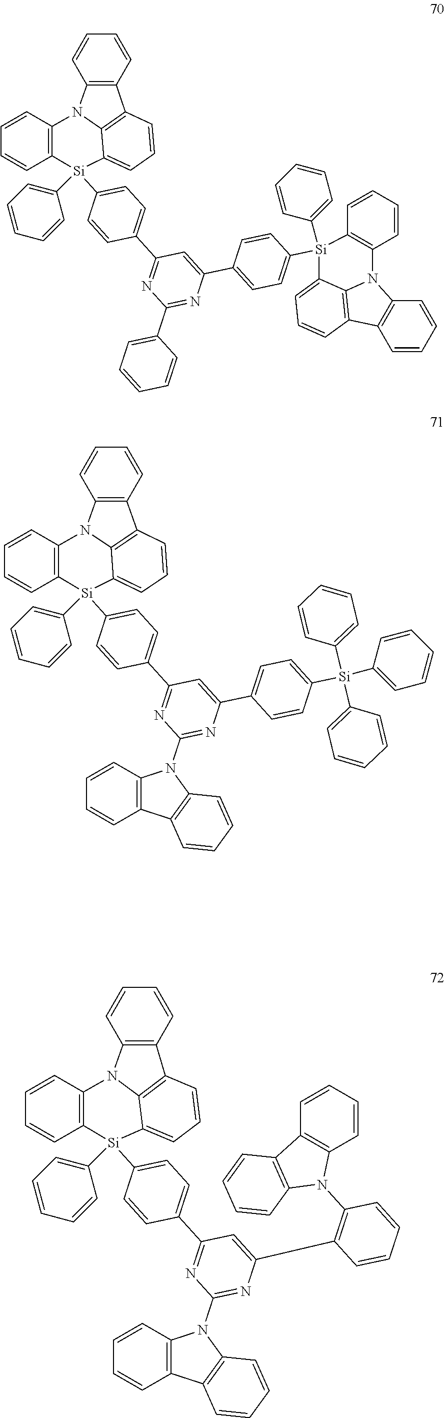 [SMILES: c1ccc(-c2nc(-c3ccc([Si]4(c5ccccc5)c5ccccc5-n5c6ccccc6c6cccc4c65)cc3)cc(-c3ccc([Si]4(c5ccccc5)c5ccccc5-n5c6ccccc6c6cccc4c65)cc3)n2)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-n4c5ccccc5c5ccccc54)n3)cc2)cc1 ; c1ccc([Si]2(c3ccc(-c4cc(-c5ccccc5-n5c6ccccc6c6ccccc65)nc(-n5c6ccccc6c6ccccc65)n4)cc3)c3ccccc3-n3c4ccccc4c4cccc2c43)cc1] 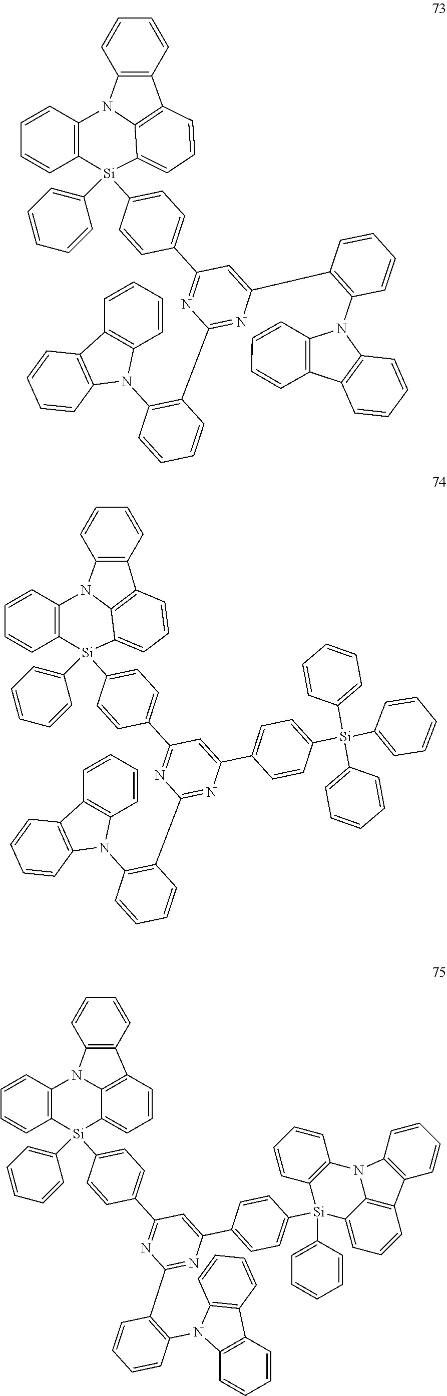 [SMILES: c1ccc([Si]2(c3ccc(-c4cc(-c5ccccc5-n5c6ccccc6c6ccccc65)nc(-c5ccccc5-n5c6ccccc6c6ccccc65)n4)cc3)c3ccccc3-n3c4ccccc4c4cccc2c43)cc1 ; c1ccc([Si](c2ccccc2)(c2ccccc2)c2ccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)cc2)cc1 ; c1ccc([Si]2(c3ccc(-c4cc(-c5ccc([Si]6(c7ccccc7)c7ccccc7-n7c8ccccc8c8cccc6c87)cc5)nc(-c5ccccc5-n5c6ccccc6c6ccccc65)n4)cc3)c3ccccc3-n3c4ccccc4c4cccc2c43)cc1] 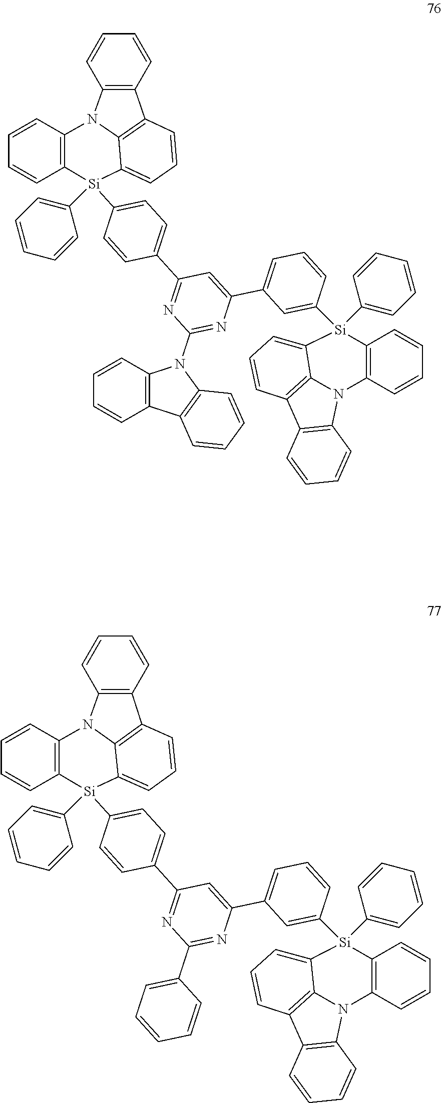 [SMILES: c1ccc([Si]2(c3ccc(-c4cc(-c5cccc([Si]6(c7ccccc7)c7ccccc7-n7c8ccccc8c8cccc6c87)c5)nc(-n5c6ccccc6c6ccccc65)n4)cc3)c3ccccc3-n3c4ccccc4c4cccc2c43)cc1 ; c1ccc(-c2nc(-c3ccc([Si]4(c5ccccc5)c5ccccc5-n5c6ccccc6c6cccc4c65)cc3)cc(-c3cccc([Si]4(c5ccccc5)c5ccccc5-n5c6ccccc6c6cccc4c65)c3)n2)cc1] 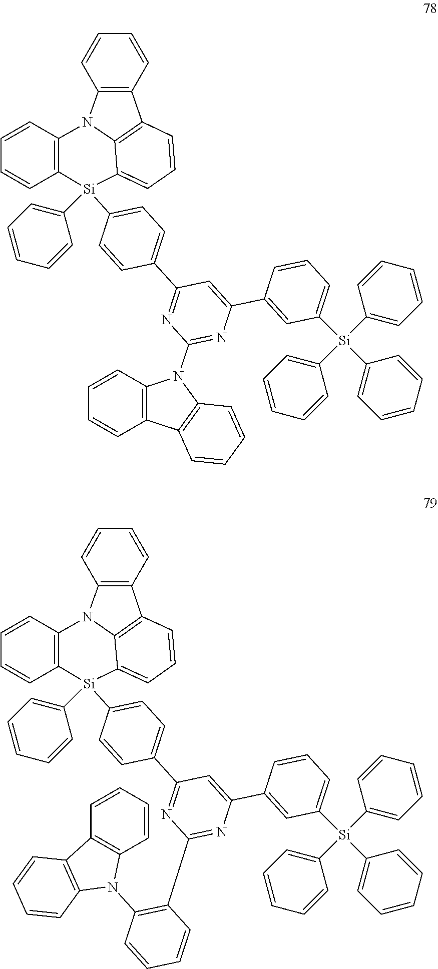 [SMILES: c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-n4c5ccccc5c5ccccc54)n3)c2)cc1 ; c1ccc([Si](c2ccccc2)(c2ccccc2)c2cccc(-c3cc(-c4ccc([Si]5(c6ccccc6)c6ccccc6-n6c7ccccc7c7cccc5c76)cc4)nc(-c4ccccc4-n4c5ccccc5c5ccccc54)n3)c2)cc1] 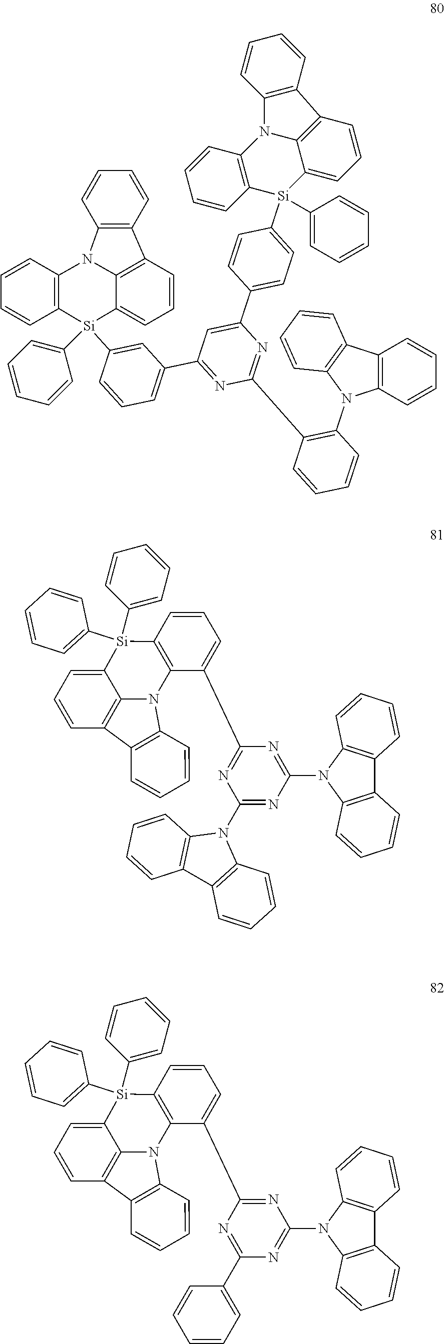 [SMILES: c1ccc([Si]2(c3ccc(-c4cc(-c5cccc([Si]6(c7ccccc7)c7ccccc7-n7c8ccccc8c8cccc6c87)c5)nc(-c5ccccc5-n5c6ccccc6c6ccccc65)n4)cc3)c3ccccc3-n3c4ccccc4c4cccc2c43)cc1 ; c1ccc([Si]2(c3ccccc3)c3cccc(-c4nc(-n5c6ccccc6c6ccccc65)nc(-n5c6ccccc6c6ccccc65)n4)c3-n3c4ccccc4c4cccc2c43)cc1 ; c1ccc(-c2nc(-c3cccc4c3-n3c5ccccc5c5cccc(c53)[Si]4(c3ccccc3)c3ccccc3)nc(-n3c4ccccc4c4ccccc43)n2)cc1] 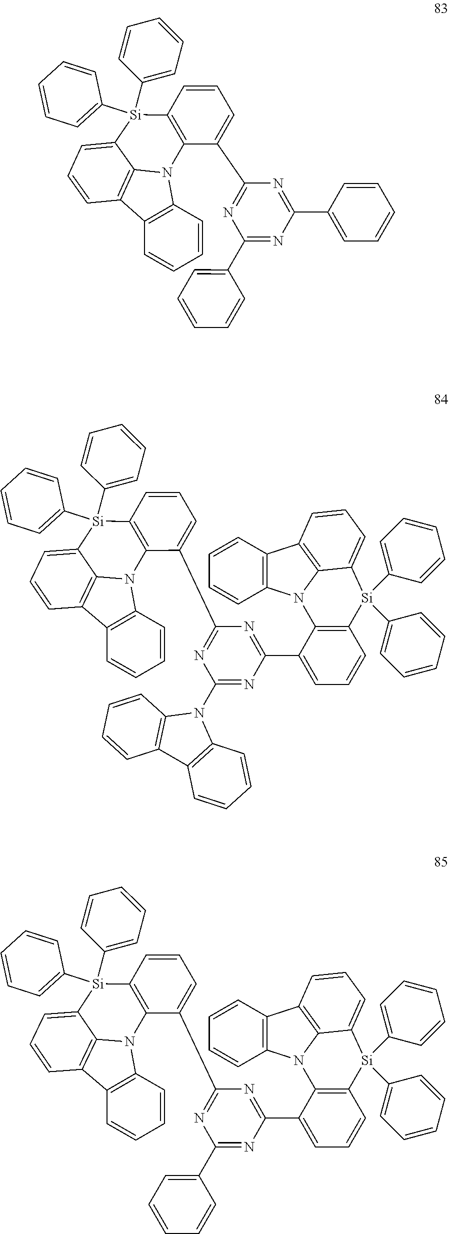 [SMILES: c1ccc(-c2nc(-c3ccccc3)nc(-c3cccc4c3-n3c5ccccc5c5cccc(c53)[Si]4(c3ccccc3)c3ccccc3)n2)cc1 ; c1ccc([Si]2(c3ccccc3)c3cccc(-c4nc(-c5cccc6c5-n5c7ccccc7c7cccc(c75)[Si]6(c5ccccc5)c5ccccc5)nc(-n5c6ccccc6c6ccccc65)n4)c3-n3c4ccccc4c4cccc2c43)cc1 ; c1ccc(-c2nc(-c3cccc4c3-n3c5ccccc5c5cccc(c53)[Si]4(c3ccccc3)c3ccccc3)nc(-c3cccc4c3-n3c5ccccc5c5cccc(c53)[Si]4(c3ccccc3)c3ccccc3)n2)cc1] 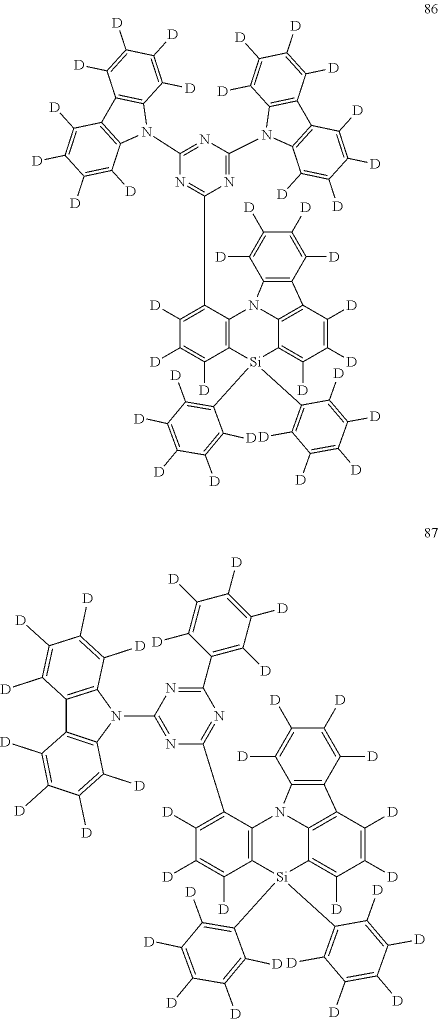 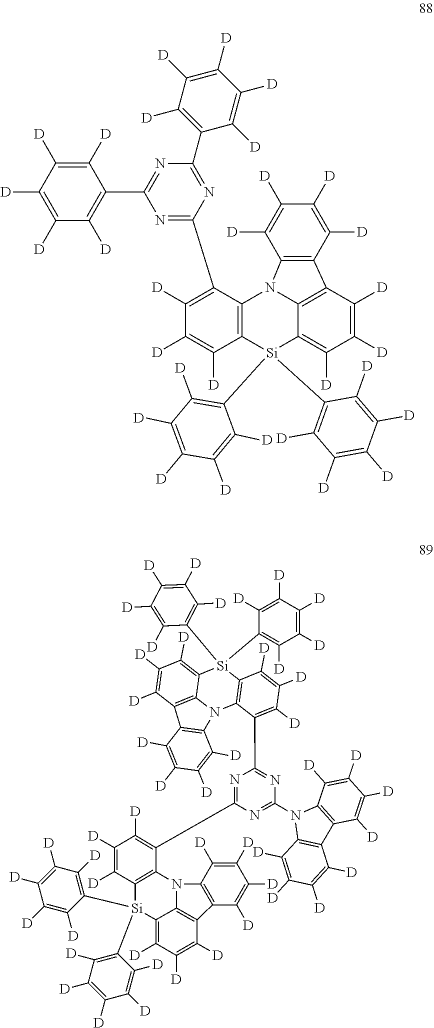 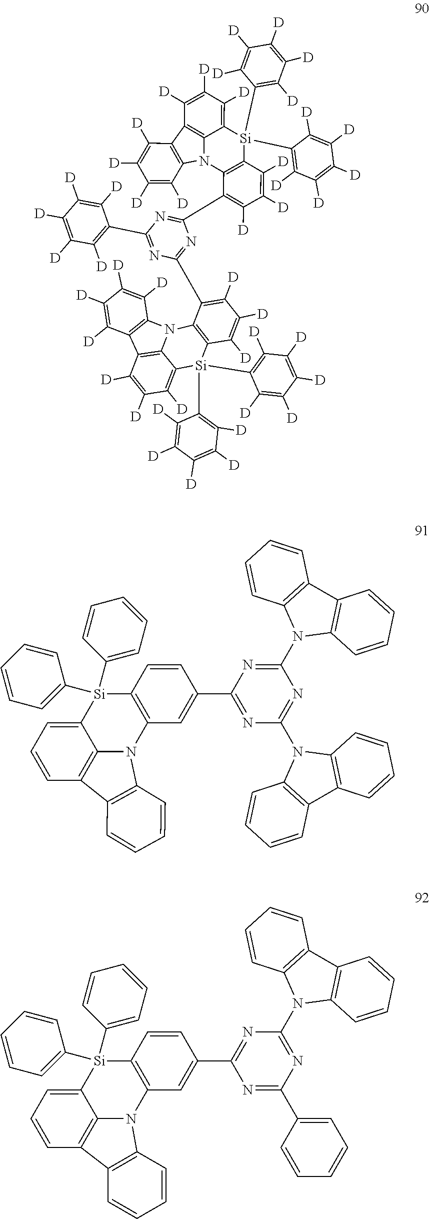 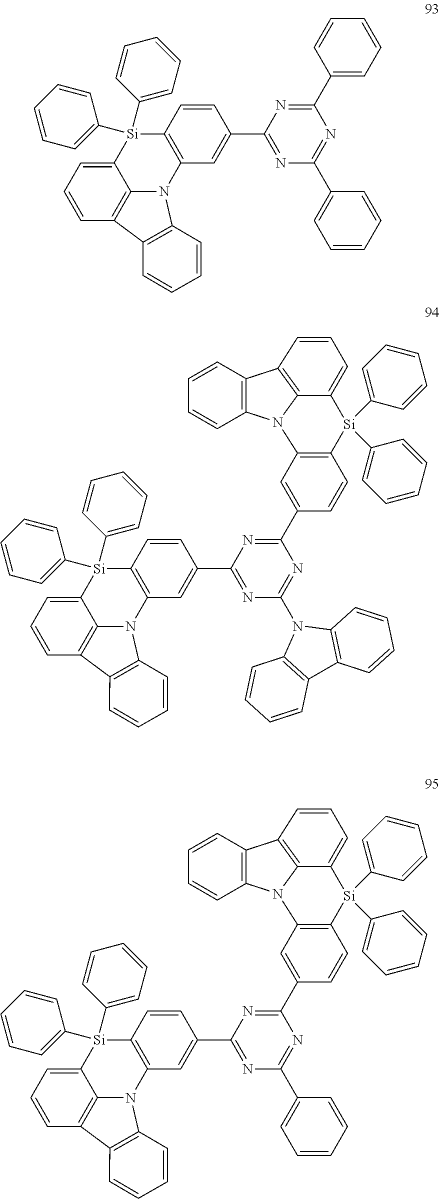 [SMILES: c1ccc(-c2nc(-c3ccccc3)nc(-c3ccc4c(c3)-n3c5ccccc5c5cccc(c53)[Si]4(c3ccccc3)c3ccccc3)n2)cc1 ; c1ccc([Si]2(c3ccccc3)c3ccc(-c4nc(-c5ccc6c(c5)-n5c7ccccc7c7cccc(c75)[Si]6(c5ccccc5)c5ccccc5)nc(-n5c6ccccc6c6ccccc65)n4)cc3-n3c4ccccc4c4cccc2c43)cc1 ; c1ccc(-c2nc(-c3ccc4c(c3)-n3c5ccccc5c5cccc(c53)[Si]4(c3ccccc3)c3ccccc3)nc(-c3ccc4c(c3)-n3c5ccccc5c5cccc(c53)[Si]4(c3ccccc3)c3ccccc3)n2)cc1] 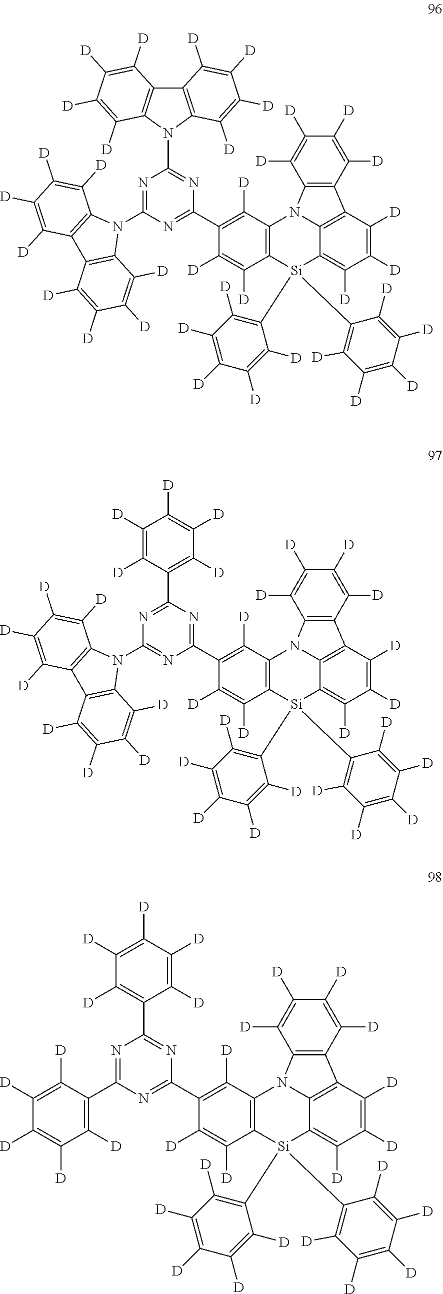 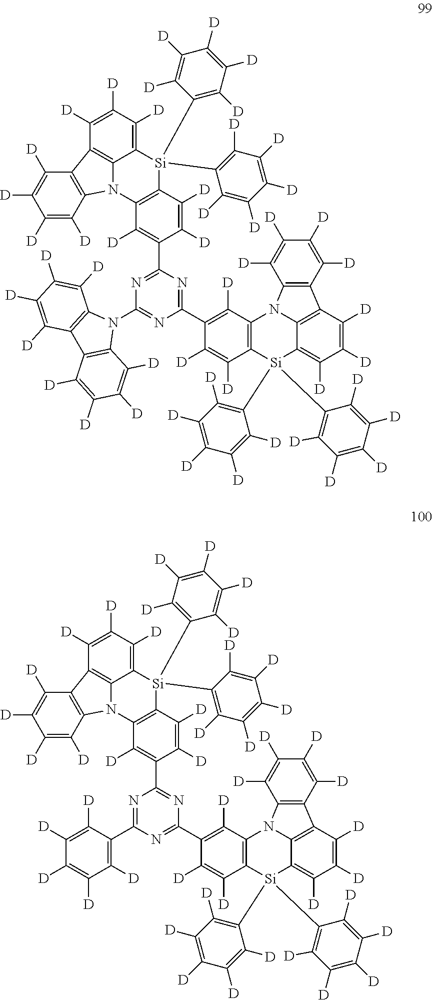 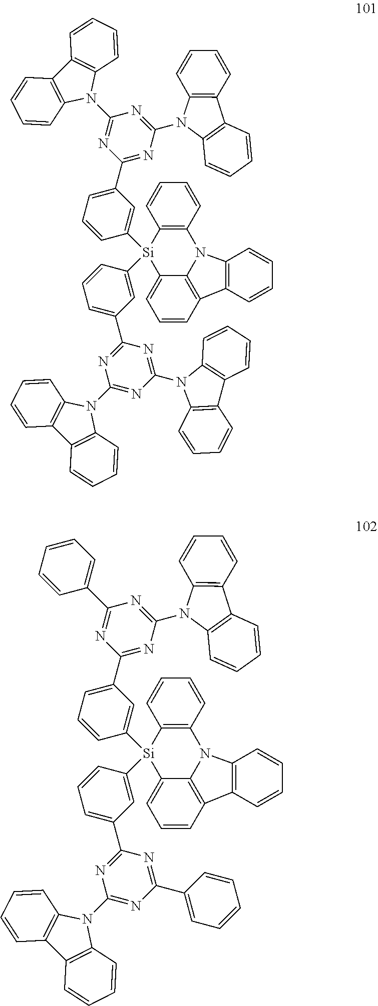 [SMILES: c1cc(-c2nc(-n3c4ccccc4c4ccccc43)nc(-n3c4ccccc4c4ccccc43)n2)cc([Si]2(c3cccc(-c4nc(-n5c6ccccc6c6ccccc65)nc(-n5c6ccccc6c6ccccc65)n4)c3)c3ccccc3-n3c4ccccc4c4cccc2c43)c1 ; c1ccc(-c2nc(-c3cccc([Si]4(c5cccc(-c6nc(-c7ccccc7)nc(-n7c8ccccc8c8ccccc87)n6)c5)c5ccccc5-n5c6ccccc6c6cccc4c65)c3)nc(-n3c4ccccc4c4ccccc43)n2)cc1] 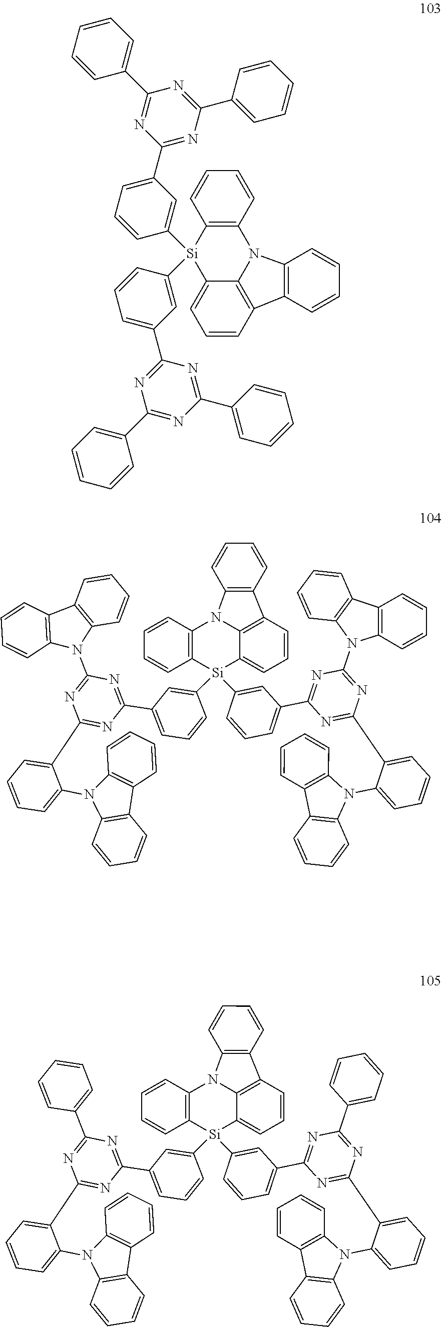 [SMILES: c1ccc(-c2nc(-c3ccccc3)nc(-c3cccc([Si]4(c5cccc(-c6nc(-c7ccccc7)nc(-c7ccccc7)n6)c5)c5ccccc5-n5c6ccccc6c6cccc4c65)c3)n2)cc1 ; c1cc(-c2nc(-c3ccccc3-n3c4ccccc4c4ccccc43)nc(-n3c4ccccc4c4ccccc43)n2)cc([Si]2(c3cccc(-c4nc(-c5ccccc5-n5c6ccccc6c6ccccc65)nc(-n5c6ccccc6c6ccccc65)n4)c3)c3ccccc3-n3c4ccccc4c4cccc2c43)c1 ; c1ccc(-c2nc(-c3cccc([Si]4(c5cccc(-c6nc(-c7ccccc7)nc(-c7ccccc7-n7c8ccccc8c8ccccc87)n6)c5)c5ccccc5-n5c6ccccc6c6cccc4c65)c3)nc(-c3ccccc3-n3c4ccccc4c4ccccc43)n2)cc1] 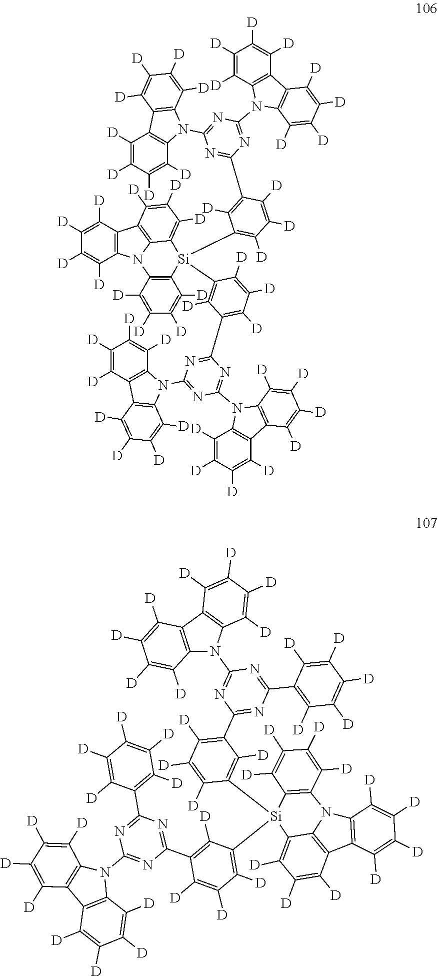 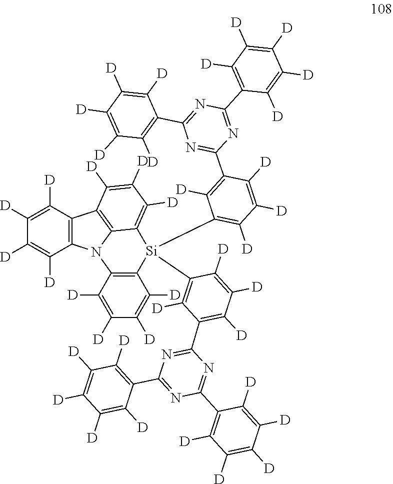 [SMILES: [2H]c1c([2H])c([2H])c(-c2nc(-c3c([2H])c([2H])c([2H])c([2H])c3[2H])nc(-c3c([2H])c([2H])c([2H])c([Si]4(c5c([2H])c([2H])c([2H])c(-c6nc(-c7c([2H])c([2H])c([2H])c([2H])c7[2H])nc(-c7c([2H])c([2H])c([2H])c([2H])c7[2H])n6)c5[2H])c5c([2H])c([2H])c([2H])c([2H])c5-n5c6c([2H])c([2H])c([2H])c([2H])c6c6c([2H])c([2H])c([2H])c4c65)c3[2H])n2)c([2H])c1[2H]] 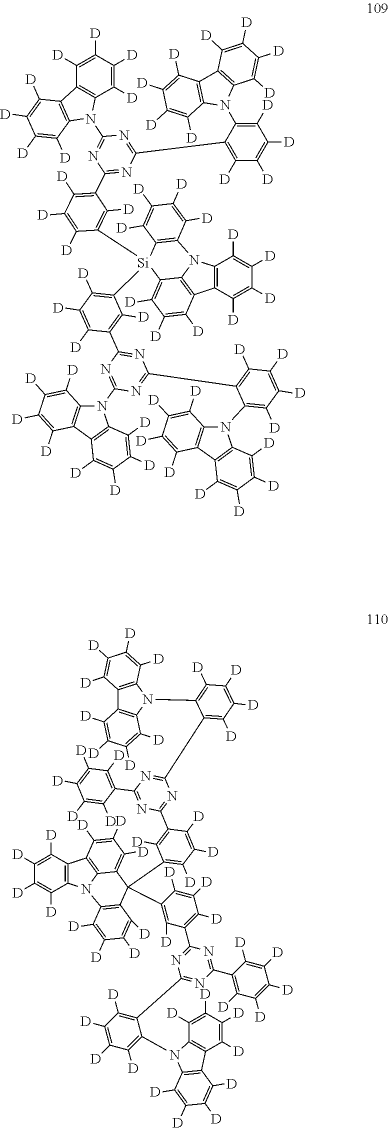 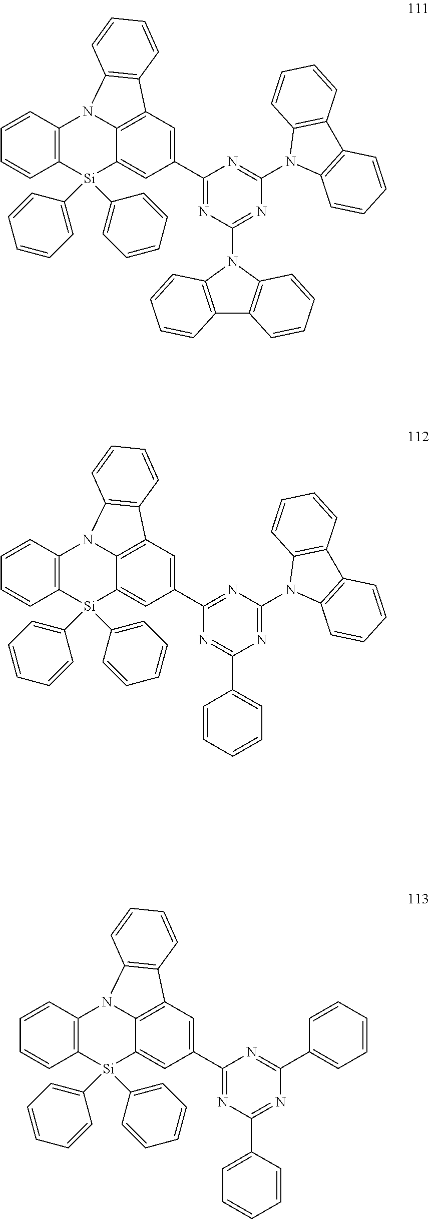 [SMILES: c1ccc([Si]2(c3ccccc3)c3ccccc3-n3c4ccccc4c4cc(-c5nc(-n6c7ccccc7c7ccccc76)nc(-n6c7ccccc7c7ccccc76)n5)cc2c43)cc1 ; c1ccc(-c2nc(-c3cc4c5c(c3)c3ccccc3n5-c3ccccc3[Si]4(c3ccccc3)c3ccccc3)nc(-n3c4ccccc4c4ccccc43)n2)cc1 ; c1ccc(-c2nc(-c3ccccc3)nc(-c3cc4c5c(c3)c3ccccc3n5-c3ccccc3[Si]4(c3ccccc3)c3ccccc3)n2)cc1] 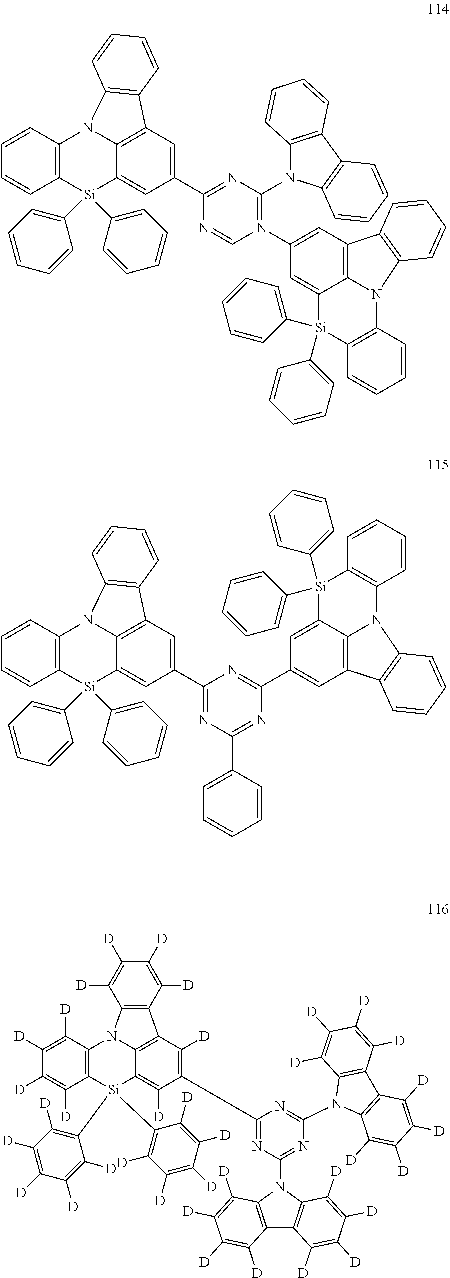 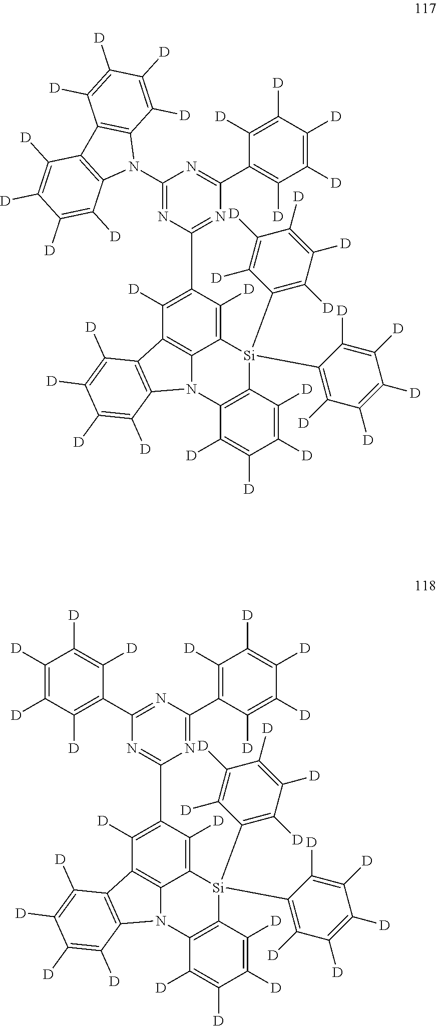 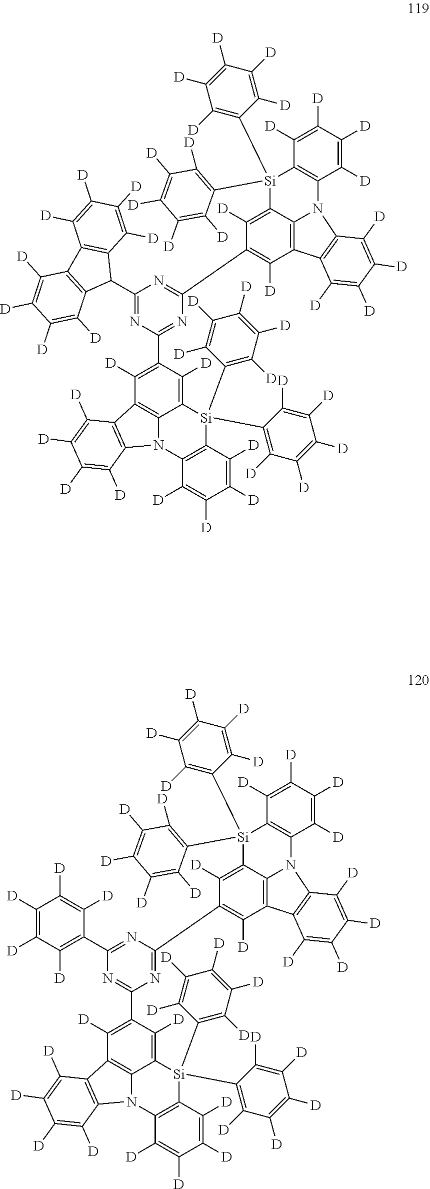 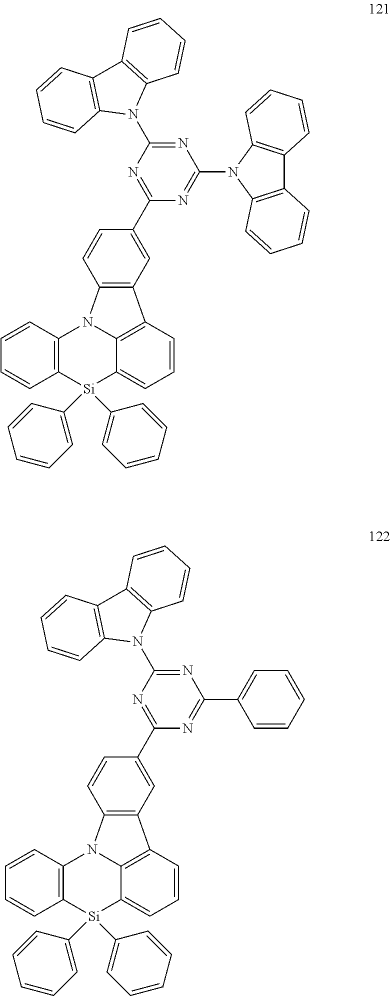 [SMILES: c1ccc([Si]2(c3ccccc3)c3ccccc3-n3c4ccc(-c5nc(-n6c7ccccc7c7ccccc76)nc(-n6c7ccccc7c7ccccc76)n5)cc4c4cccc2c43)cc1 ; c1ccc(-c2nc(-c3ccc4c(c3)c3cccc5c3n4-c3ccccc3[Si]5(c3ccccc3)c3ccccc3)nc(-n3c4ccccc4c4ccccc43)n2)cc1] 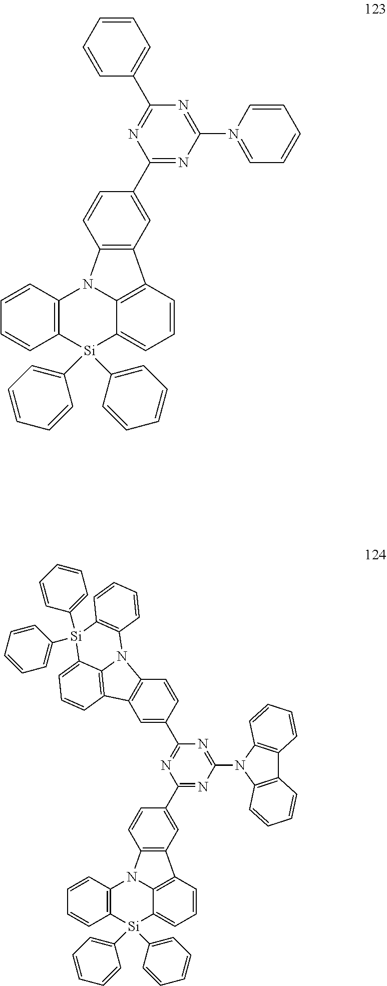 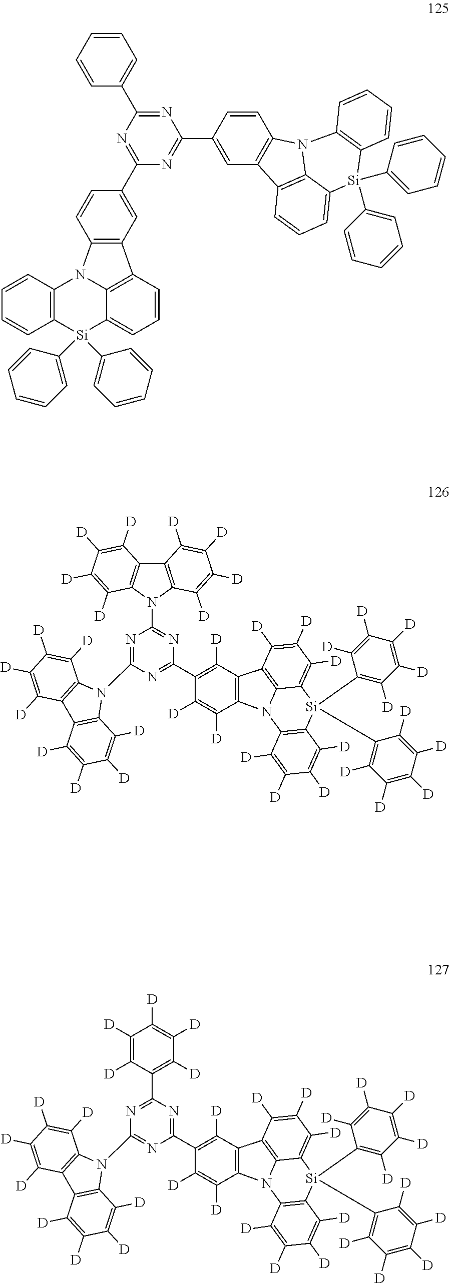 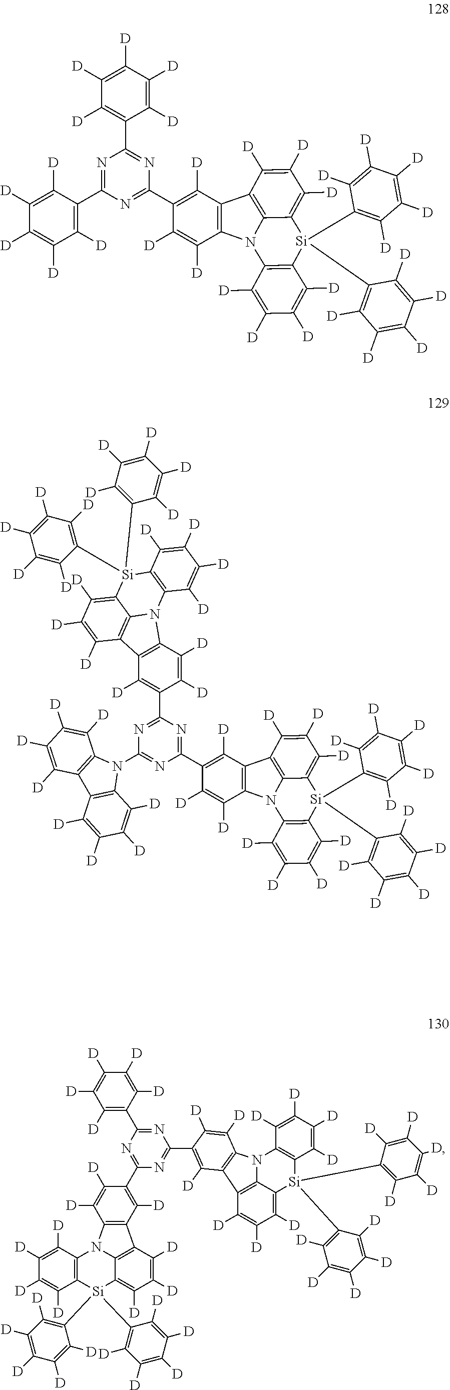
where, in Compound Group 1, D is a deuterium atom.

19. A display device comprising:
a base layer;
a circuit layer on the base layer; and
a display device layer on the circuit layer and comprising a light-emitting element,
the light-emitting element comprising:
a first electrode;
a second electrode facing the first electrode; and
an emission layer between the first electrode and the second electrode and comprising a polycyclic compound represented by Formula 1: 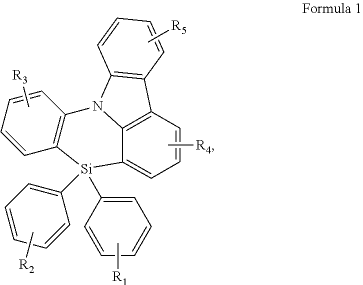
in Formula 1,
at least one selected from among R₁ to R₅ is represented by Formula 2, and any remaining selected from among R₁ to R₅ are each a hydrogen atom or a deuterium atom: 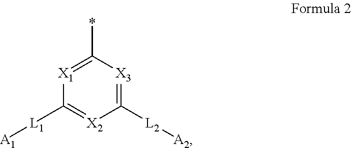
in Formula 2,
X₁ to X₃ are each independently N, CH, or CD,
at least two selected from among X₁ to X₃ are each N,
L₁ and L₂ are each independently a direct linkage, a substituted or unsubstituted arylene group having 6 to 30 ring-forming carbon atoms, or a substituted or unsubstituted heteroarylene group having 3 to 30 ring-forming carbon atoms,
A₁ and A₂ are each independently a substituted or unsubstituted aryl group having 6 to 30 ring-forming carbon atoms, a substituted or unsubstituted heterocyclic group having 3 to 30 ring-forming carbon atoms, or a substituted or unsubstituted silyl group, and 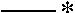 [SMILES: *C]
is a portion connected to Formula 1.

20. The display device of claim 19, wherein the light-emitting element is configured to emit blue light.
